(19) United States
(12) Patent Application Publication
(10) Pub. No.: US 2026/0262438 A1
(43) Pub. Date: Sep. 3, 2026

(54) METAL COMPLEX AND ORGANIC ELECTROLUMINESCENT DEVICE

(71) Applicant: SHENZHEN UNIVERSITY, Shenzhen, Guangdong (CN)

(72) Inventors: Kai LI, Shenzhen (CN); Jiangong YANG, Shenzhen (CN); Chuluo YANG, Shenzhen (CN)

(73) Assignee: SHENZHEN UNIVERSITY, Shenzhen, Guangdong (CN)

(21) Appl. No.: 18/725,729

(22) PCT Filed: Jun. 29, 2023
(86) PCT No.: PCT/CN2023/104046

§ 371 Date: Jun. 28, 2024

(30) Foreign Application Priority Data
Apr. 21, 2023 (CN) 202310461167.7

(51) Int. Cl. H10K 85/30; C07F 15/00; C09K 11/06; H10K 50/12; H10K 101/20

(52) U.S. Cl. CPC H10K 85/346; C07F 15/006; C07F 15/0086; C09K 11/06; H10K 85/341; C09K 2211/1007; C09K 2211/1029; C09K 2211/1044; C09K 2211/1059; C09K 2211/185; H10K 50/12; H10K 2101/20

(57) ABSTRACT

The present application relates to the technical field of electronic materials, in particular to a metal complex and an organic electroluminescent device. The metal complex provided by the present application has the following structure:

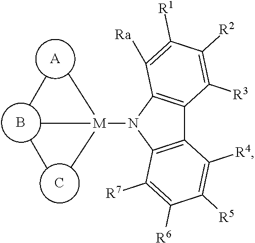

and thus the organic electroluminescent device containing the metal complex may have high external quantum efficiency and a long device life.

The present application claims priority to the Chinese patent application No. 202310461167.7 filed on Apr. 21, 2023 to the China Patent Office, and entitled “METAL COMPLEX AND ORGANIC ELECTROLUMINESCENT DEVICE”, the entire content of which is incorporated herein by reference.

### TECHNICAL FIELD

The present application relates to the technical field of electronic materials, in particular to a metal complex and an organic electroluminescent device.

### BACKGROUND

Organic light-emitting diodes (OLEDs) may convert electric energy into optical energy, have the characteristics of low driving voltage, low energy consumption, flexibility, short response time, wide using temperature range and the like, and have broad application prospects in the fields of industrial illumination, displays such as smart phones, and displaying on large-size televisions. Therefore, the emergence of the OLEDs has caused a great response in the industrial and academic circles, and the OLEDs are considered to be the dominant lighting and flat panel display technology in the future. An OLED device generally consists of two electrodes (anode and cathode) and several organic layers, such as a hole injection layer, hole and electron transport layers, and a light-emitting layer (EML) between the two electrodes. Under external voltage injection, opposite charge carriers of holes and electrons are injected from the anode and the cathode, ultimately recombining within the light-emitting layer to produce photons. The light-emitting layer can not only determine the performance of the device to a great extent, but also determine a processing method of the device, making it the most critical part of all components of an OLED.

In the past thirty years, luminescent materials have developed rapidly, transitioning from traditional fluorescent, phosphorescent, and triplet-triplet annihilation (TTA) materials to the era of third-generation thermally activated delayed fluorescence (TADF) materials. According to the spin-statistical distribution, when the OLED device is excited by an electric field, singlet excitons and triplet excitons with a ratio of 1:3 will be produced in the light-emitting layer. The different exciton utilization rates of different luminescent materials will lead to the difference in the efficiency of OLED devices. For example, the first generation of fluorescent materials could only utilize singlet excitons, resulting in a theoretical upper limit of only 25% for the internal quantum efficiency (i.e., exciton utilization rate), and maximum external quantum efficiency (the proportion of photons emitted by the light-emitting layer to injected charges) of only 5% of a fluorescent OLED. The second generation of OLED materials use a phosphorescent complex containing extremely rare precious metal iridium. Due to the simultaneous utilization of singlet excitons and triplet excitons, the theoretical internal quantum efficiency of the phosphorescent OLED may reach 100%. However, due to the high manufacturing cost and heavy metal pollution of precious metal phosphorescent materials, there are significant obstacles in the development of novel phosphorescent materials.

TADF materials may up-convert triplet excitons into singlet excitons through reverse inter system crossover (RISC), thus capturing triplet excitons and achieving 100% theoretical internal quantum efficiency. Compared with organic metal phosphorescent complex materials, the chemical design of organic TADF luminescent materials has the greater degree of freedom, and they exhibit the higher long-term stability and greater sustainability. The potential high efficiency, high design diversity, and environmental protection characteristics make the TADF materials the third generation of OLED device materials.

The TADF materials may be divided into pure organic materials and metal complex materials. The pure organic TADF materials usually have a long emission lifetime, and the efficiency of the device rolls-off severely under high brightness. The long emission lifetime is also considered a key reason for the poor stability of the OLED device.

However, a linear carbene-metal-amine complex has fewer types of ligands, short device lifetime and low efficiency, and still has problems in practical applications. A platinum (II) complex is widely used in phosphorescent OLED devices, but a platinum (II) complex TADF material is rarely developed, this is mainly due to a large spin orbital coupling constant of metal platinum (II), which leads to phosphorescent emission as the main emission; and on the other hand, some palladium (II) complex OLED devices have excellent performance, however, there are fewer literature reports on palladium (II) complex OLED materials, whether they are phosphorescent or TADF materials, and there is an urgent need to design a novel palladium (II) complex OLED system.

### SUMMARY OF THE INVENTION

Therefore, the technical problem to be solved by the present application is to overcome the defects that in the prior art, linear carbene-metal-amine complex TADF materials have low performance, and a prepared organic electroluminescent device is short in device lifetime and low in external quantum efficiency. Accordingly, a metal complex and an organic electroluminescent device are provided.

A solution adopted by the present application is as follows:
the present application provides a metal complex, having the following structure:

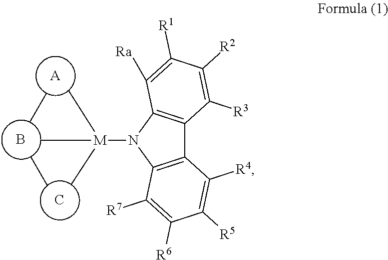

wherein M is selected from platinum or palladium, and an oxidation state of M is +2;
the ring A, the ring B and the ring C are each independently selected from a substituted or unsubstituted C₆-C₄₈ aromatic ring, and a substituted or unsubstituted C₄-C₄₈ heteroaromatic ring; the ring A and the ring B are interconnected by single bond connection or by forming a fused ring; the ring B and the ring C are interconnected by single bond connection or by forming a fused ring; and the ring A, the ring B and the ring C together form a negative monovalent tridentate ligand in coordination with the metal M at the center;
R¹-R⁷ are the same or different and are each independently selected from hydrogen, a substituted or unsubstituted C₁-C₄₀ alkyl group, a substituted or unsubstituted C₆-C₄₈ aryl group and a substituted or unsubstituted C₃-C₄₈ heteroaryl group; and
Ra is a substituted or unsubstituted C₆-C₄₈ aryl group or a substituted or unsubstituted C₆-C₄₈ heteroaryl group.

Optionally, substituents for the substituted C₆-C₄₈ aromatic ring, the substituted C₄-C₄₈ heteroaromatic ring, the substituted C₁-C₄₀ alkyl group, the substituted C₆-C₄₈ aryl group and the substituted C₃-C₄₈ heteroaryl group are selected from one of deuterium, halogen, cyano, a C₁-C₆ alkyl group, a C₃-C₃₀ cycloalkyl group, a C₆-C₃₀ aryl group and a C₃-C₃₀ heteroaryl group.

In the present application, the oxidation state of M is +2.

Optionally, R¹, R³, R⁴, R⁶ and R⁷ are hydrogen, and R² and R⁵ are the same or different and are each independently selected from a substituted or unsubstituted C₁-C₄₀ alkyl group, a substituted or unsubstituted C₆-C₄₈ aryl group, and a substituted or unsubstituted C₃-C₄₈ heteroaryl group.

Optionally, the substituted C₁-C₄₀ alkyl group, the substituted C₆-C₄₈ aryl group and the substituted C₃-C₄₈ heteroaryl group are substituted by one or more substituents R_{b}; and each R_{b} is independently selected from hydrogen, halogen, cyano, a C₁-C₁₀ alkyl group and a C₆-C₃₀ aryl group.

Optionally, the C₁-C₄₀ alkyl group is selected from methyl, ethyl, n-propyl, isopropyl, n-butyl, isobutyl, sec-butyl and tert-butyl;
the C₁-C₁₀ alkyl group is selected from methyl, ethyl, n-propyl, isopropyl, n-butyl, isobutyl, sec-butyl and tert-butyl;
the C₆-C₄₈ aryl group is selected from phenyl, naphthyl and anthryl; and
the C₆-C₃₀ aryl group is selected from phenyl, naphthyl and anthryl.

Optionally,
the tridentate ligand formed by the ring A, the ring B and the ring C has any one of the following structures:

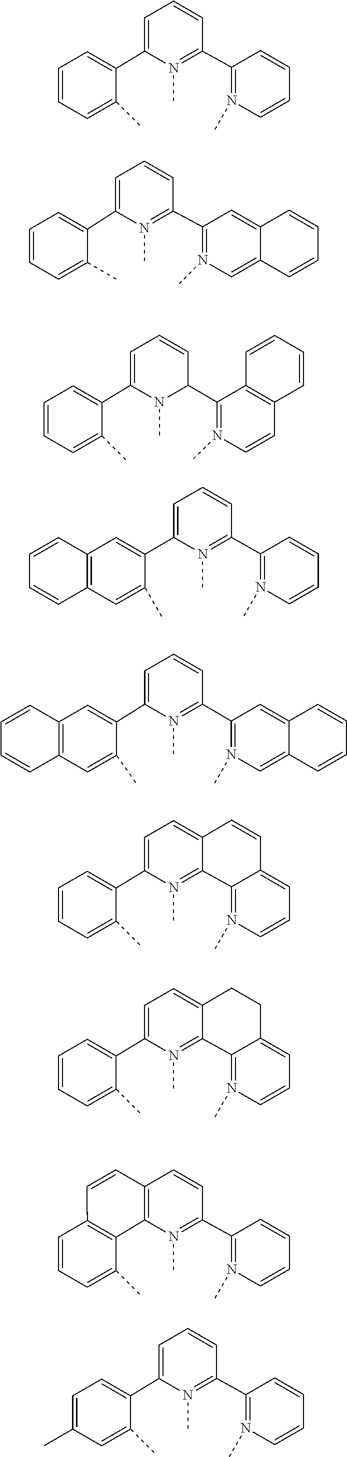

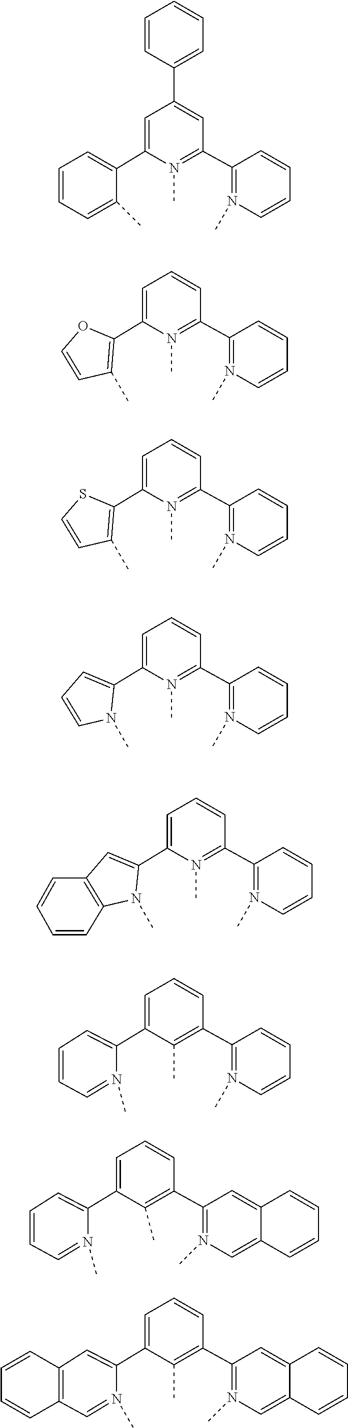

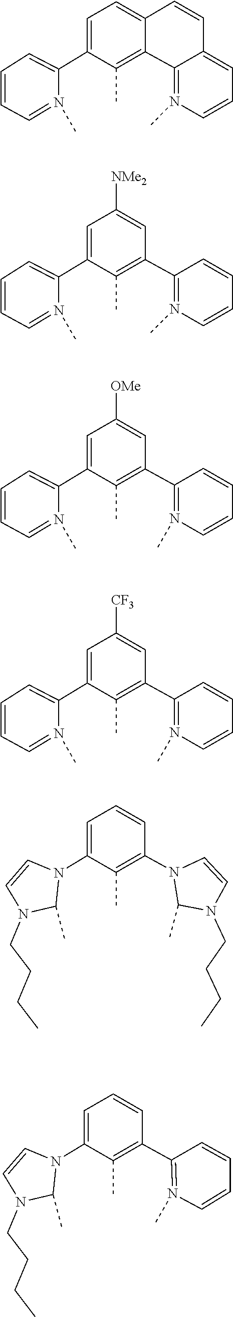

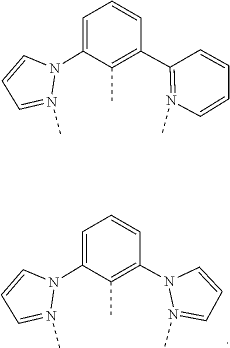

Optionally, Ra has any one of the following structures:

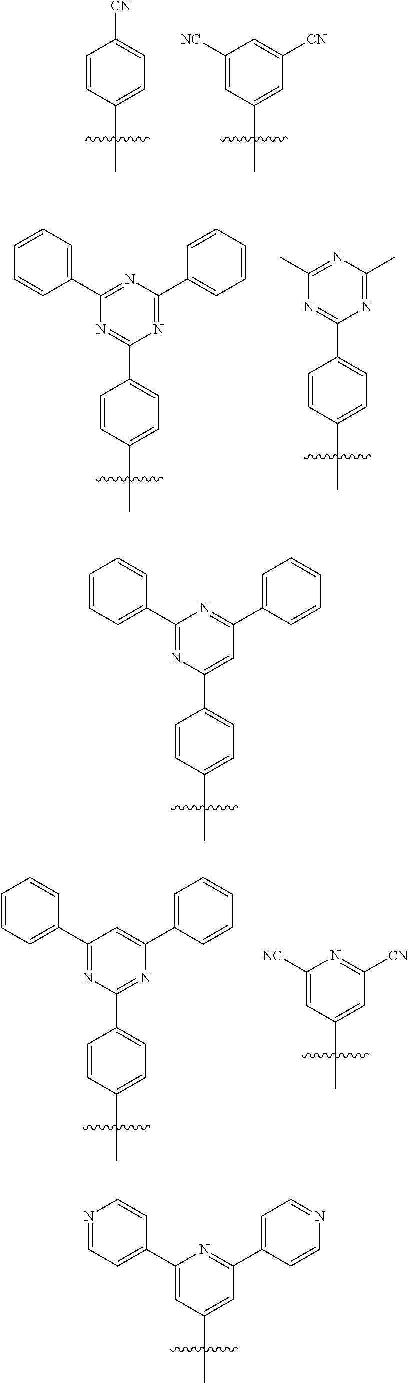

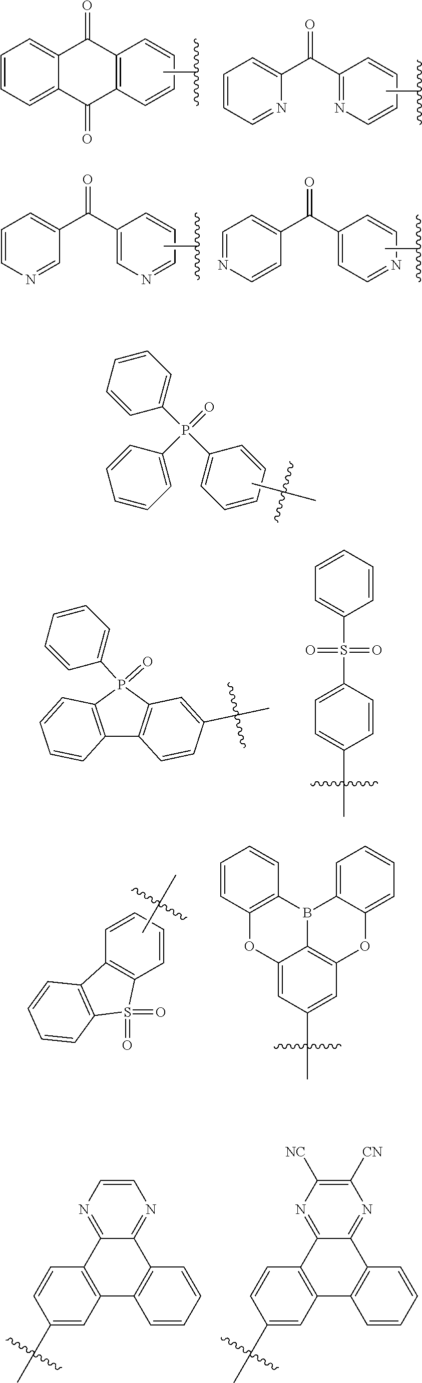

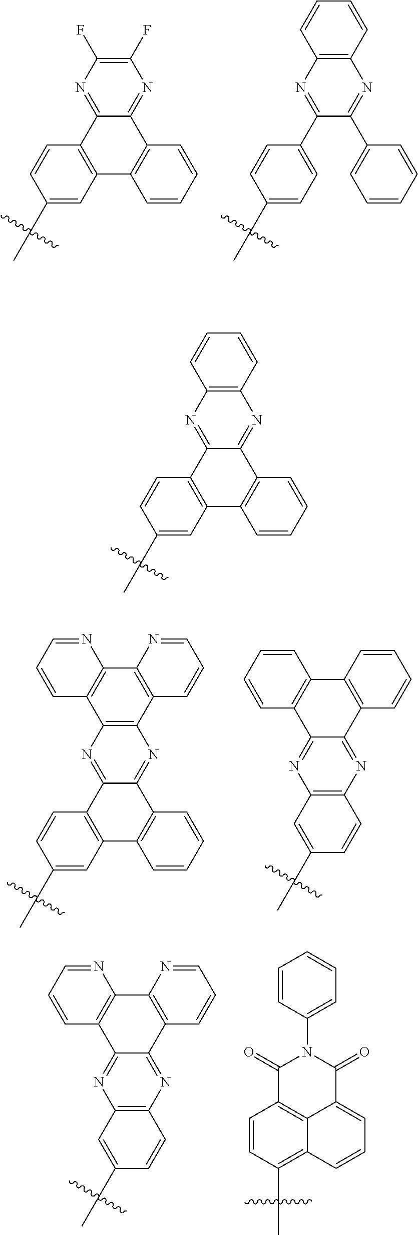

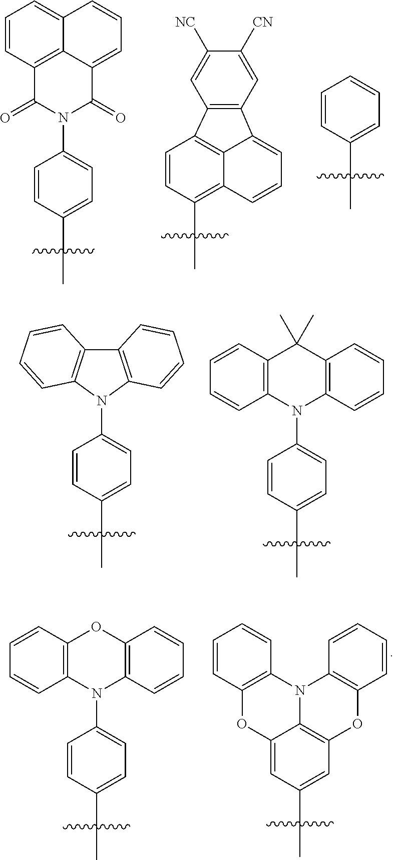

Optionally, the metal complex has any one of the following structures:

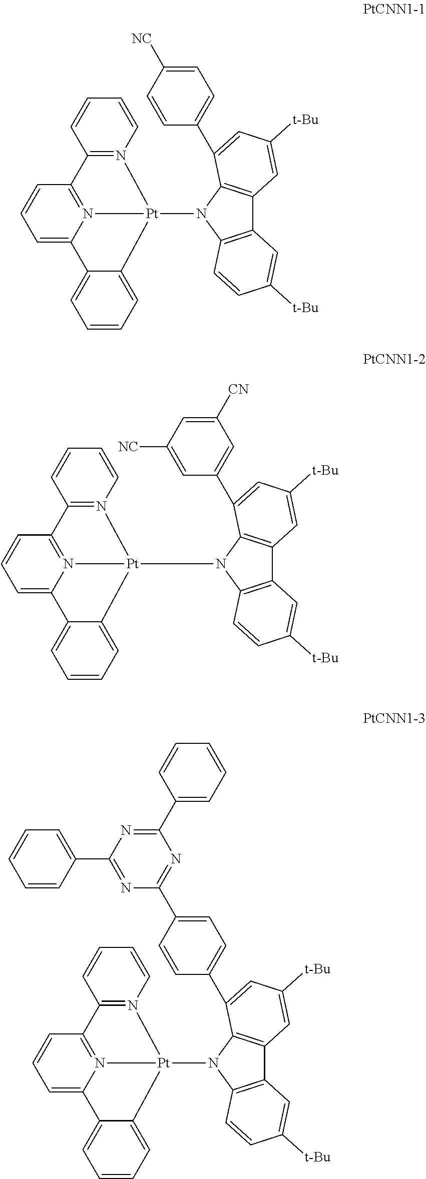

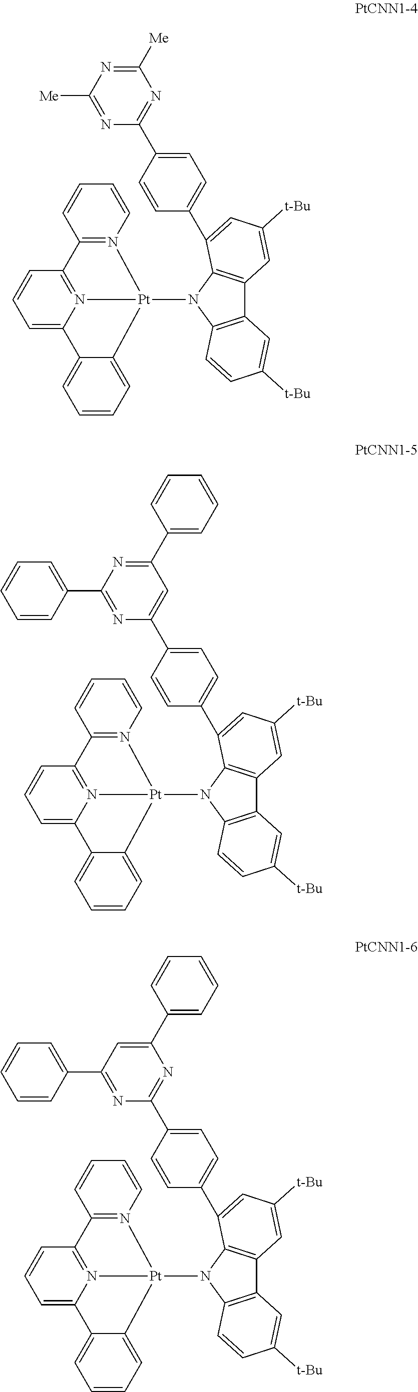

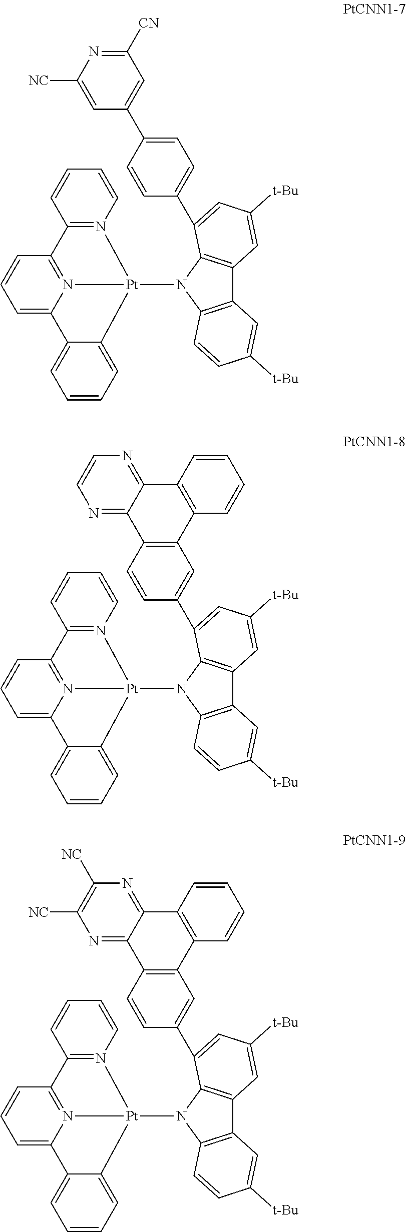

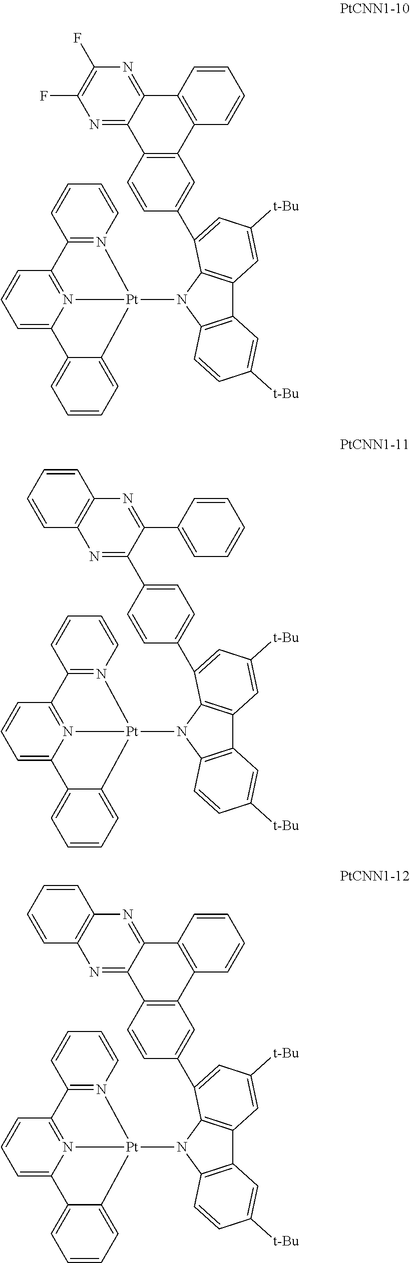

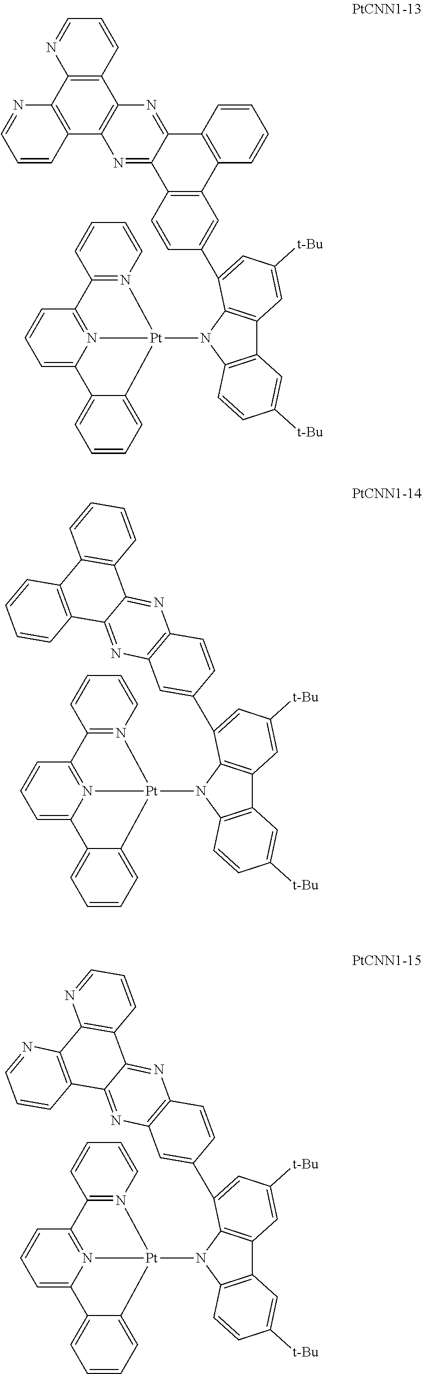

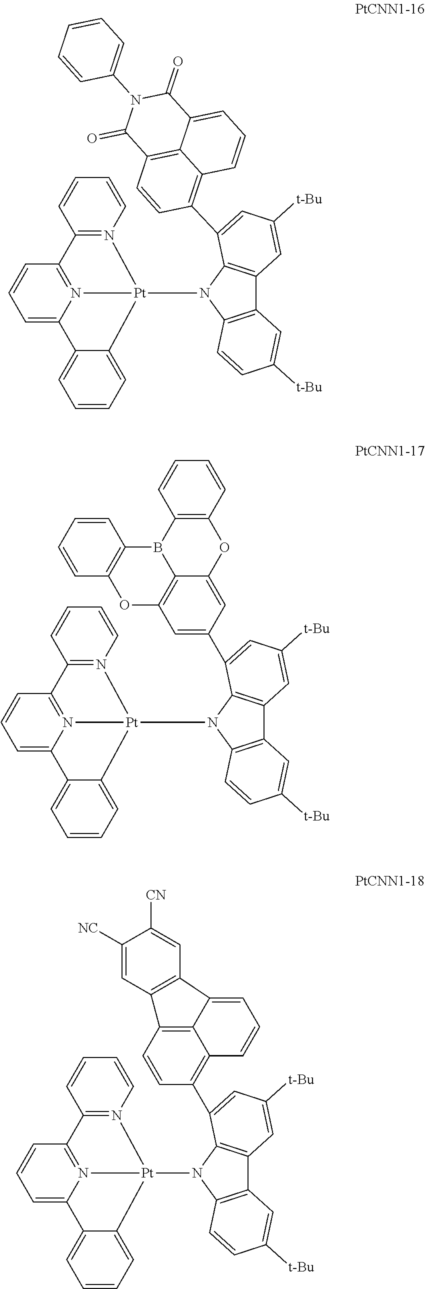

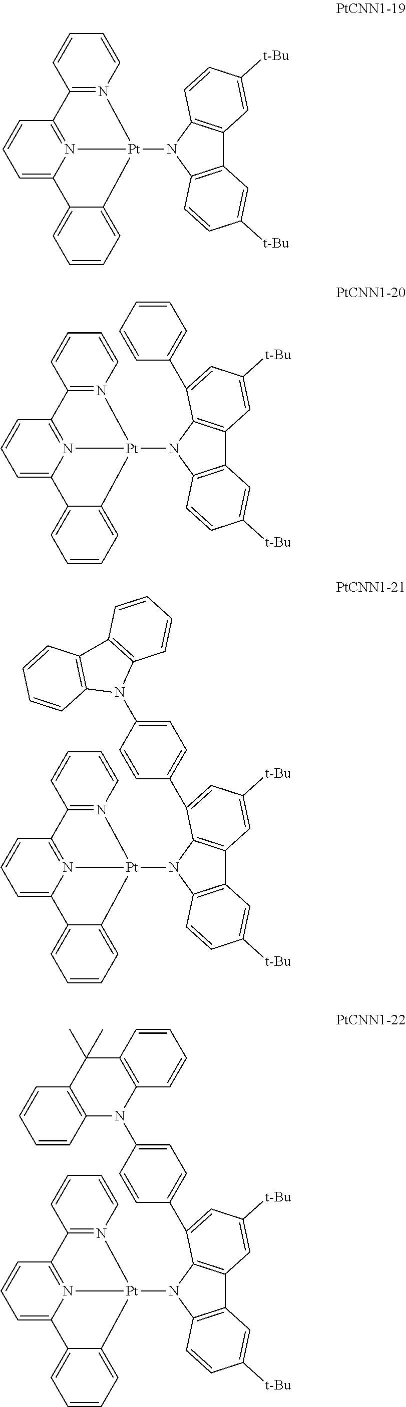

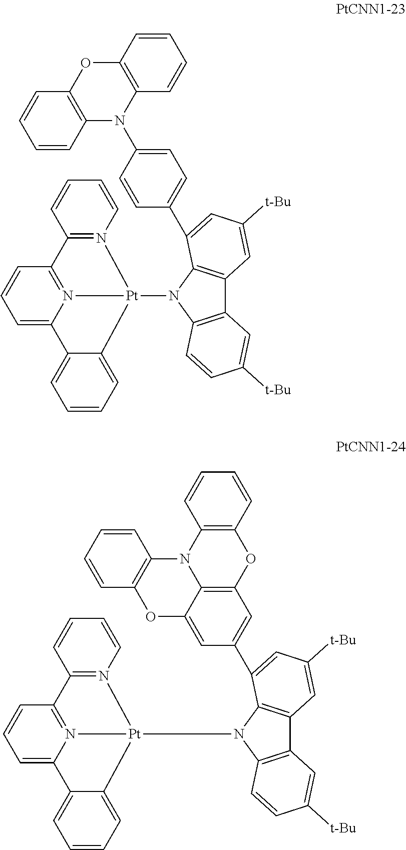

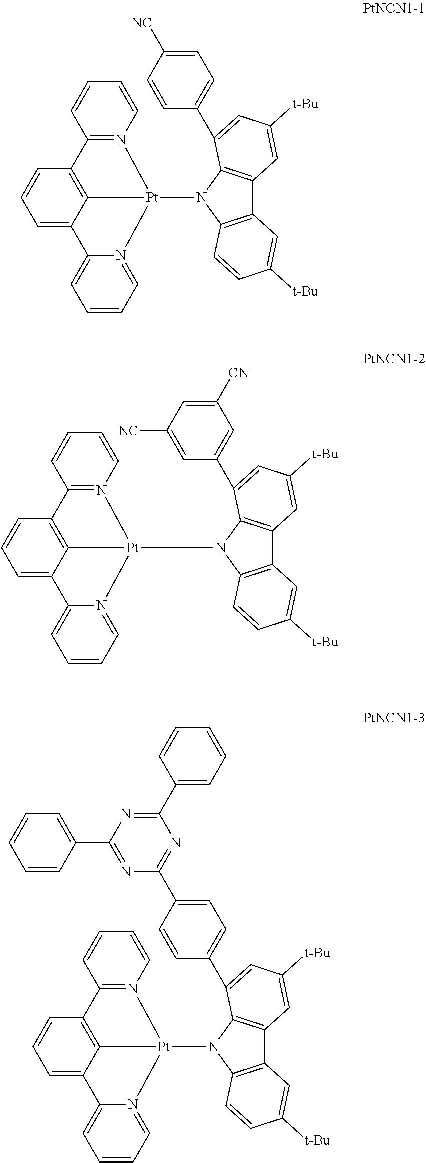

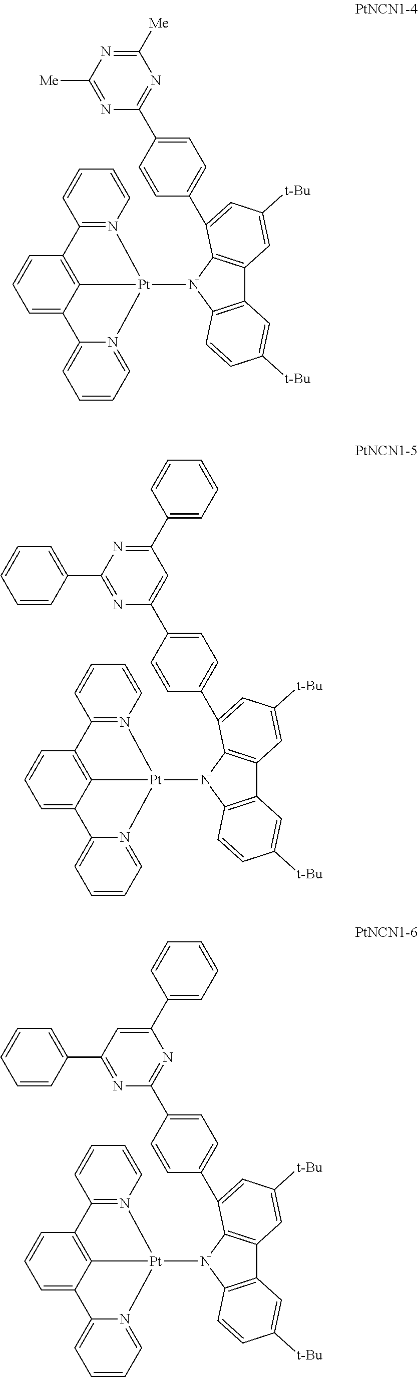

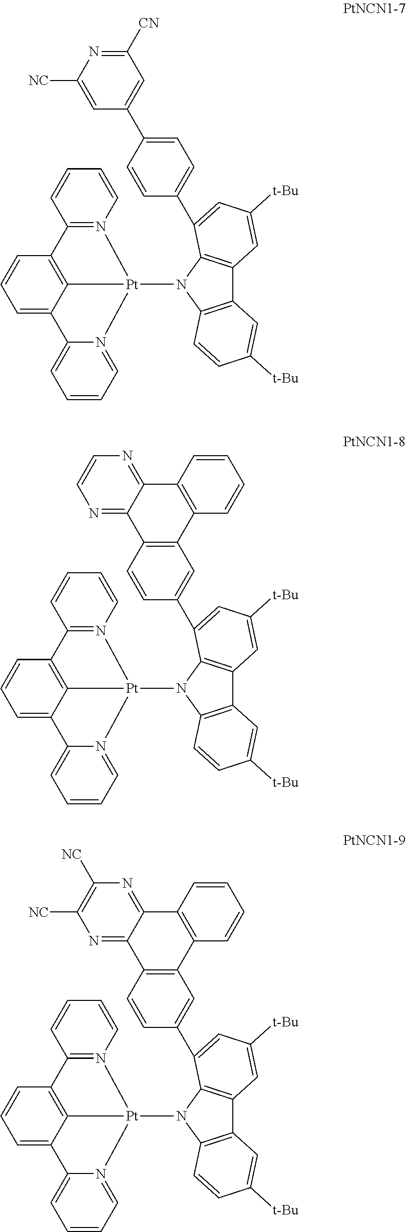

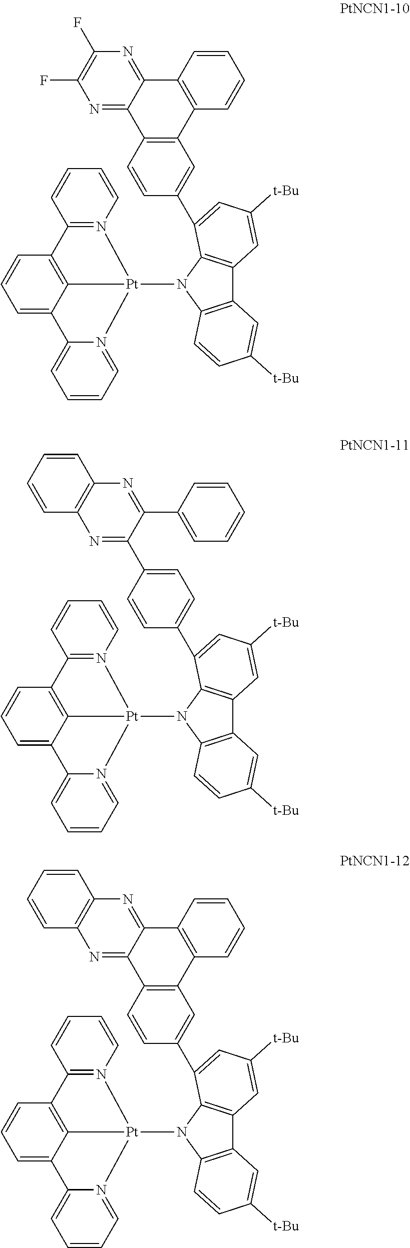

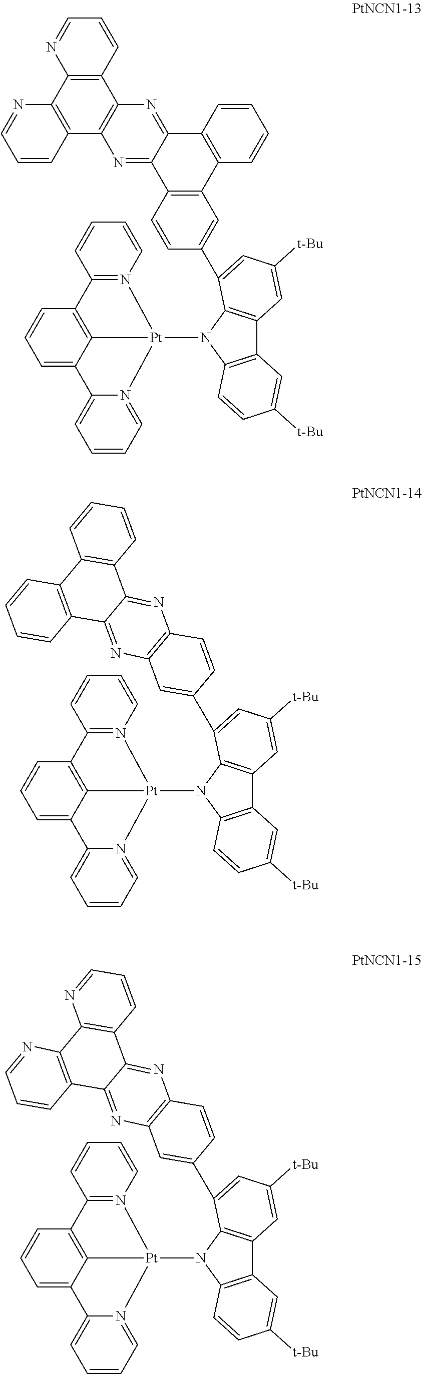

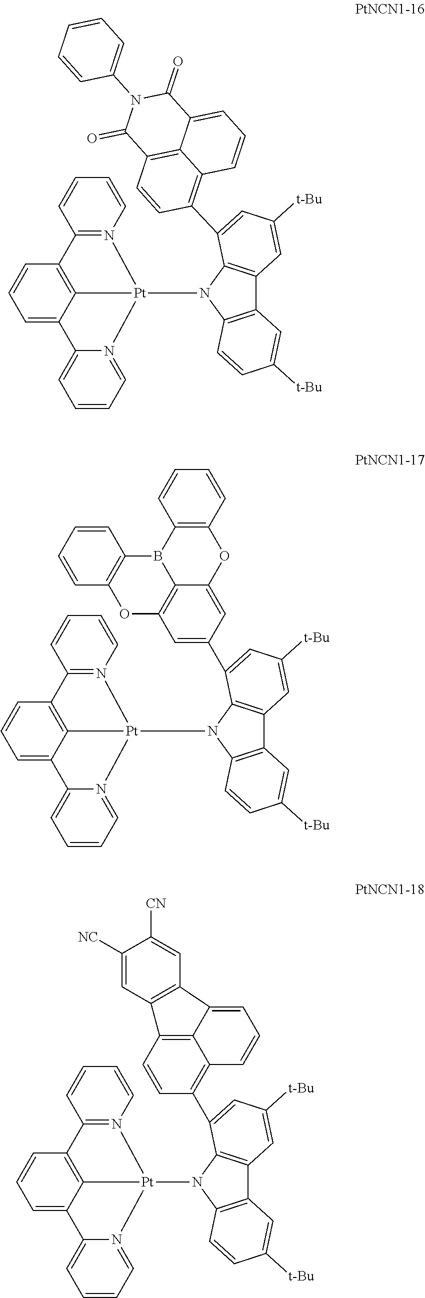

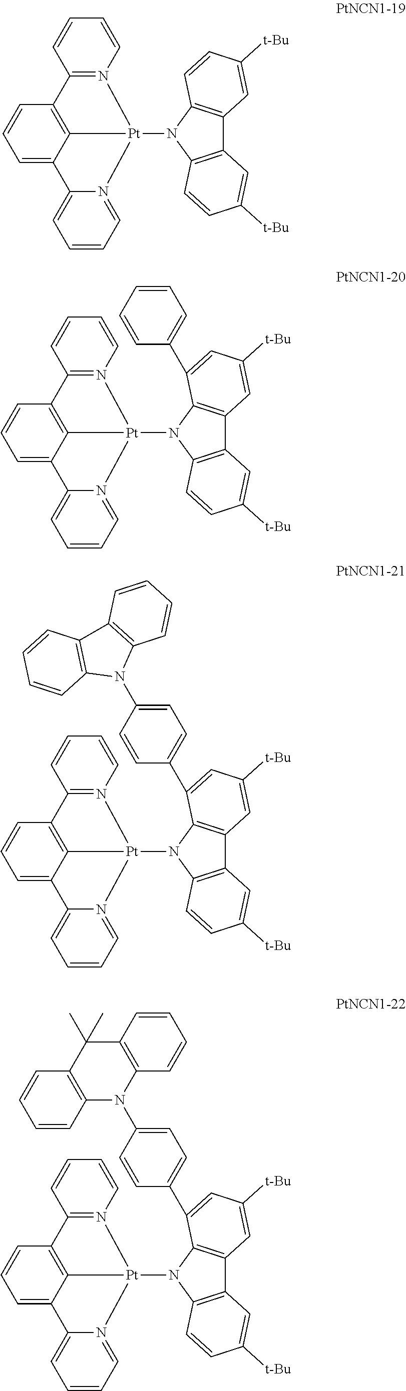

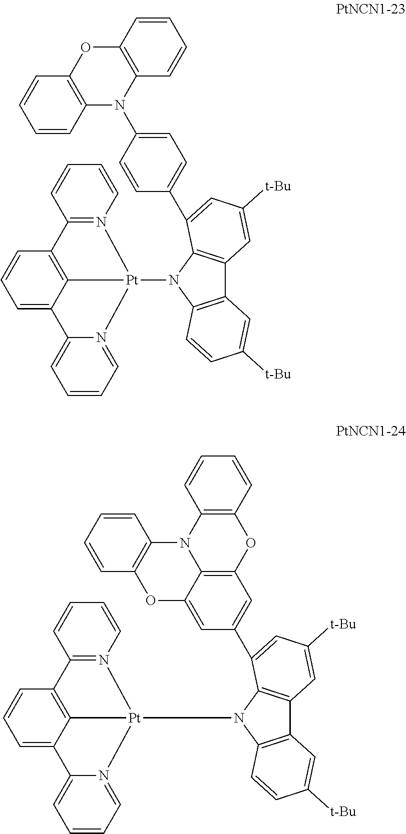

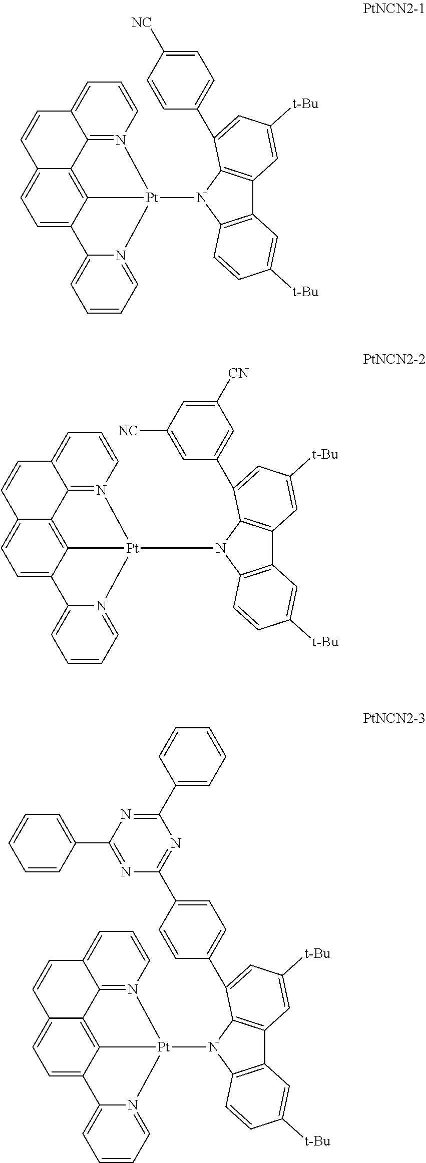

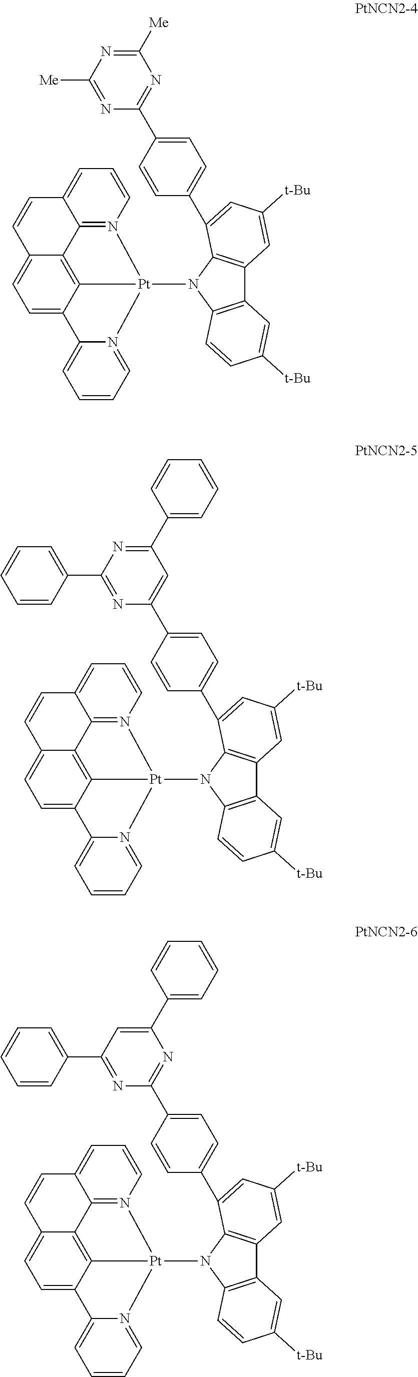

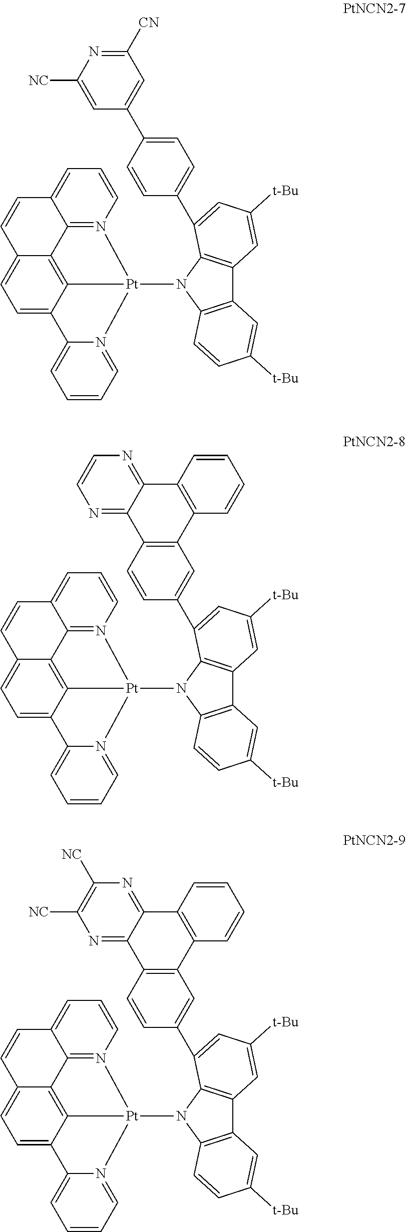

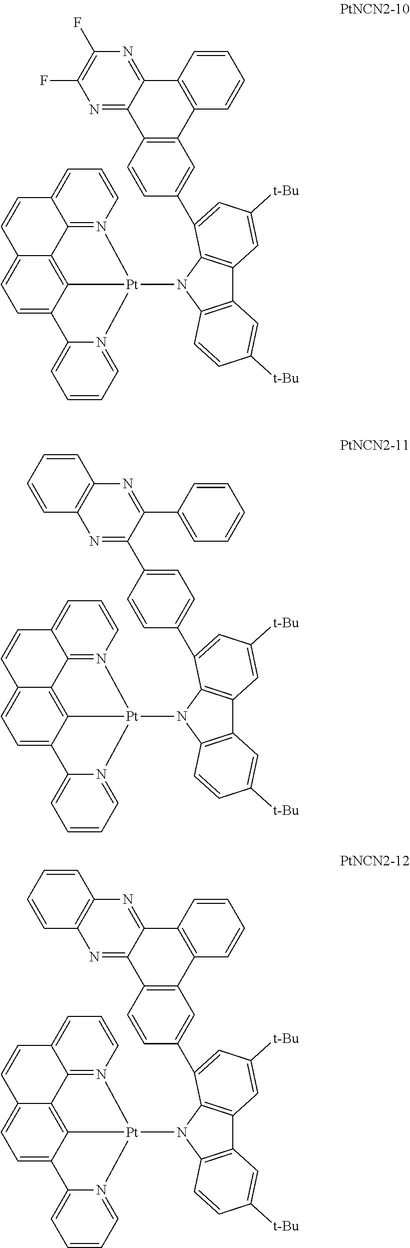

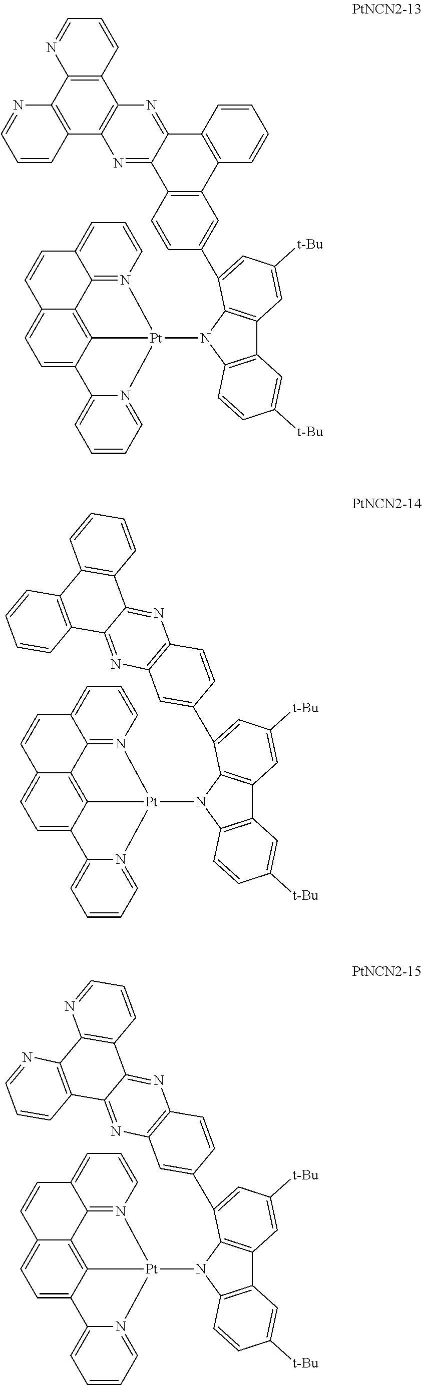

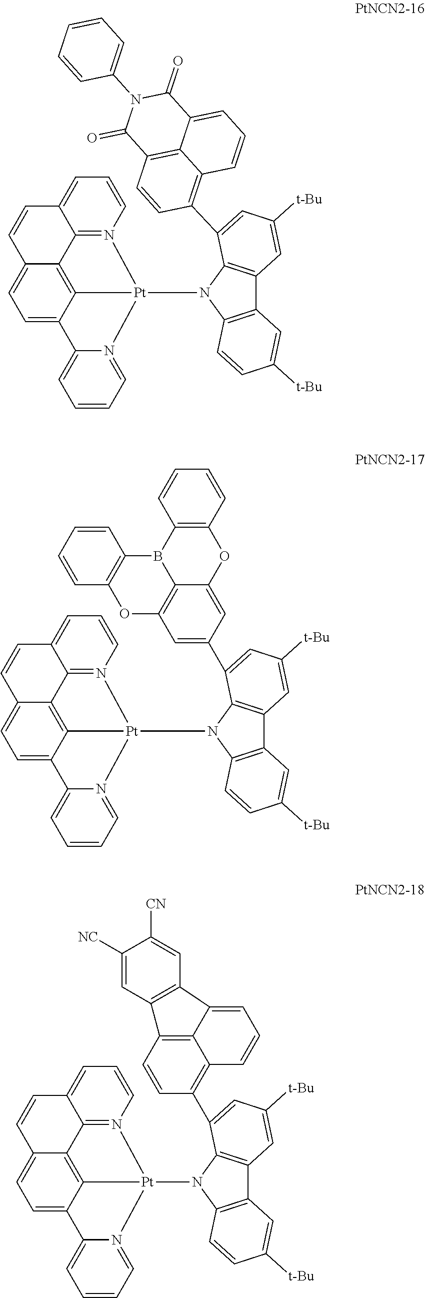

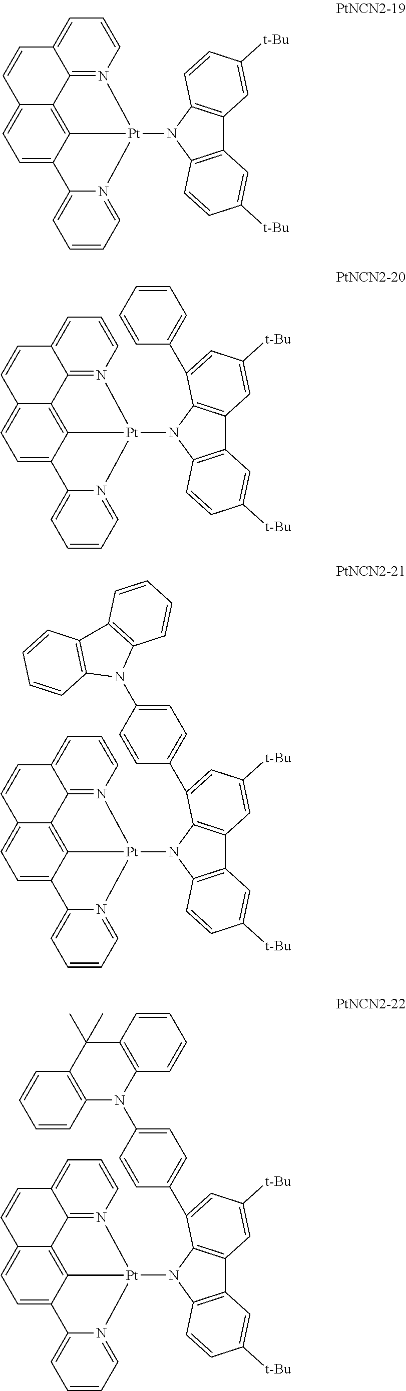

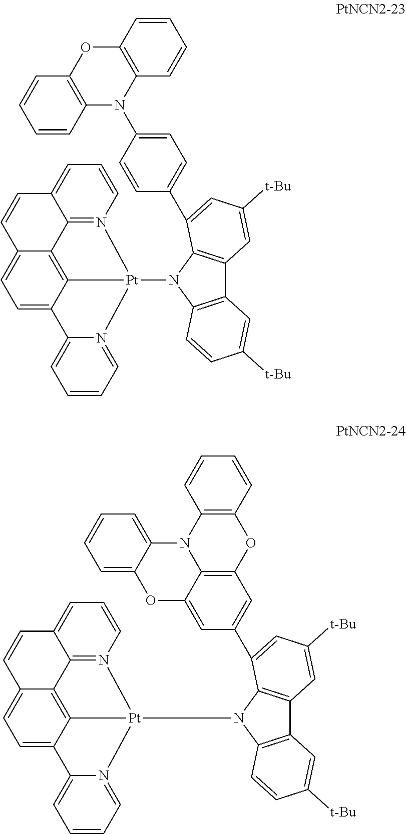

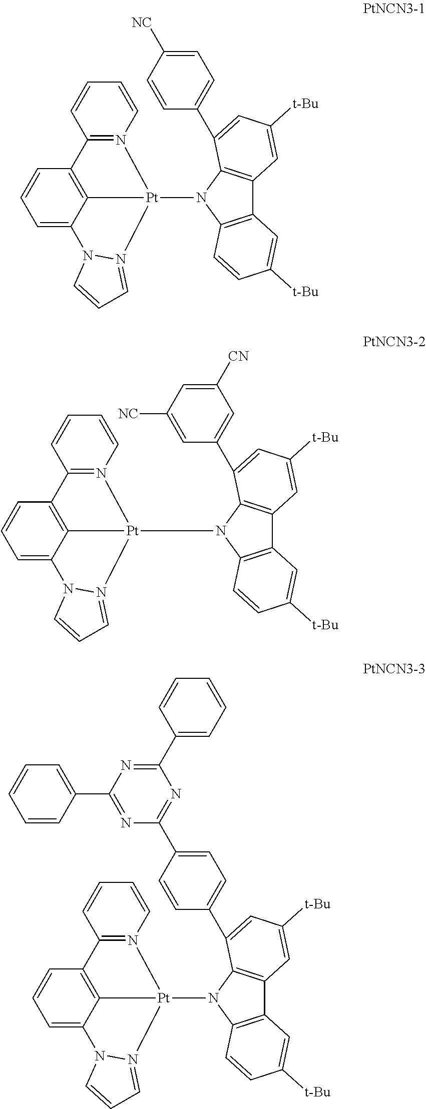

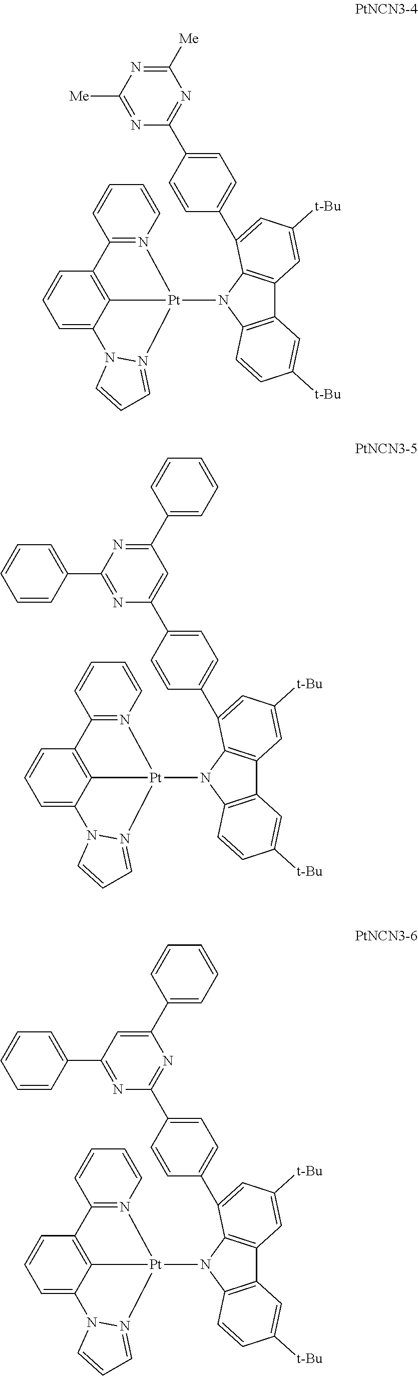

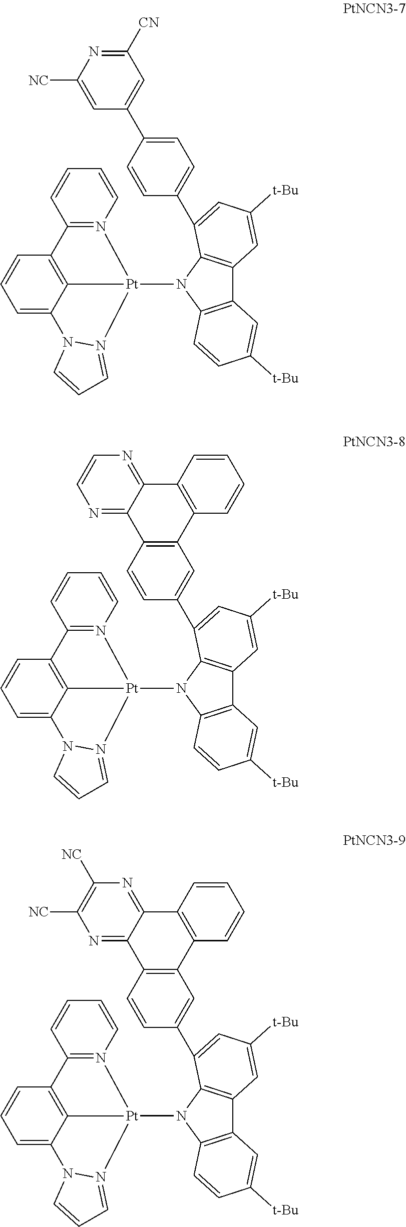

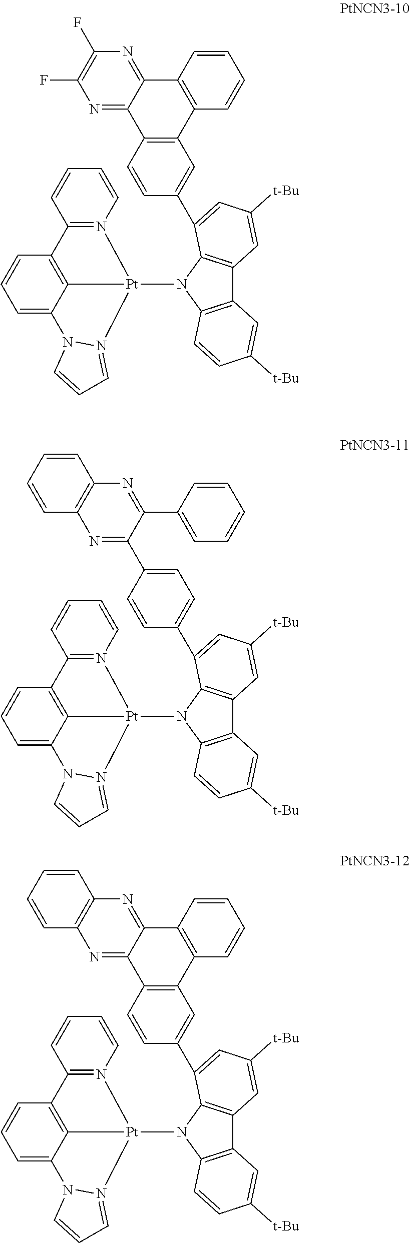

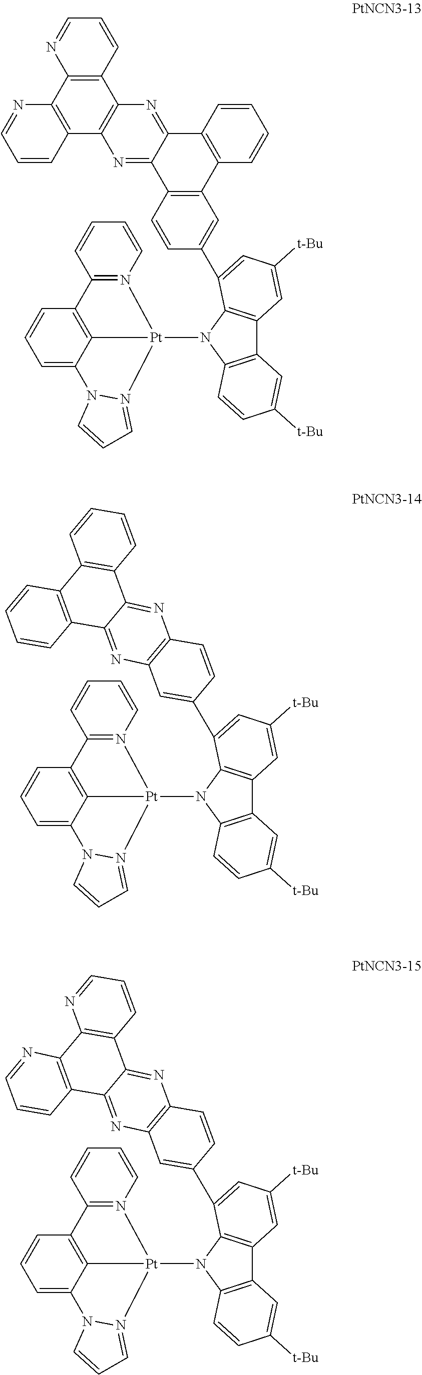

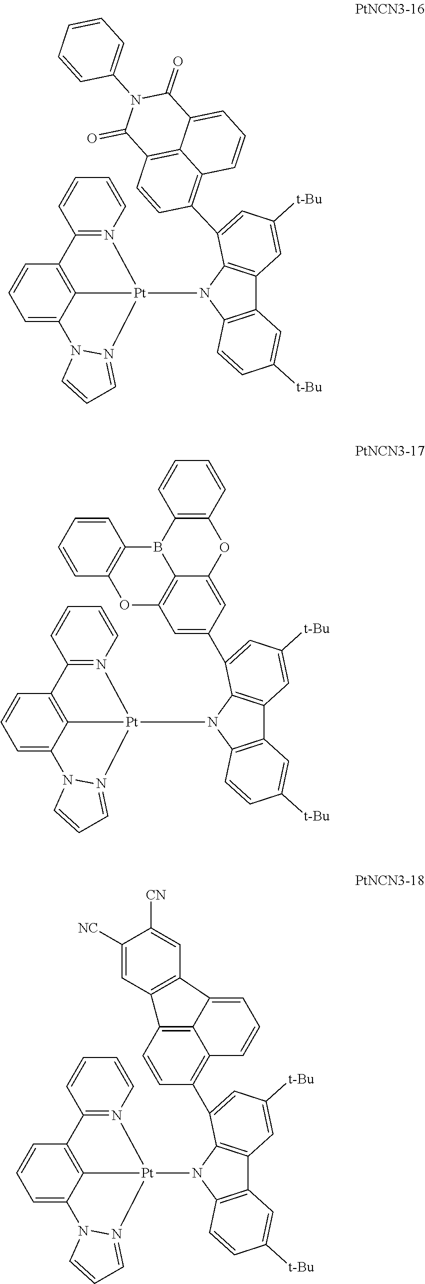

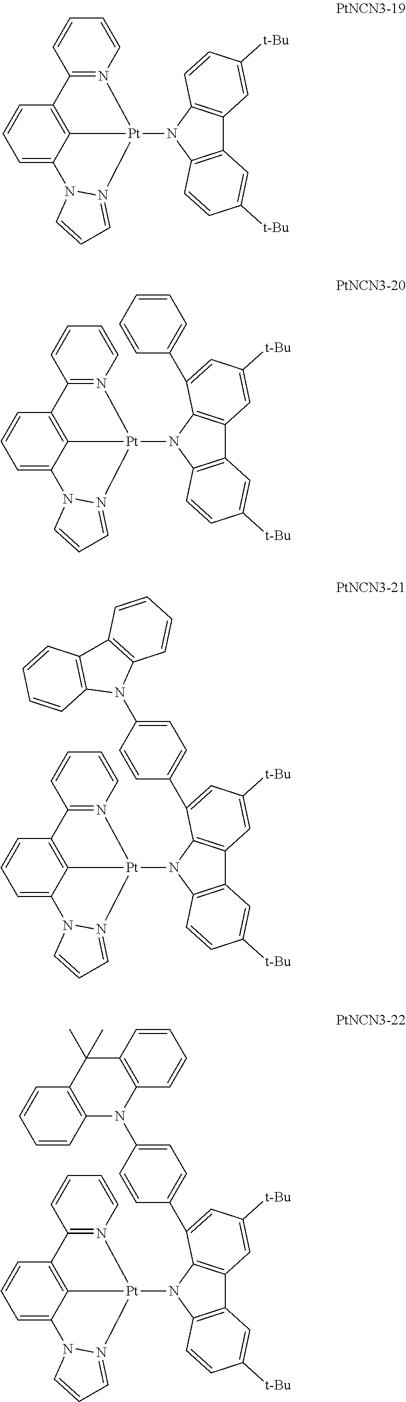

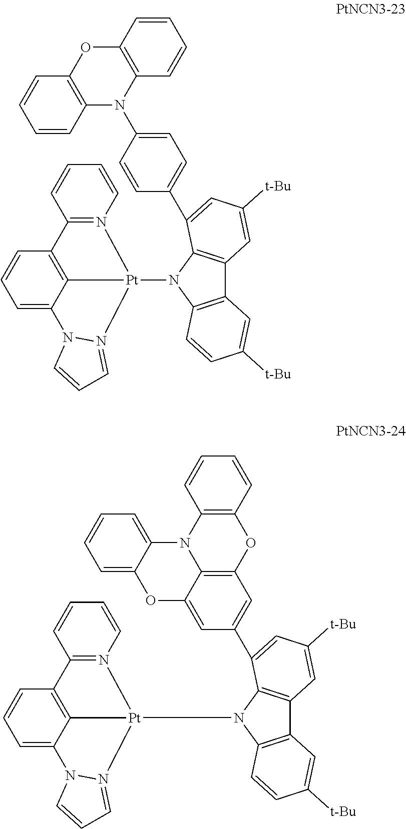

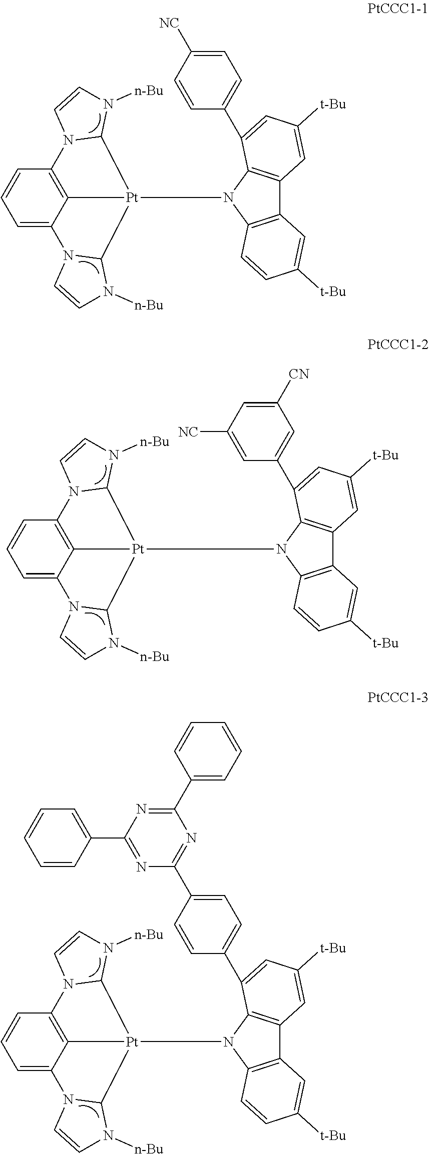

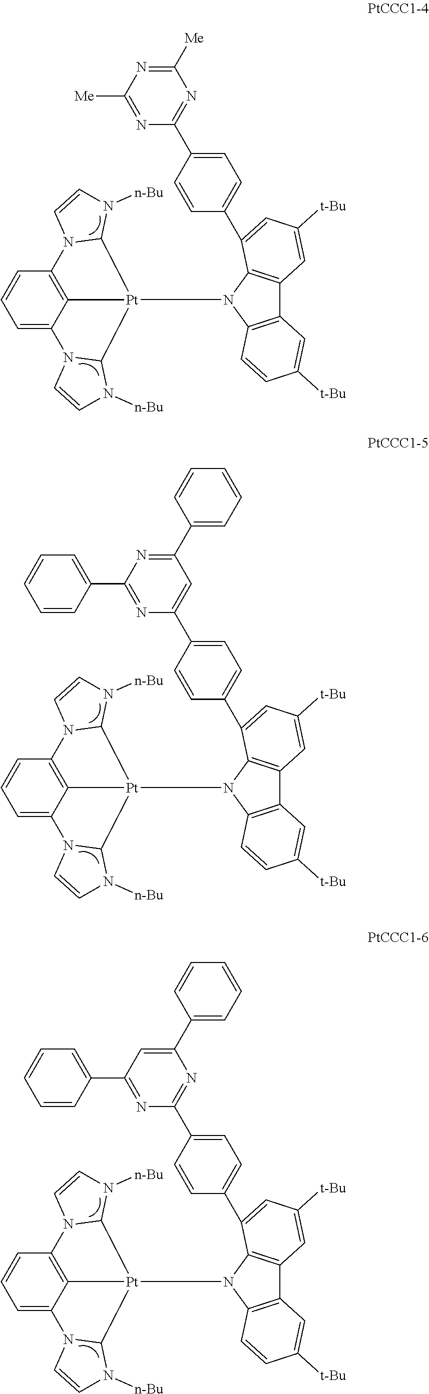

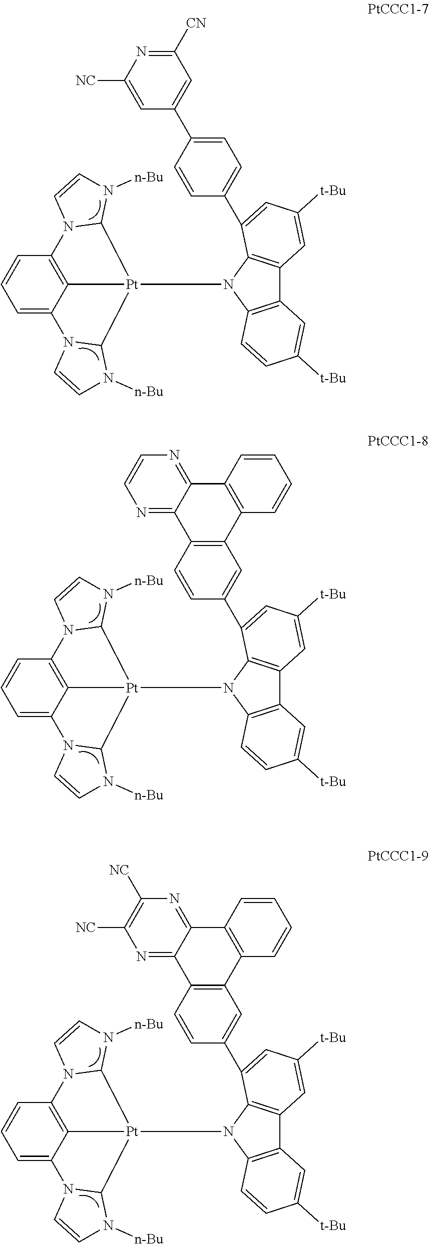

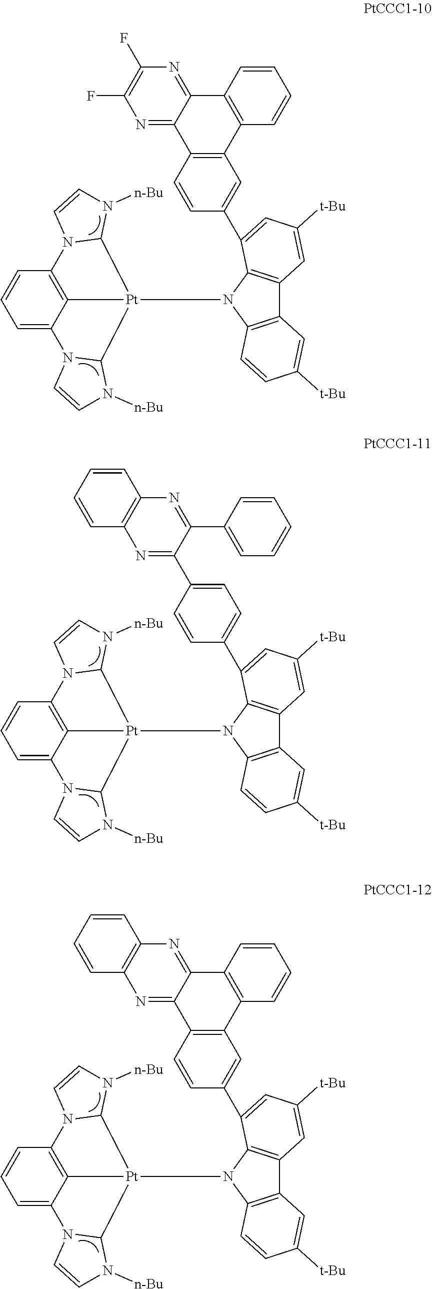

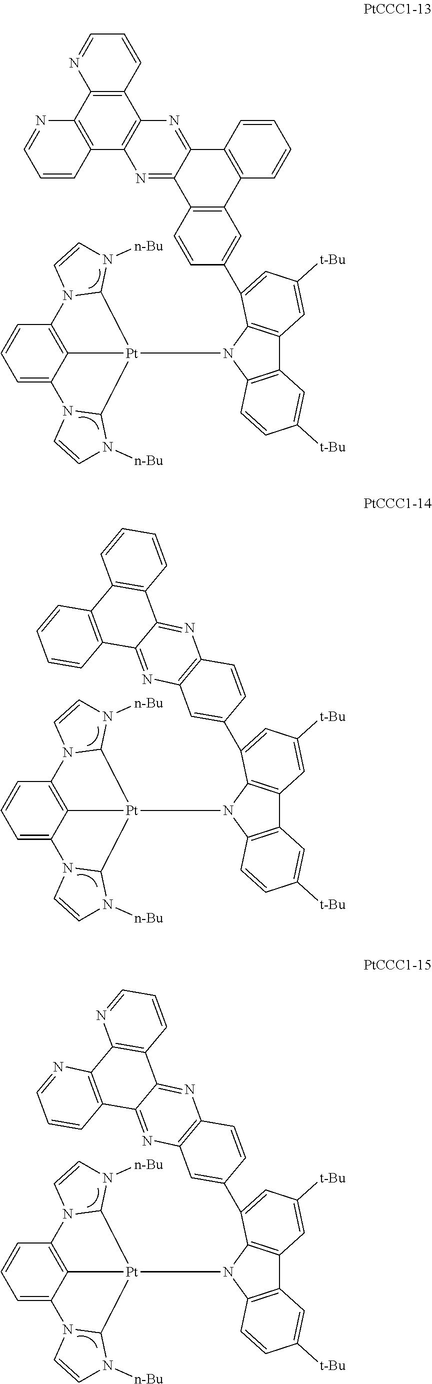

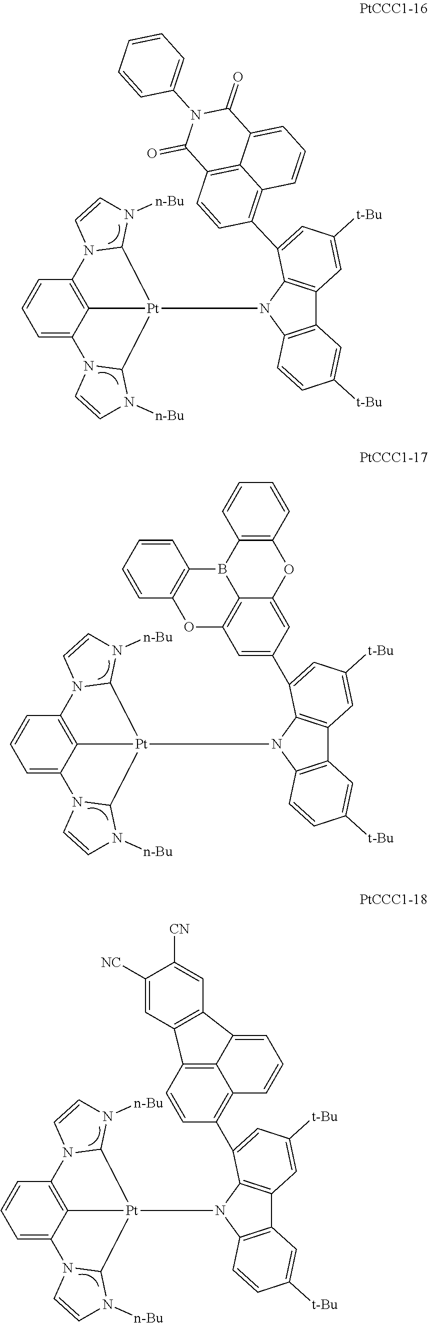

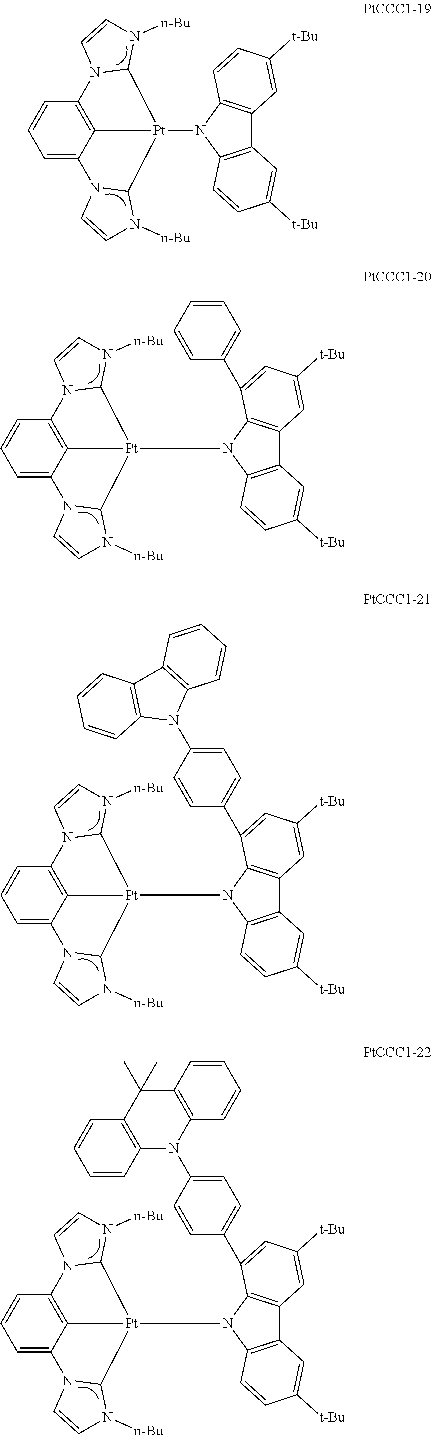

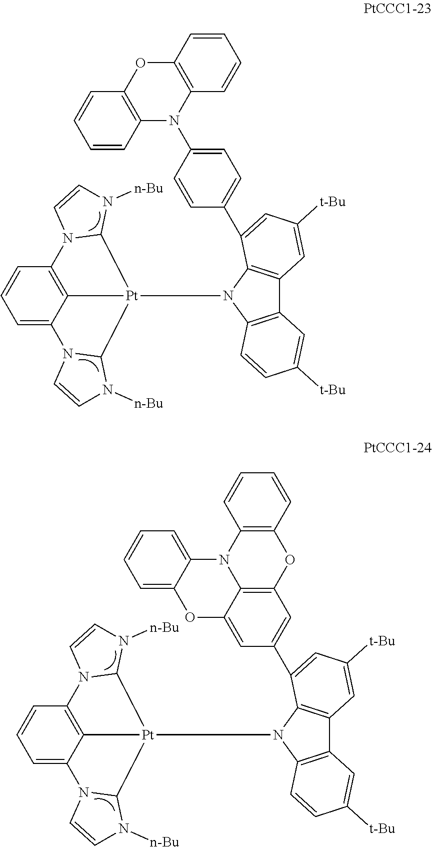

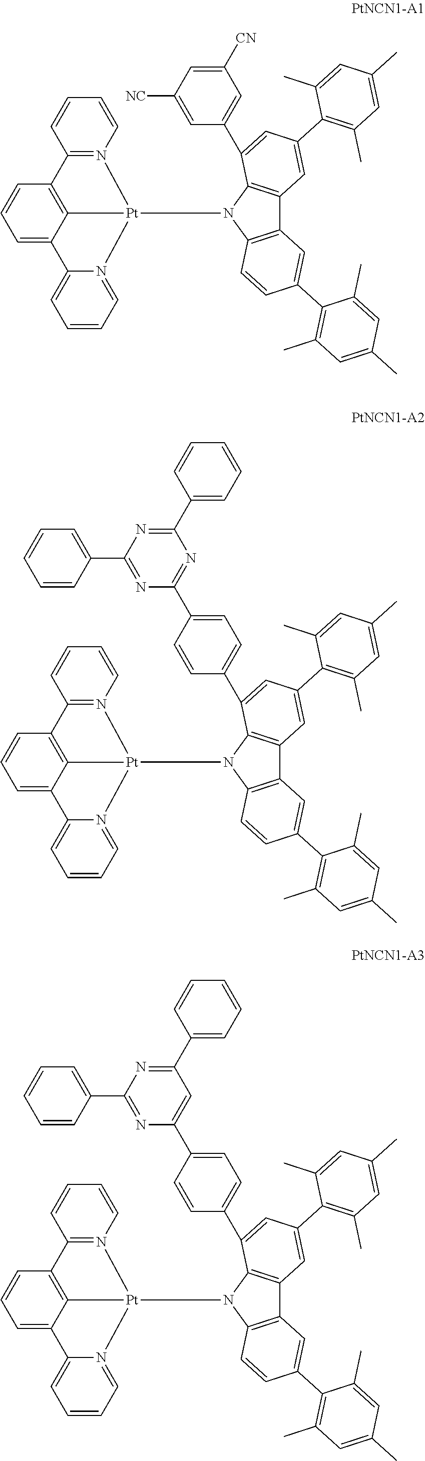

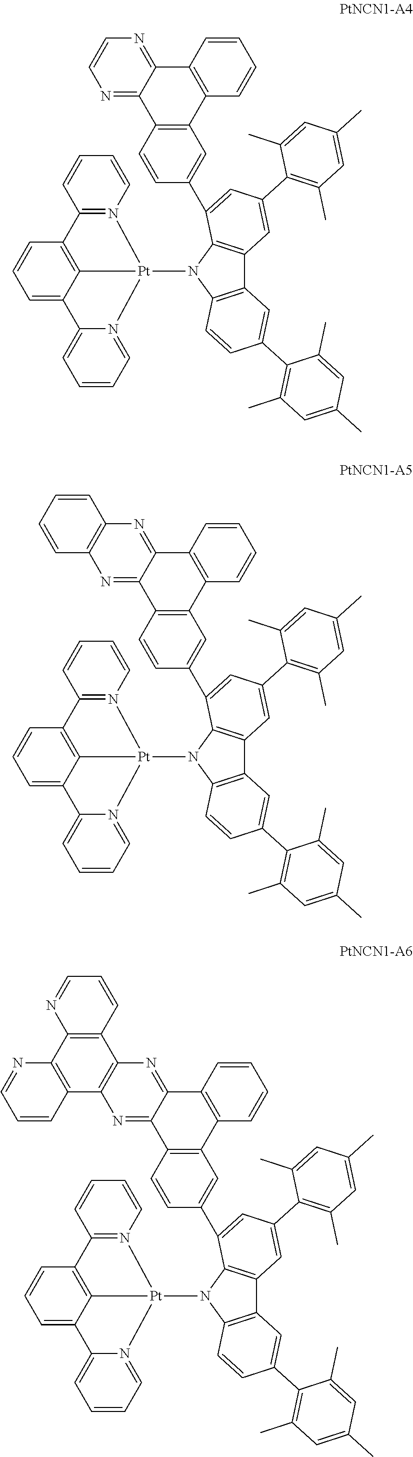

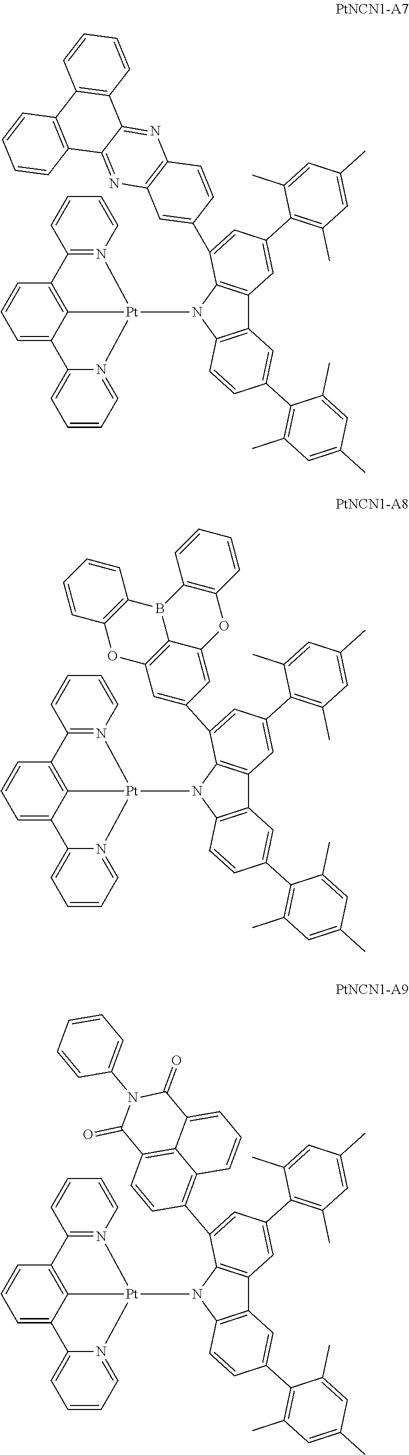

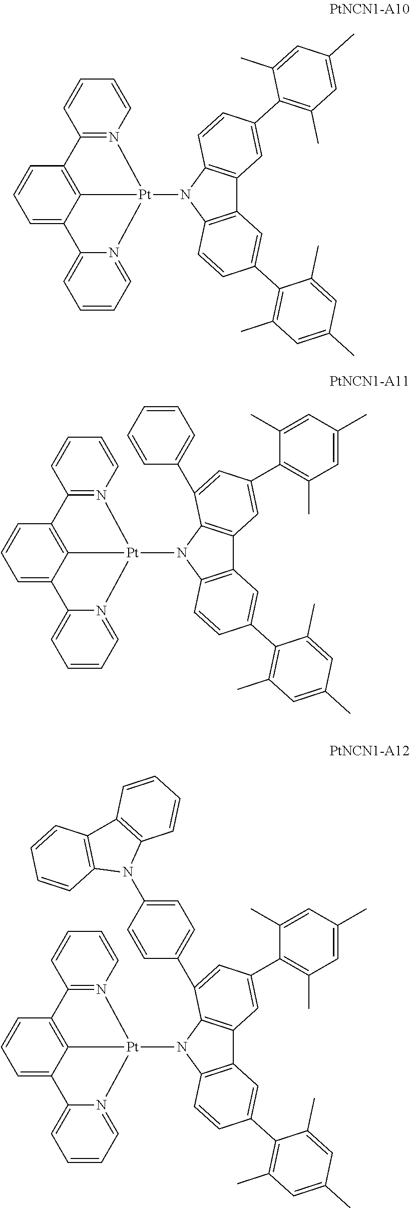

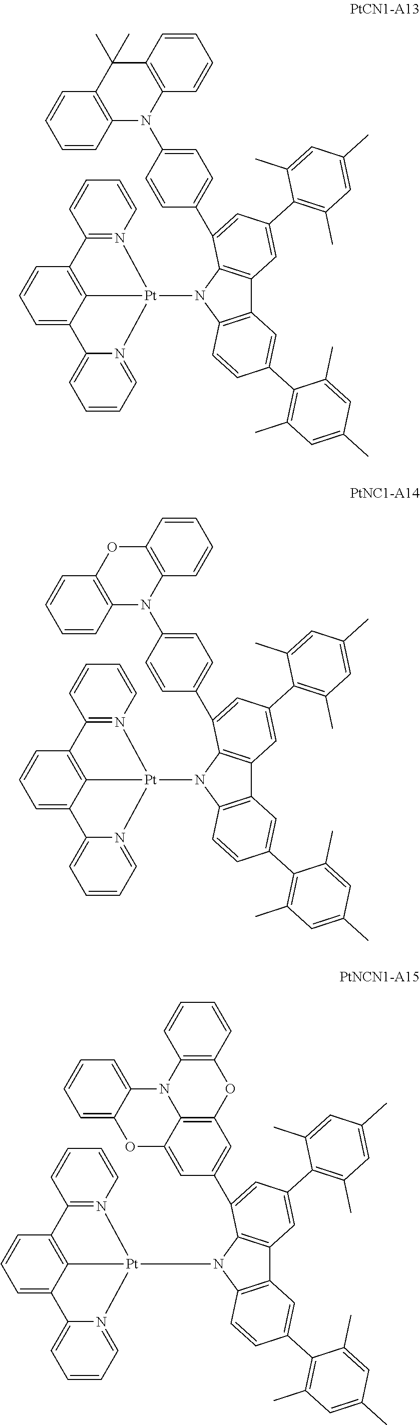

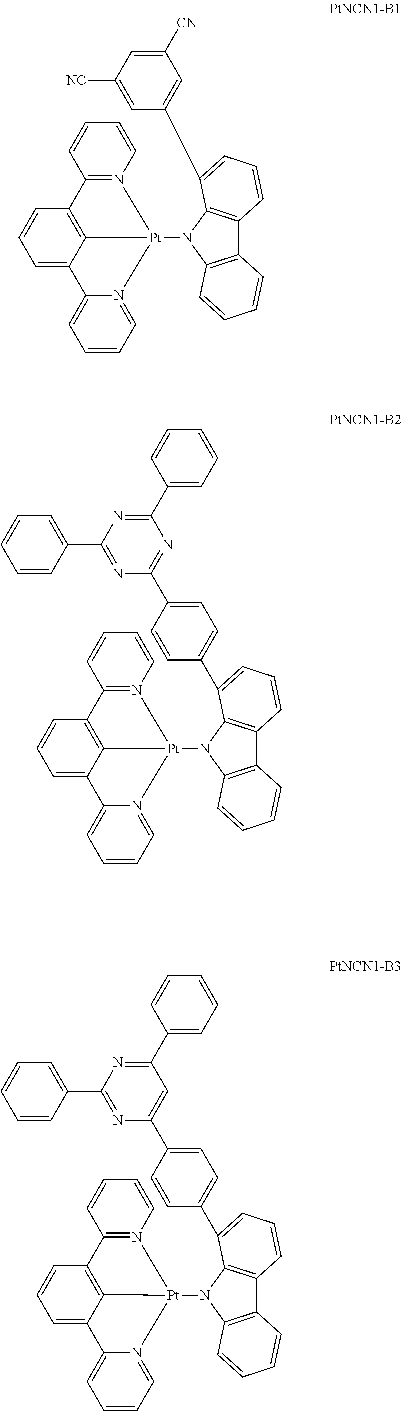

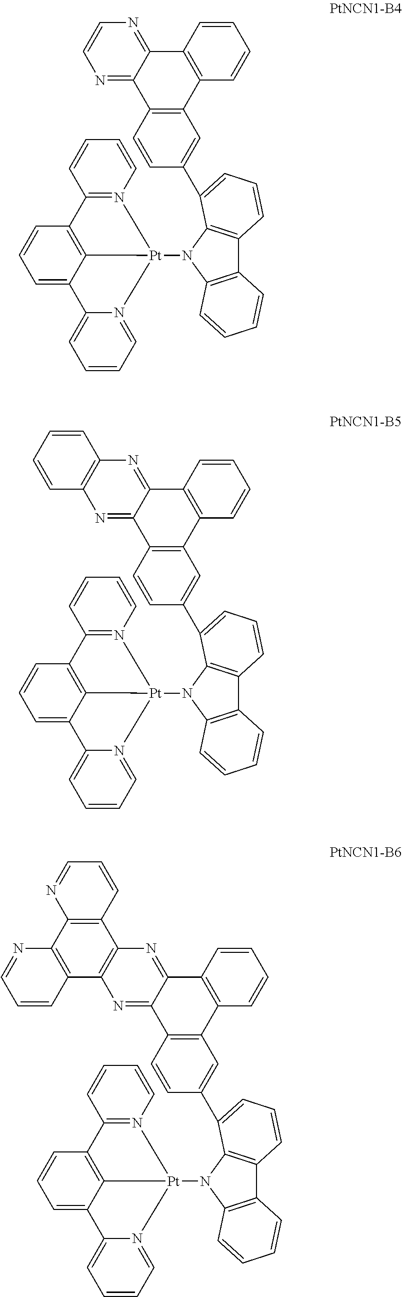

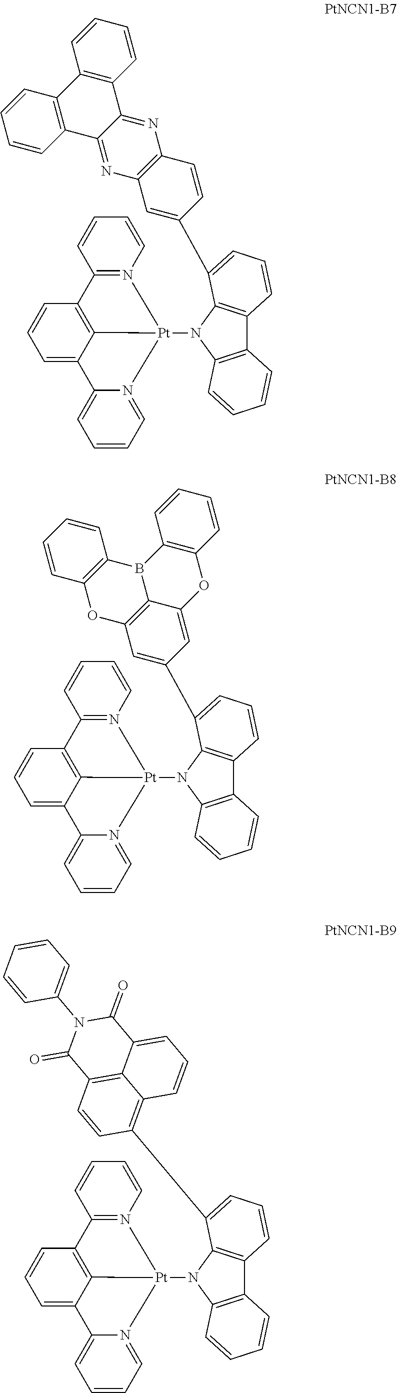

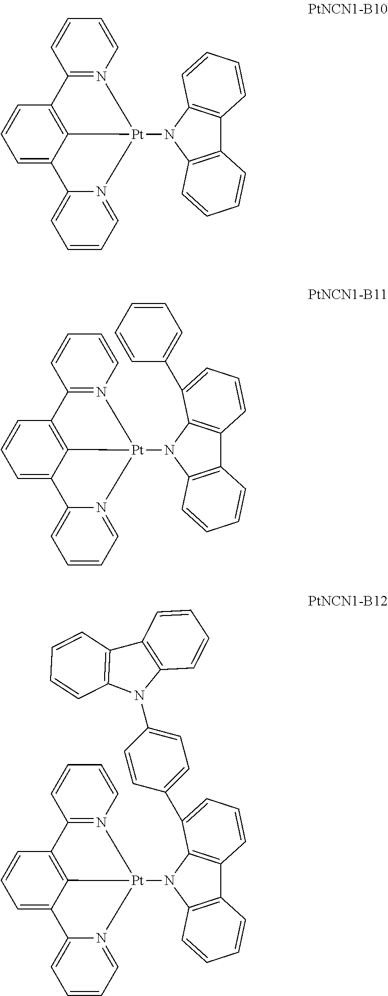

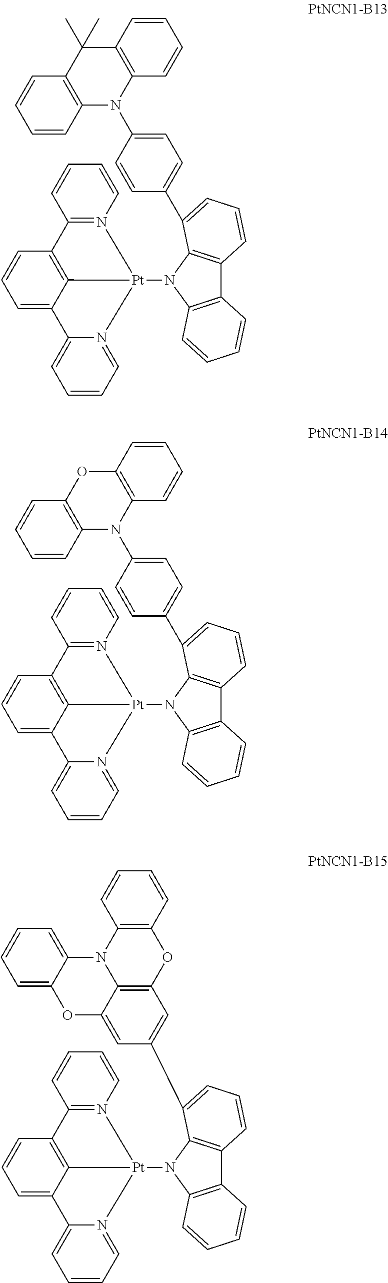

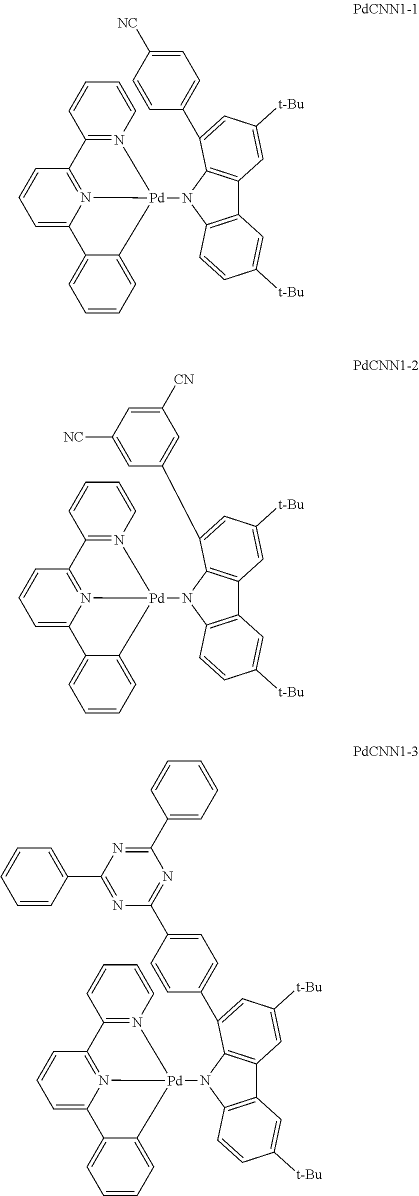

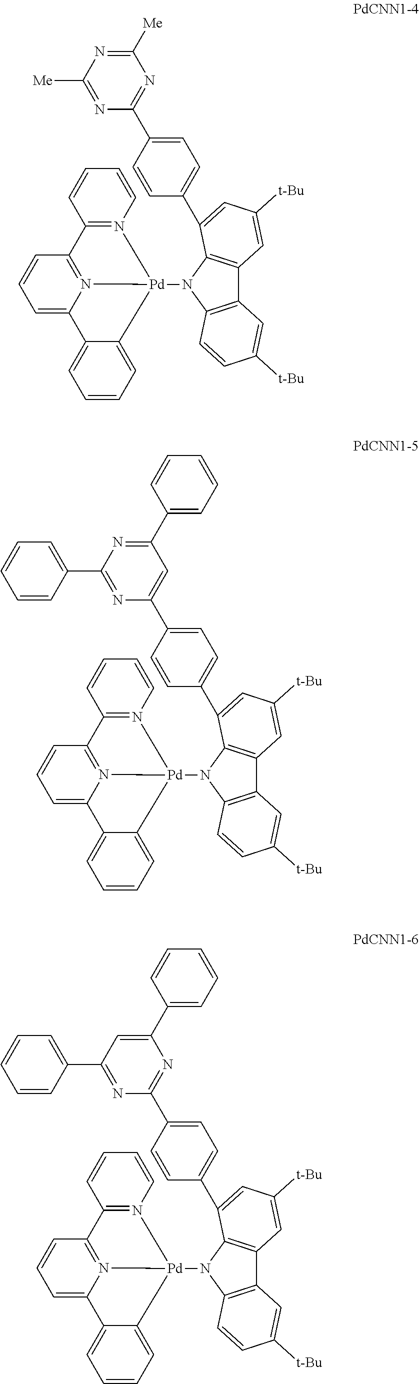

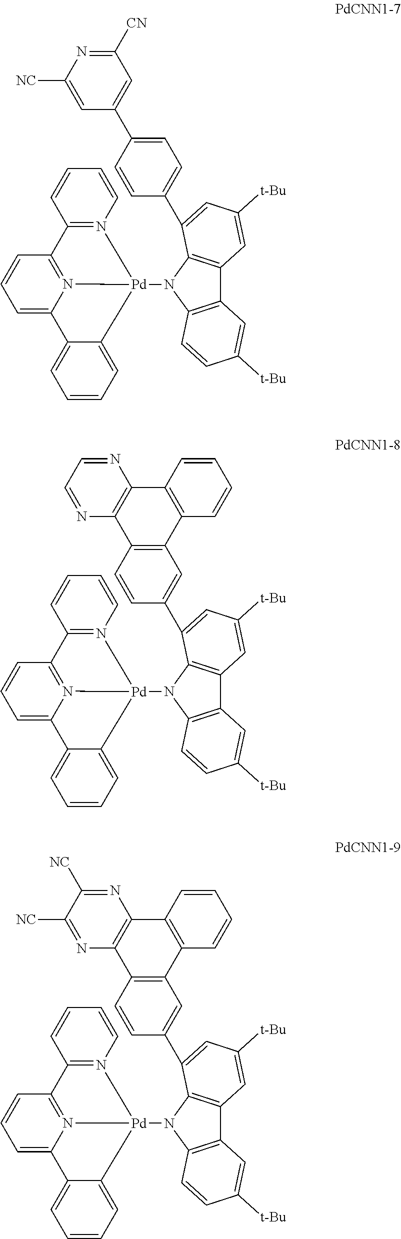

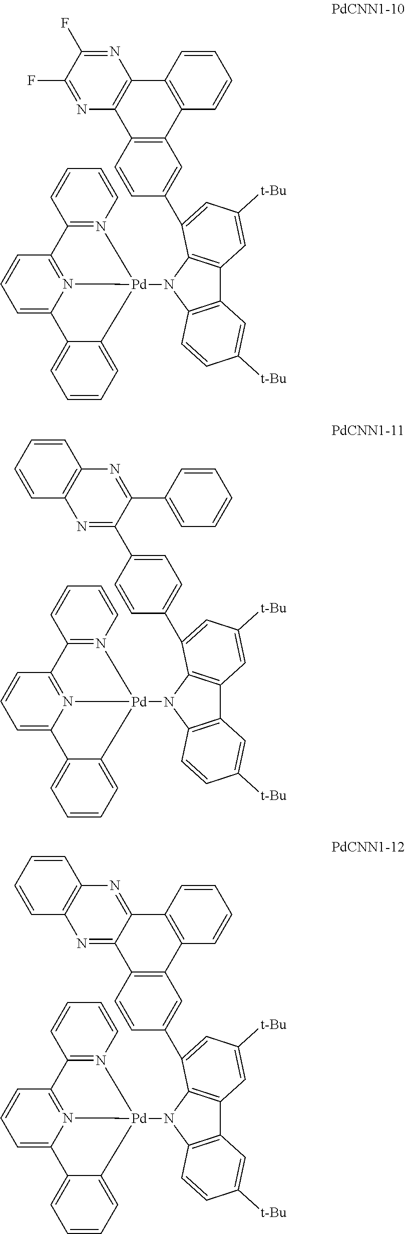

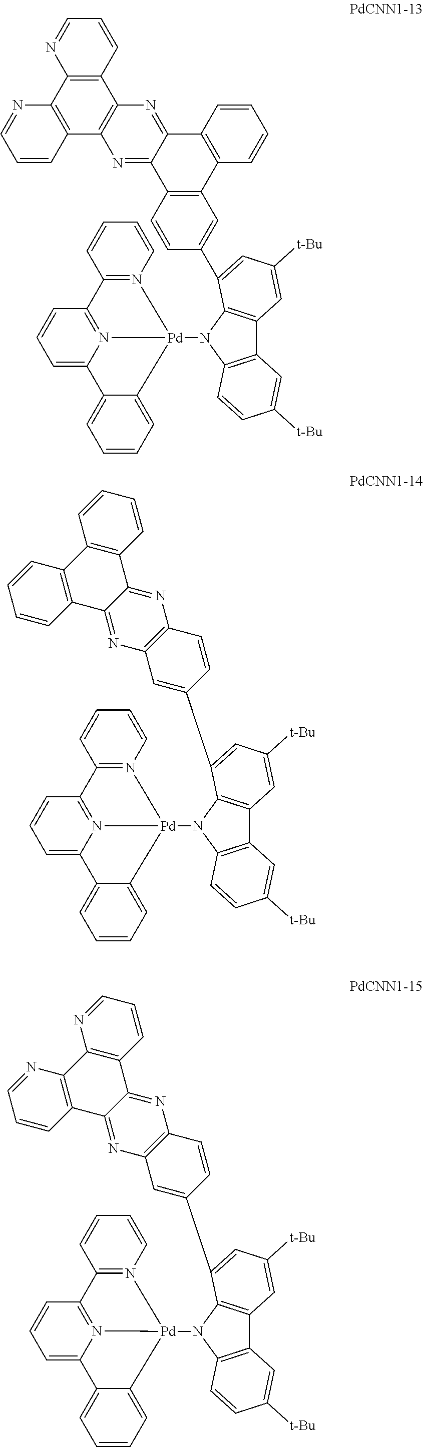

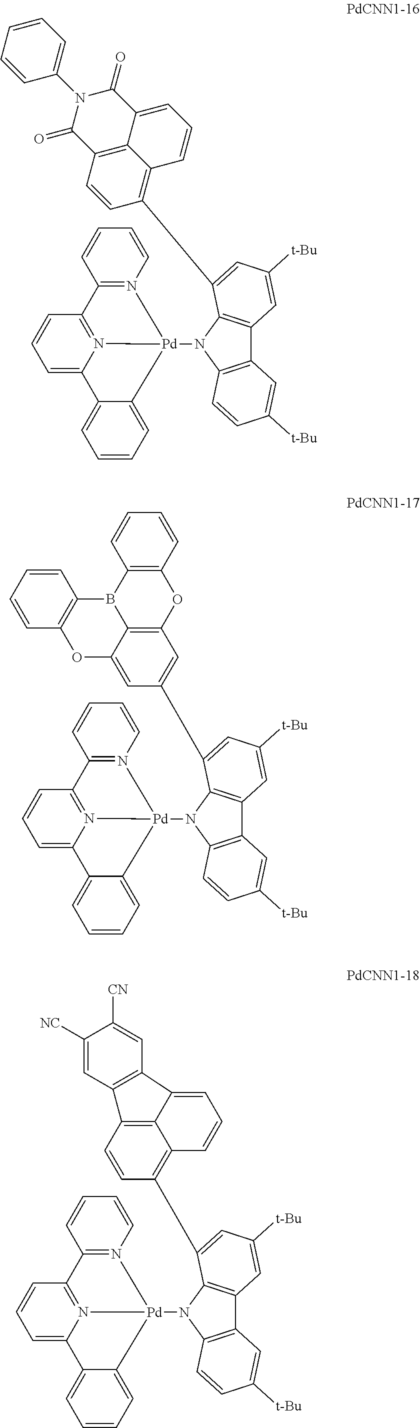

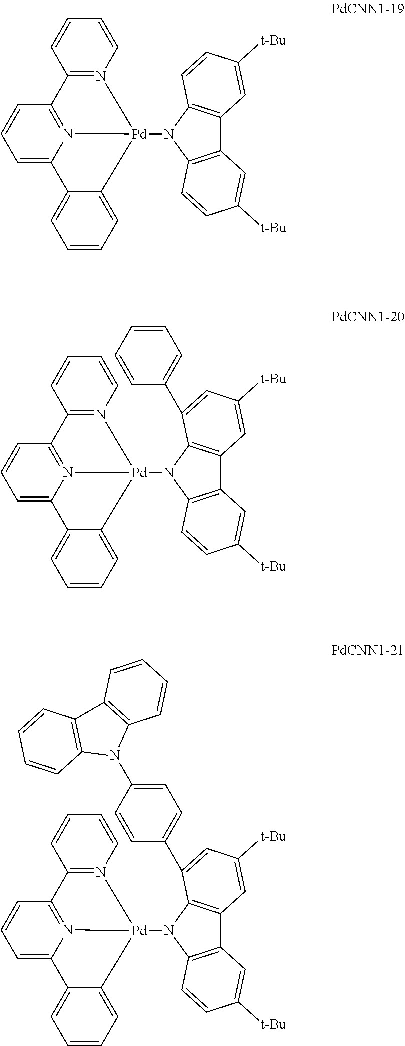

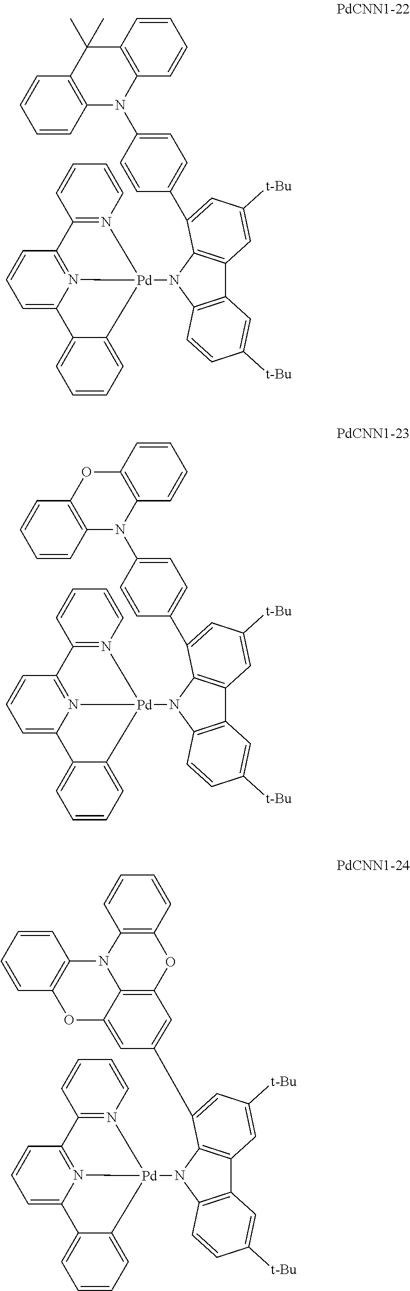

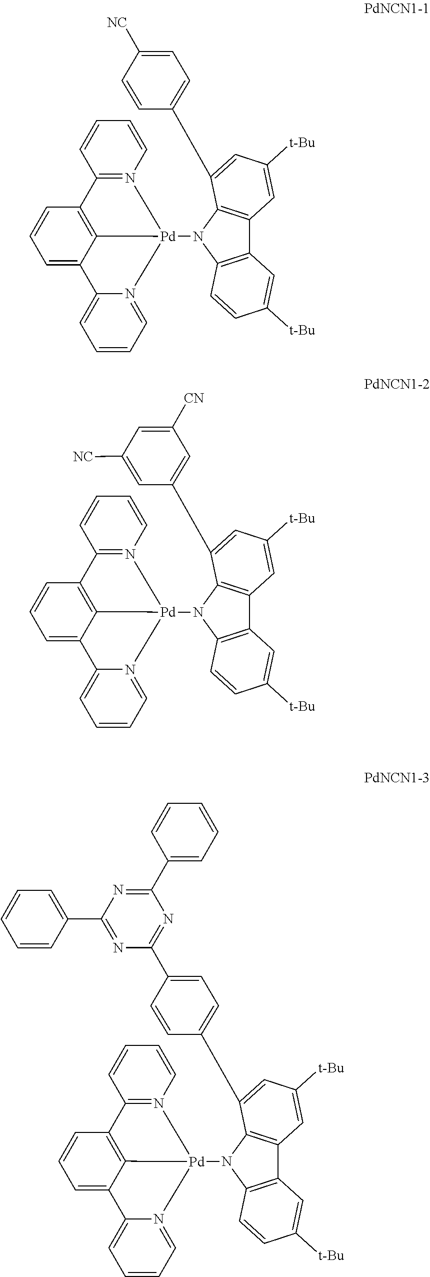

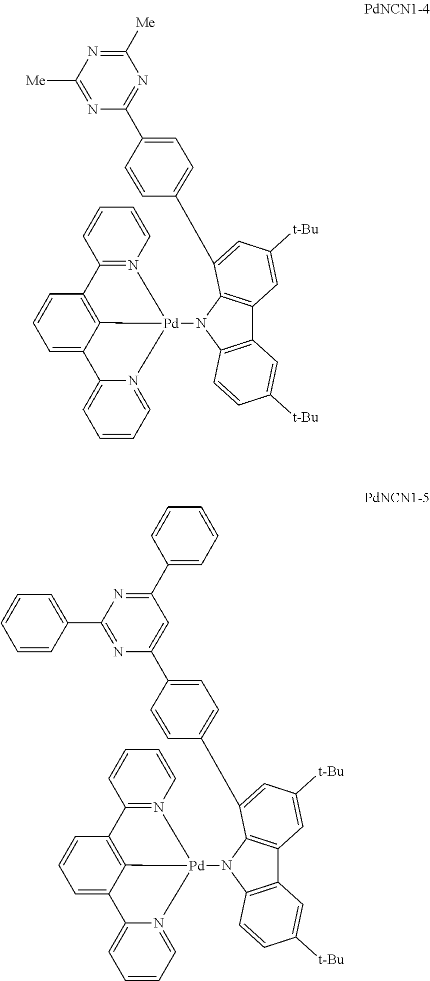

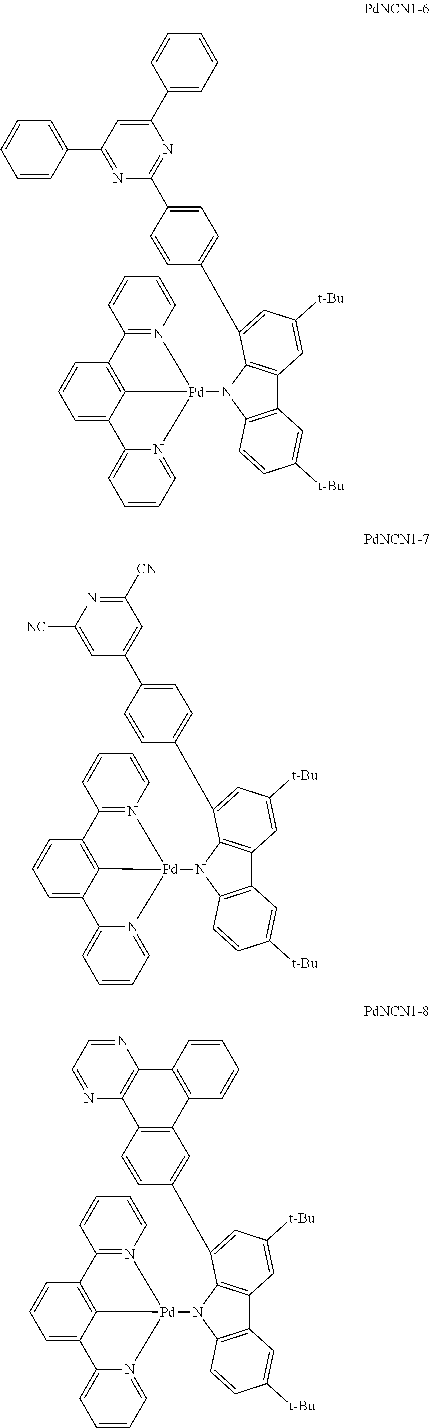

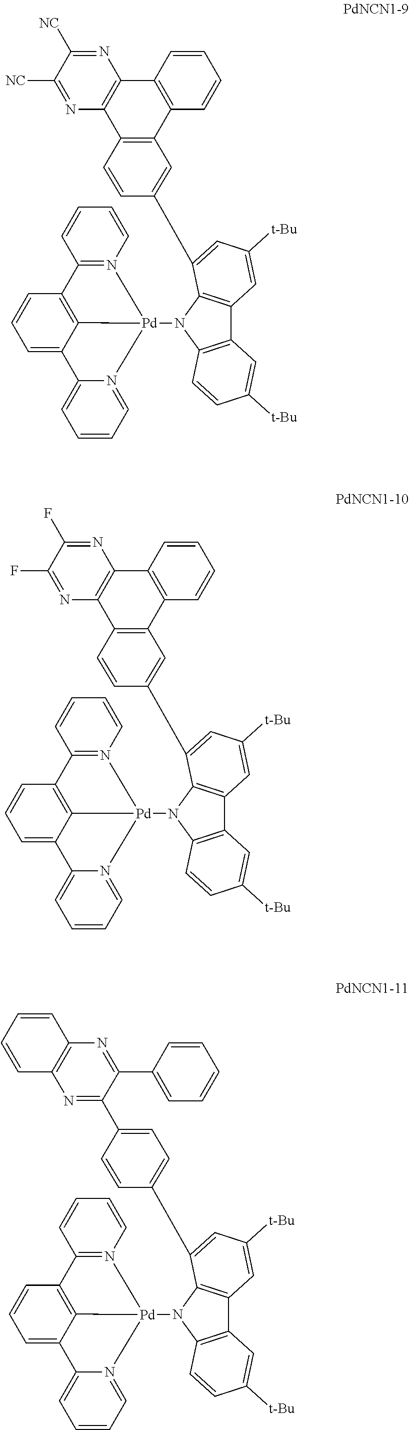

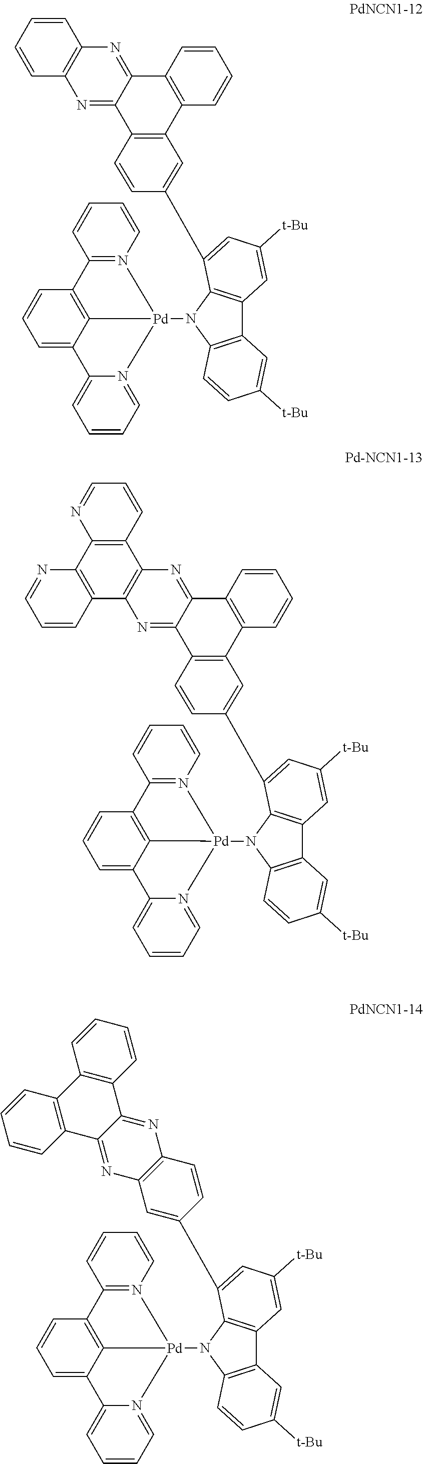

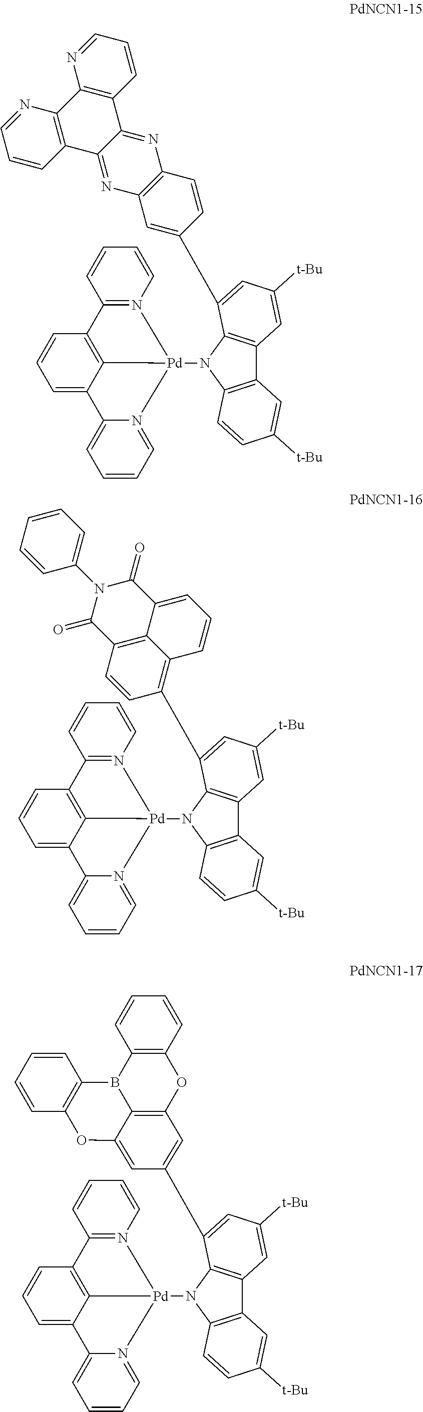

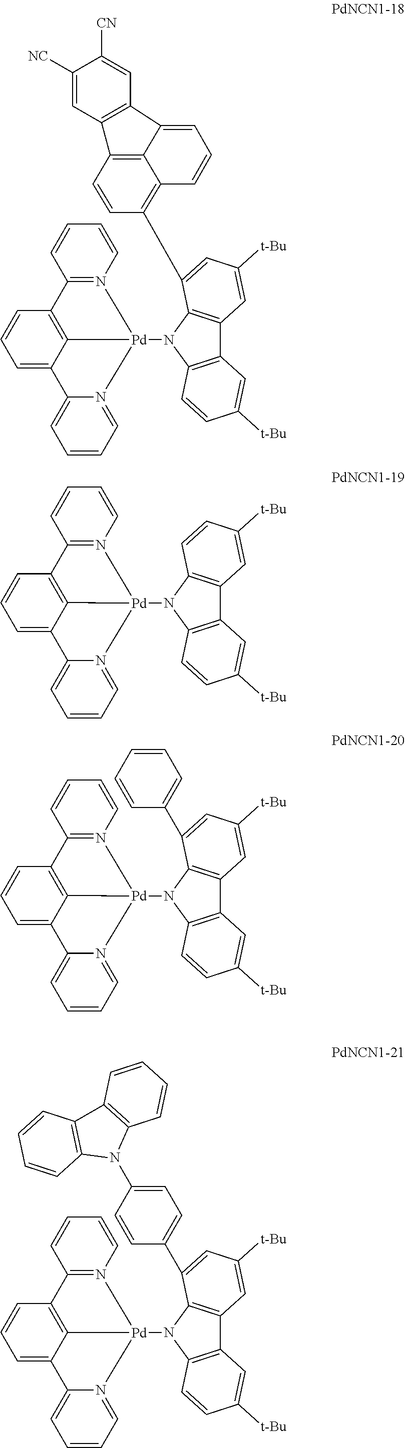

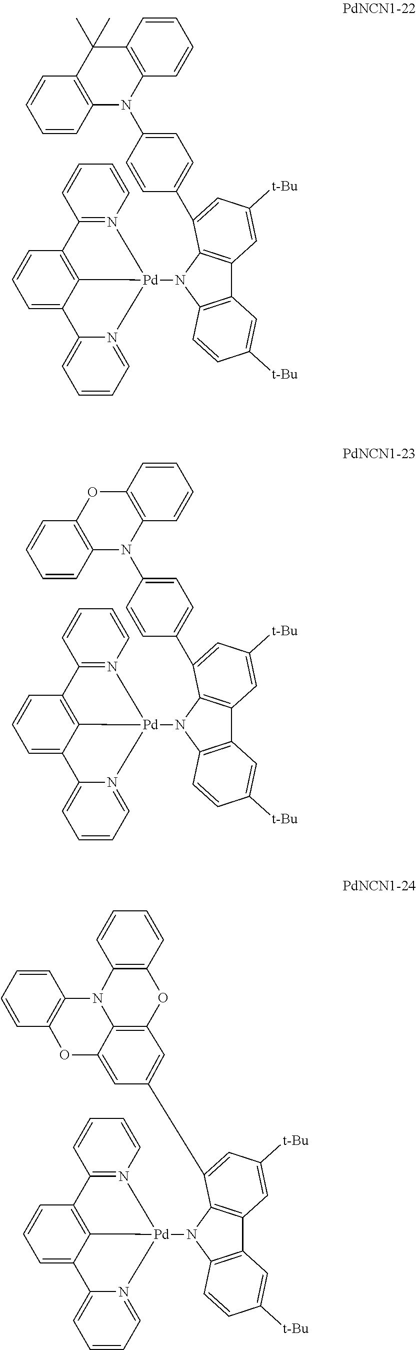

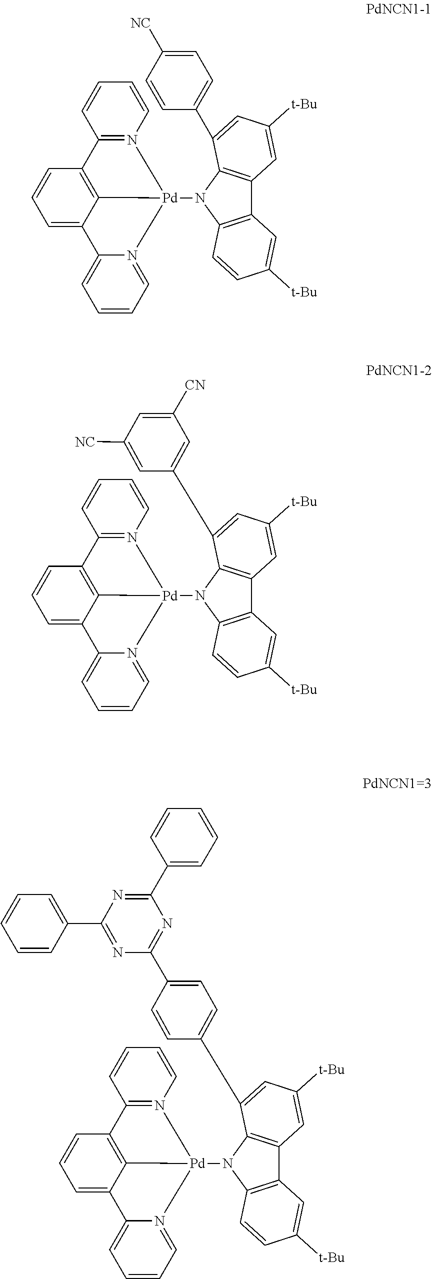

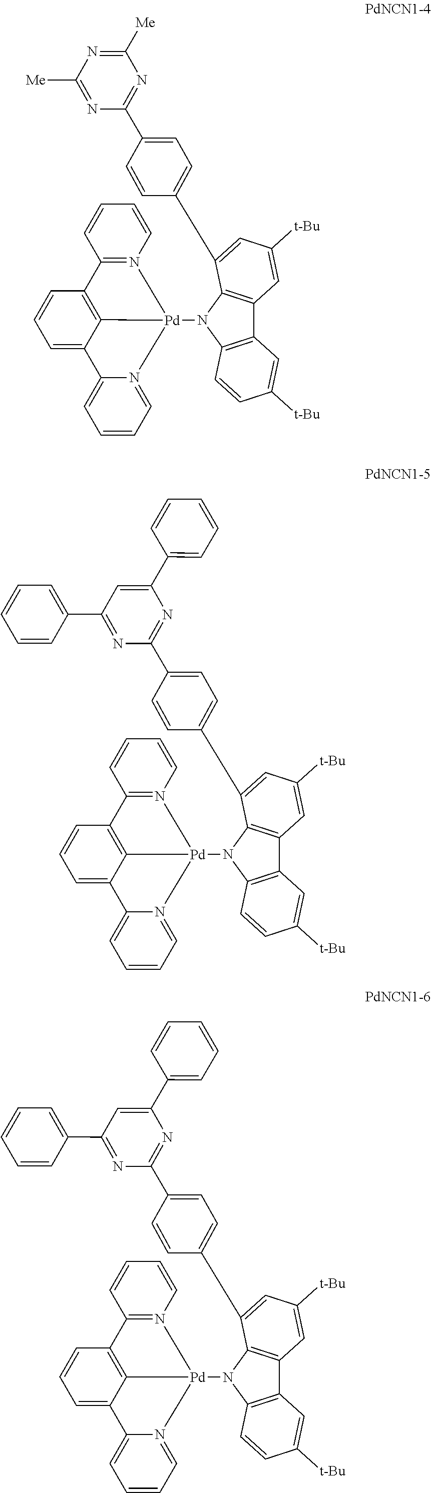

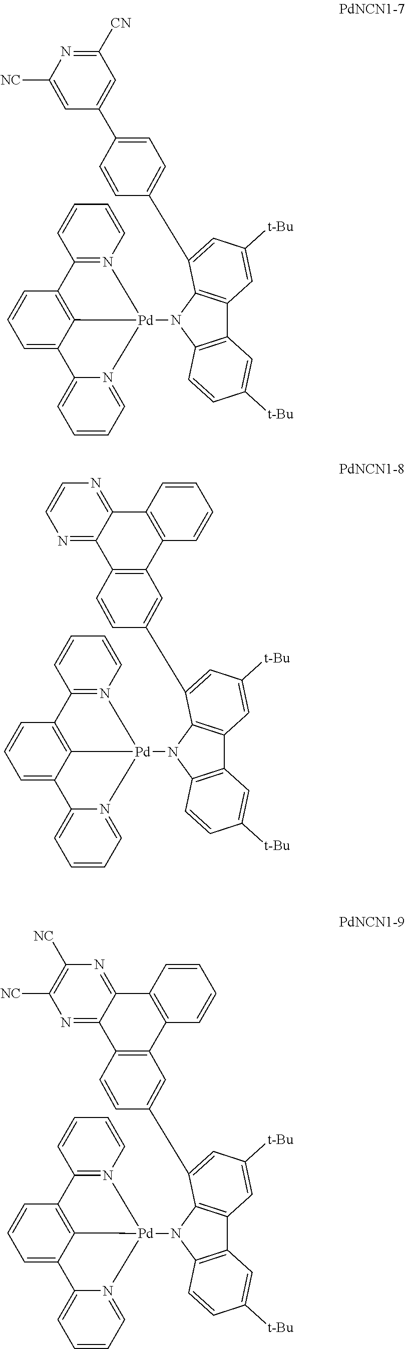

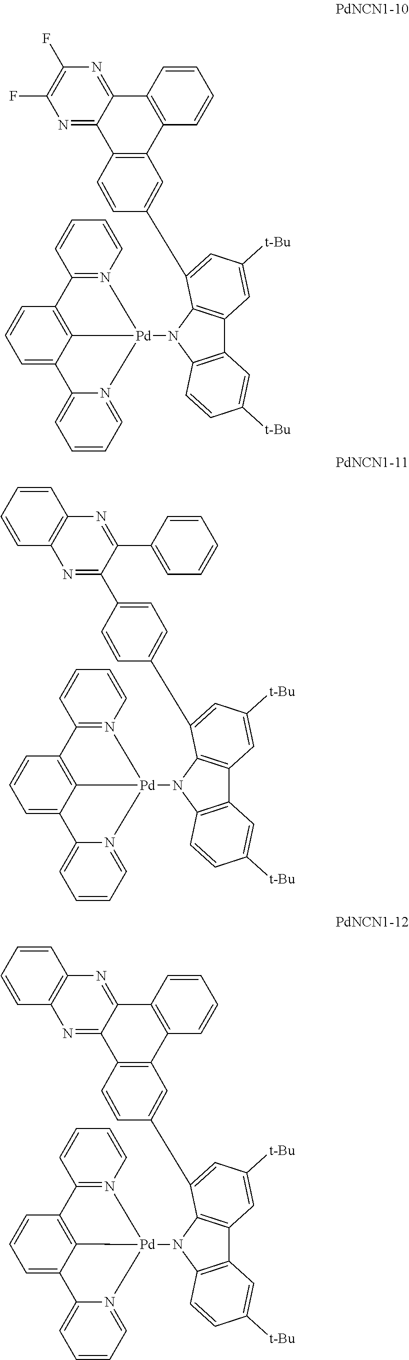

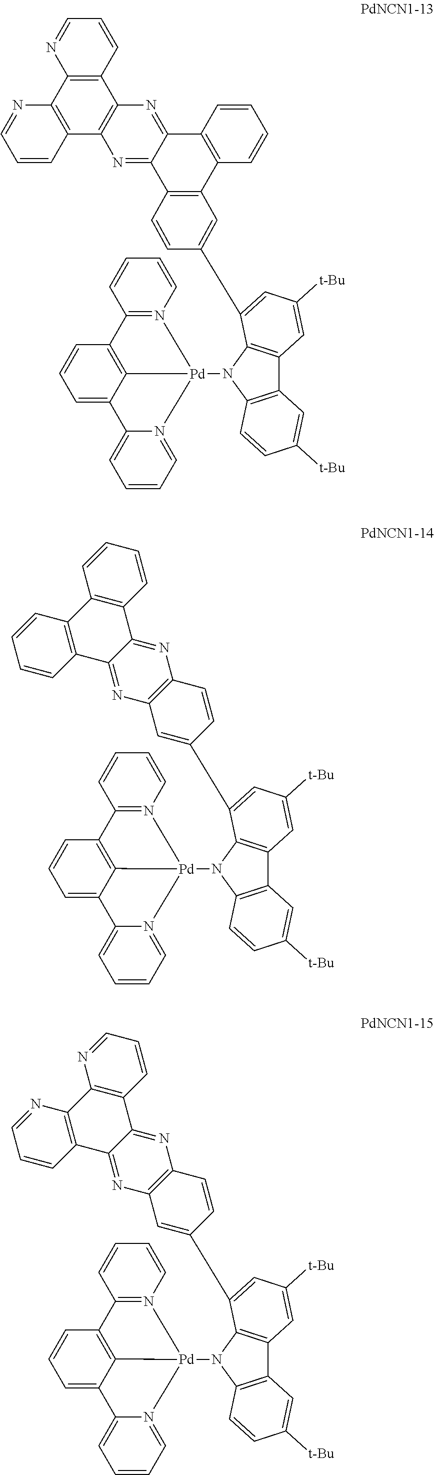

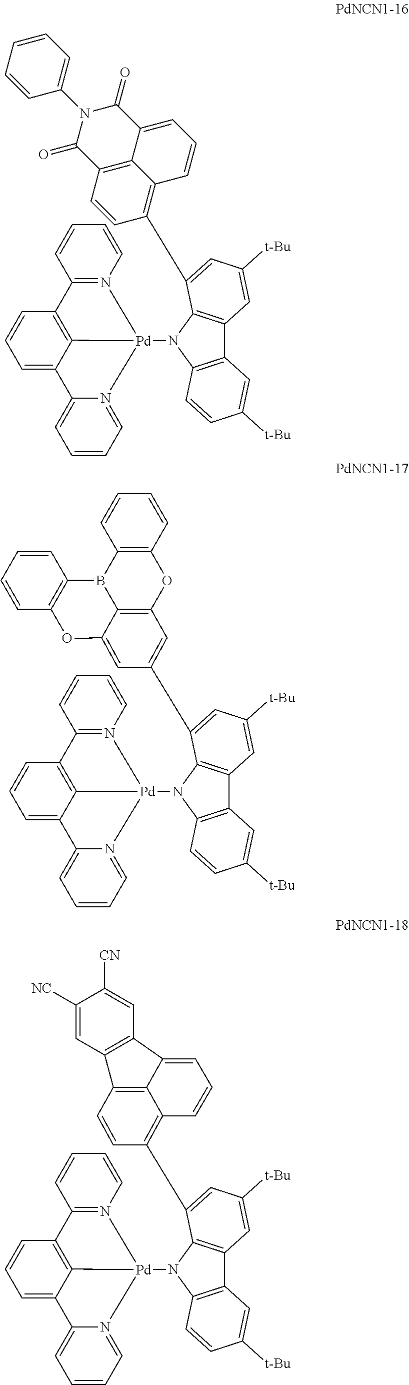

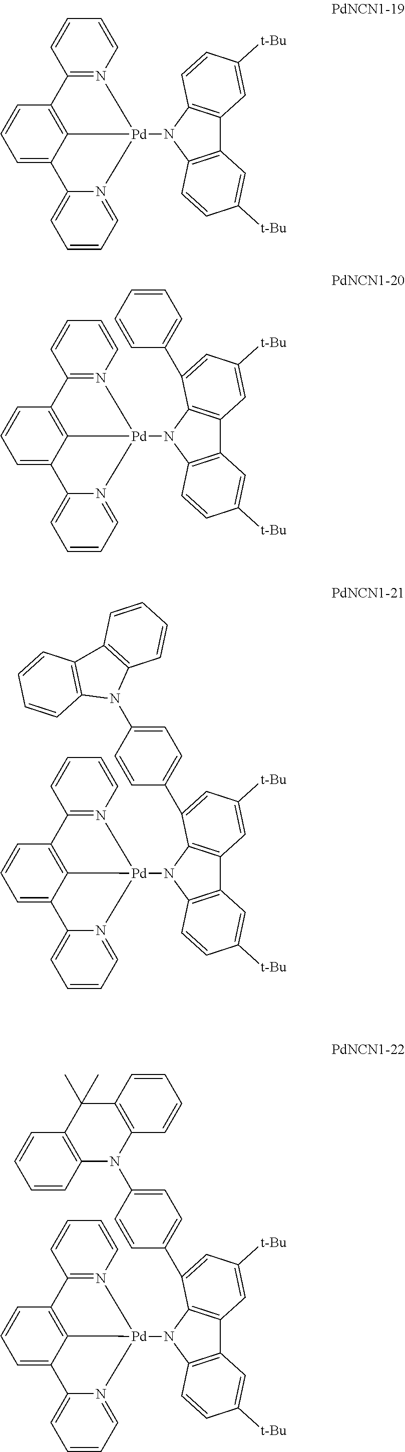

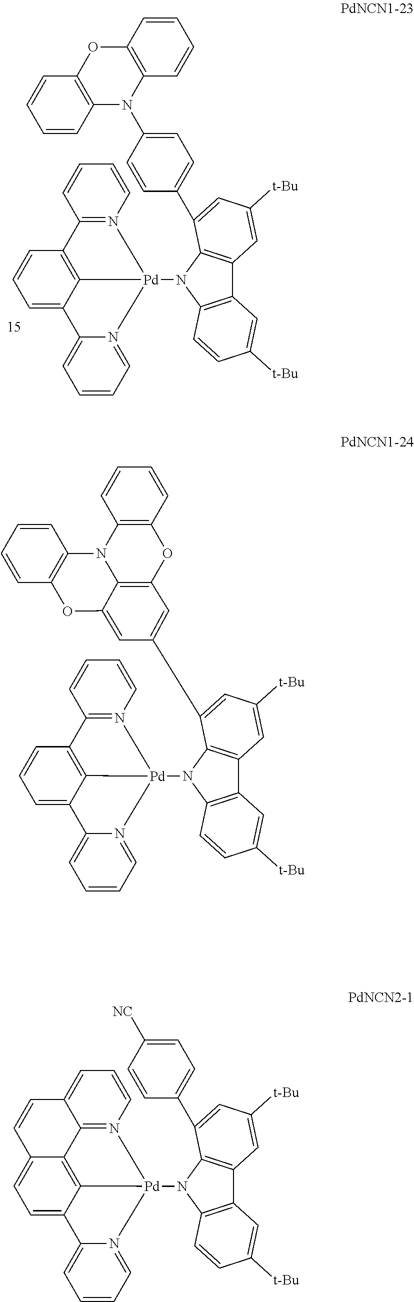

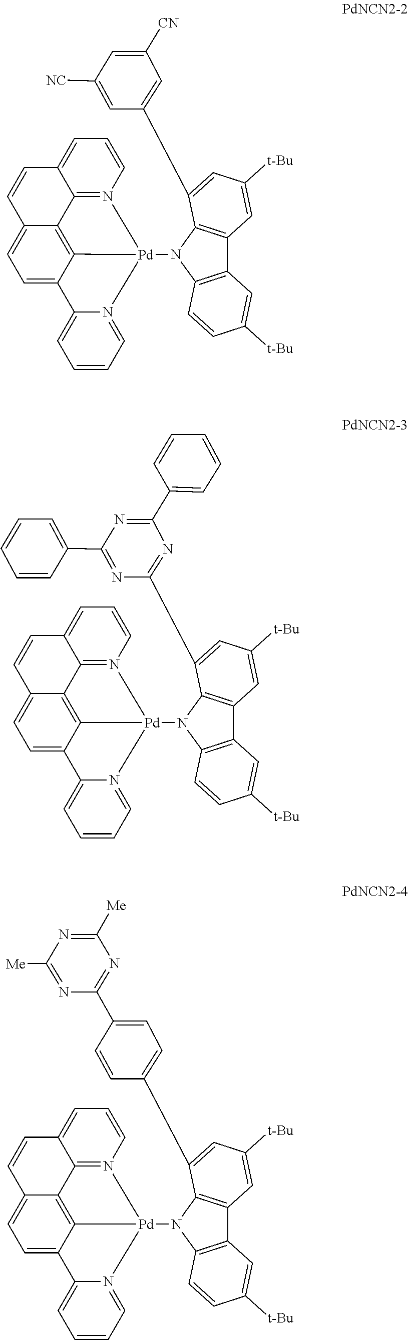

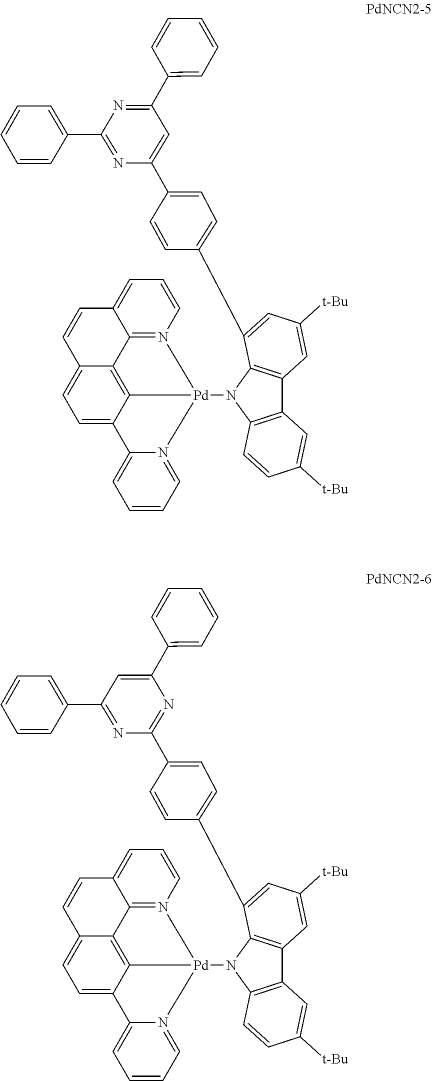

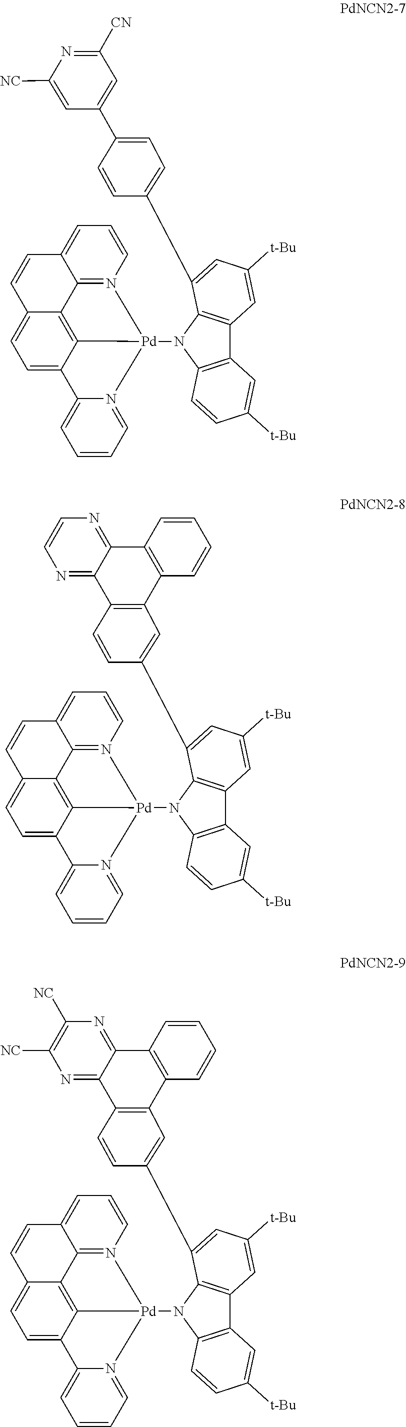

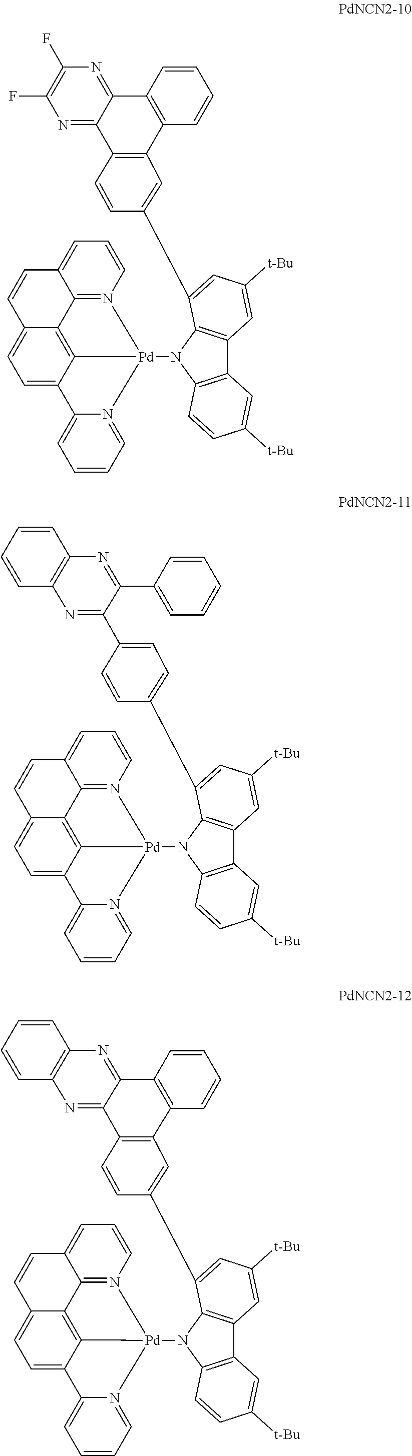

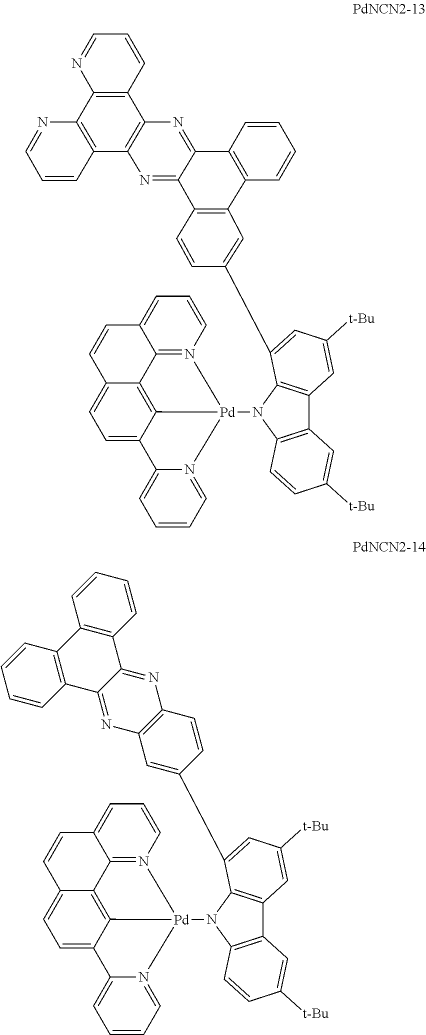

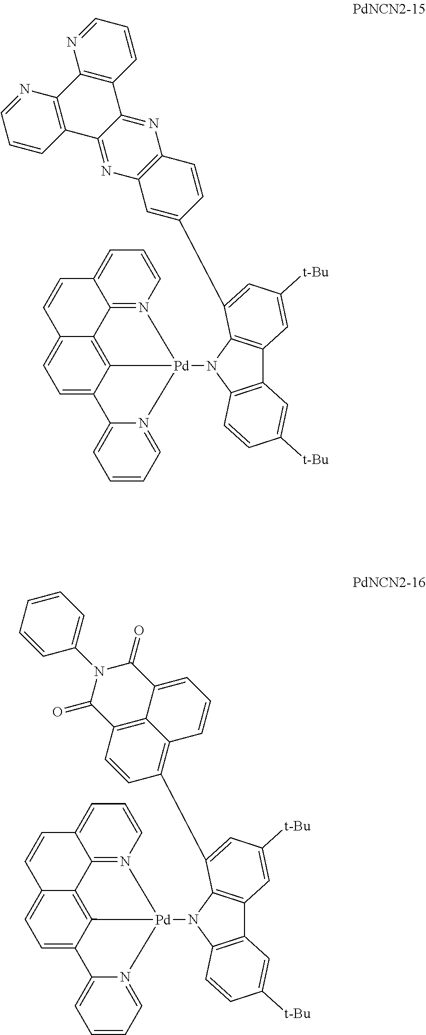

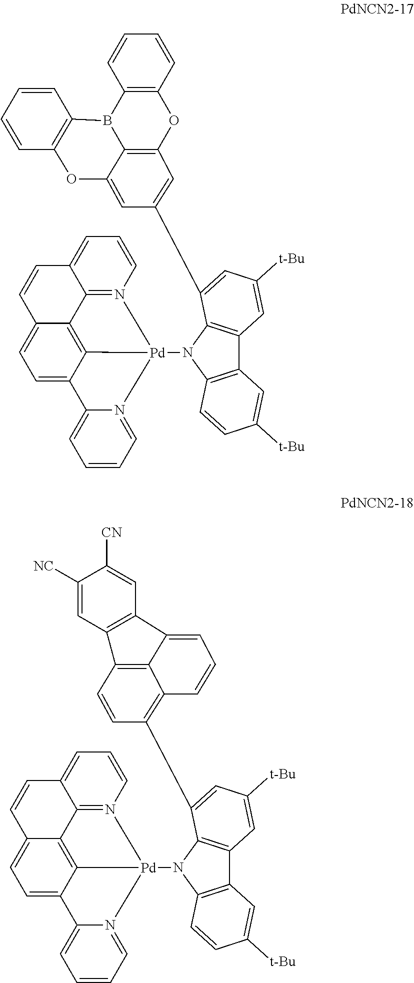

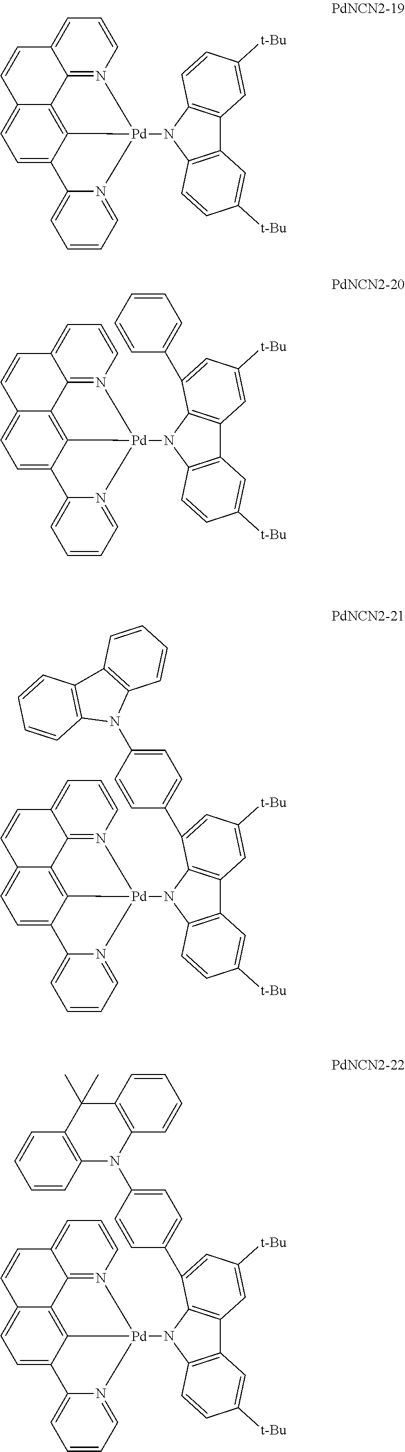

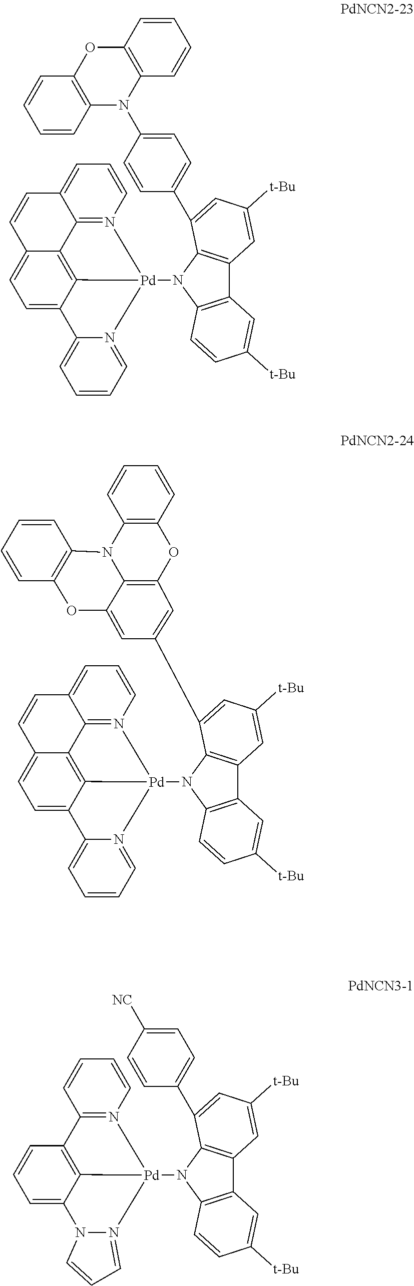

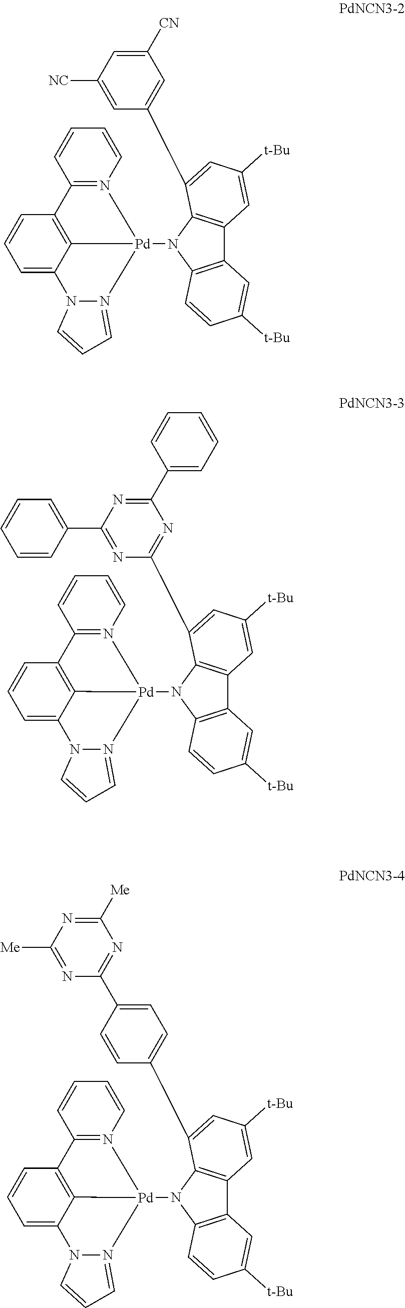

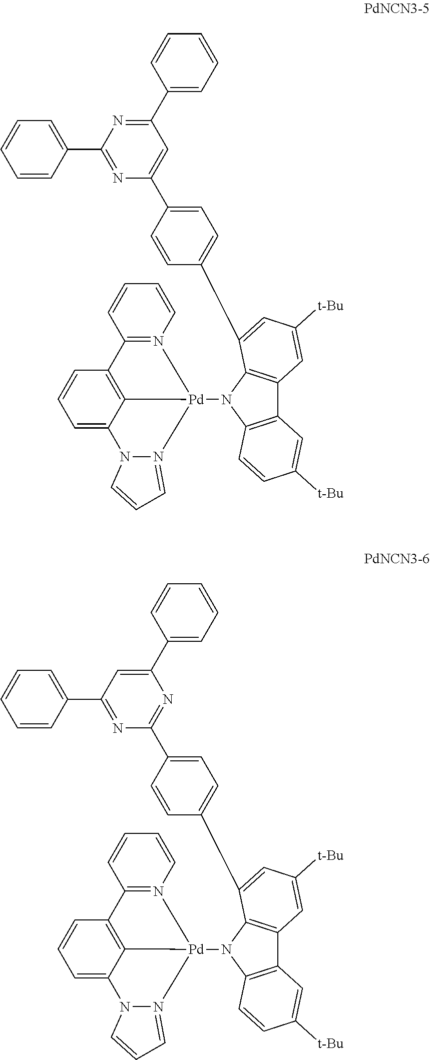

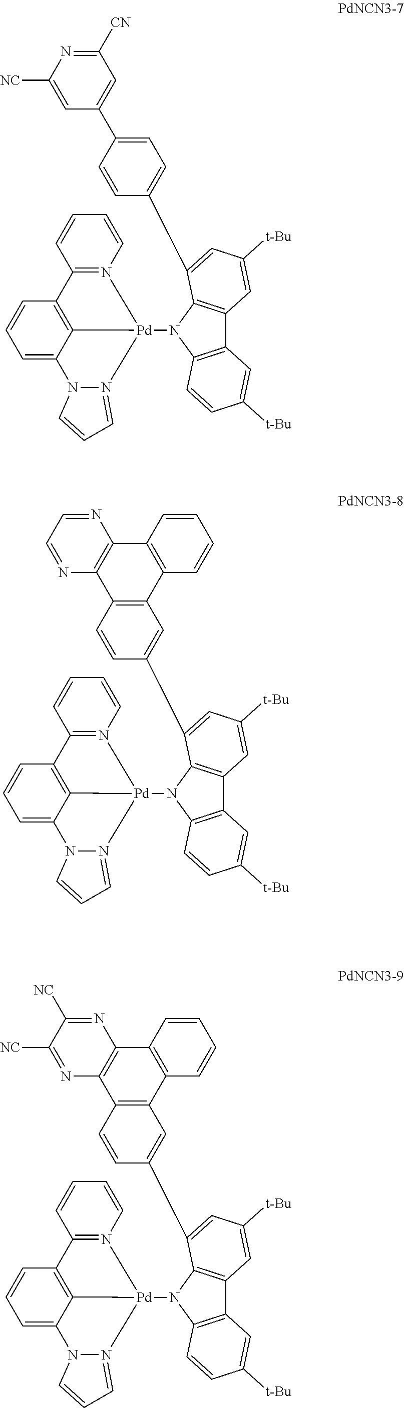

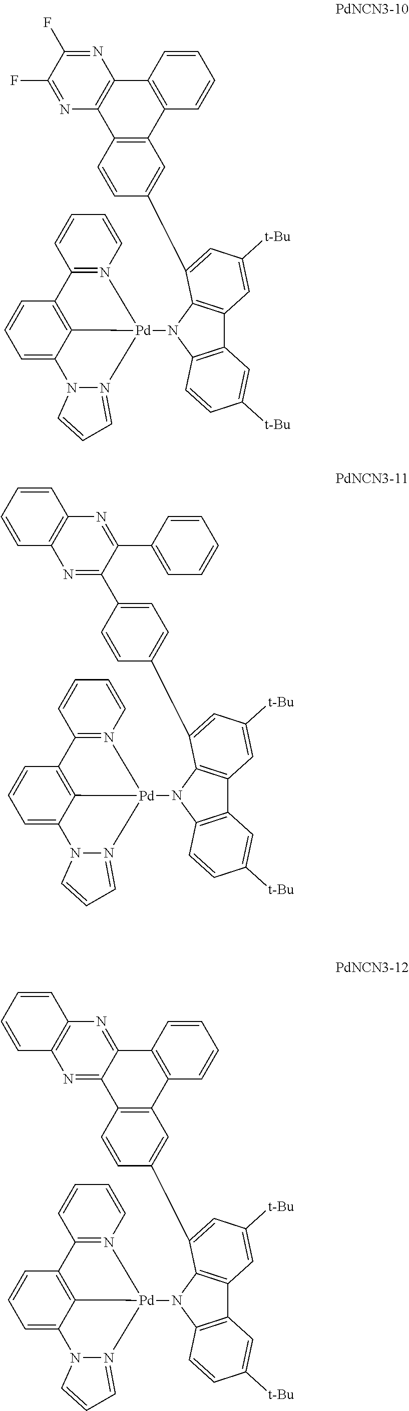

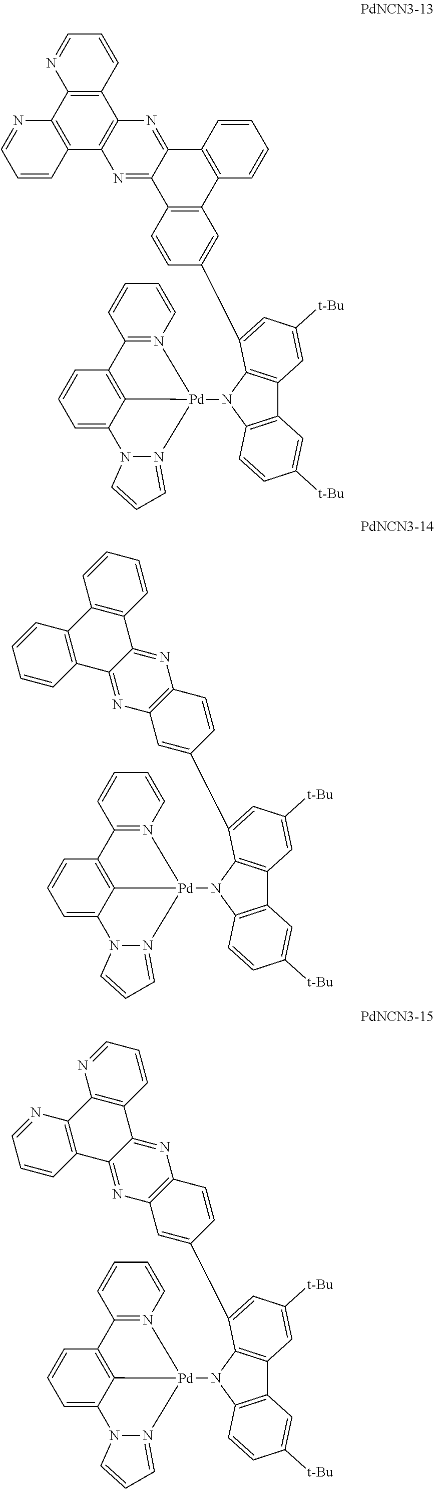

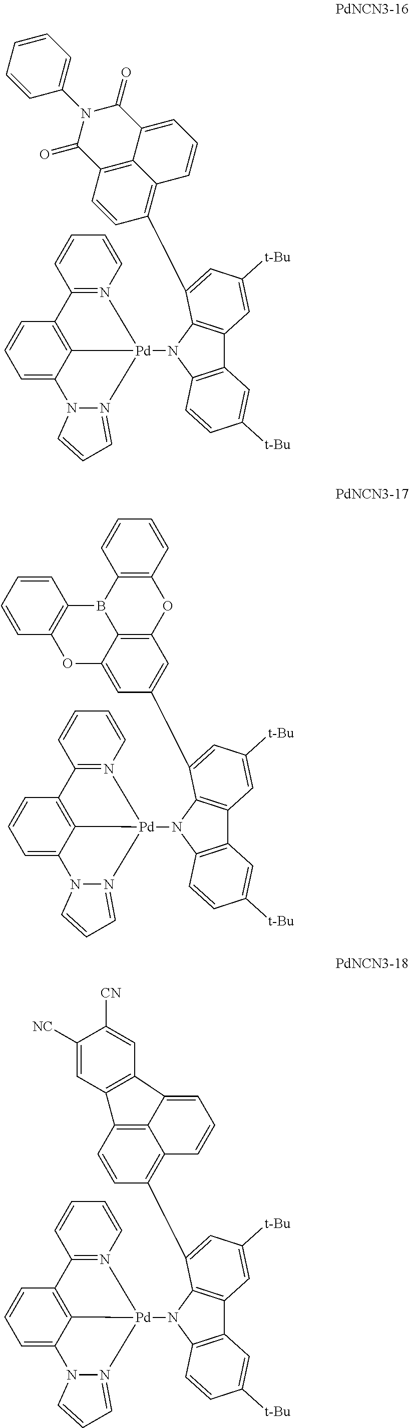

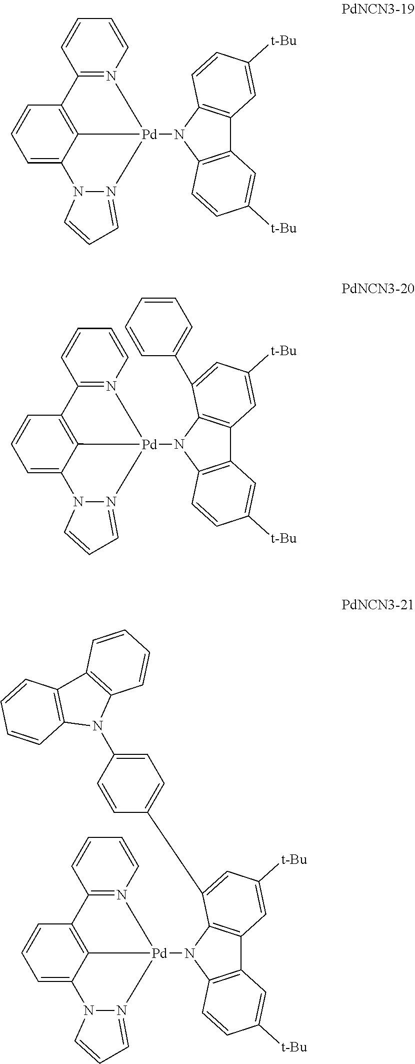

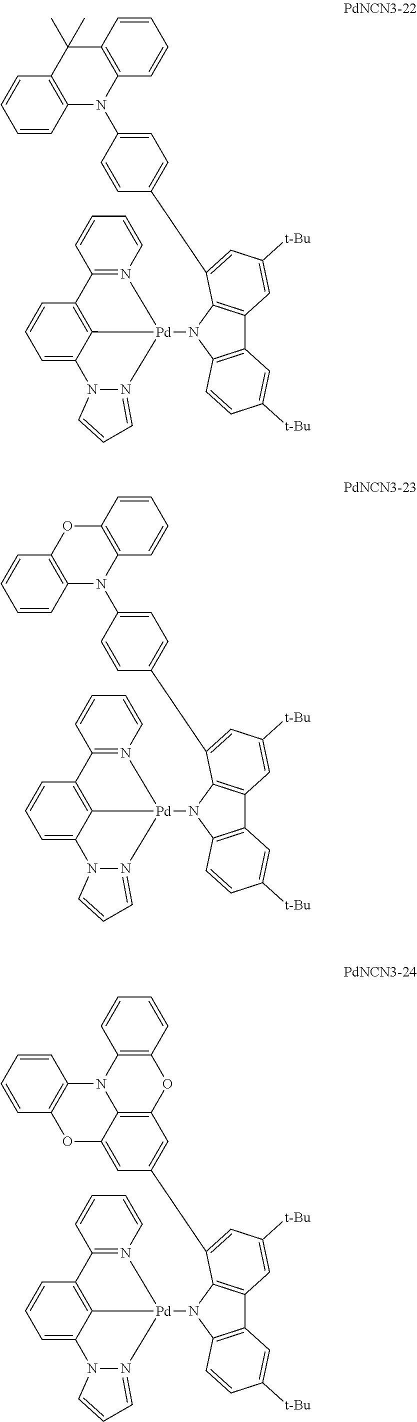

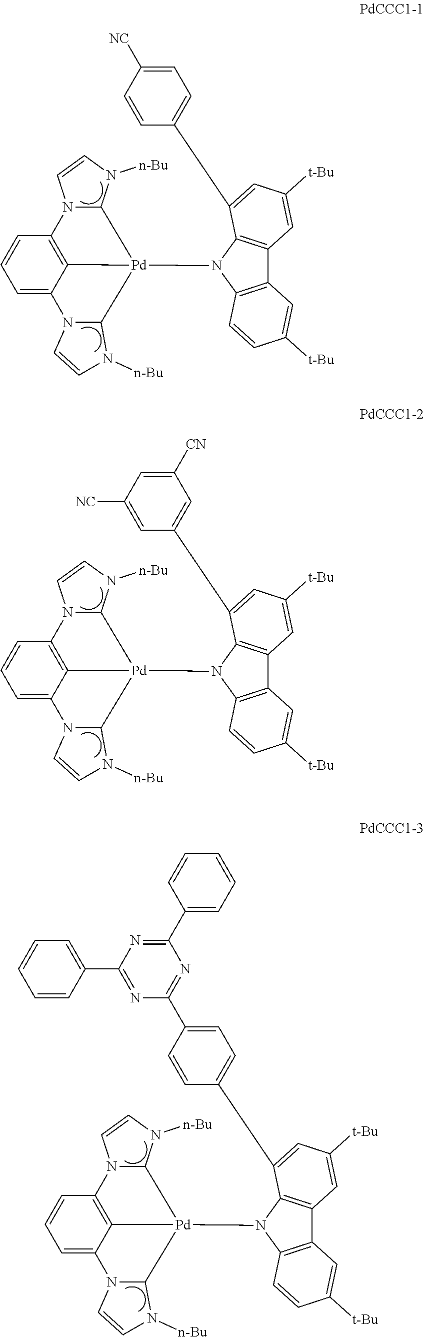

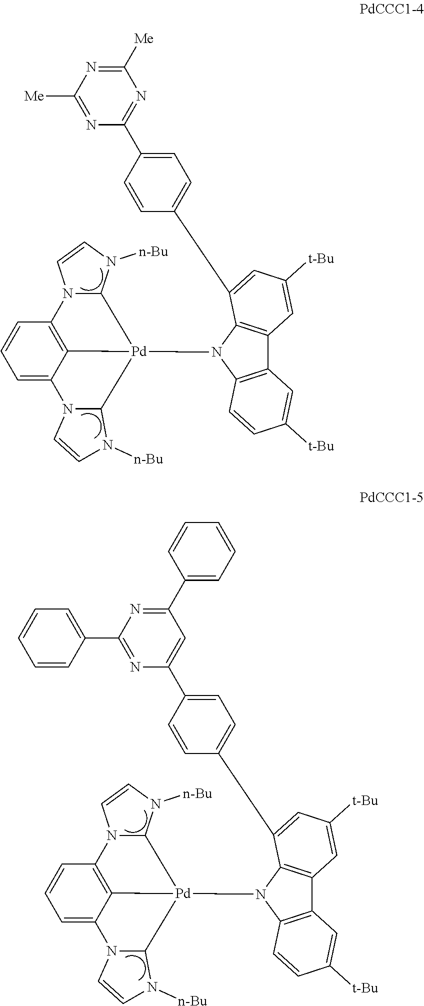

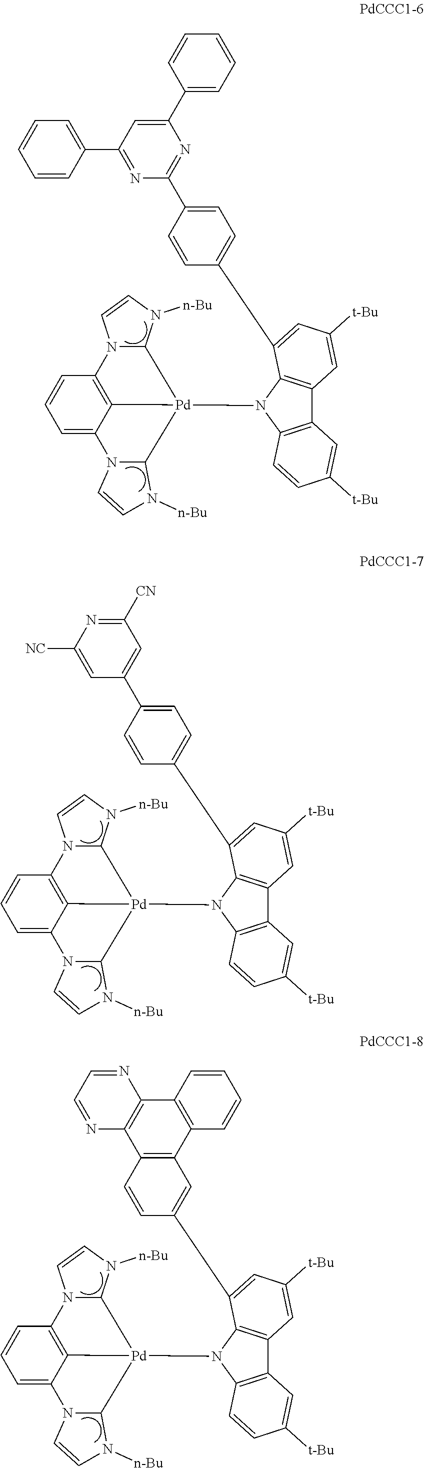

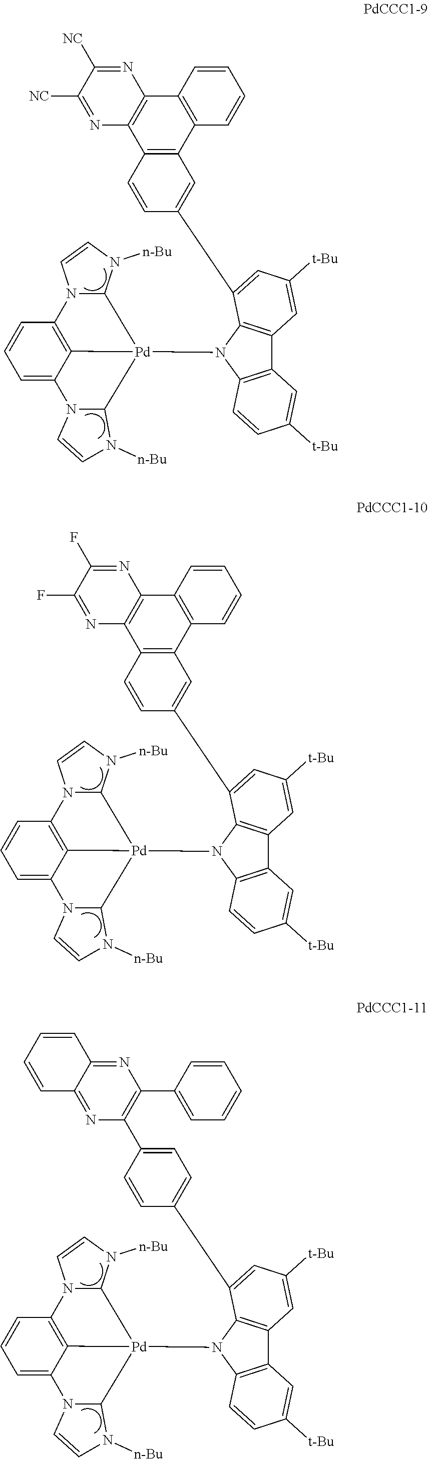

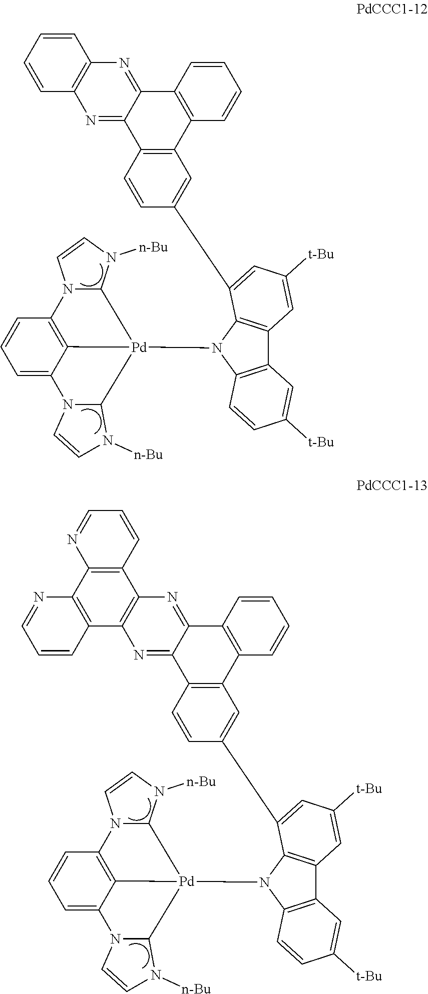

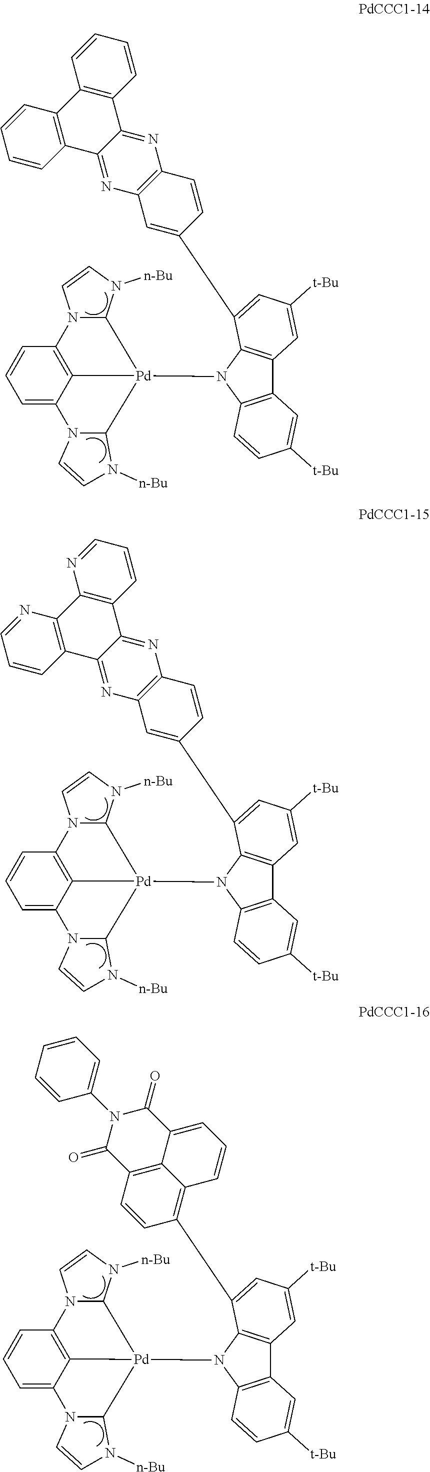

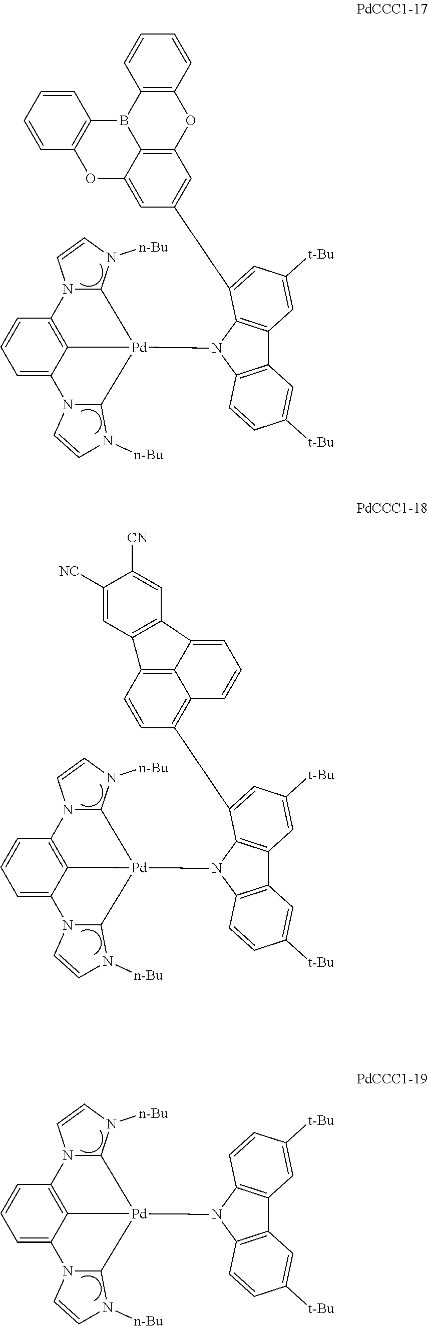

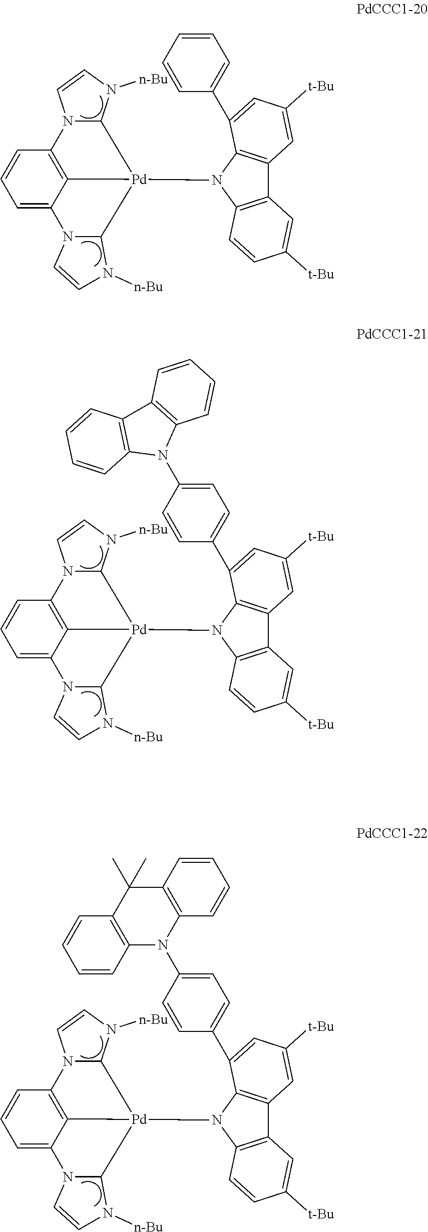

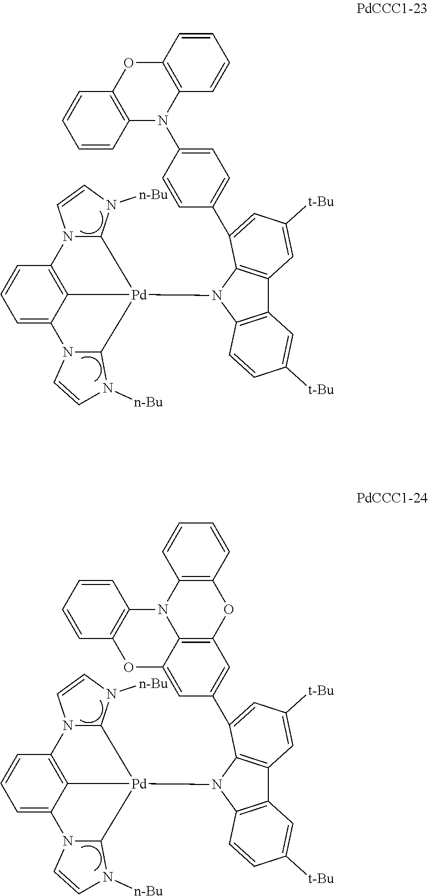

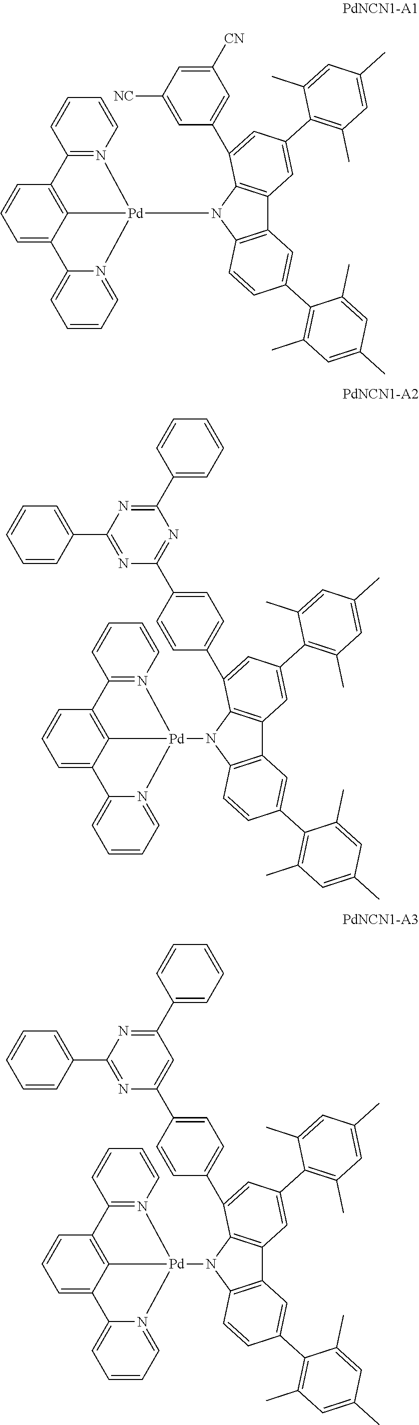

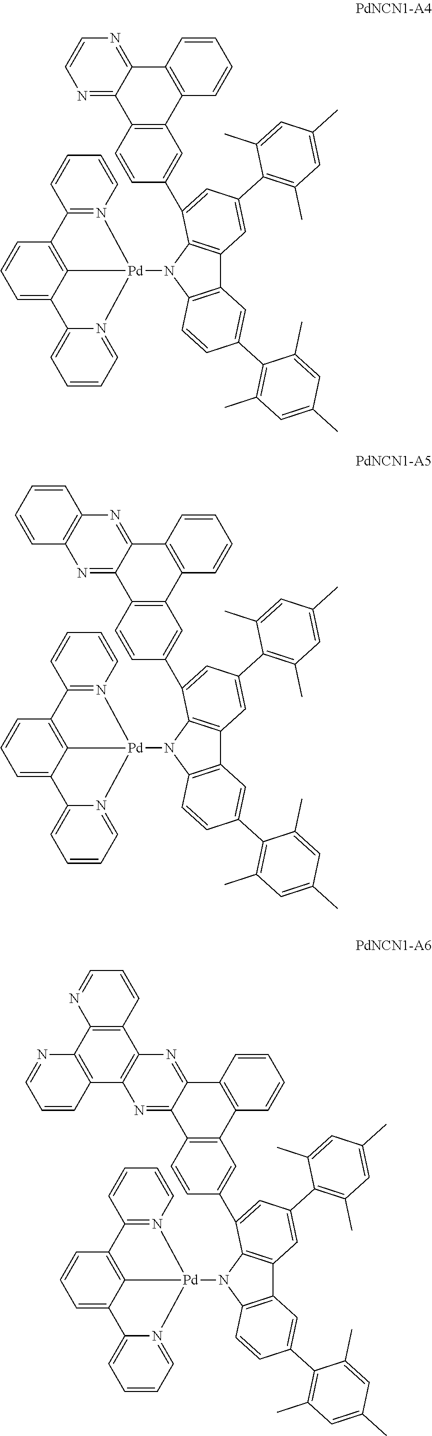

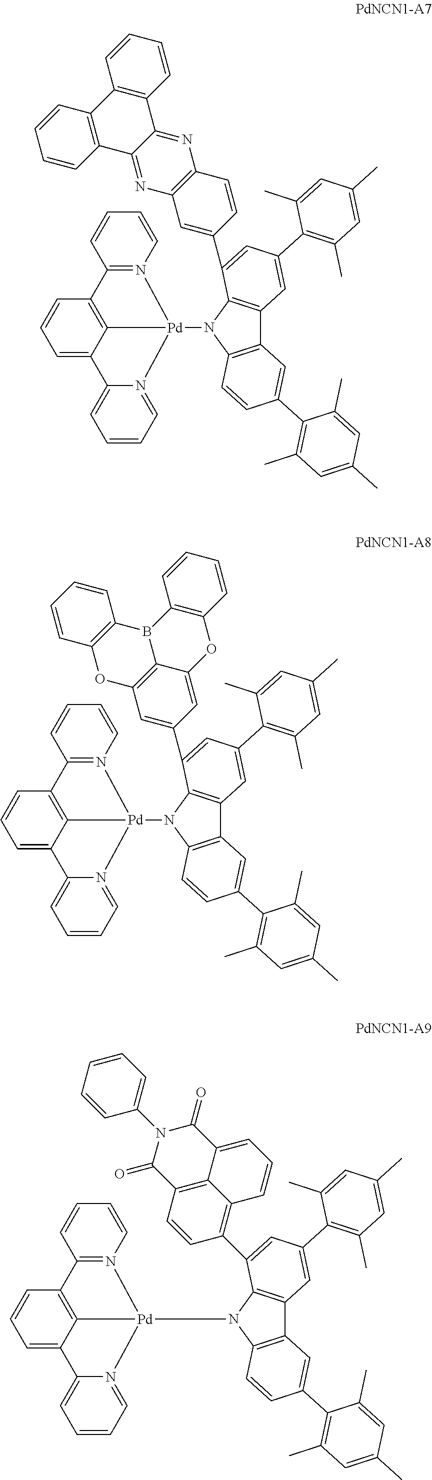

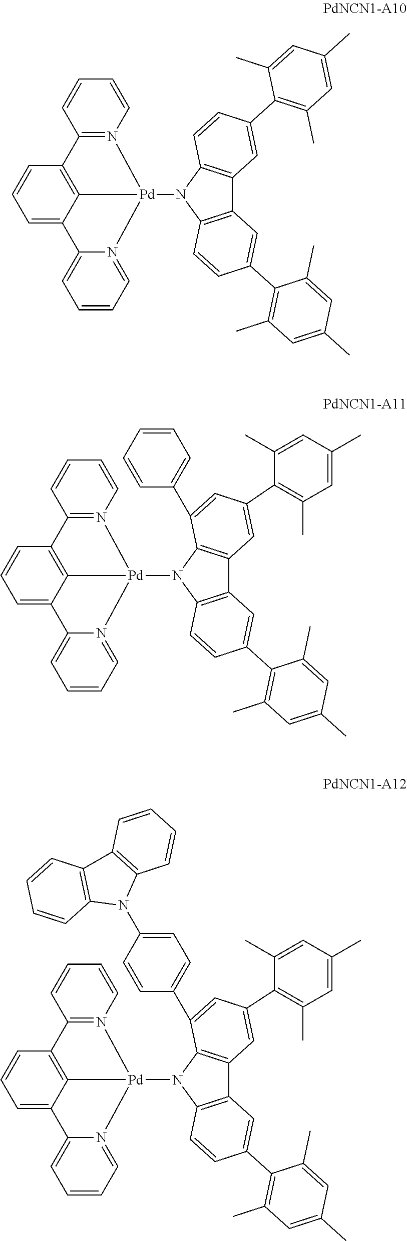

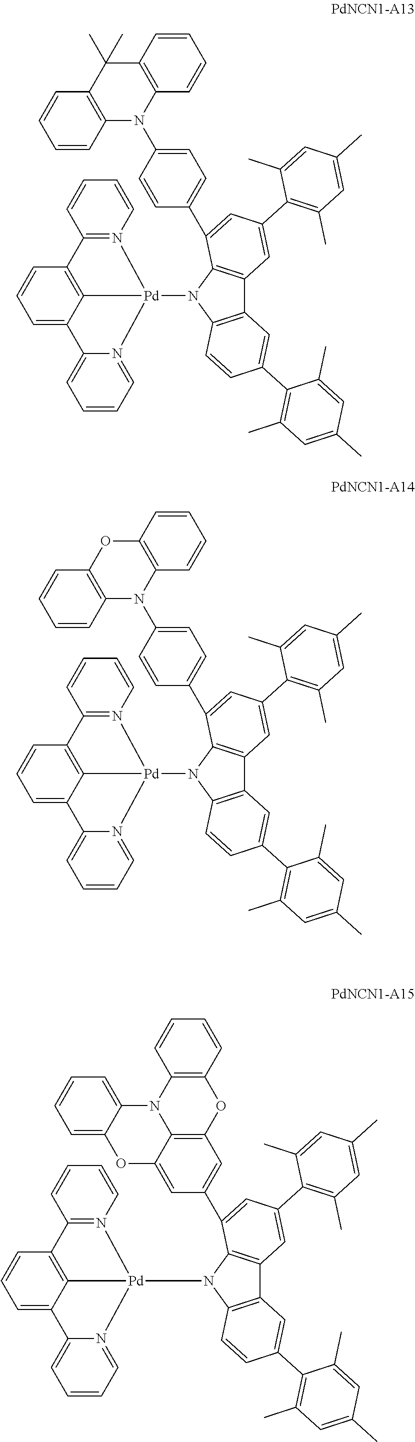

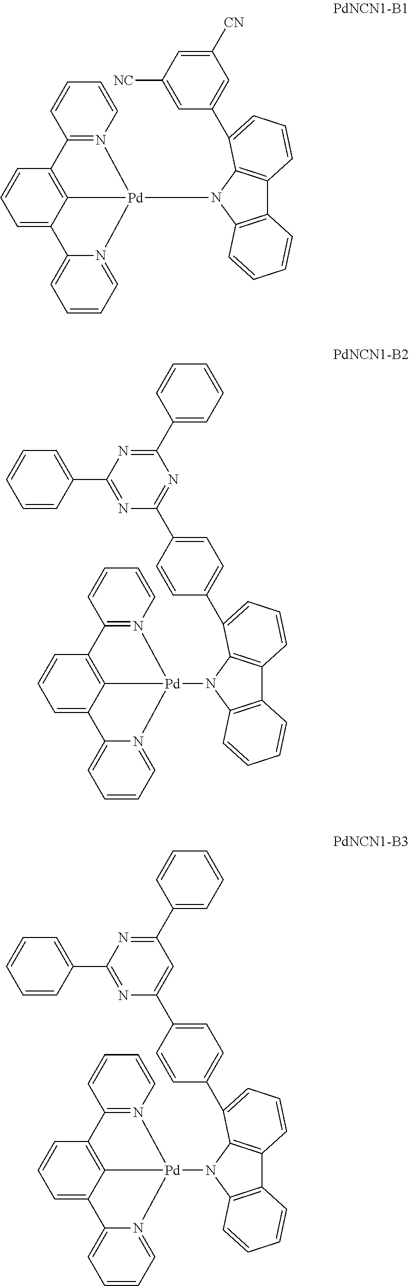

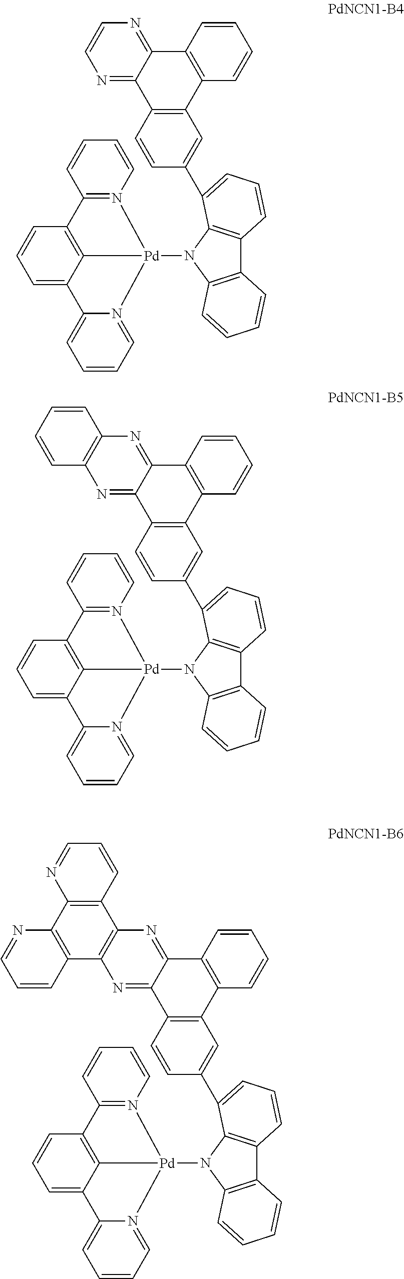

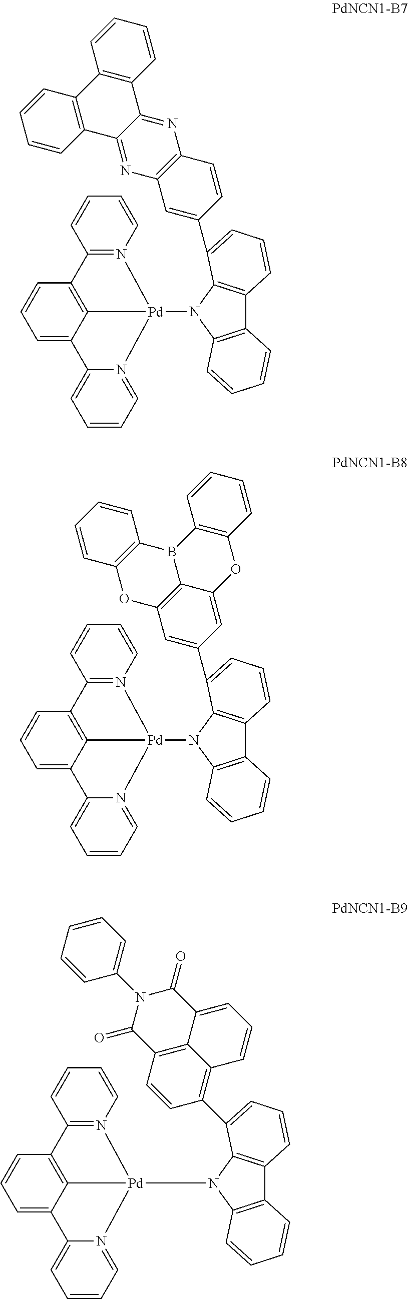

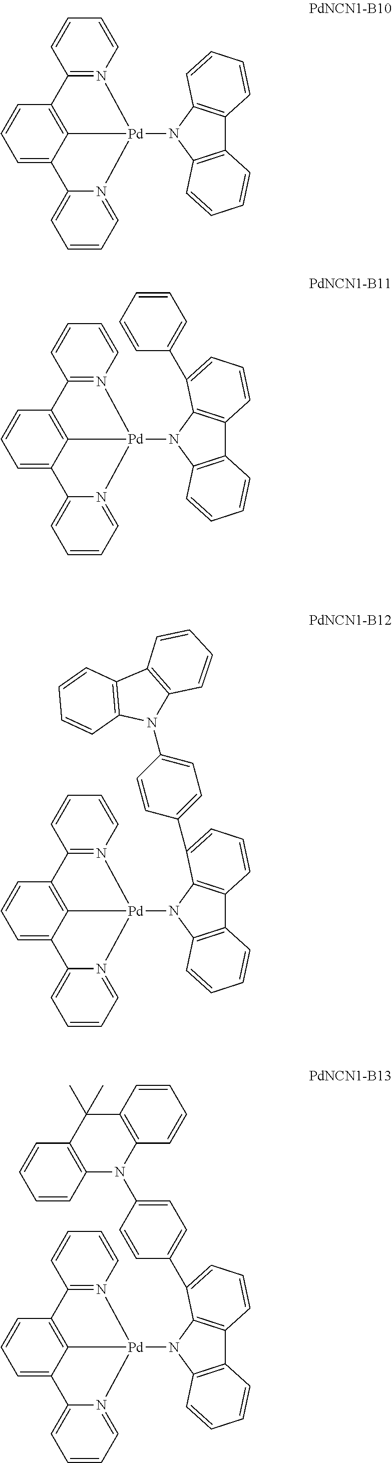

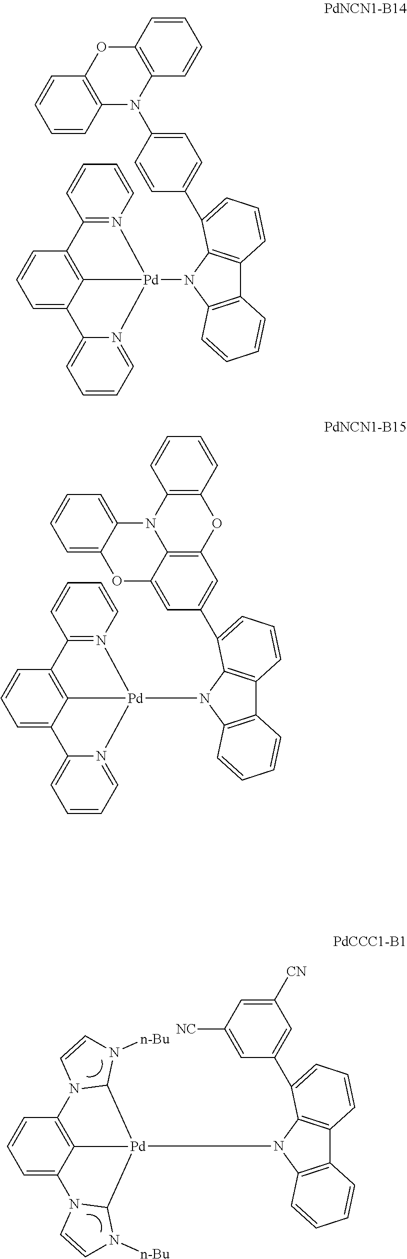

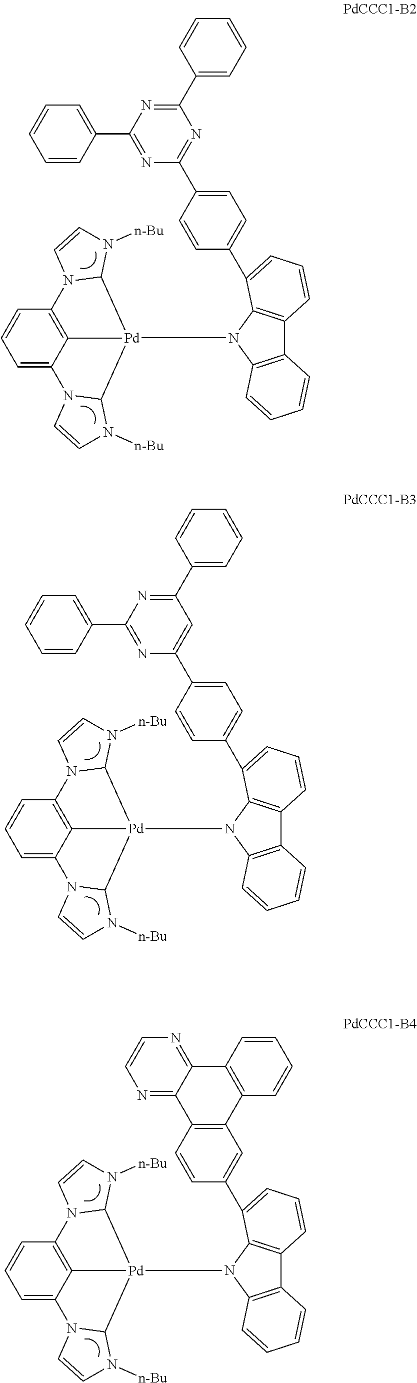

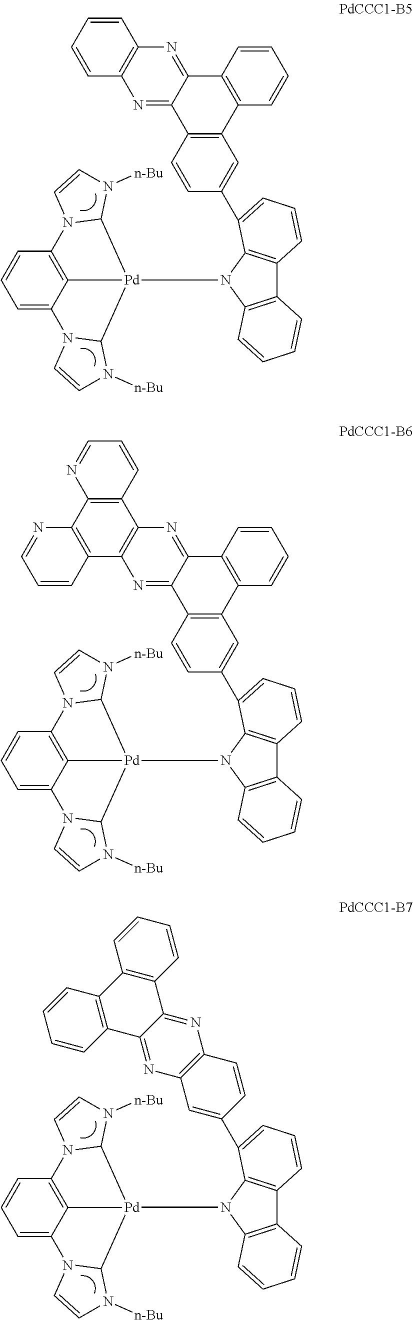

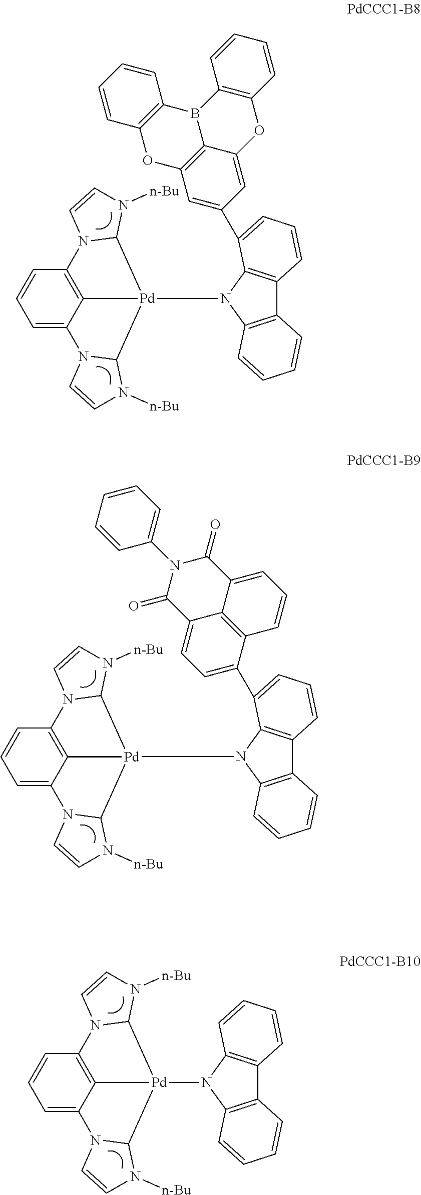

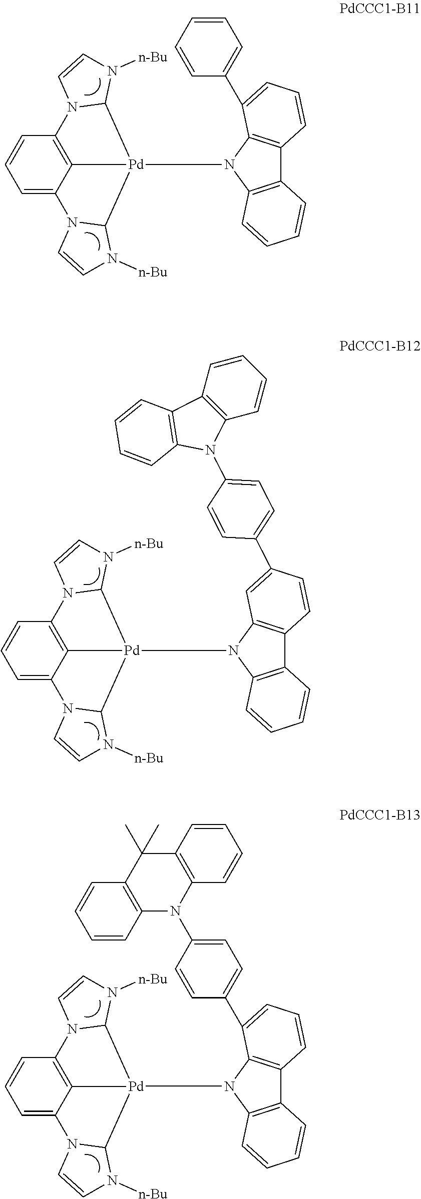

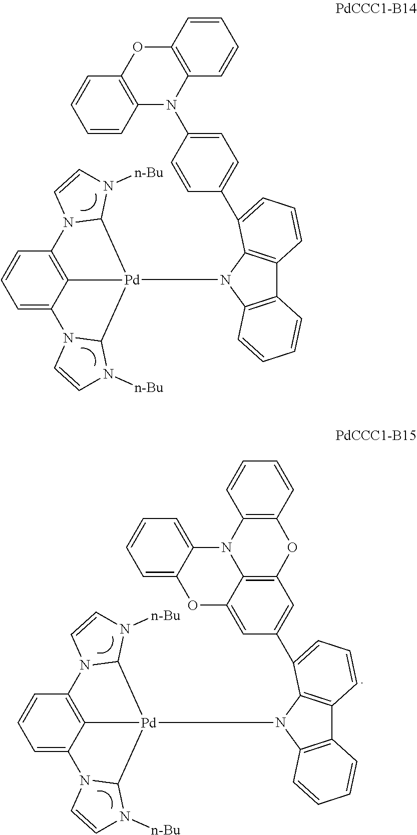

The present application further provides a preparation method for the above metal complex, including the following steps:
step 1: reacting a tridentate ligand with potassium tetrachloroplatinate or palladium dichloride to generate a tridentate ligand M metal chloride E;
step 2: obtaining a compound aryl boronate B from a compound A and bis(pinacolato)diboron via Suzuki coupling reaction, and then obtaining a ligand D from the compound B and a compound C via the Suzuki coupling reaction;
or, obtaining a compound N through reaction of the compound C and pinacolborane, and then obtaining the ligand D from the compound N and the compound A via the Suzuki coupling reaction; and
step 3: obtaining the metal complex (the compound of General Formula 1) through coordination reaction of the ligand D and the tridentate ligand M metal chloride E.

A synthetic route for the metal complex of the present application is as shown below:

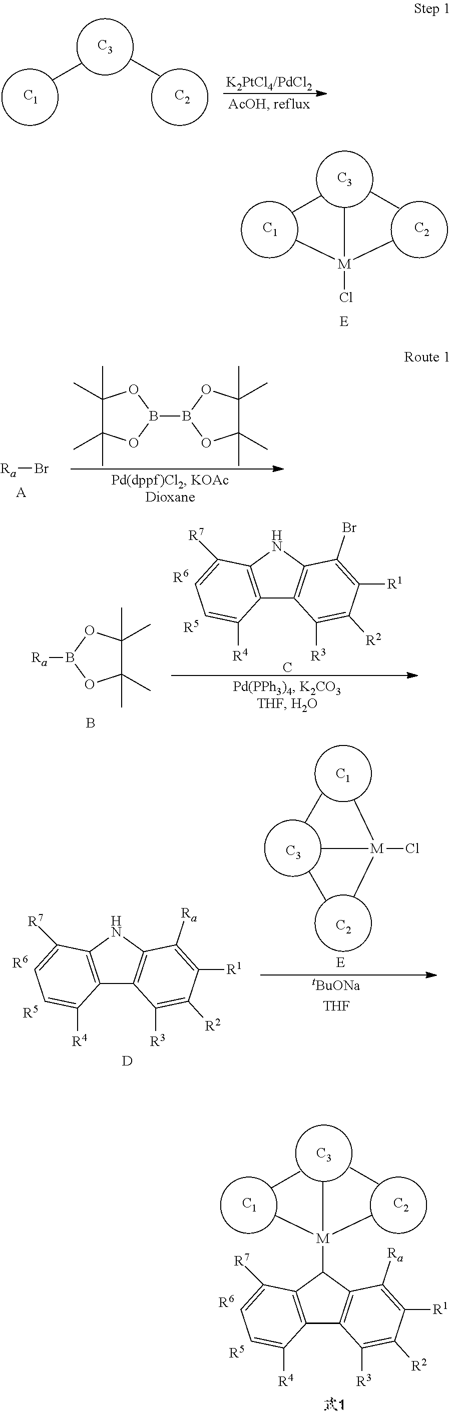

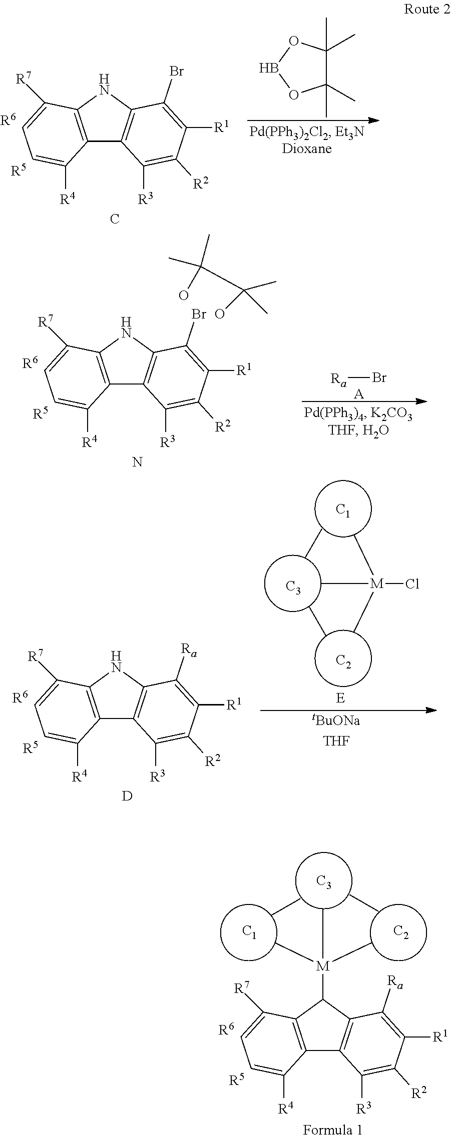

The present application further provides an organic electroluminescent device. The organic electroluminescent device includes a first electrode, a second electrode and a light-emitting layer located between the first electrode and the second electrode, and the light-emitting layer includes any one of or a combination of at least two of the above metal complex.

Optionally, the light-emitting layer includes the above metal complex together with an organic functional material, and by mass percentage, a proportion of the metal complex is 0.01%-100%, and a proportion of the organic functional material is 0-99.9%.

It should be noted that, an application of the metal complex of the present application is not limited to the composition of the device, and a membrane thickness or composition material of each layer may be properly changed according to basic physical properties of specific compound structures of the present application.

A preparation method for the organic device of the present application is a conventional method in the art. Optionally, preparation of the organic electroluminescent device includes the following steps: using a glass substrate on which ITO is evaporated as a transparent supporting substrate, and forming respective organic layers and metal electrodes on an ITO membrane of the transparent supporting substrate in sequence through evaporation.

The present application further provides a use of the above organic electroluminescent device in an electronic device.

The present application has the beneficial effects:
the metal complex provided by the present application has the structure of Formula 1, the structure containing tridentate ligand-metal-secondary amines has good thermally activated delayed fluorescence (TADF) performance, through the unique structure and a transition mode of molecules, and the introduction of groups with an electron withdrawing effect such as an aryl group and a heteroaryl group at the first substitution site Ra of carbazole, intra-molecule non-covalent interactions between Ra and the tridentate ligand may be formed, the stability of the metal complex is improved, a charge transfer process within and between ligands is enhanced, and thus geometric distortion of the metal complex is suppressed and then a non-radiative transition process is suppressed, so that the manufactured organic electroluminescent device has high external quantum efficiency and a long device lifetime, with the external quantum efficiency of up to 35.6%.

Further, the tridentate ligand used in the metal complex provided by the present application may be obtained with a high yield through simple organic synthesis, and the raw material cost is low, which is of great significance for a mass production process of luminescent materials.

### BRIEF DESCRIPTION OF THE DRAWINGS

In order to describe technical solutions in specific implementations of the present application or in the prior art more clearly, the accompanying drawings that need to be used in the description of the specific implementations or the prior art will be briefly introduced below. Apparently, the accompanying drawings in the following description are some implementations of the present application, and for those of ordinary skill in the art, on the premise of no creative labor, other accompanying drawings can further be obtained from these accompanying drawings.

FIG. 1 is a structural diagram of an organic electroluminescent device in Device Examples 1-11 of the present application.

FIG. 2 is a crystal structural diagram of PtNCN1-12 prepared in Example 3 of the present application.

FIG. 3 is a thermogravimetric analysis curve of the PtNCN1-12 prepared in Example 3 of the present application.

FIG. 4 is an absorption spectrogram of PdCCC1-B5 prepared in Example 30 of the present application in a toluene solution.

FIG. 5 is an absorption spectrogram of PdCCC1-5 prepared in Example 28 of the present application in a toluene solution.

FIG. 6 is an absorption spectrogram of PdCCC1-3 prepared in Example 26 of the present application in a toluene solution.

FIG. 7 is an emission spectrogram of the PdCCC1-B5 prepared in Example 30 of the present application in a toluene solution.

FIG. 8 is an emission spectrogram of the PdCCC1-5 prepared in Example 28 of the present application in a toluene solution.

FIG. 9 is an emission spectrogram of the PdCCC1-3 prepared in Example 26 of the present application in a toluene solution.

FIG. 10 is an absorption spectrogram of PtNCN1-5 prepared in Example 7 of the present application in a toluene solution.

FIG. 11 is an absorption spectrogram of PtNCN1-3 prepared in Example 8 of the present application in a toluene solution.

FIG. 12 is an absorption spectrogram of PtNCN1-16 prepared in Example 11 of the present application in a toluene solution.

FIG. 13 is an absorption spectrogram of PtNCN1-12 prepared in Example 3 of the present application in a toluene solution.

FIG. 14 is an absorption spectrogram of PtNCN1-20 prepared in Example 21 of the present application in a toluene solution.

FIG. 15 is an absorption spectrogram of PtNCN1-21 prepared in Example 22 of the present application in a toluene solution.

FIG. 16 is an absorption spectrogram of PtNCN3-16 prepared in Example 16 of the present application in a toluene solution.

FIG. 17 is an absorption spectrogram of PtNCN3-22 prepared in Example 23 of the present application in a toluene solution.

FIG. 18 is an absorption spectrogram of PtNCN3-23 prepared in Example 24 of the present application in a toluene solution.

FIG. 19 is an absorption spectrogram of PtNCN3-24 prepared in Example 25 of the present application in a toluene solution.

FIG. 20 is an emission spectrogram of the PtNCN1-5 prepared in Example 7 of the present application in a tetrahydrofuran solution.

FIG. 21 is an emission spectrogram of the PtNCN1-3 prepared in Example 8 of the present application in a tetrahydrofuran solution.

FIG. 22 is an emission spectrogram of the PtNCN1-12 prepared in Example 3 of the present application in a toluene solution.

FIG. 23 is an emission spectrogram of the PtNCN1-5 prepared in Example 7 of the present application in a polymethyl methacrylate thin film.

FIG. 24 is an emission spectrogram of the PtNCN1-3 prepared in Example 8 of the present application in a polymethyl methacrylate thin film.

FIG. 25 is an emission spectrogram of the PtNCN1-16 prepared in Example 11 of the present application in a polymethyl methacrylate thin film.

FIG. 26 is an emission spectrogram of the PtNCN1-12 prepared in Example 3 of the present application in a polymethyl methacrylate thin film.

FIG. 27 is an emission spectrogram of the PtNCN1-20 prepared in Example 21 of the present application in a polymethyl methacrylate thin film.

FIG. 28 is an emission spectrogram of the PtNCN1-21 prepared in Example 22 of the present application in a polymethyl methacrylate thin film.

FIG. 29 is an emission spectrogram of the PtNCN3-22 prepared in Example 23 of the present application in a polymethyl methacrylate thin film.

FIG. 30 is an emission spectrogram of the PtNCN3-23 prepared in Example 24 of the present application in a polymethyl methacrylate thin film.

FIG. 31 is an emission spectrogram of the PtNCN3-24 prepared in Example 25 of the present application in a polymethyl methacrylate thin film.

FIG. 32 is an emission spectrogram of PdCCC1-12 prepared in Example 27 of the present application in a polymethyl methacrylate thin film.

FIG. 33 is an emission spectrogram of the PdCCC1-3 prepared in Example 26 of the present application in a polymethyl methacrylate thin film.

FIG. 34 is a lifetime attenuation graph of the PtNCN1-5 prepared in Example 7 of the present application in a polymethyl methacrylate thin film.

FIG. 35 is a lifetime attenuation graph of the PtNCN1-3 prepared in Example 8 of the present application in a polymethyl methacrylate thin film.

FIG. 36 is a lifetime attenuation graph of the PtNCN1-16 prepared in Example 11 of the present application in a polymethyl methacrylate thin film.

FIG. 37 is a lifetime attenuation graph of the PtNCN1-12 prepared in Example 3 of the present application in a polymethyl methacrylate thin film.

FIG. 38 is a lifetime attenuation graph of the PtNCN1-20 prepared in Example 21 of the present application in a polymethyl methacrylate thin film.

FIG. 39 is a lifetime attenuation graph of the PtNCN1-21 prepared in Example 21 of the present application in a polymethyl methacrylate thin film.

FIG. 40 is a lifetime attenuation graph of the PtNCN3-16 prepared in Example 16 of the present application in a polymethyl methacrylate thin film.

FIG. 41 is a lifetime attenuation graph of the PtNCN3-22 prepared in Example 23 of the present application in a polymethyl methacrylate thin film.

FIG. 42 is a lifetime attenuation graph of the PtNCN3-23 prepared in Example 24 of the present application in a polymethyl methacrylate thin film.

FIG. 43 is a lifetime attenuation graph of the PtNCN3-24 prepared in Example 25 of the present application in a polymethyl methacrylate thin film.

FIG. 44 is a lifetime attenuation graph of the PdCCC1-12 prepared in Example 27 of the present application in a polymethyl methacrylate thin film.

FIG. 45 is a lifetime attenuation graph of the PdCCC1-3 prepared in Example 26 of the present application in a polymethyl methacrylate thin film.

FIG. 46 is an electroluminescent diagram based on a compound PtNCN1-12 in Device Examples 1-4 of the present application.

FIG. 47 is an electroluminescent quantum efficiency diagram based on a compound PtNCN1-12 in Device Examples 1-4 of the present application.

FIG. 48 is an electroluminescent diagram based on a compound PdCCC1-12 in Device Examples 5-7 of the present application.

FIG. 49 is an electroluminescent quantum efficiency diagram based on the compound PdCCC1-12 in Device Examples 5-7 of the present application.

FIG. 50 is change of brightness with time based on a compound PdCCC1-12 in Device Example 12 of the present application.

FIG. 51 is an electroluminescent diagram based on a compound PdCCC1-5 in Device Examples 8-9 of the present application.

FIG. 52 is an electroluminescent quantum efficiency diagram based on the compound PdCCC1-5 in Device Examples 8-9 of the present application.

FIG. 53 is an electroluminescent diagram based on a compound PdCCC1-3 in Device Examples 10-11 of the present application.

FIG. 54 is an electroluminescent quantum efficiency diagram based on the compound PdCCC1-3 in Device Examples 10-11 of the present application.

### REFERENCE NUMERALS

1—anode layer, 2—hole injection layer, 3—first hole transport layer, 4—second hole transport layer, 5—electron block layer, 6—light-emitting layer, 7—first electron transport layer, 8—second electron transport layer, 9—electron injection layer, 10—cathode layer, and 100—glass substrate.

### DETAILED DESCRIPTION

The following examples are provided for further better understanding of the present application and are not limited to the optimal implementations, they do not limit the content and scope of protection of the present application, and any product that is the same as or similar to the present application obtained by anyone under the inspiration of the present application or by combining the present application with other prior art features falls within the scope of protection of the present application.

If specific experimental steps or conditions are not specified in the examples, the operation or conditions of conventional experimental steps described in the literature in this field can be carried out. The adopted reagents or instruments which are not specified with the manufacturer are conventional commercially-available reagent products.

A preparation method for a metal complex in this example includes the following steps:
step 1: a tridentate ligand reacts with potassium tetrachloroplatinate to generate a tridentate ligand M metal chloride E;
step 2: a compound aryl boronate B is obtained from a compound A and bis(pinacolato)diboron via Suzuki coupling reaction, and then a ligand D is obtained from the compound B and a compound C via the Suzuki coupling reaction;
or, a compound N is obtained through reaction of the compound C and pinacolborane, and then the ligand D is obtained from the compound N and the compound A via the Suzuki coupling reaction; and
step 3: the metal complex (the compound of General Formula 1) is obtained through coordination reaction of the ligand D and the tridentate ligand M metal chloride E.

A synthetic route for the metal complex in this example is as shown below:

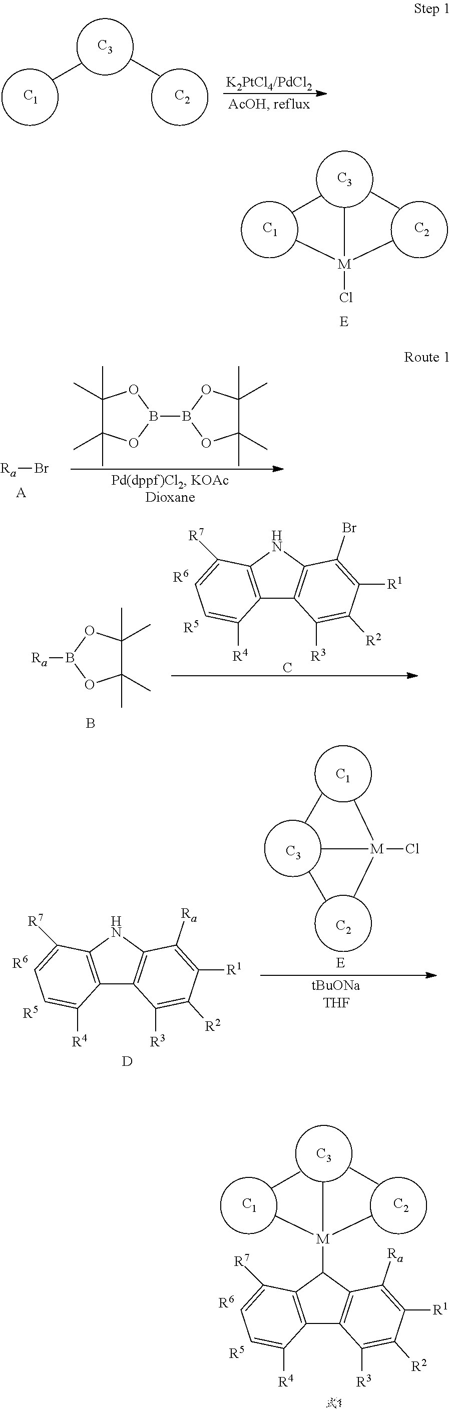

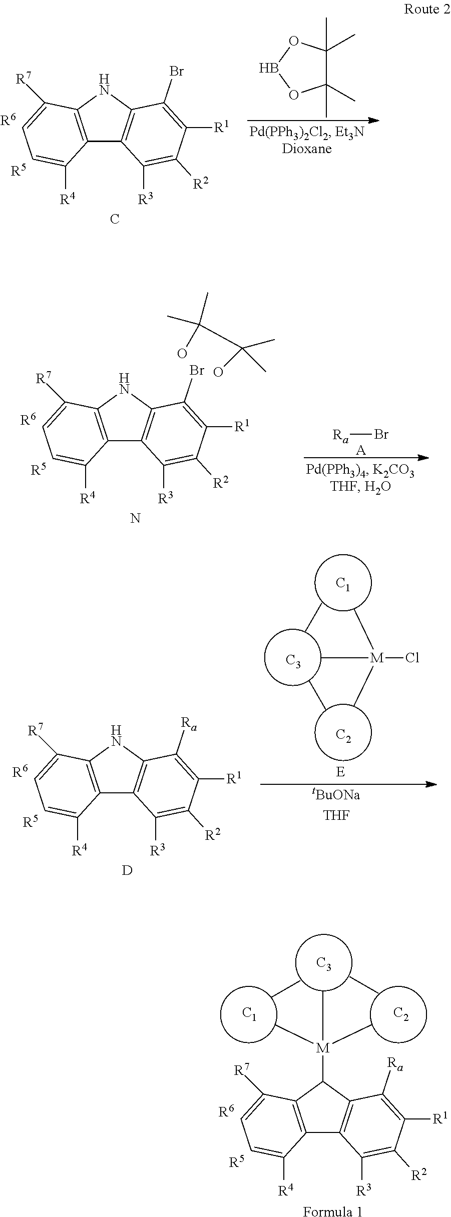

### Example 1

This example provided a preparation method for a tridentate ligand intermediate and its tridentate ligand M metal chloride required for preparing a metal complex subsequently, which was specifically as shown below:

### 1) Preparation of Tridentate Ligand Intermediate CNN

A synthetic route of the tridentate ligand intermediate CNN was as shown below:

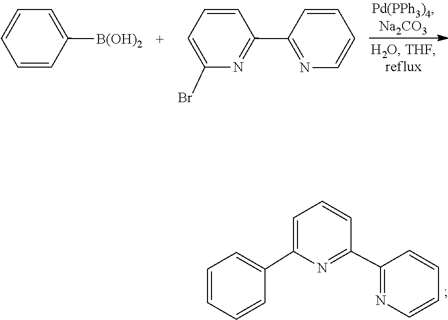 [SMILES: OB(O)c1ccccc1 ; Brc1cccc(-c2ccccn2)n1 ; c1ccc(-c2cccc(-c3ccccn3)n2)cc1]

phenylboronic acid (244 mg, 2 mmol), 6-bromo-2,2-bipyridine (383 mg, 1.63 mmol), Na₂CO₃ (864 mg, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=10:1) was carried out to obtain the colorless solid intermediate CNN (a yield being 98%).

### 2) Preparation of Tridentate Ligand Intermediate NCN1

A synthetic route of the tridentate ligand intermediate NCN1 was as shown below:

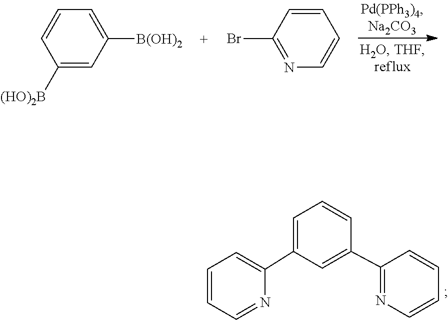 [SMILES: OB(O)c1cccc(B(O)O)c1 ; Brc1ccccn1 ; c1ccc(-c2cccc(-c3ccccn3)c2)nc1]

1,3-diphenylboronic acid (166 mg, 1 mmol), 1-bromopyridine (258 mg, 1.63 mmol), Na₂CO₃ (864 mg, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=10:1) was carried out to obtain the colorless solid intermediate NCN1 (a yield being 88%). ¹H NMR (400 MHz, CDCl₃) δ 8.71 (d, J=4.4 Hz, 2H), 8.64 (s, 1H), 8.05 (d, J=7.6 Hz, 2H), 7.81 (d, J=7.5 Hz, 2H), 7.72 (t, J=7.6 Hz, 2H), 7.57 (t, J=7.8 Hz, 1H), 7.21 (t, J=5.6 Hz, 2H); ¹³C NMR (101 MHz, CDCl3) δ 157.1, 149.7, 139.9, 136.8, 129.2, 127.5, 125.5, 122.3, 120.7 ppm; EI-MS: m/z calcd for C₁₆H₁₂N₂[M]⁺: 232.10; found: 232.27.

### 3) Preparation of Tridentate Ligand Intermediate NCN2

A synthetic route of the tridentate ligand intermediate NCN2 was as shown below:

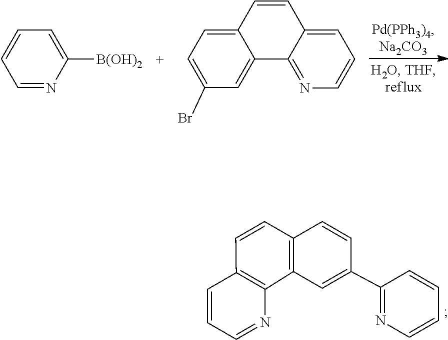 [SMILES: OB(O)c1ccccn1 ; Brc1ccc2ccc3cccnc3c2c1 ; c1ccc(-c2ccc3ccc4cccnc4c3c2)nc1]

2-pyridineboronic acid (234 mg, 1.9 mmol), monobromine (421 mg, 1.63 mmol), Na₂CO₃ (864 mg, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=10:1) was carried out to obtain the colorless solid intermediate NCN2 (a yield being 78%).

### 4) Preparation of Tridentate Ligand Intermediate NCN3

A synthetic route of the tridentate ligand intermediate NCN3 was as shown below:

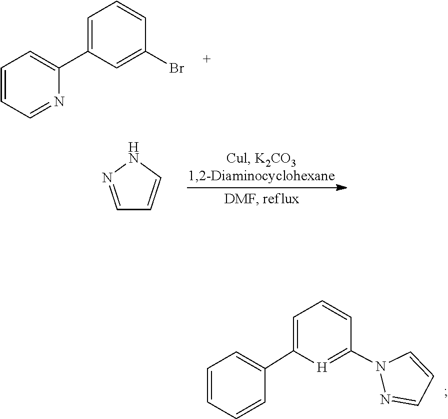

2-(3-bromobenzene)-pyridine (234 mg, 1 mmol), pyrazole (102 mg, 1.5 mmol), K₂CO₃ (830 mg, 6 mmol), 1,2-cyclohexanediamine (46 mg, 0.4 mmol) and copper iodide (19 mg, 0.1 mmol) were dissolved in 30 ml of DMF and stirred, a temperature was slowly raised to 130° C., reaction was performed overnight, dichloromethane and water were used for extraction, reduced pressure distillation was carried out, and column chromatography purification (an eluent being petroleum ether:dichloromethane=2:1) was carried out to obtain the colorless solid intermediate NCN3 (a yield being 88%). 1H NMR (500 MHz, CDCl3) δ 8.73 (d, J=4.6 Hz, 1H), 8.38 (t, J=1.9 Hz, 1H), 8.07 (d, J=2.4 Hz, 1H), 8.03 (s, 1H), 7.93 (d, J=7.8 Hz, 1H), 7.80 (m, 4H), 7.58 (t, J=7.9 Hz, 1H), 7.29 (m, 1H).

### 5) Preparation of Tridentate Ligand Intermediate CCC1

A synthetic route of the tridentate ligand intermediate CCC1 was as shown below:

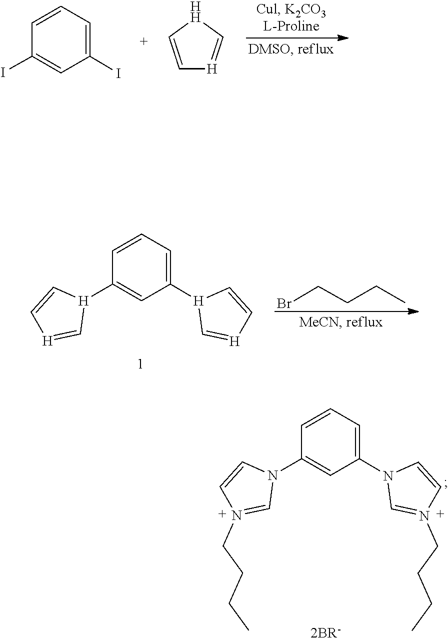

1,3-benzene diiodide (330 mg, 1 mmol), imidazole (102 mg, 1.5 mmol), K₂CO₃ (830 mg, 6 mmol), copper iodide (19 mg, 0.1 mmol) and L-proline (58 mg, 0.5 mmol) were dissolved in 30 ml of an anhydrous DMSO solution and stirred, a temperature was slowly raised to 140° C., reaction was performed for 48 h, dichloromethane and water were used for extraction, reduced pressure distillation was carried out, and column chromatography purification (an eluent being petroleum ether:dichloromethane=2:1) was carried out to obtain a colorless solid intermediate 1 (a yield being 80%).

The intermediate 1 (210 mg, 1 mmol) and n-butyl bromide (1370 mg, 10 mmol) were dissolved in 30 ml of an acetonitrile solution and stirred, a temperature was slowly raised to 80° C., reaction was performed for 72 h, and filtering and reduced pressure distillation were carried out to obtain the colorless solid intermediate CCC1 (a yield being 60%). 1H NMR (300 MHz, CD2Cl2): δ 11.56 (s, 2H), 9.04 (t, J=2.0 Hz, 1H), 8.91 (t, J=1.8 Hz, 2H), 8.24 (dd, J=8.3, 2.0 Hz, 2H), 7.72 (t, J=8.3 Hz, 1H), 7.60 (t, J=1.8 Hz, 2H), 4.45 (t, J=7.3 Hz, 4H), 2.02 (tt, J=7.5 Hz, 4H), 1.43 (qt, J=7.5 Hz, 4H), 1.00 (t, J=7.3 Hz, 6H). 13C NMR (126 MHz, CD2Cl2): δ 137.0, 136.5, 133.0, 123.4, 122.8, 122.4, 115.5, 51.0, 32.4, 20.1, 13.8.

### 6) Preparation of Tridentate Ligand Metal Chloride ClPtCNN

A synthetic route of the tridentate ligand metal chloride ClPtCNN was as shown below:

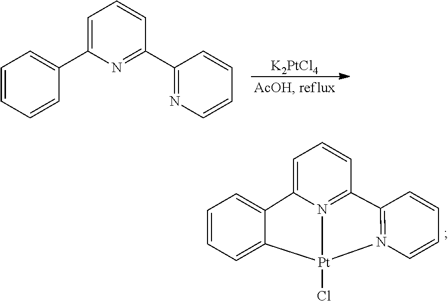

a CNN ligand (232 mg, 1 mmol) and potassium tetrachloroplatinate (415 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPtCNN (a yield being 65%).

### 7) Preparation of Tridentate Ligand Metal Chloride ClPtNCN1

A synthetic route of the tridentate ligand metal chloride ClPtNCN1 was as shown below:

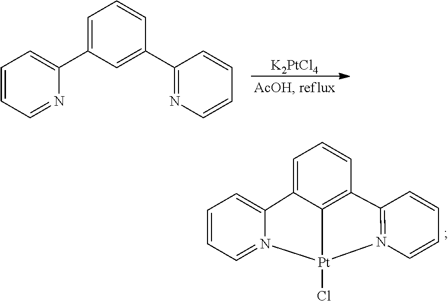

an NCN1 ligand (232 mg, 1 mmol) and potassium tetrachloroplatinate (415 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPtNCN1 (a yield being 69%). 1H NMR (300 MHz, DMSO-d6) δ 9.07 (dd, J=5.5, 0.9 Hz, 2H), 8.17 (td, J=7.7, 1.6 Hz, 2H), 8.07 (br d, J=7.6 Hz, 2H), 7.70 (d, J=7.7 Hz, 2H), 7.52 (ddd, J=7.4, 5.8, 1.6 Hz, 2H), 7.23 (t, J=7.7 Hz, 1H); 13C NMR (75 MHz, DMSO-d6) δ 166.73, 161.19, 151.41, 140.65, 140.60, 125.09, 124.28, 123.28, 120.62.

### 8) Preparation of Tridentate Ligand Metal Chloride ClPtNCN2

A synthetic route of the tridentate ligand metal chloride ClPtNCN2 was as shown below:

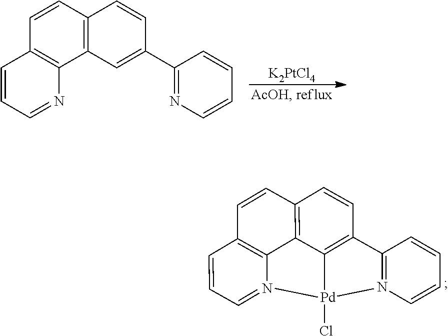

an NCN2 ligand (256 mg, 1 mmol) and potassium tetrachloroplatinate (415 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPtNCN2 (a yield being 75%).

### 9) Preparation of Tridentate Ligand Metal Chloride ClPtNCN3

A synthetic route of the tridentate ligand metal chloride ClPtNCN3 was as shown below:

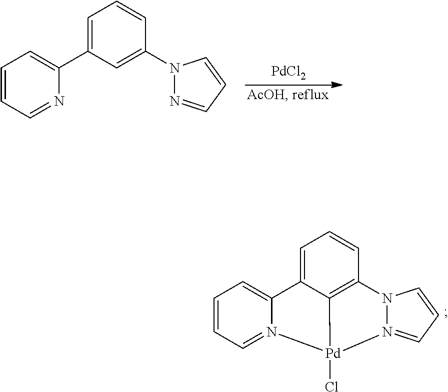

an NCN3 ligand (221 mg, 1 mmol) and potassium tetrachloroplatinate (415 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPtNCN3 (a yield being 70%). 1H NMR (500 MHz, CDCl3) δ 9.35 (t, J=10.3 Hz, 1H), 8.07 (dd, J=10.2, 2.6 Hz, 2H), 7.99 (td, J=7.8, 1.5 Hz, 1H), 7.73 (d, J=7.7 Hz, 1H), 7.38 (d, J=7.7 Hz, 1H), 7.34 (m, 1H), 7.28 (m, 4H), 7.15 (d, J=7.8 Hz, 1H), 6.68 (m, 1+H).

10) Preparation of Tridentate Ligand Metal Chloride ClPtCCC1

A synthetic route of the tridentate ligand metal chloride ClPtCCC1 was as shown below:

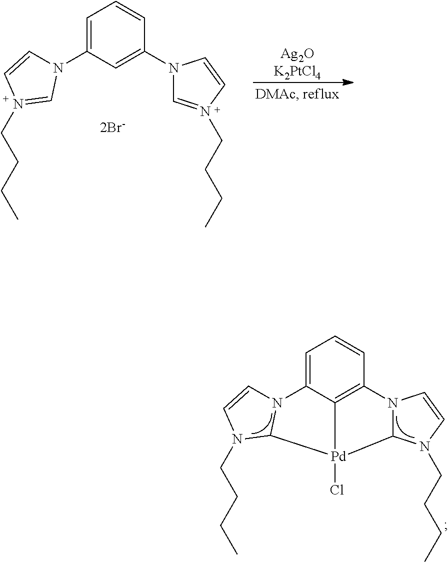

a CCC1 ligand (324 mg, 1 mmol), potassium tetrachloroplatinate (830 mg, 2 mmol) and silver oxide (552 mg, 2.38 mmol) were dissolved in 20 mL of DMSO and stirred with light shielded, a temperature was slowly raised to 156° C., and after reaction was performed for 72 hours, a coarse product was suspended in dichloromethane and filtered. A filtrate was washed with water, and an organic phase was dried with magnesium sulfate. Acetonitrile was added after the organic phase was subjected to rotary evaporation, and then rotary evaporation was carried out again to obtain the yellow solid intermediate ClPtCCC1 (a yield being 70%).

### 11) Preparation of Tridentate Ligand Metal Chloride ClPdCNN

A synthetic route of the tridentate ligand metal chloride ClPdCNN was as shown below:

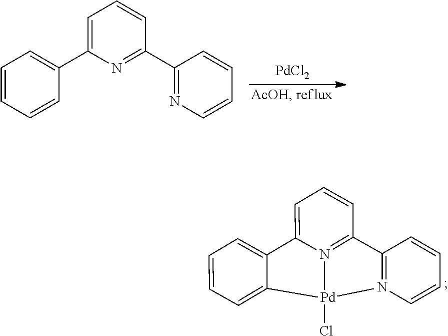

a CNN ligand (232 mg, 1 mmol) and palladium dichloride (177 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPdCNN (a yield being 75%).

### 12) Preparation of Tridentate Ligand Metal Chloride ClPdNCN1

A synthetic route of the tridentate ligand metal chloride ClPdNCN1 was as shown below:

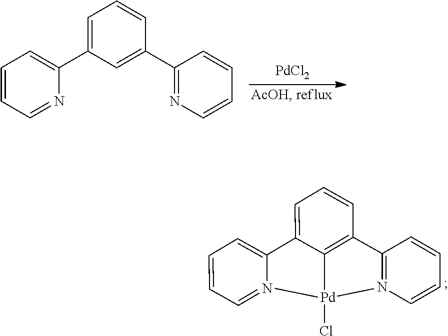

an NCN1 ligand (232 mg, 1 mmol) and palladium dichloride (177 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPdNCN1 (a yield being 69%).

### 13) Preparation of Tridentate Ligand Metal Chloride ClPdNCN2

A synthetic route of the tridentate ligand metal chloride ClPdNCN2 was as shown below:

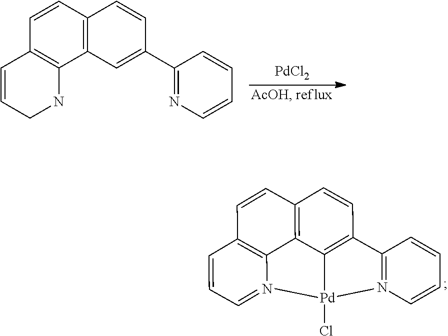

an NCN2 ligand (256 mg, 1 mmol) and palladium dichloride (177 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPdNCN2 (a yield being 75%).

### 14) Preparation of Tridentate Ligand Metal Chloride ClPdNCN3

A synthetic route of the tridentate ligand metal chloride ClPdNCN3 was as shown below:

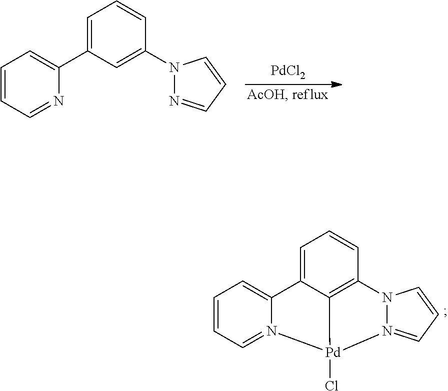

an NCN3 ligand (221 mg, 1 mmol) and palladium dichloride (177 mg, 1 mmol) were dissolved in 20 mL of glacial acetic acid and stirred, a temperature was slowly raised to 120° C., filtering was carried out after reaction was performed for 72 hours, and washing and drying were carried out to obtain the colorless solid intermediate ClPdNCN3 (a yield being 70%).

### 15) Preparation of Tridentate Ligand Metal Chloride ClPdCCC1

A synthetic route of the tridentate ligand metal chloride ClPdCCC1 was as shown below

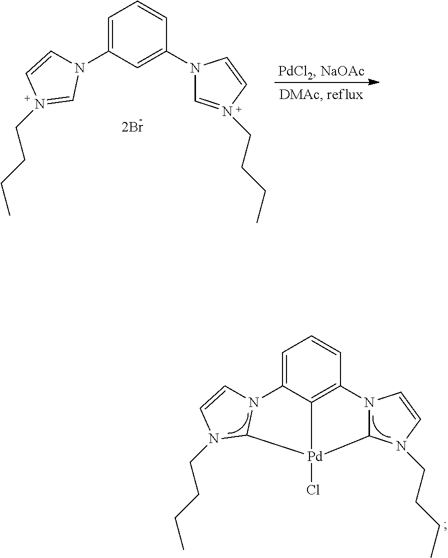

a CCC1 ligand (485 mg, 1 mmol), palladium dichloride (177 mg, 2 mmol) and sodium acetate (320 mg, 4 mmol) were dissolved in 20 mL of DMAc (N,N-dimethylacetamide) and stirred, a temperature was slowly raised to 140° C., and after reaction was performed for three days, a coarse product was suspended in dichloromethane and filtered. A filtrate was washed with water, and an organic phase was dried with magnesium sulfate. Acetonitrile was added after the organic phase was subjected to rotary evaporation, then rotary evaporation was carried out again, and finally a final product was obtained through column chromatography purification (a yield being 36%). 1H NMR (500 MHz, CDCl3) δ 7.32 (d, J=1.9 Hz, 2H), 7.13 (t, J=7.8 Hz, 1H), 6.91 (d, J=1.9 Hz, 2H), 6.89 (s, 1H), 6.87 (s, 1H), 4.76 (t, J=7.4 Hz, 4H), 1.88 (m, 4H), 1.47 (dq, J=14.9, 7.4 Hz, 4H), 0.96 (t, J=7.4 Hz, 6H).

### Example 2

This example provided a preparation method for an intermediate compound required for preparing a metal complex subsequently, which was specifically as shown below:

### 1) Preparation of Intermediate 1

A synthetic route of the intermediate 1 was as shown below:

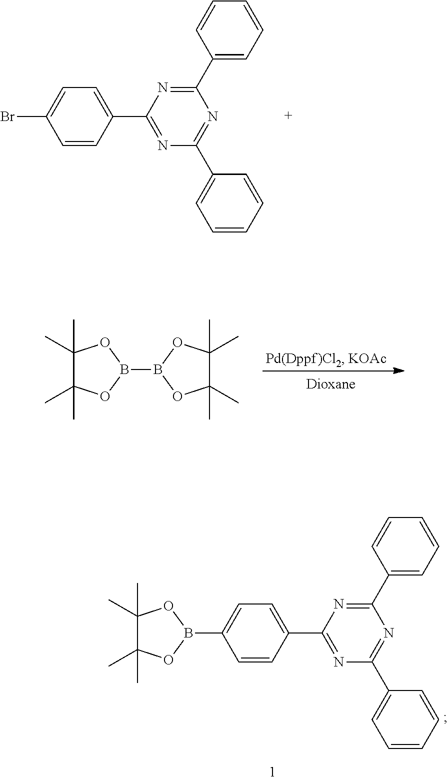

a preparation method thereof specifically included the following steps:
2-(4-Bromophenyl)-4,6-diphenyl-1,3,5-triazine (3 g, 7.73 mmol), bis(pinacolato)diboron (4.9 g, 19.3 mmol), [1,1-bis(diphenylphosphino)ferrocene]palladium dichloride (565 mg, 0.773 mmol) and potassium acetate (4.55 g, 46.358 mmol) were dissolved in 100 ml of an anhydrous 1,4-dioxane solvent, reflux was carried out at 108° C. for 12 hours, a reaction liquid was filtered using diatomite, reduced pressure distillation was carried out on a filtrate, and column chromatography purification was carried out to obtain the white solid intermediate 1 (a yield being 95%).

### 2) Preparation of Intermediate 2

A synthetic route of the intermediate 2 was as shown below:

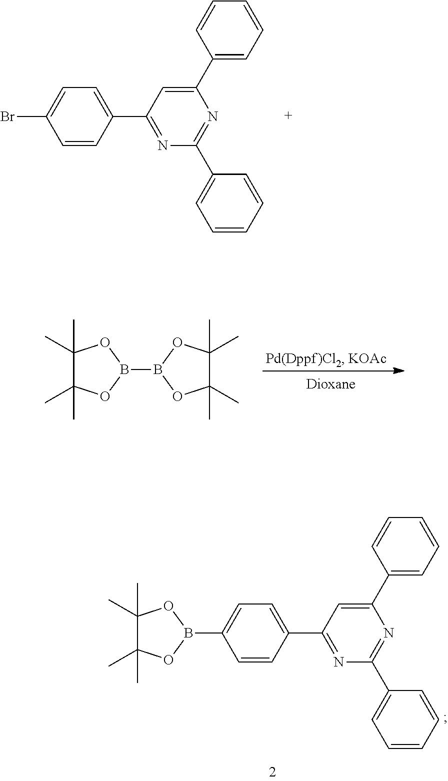

a preparation method thereof specifically included the following steps:
2-(4-Bromophenyl)-4,6-diphenyl-1,3,5-pyrimidine (3 g, 7.726 mmol), bis(pinacolato)diboron (4.9 g, 19.3 mmol), [11,1-bis(diphenylphosphino)ferrocene]palladium dichloride (565 mg, 0.773 mmol) and potassium acetate (4.55 g, 46.358 mmol) were dissolved in 100 ml of an anhydrous 1,4-dioxane solvent, reflux was carried out at 108° C. for 12 hours, a reaction liquid was filtered using diatomite, reduced pressure distillation was carried out on a filtrate, and column chromatography purification was carried out to obtain the white solid intermediate 2 (a yield being 90%).

### 3) Preparation of Intermediate 3

A synthetic route of the intermediate 3 was as shown below:

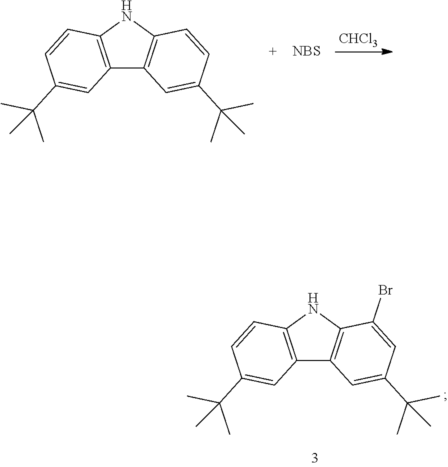 [SMILES: CC(C)(C)c1ccc2[nH]c3ccc(C(C)(C)C)cc3c2c1 ; "NBS" ; "CHCl3" ; CC(C)(C)c1ccc2[nH]c3c(Br)cc(C(C)(C)C)cc3c2c1]

a preparation method thereof specifically included the following steps:
3,6-di-tert-butyl-9H-carbazole (13.97 g, 50 mmol) was added into 300 ml of a chloroform solution, ice bath was carried out to reduce a temperature to 0° C., stirring was carried out, 30 ml of a chloroform solution in which NBS (7.079 g, 60 mmol) was dissolved was added dropwise, a product was wrapped with aluminum-foil paper to react for 8 h, reduced pressure distillation was carried out, a solvent was removed, and column chromatography purification was carried out using dichloromethane/petroleum ether to obtain the white solid intermediate 3 (a yield being 90%). 1H NMR (400 MHz, CDCl3): δ 8.06 (d, J=1.6 Hz, 1H), 8.05 (s, 1H), 8.03 (d, J=1.4 Hz, 1H), 7.61 (d, J=1.5 Hz, 1H), 7.52 (dd, J=8.6, 1.8 Hz, 1H), 7.40 (d, J=8.5 Hz, 1H), 1.47 (d, J=3.6 Hz, 18H).

### 4) Preparation of Intermediate 4

A synthetic route of the intermediate 4 was as shown below:

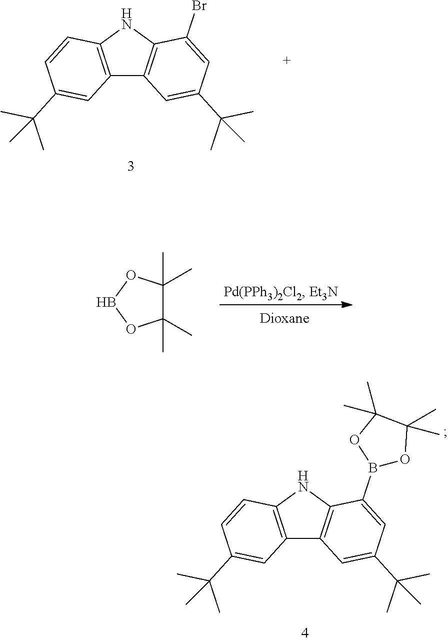

a preparation method thereof specifically included the following steps:
the intermediate 3 (358 mg, 1 mmol), pinacolborane (0.8 mL, 5 mmol), [bis(triphenylphosphino)]palladium dichloride (70.2 mg, 0.1 mmol) and triethylamine (1.49 mL) were dissolved in 10 ml of an anhydrous 1,4-dioxane solvent, reflux was carried out overnight at 108° C., a reaction liquid was filtered using diatomite, reduced pressure distillation was carried out on a filtrate, and column chromatography purification (an eluent being petroleum ether:dichloromethane=20:1) was carried out to obtain the white solid intermediate 4 (a yield being 95%). 1H NMR (400 MHz, CDCl3): δ 8.96 (s, 1H), 8.22 (d, J=2.0 Hz, 1H), 8.08 (d, J=1.6 Hz, 1H), 7.89 (d, J=2.0 Hz, 1H), 7.47 (dd, J=8.5, 1.9 Hz, 1H), 7.40 (d, J=8.5 Hz, 1H), 1.50-1.41 (m, 30H).

### 5) Preparation of Intermediate 5

A synthetic route of the intermediate 5 was as shown below:

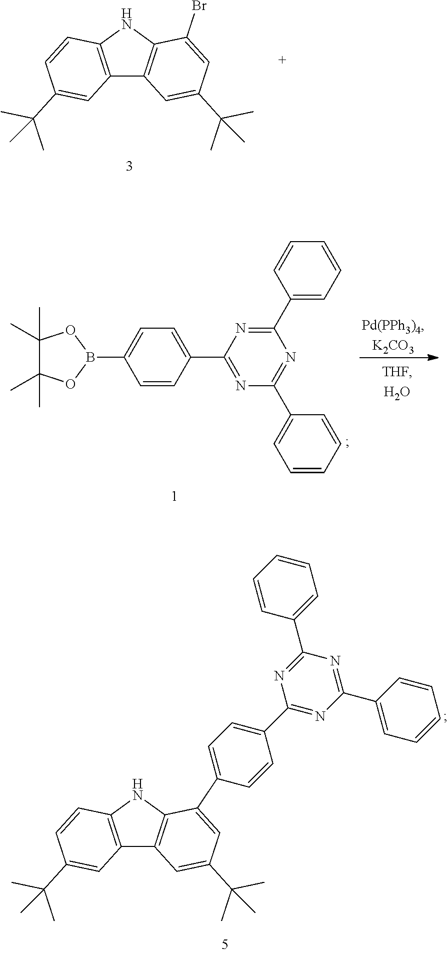 [SMILES: CC(C)(C)c1ccc2[nH]c3c(Br)cc(C(C)(C)C)cc3c2c1 ; CC1(C)OB(c2ccc(-c3nc(-c4ccccc4)nc(-c4ccccc4)n3)cc2)OC1(C)C ; CC(C)(C)c1ccc2[nH]c3c(-c4ccc(-c5nc(-c6ccccc6)nc(-c6ccccc6)n5)cc4)cc(C(C)(C)C)cc3c2c1]

a preparation method thereof specifically included the following steps:
the intermediate 3 (700 mg, 1.955 mmol), the intermediate 1 (708 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=20:1) was carried out to obtain the yellow-green solid intermediate 5 (a yield being 98%), wherein the product emitted sky-blue light under a 365 nm ultraviolet lamp. 1H NMR (500 MHz, CDCl3) δ 8.98-8.95 (m, 2H), 8.84-8.82 (m, 4H), 8.21 (s, 1H), 8.13 (dd, J=5.5 Hz, J=1.5 Hz, 2H), 7.94-7.92 (m, 2H), 7.64-7.58 (m, 7H), 7.50 (dd, J=8.5 Hz, J=2.0 Hz, 1H), 7.36 (d, J=8.5 Hz, 1H), 1.53 (s, 9H), 1.47 (s, 9H).

### 6) Preparation of Intermediate 6

A synthetic route of the intermediate 6 was as shown below:

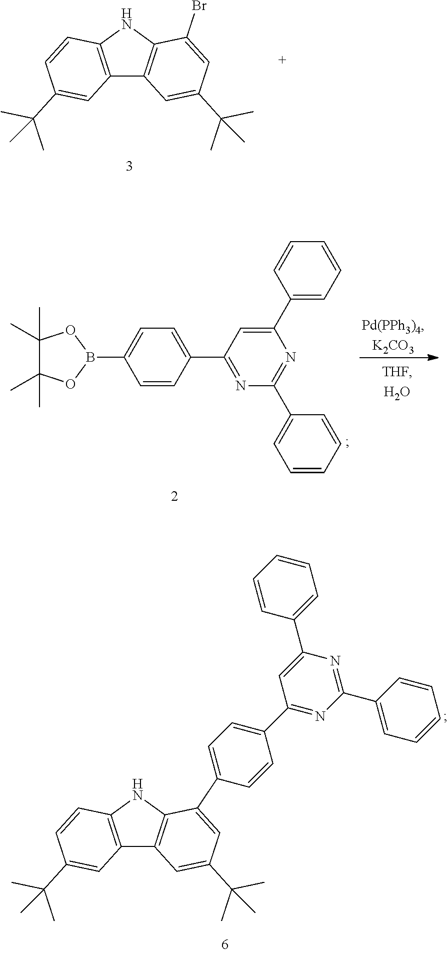 [SMILES: CC(C)(C)c1ccc2[nH]c3c(Br)cc(C(C)(C)C)cc3c2c1 ; CC1(C)OB(c2ccc(-c3cc(-c4ccccc4)nc(-c4ccccc4)n3)cc2)OC1(C)C ; CC(C)(C)c1ccc2[nH]c3c(-c4ccc(-c5cc(-c6ccccc6)nc(-c6ccccc6)n5)cc4)cc(C(C)(C)C)cc3c2c1]

a preparation method thereof specifically included the following steps:
the intermediate 3 (700 mg, 1.955 mmol), the intermediate 2 (708 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=20:1) was carried out to obtain the green solid intermediate 6 (a yield being 88%), wherein the product emitted sky-blue light under a 365 nm ultraviolet lamp. 1H NMR (500 MHz, CDCl3) δ 8.79-8.77 (m, 2H), 8.50-8.48 (m, 2H), 8.35-8.33 (m, 2H), 8.18 (s, 1H), 8.13 (t, J=2.5 Hz, 2H), 8.11 (s, 1H), 7.92-7.91 (m, 2H), 7.62-7.54 (m, 7H), 7.49 (dd, J=8.5 Hz, J=1.5 Hz, 1H), 7.35 (d, J=8.5 Hz, 1H), 1.52 (s, 9H), 1.47 (s, 9H).

### 7) Preparation of Intermediate 7

A synthetic route of the intermediate 7 was as shown below:

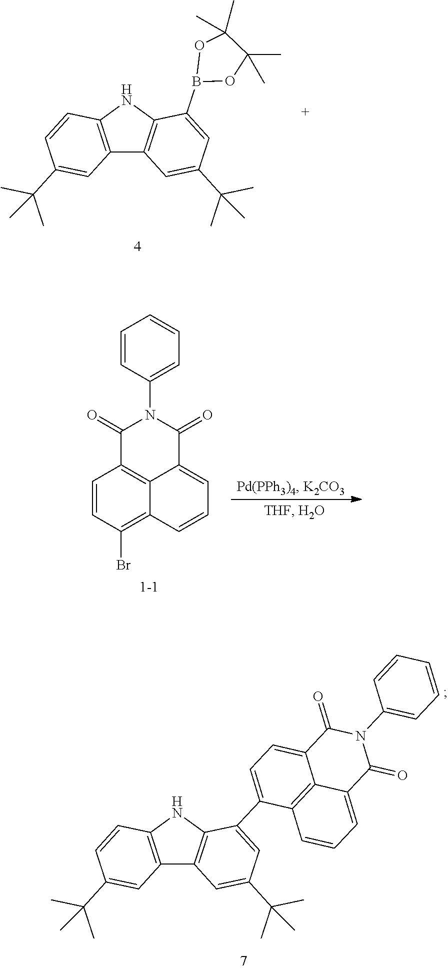

a preparation method thereof specifically included the following steps:
the intermediate 4 (791 mg, 1.955 mmol), an intermediate 1-1 (665 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=5:1) was carried out to obtain the yellow solid intermediate 7 (a yield being 75%).

### 8) Preparation of Intermediate 8

A synthetic route of the intermediate 8 was as shown below:

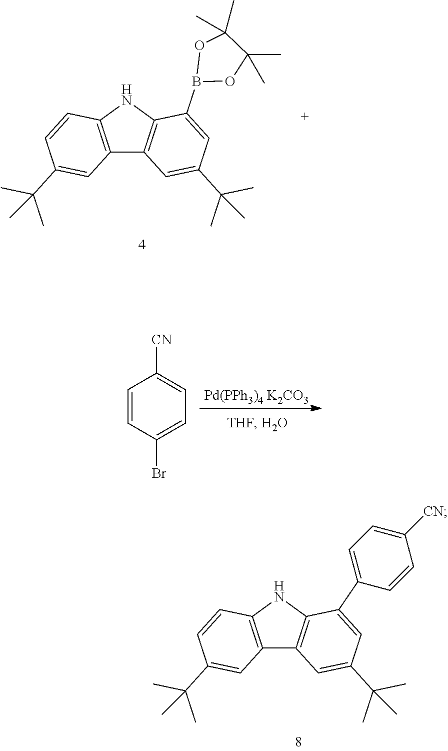

a preparation method thereof specifically included the following steps:
the intermediate 4 (791 mg, 1.955 mmol), an intermediate 1-2 (300 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out on an extract liquor, and column chromatography purification (an eluent being petroleum ether:dichloromethane=2:1) was carried out to obtain the yellow solid intermediate 8 (a yield being 60%). 1H NMR (500 MHz, CDCl3) δ 8.46 (m, 1H), 8.36 (d, J=8.0 Hz 1H), 8.23 (m, 1H), 8.18 (s, 1H), 7.84 (t, J=2.5 Hz, 4H), 7.62-7.50 (m, 2H), 1.43 (s, 9H), 1.32 (s, 9H).

### 9) Preparation of Intermediate 9

A synthetic route of the intermediate 9 was as shown below:

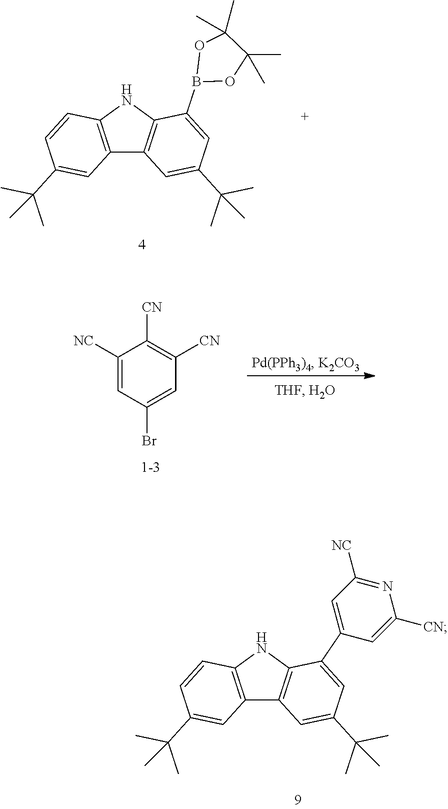

a preparation method thereof specifically included the following steps:
the intermediate 4 (791 mg, 1.955 mmol), an intermediate 1-3 (340 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=5:1) was carried out to obtain the white solid intermediate 9 (a yield being 60%). 1H NMR (500 MHz, CDCl3) δ 9.21 (d, J=8.5 Hz, 2H), 8.58 (d, J=8.0 Hz 1H), 8.33 (m, 1H), 8.18 (s, 1H), 7.66-7.55 (m, 2H), 1.50 (s, 9H), 1.44 (s, 9H).

### 10) Preparation of Intermediate 10

A synthetic route of the intermediate 10 was as shown below:

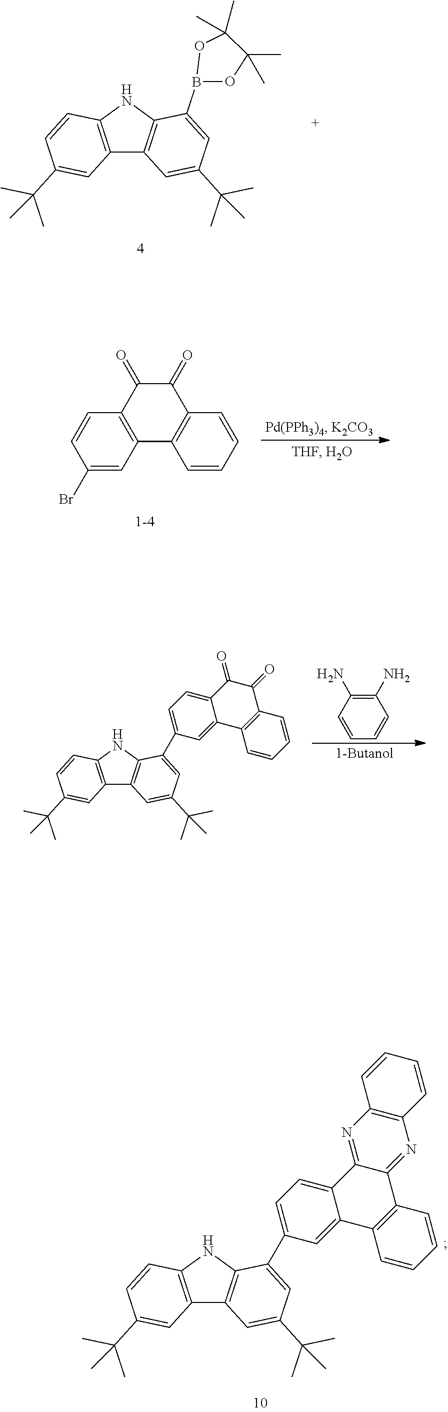

a preparation method thereof specifically included the following steps:
the intermediate 4 (791 mg, 1.955 mmol), an intermediate 1-4 (470 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=10:1) was carried out to obtain a white product (a yield being 75%).

Afterwards, the product obtained in the last step (970 mg, 2 mmol) and 1,2-phenylenediamine (216 mg, 2 mmol) were added into a double-neck reaction flask, 20 mL of 1-butanol was injected under a nitrogen atmosphere, reaction was performed at 120° C., and reflux was carried out for 12 hours. After the reaction was completed, a solvent was spin-dried, and the deep-yellow product 10 was obtained through column chromatography purification (a yield being 98%). 1H NMR (500 MHz, CDCl3) δ 9.53 (d, J=8.0 Hz, 1H), 9.47-9.45 (m, 1H), 8.86 (d, J=1.5 Hz, 1H), 8.60-8.58 (m, 1H), 8.42-8.37 (m, 3H), 8.20 (dd, J=10.0 Hz, J=1.5 Hz, 2H), 8.06 (dd, J=8.5 Hz, J=1.5 Hz, 1H), 7.93-7.89 (m, 2H), 7.82-7.78 (m, 2H), 7.69 (d, J=2.0 Hz, J=1.5 Hz, 1H), 7.53 (dd, J=8.5 Hz, J=2.0 Hz, 1H), 7.42 (d, J=5.5 Hz, 1H), 1.59 (s, 10H), 1.51 (s, 9H).

### 11) Preparation of Intermediate 11

A synthetic route of the intermediate 11 was as shown below:

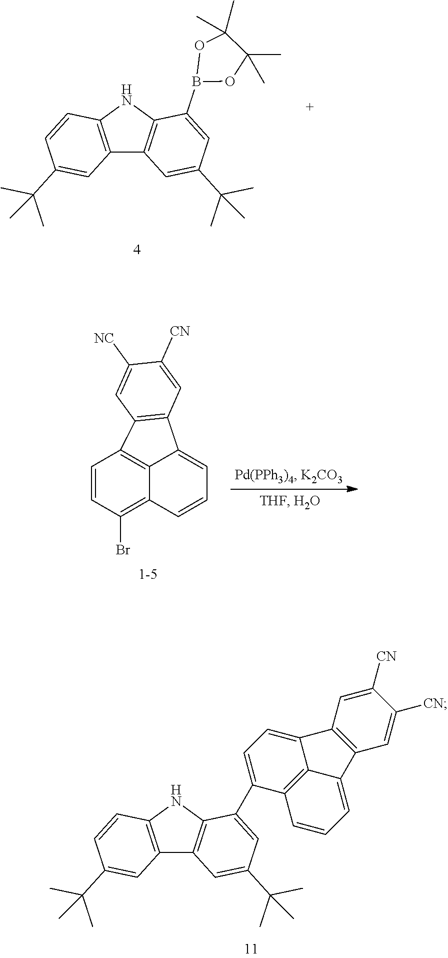

a preparation method thereof specifically included the following steps:
the intermediate 4 (791 mg, 1.955 mmol), an intermediate 1-5 (538 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=7:1) was carried out to obtain the yellow solid intermediate 11 (a yield being 77%). 1H NMR (500 MHz, DMSO-d6) δ 11.70 (s, 1H), 9.66 (d, J=8.0 Hz, 1H), 9.50-9.42 (m, 2H), 8.80 (d, J=1.5 Hz, 1H), 8.20 (dd, J=10.0 Hz, J=1.5 Hz, 2H), 8.06 (dd, J=8.5 Hz, J=1.5 Hz, 2H), 7.91 (m, 2H), 7.53 (dd, J=8.5 Hz, J=2.0 Hz, 1H), 7.42 (d, J=5.5 Hz, 1H), 1.60 (s, 9H), 1.51 (s, 9H).

### 12) Preparation of Intermediate 12

A synthetic route of the intermediate 12 was as shown below:

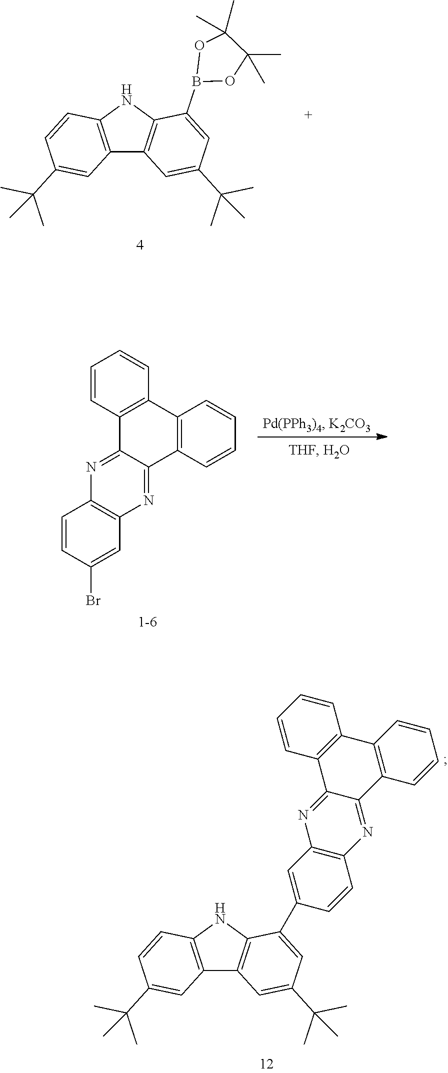

a preparation method thereof specifically included the following steps:
the intermediate 4 (791 mg, 1.955 mmol), an intermediate 1-6 (586 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=15:1) was carried out to obtain the yellow solid intermediate 12 (a yield being 50%). 1H NMR (500 MHz, CDCl3) δ 9.02 (d, J=8.0 Hz, 1H), 8.95 (m, 1H), 8.80 (d, J=1.5 Hz, 1H), 8.60 (m, 1H), 8.22 (m, 3H), 8.10 (dd, J=10.0 Hz, J=1.5 Hz, 2H), 7.96 (dd, J=8.5 Hz, J=1.5 Hz, 1H), 7.80 (m, 2H), 7.72 (m, 2H), 7.60 (d, J=2.0 Hz, J=1.5 Hz, 1H), 7.43 (dd, J=8.5 Hz, J=2.0 Hz, 1H), 7.03 (d, J=5.5 Hz, 1H), 1.66 (s, 9H), 1.55 (s, 9H).

### 13) Preparation of Intermediate 13

A synthetic route of the intermediate 13 was as shown below:

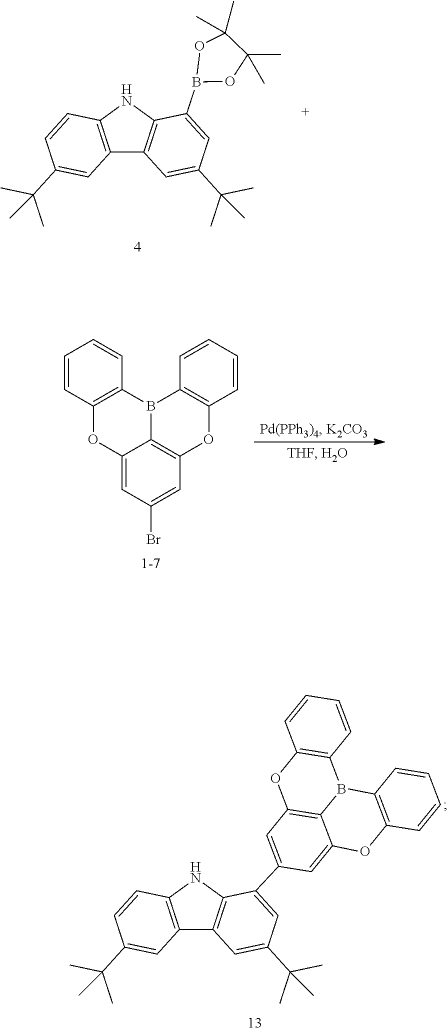

a preparation method thereof specifically included the following steps:
the intermediate 4 (791 mg, 1.955 mmol), an intermediate 1-7 (570 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=8:1) was carried out to obtain the pale-yellow solid intermediate 13 (a yield being 53%). 1H NMR (500 MHz, CDCl3) δ (ppm): 8.71 (dd, J=8.0, 2.0 Hz, 2H), 8.38 (s, 1H), 8.17 (dd, J=12.5, 2.0 Hz, 2H), 7.74 (t, J=7.8 Hz, 2H), 7.67 (s, 1H), 7.60-7.58 (m, 4H), 7.51 (dd, J=8.5, 2.0 Hz, 1H), 7.46-7.36 (m, 3H), 1.56 (s, 9H), 1.50 (s, 9H). 13C NMR (500 MHz, CDCl3) δ (ppm): 160.73, 158.15, 146.84, 143.08, 142.69, 138.21, 135.87, 134.76, 133.85, 124.29, 124.07, 123.97, 123.64, 123.54, 123.10, 122.53, 118.61, 116.64, 116.47, 113.91, 110.42, 108.39, 35.02, 34.90, 32.27, 32.20.

### 14) Preparation of Intermediate 14

A synthetic route of the intermediate 14 was as shown below:

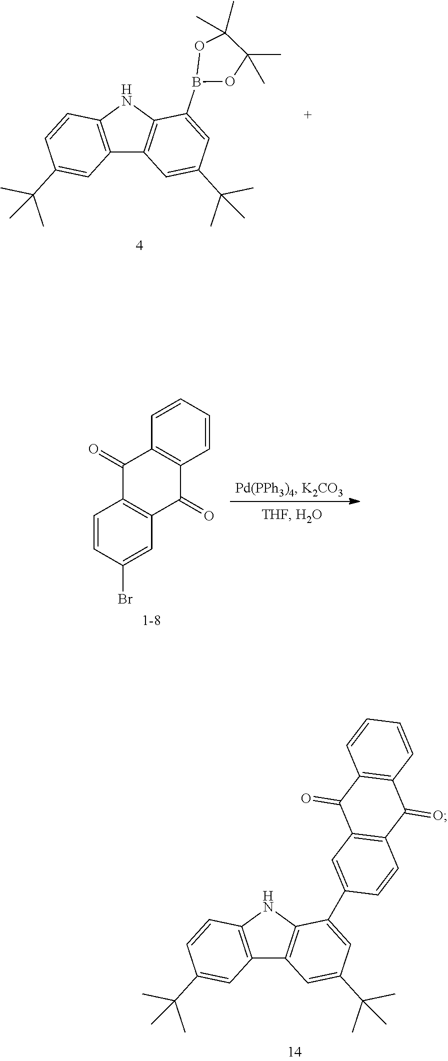

a preparation method thereof specifically included the following steps:
the intermediate 4 (791 mg, 1.955 mmol), an intermediate 1-8 (467 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=5:1) was carried out to obtain the yellow solid intermediate 14 (a yield being 88%). 1H NMR (500 MHz, DMSO-d6) δ 10.07 (s, 1H), 9.28 (d, J=8.5 Hz, 2H), 9.00 (d, J=8.0 Hz 2H), 8.88 (t, J=8.0 Hz, 1.5 Hz 1H), 8.33 (m, 4H), 8.18 (s, 1H), 7.66-7.55 (m, 2H), 1.50 (s, 9H), 1.44 (s, 9H).

### 15) Preparation of Intermediate 15

A synthetic route of the intermediate 15 was as shown below:

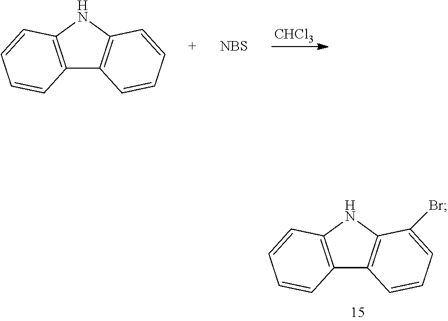

a preparation method thereof specifically included the following steps:
carbazole (8.35 g, 50 mmol) was added into 300 ml of a chloroform solution, ice bath was carried out to reduce a temperature to 0° C., stirring was carried out, 30 ml of a chloroform solution in which NBS (7.079 g, 60 mmol) was dissolved was added dropwise, a product was wrapped with aluminum-foil paper to react for 8 h, reduced pressure distillation was carried out, a solvent was removed, and column chromatography purification was carried out using dichloromethane/petroleum ether to obtain the white solid intermediate 15 (a yield being 90%).

### 16) Preparation of Intermediate 16

A synthetic route of the intermediate 16 was as shown below:

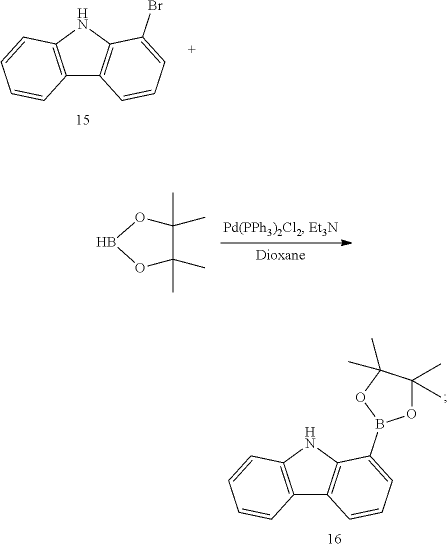

a preparation method thereof specifically included the following steps:
the intermediate 15 (250 mg, 1 mmol), pinacolborane (0.8 mL, 5 mmol), [bis(triphenylphosphino)]palladium dichloride (70.2 mg, 0.1 mmol) and triethylamine (1.49 mL) were dissolved in 10 ml of an anhydrous 1,4-dioxane solvent, reflux was carried out overnight at 108° C., a reaction liquid was filtered using diatomite, reduced pressure distillation was carried out on a filtrate, and column chromatography purification (an eluent being petroleum ether) was carried out to obtain the white solid intermediate 16 (a yield being 30%).

### 17) Preparation of Intermediate 17

A synthetic route of the intermediate 17 was as shown below:

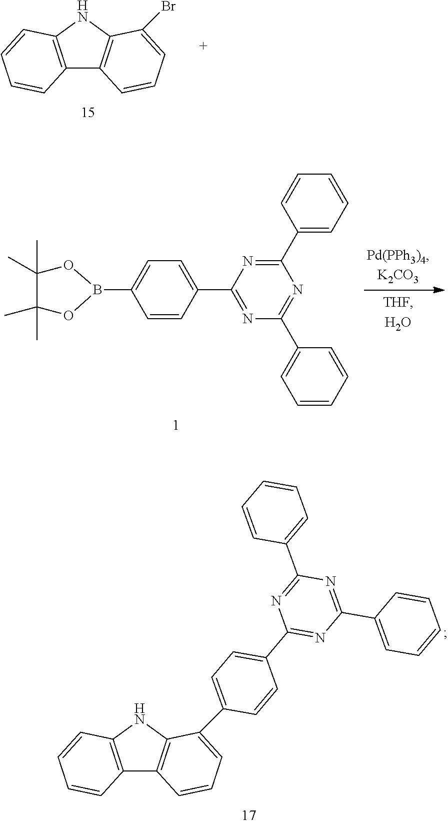 [SMILES: Brc1cccc2c1[nH]c1ccccc12 ; CC1(C)OB(c2ccc(-c3nc(-c4ccccc4)nc(-c4ccccc4)n3)cc2)OC1(C)C ; c1ccc(-c2nc(-c3ccccc3)nc(-c3ccc(-c4cccc5c4[nH]c4ccccc45)cc3)n2)cc1]

a preparation method thereof specifically included the following steps:
the intermediate 15 (500 mg, 1.955 mmol), the intermediate 1 (708 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=15:1) was carried out to obtain the light-green solid intermediate 17 (a yield being 78%). 1H NMR (500 MHz, CDCl3) δ 8.97 (m, 2H), 8.86 (m, 4H), 8.21 (s, 1H), 8.15 (dd, J=5.5 Hz, J=1.5 Hz, 4H), 7.92 (m, 2H), 7.60 (m, 7H), 7.40 (dd, J=8.5 Hz, J=2.0 Hz, 1H), 7.36 (d, J=8.5 Hz, 1H).

### 18) Preparation of Intermediate 18

A synthetic route of the intermediate 18 was as shown below:

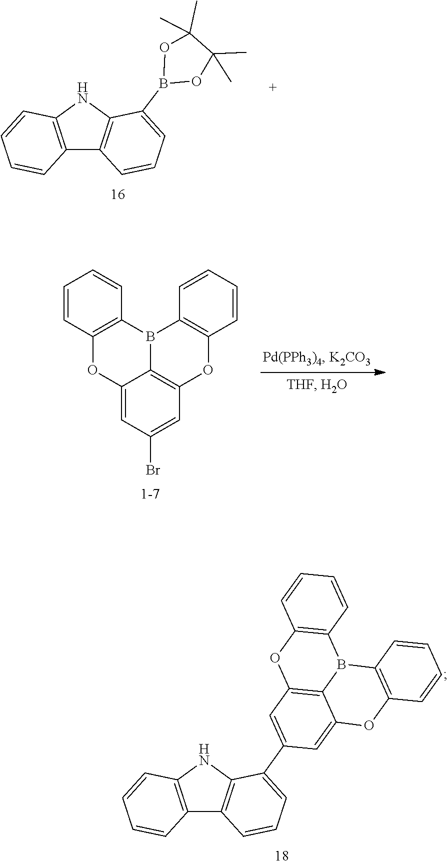 [SMILES: CC1(C)OB(c2cccc3c2[nH]c2ccccc23)OC1(C)C ; Brc1cc2c3c(c1)Oc1ccccc1B3c1ccccc1O2 ; c1ccc2c(c1)Oc1cc(-c3cccc4c3[nH]c3ccccc34)cc3c1B2c1ccccc1O3]

a preparation method thereof specifically included the following steps:
the intermediate 16 (596 mg, 1.955 mmol), an intermediate 1-7 (570 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=5:1) was carried out to obtain the yellow solid intermediate 18 (a yield being 67%). 1H NMR (500 MHz, CDCl3) δ (ppm): 8.77 (dd, J=8.0, 2.0 Hz, 2H), 8.35 (s, 1H), 8.10 (dd, J=12.5, 2.0 Hz, 2H), 7.67 (t, J=7.8 Hz, 2H), 7.66 (s, 1H), 7.52 (m, 6H), 7.41 (dd, J=8.5, 2.0 Hz, 1H), 7.30 (m, 3H).

### 19) Preparation of Intermediate 19

A synthetic route of the intermediate 19 was as shown below:

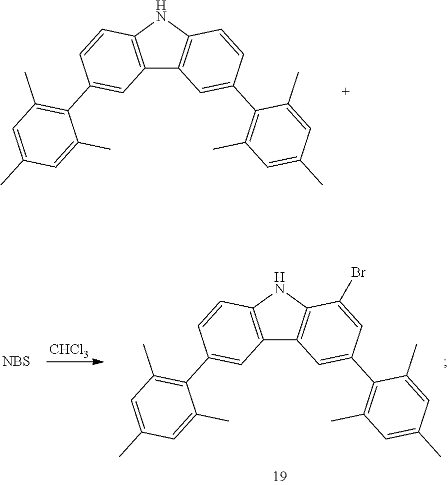

a preparation method thereof specifically included the following steps:
carbazole (20 g, 50 mmol) was added into 300 ml of a chloroform solution, ice bath was carried out to reduce a temperature to 0° C., stirring was carried out, 30 ml of a chloroform solution in which NBS (7.079 g, 60 mmol) was dissolved was added dropwise, a product was wrapped with aluminum-foil paper to react for 8 h, reduced pressure distillation was carried out, a solvent was removed, and column chromatography purification was carried out using dichloromethane/petroleum ether (50:1) to obtain the white solid intermediate 19 (a yield being 90%).

### 20) Preparation of Intermediate 20

A synthetic route of the intermediate 20 was as shown below:

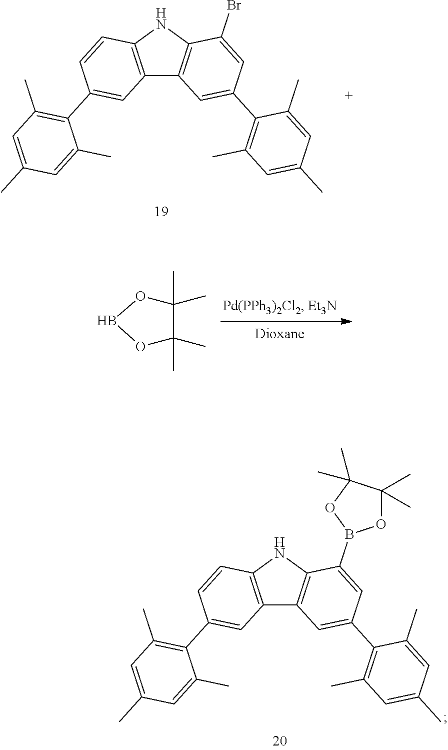

a preparation method thereof specifically included the following steps:
the intermediate 19 (482 mg, 1 mmol), pinacolborane (0.8 mL, 5 mmol), [bis(triphenylphosphino)]palladium dichloride (70.2 mg, 0.1 mmol) and triethylamine (1.49 mL) were dissolved in 10 ml of an anhydrous 1,4-dioxane solvent, reflux was carried out overnight at 108° C., a reaction liquid was filtered using diatomite, reduced pressure distillation was carried out on a filtrate, and column chromatography purification (an eluent being petroleum ether:dichloromethane=20:1) was carried out to obtain the white solid intermediate 20 (a yield being 80%).

### 21) Preparation of Intermediate 21

A synthetic route of the intermediate 21 was as shown below:

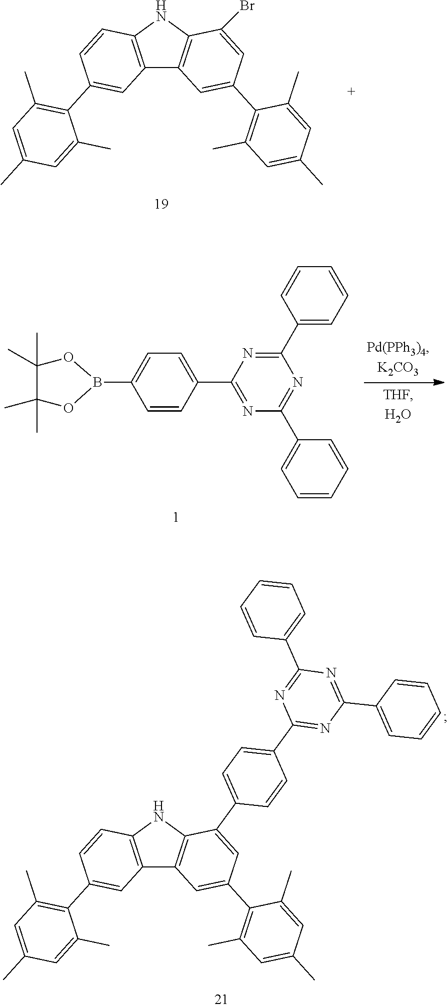

a preparation method thereof specifically included the following steps:
the intermediate 19 (800 mg, 1.955 mmol), the intermediate 1 (708 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=15:1) was carried out to obtain the light-green solid intermediate 21 (a yield being 78%). 1H NMR (500 MHz, CDCl3) δ 8.80 (m, 2H), 8.49 (m, 2H), 8.34 (m, 2H), 8.20 (s, 1H), 8.15 (t, J=2.5 Hz, 2H), 8.11 (s, 1H), 7.92-7.91 (m, 4H), 7.62-7.54 (m, 7H), 7.49 (dd, J=8.5 Hz, J=1.5 Hz, 2H), 7.35 (d, J=8.5 Hz, 2H), 2.92 (s, 6H), 2.88 (s, 6H), 2.48 (s, 3H), 2.35 (s, 3H).

### 22) Preparation of Intermediate 22

A synthetic route of the intermediate 22 was as shown below:

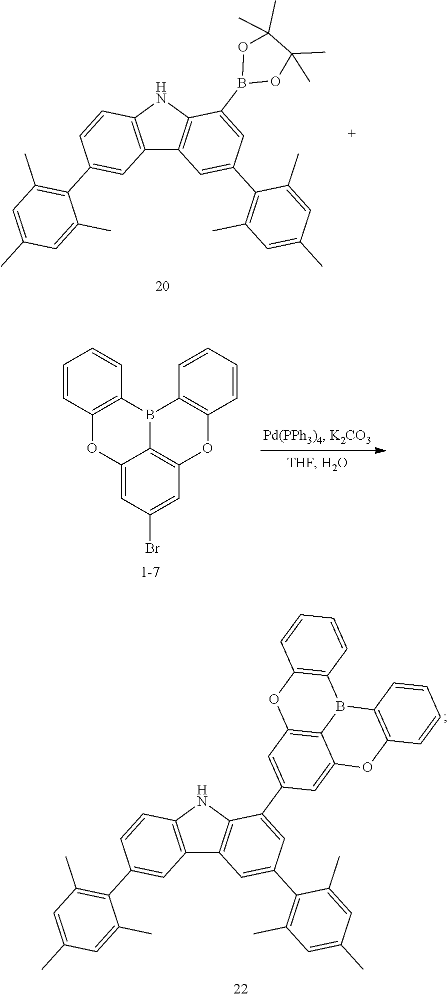

a preparation method thereof specifically included the following steps:
the intermediate 20 (1060 mg, 1.955 mmol), the intermediate 1-7 (570 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=5:1) was carried out to obtain the yellow solid intermediate 22 (a yield being 67%). 1H NMR (500 MHz, CDCl3) δ (ppm): 8.98 (dd, J=8.0, 2.0 Hz, 2H), 8.55 (s, 1H), 8.37 (dd, J=12.5, 2.0 Hz, 2H), 7.88 (t, J=7.8 Hz, 2H), 7.80 (s, 1H), 7.66 (m, 6H), 7.58 (dd, J=8.5, 2.0 Hz, 1H), 7.45 (m, 5H), 2.89 (s, 6H), 2.8. (s, 6H), 2.40 (s, 3H), 2.29 (s, 3H).

### 23) Preparation of Intermediate 23

A synthetic route of the intermediate 23 was as shown below:

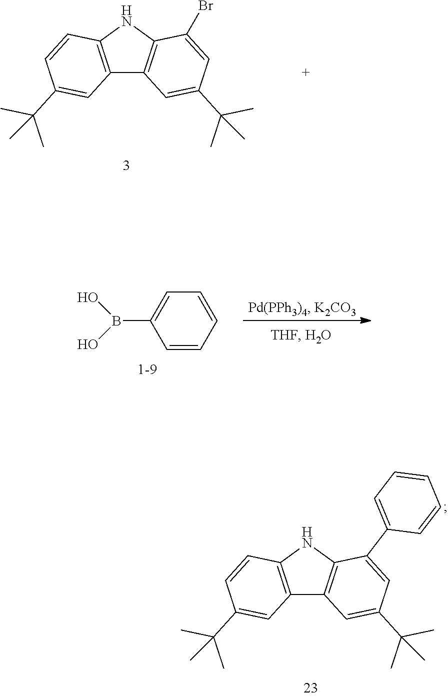 [SMILES: CC(C)(C)c1ccc2[nH]c3c(Br)cc(C(C)(C)C)cc3c2c1 ; OB(O)c1ccccc1 ; CC(C)(C)c1ccc2[nH]c3c(-c4ccccc4)cc(C(C)(C)C)cc3c2c1]

a preparation method thereof specifically included the following steps:
the intermediate 3 (700 mg, 1.955 mmol), an intermediate 1-9 (199 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=20:1) was carried out to obtain the white solid intermediate 23 (a yield being 74%), wherein the product emitted sky-blue light under a 365 nm ultraviolet lamp. 1H NMR (500 MHz, DMSO) δ 10.81 (s, 1H, NH), 8.17 (s, 2H), 7.73 (m, 2H), 7.58 (t, J=7.5 Hz, 2H), 7.43 (m, 4H), 1.45 (s, 9H), 1.41 (s, 9H).

### 24) Preparation of Intermediate 24

A synthetic route of the intermediate 24 was as shown below:

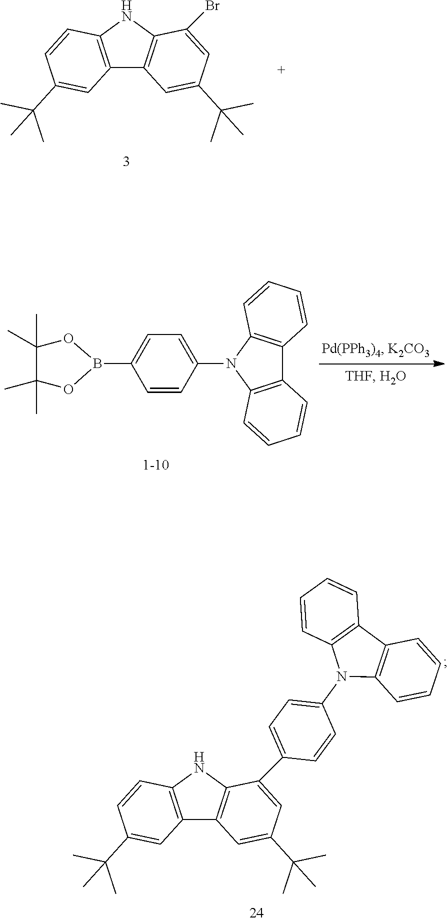 [SMILES: CC(C)(C)c1ccc2[nH]c3c(Br)cc(C(C)(C)C)cc3c2c1 ; CC1(C)OB(c2ccc(-n3c4ccccc4c4ccccc43)cc2)OC1(C)C ; CC(C)(C)c1ccc2[nH]c3c(-c4ccc(-n5c6ccccc6c6ccccc65)cc4)cc(C(C)(C)C)cc3c2c1]

a preparation method thereof specifically included the following steps:
the intermediate 3 (700 mg, 1.955 mmol), an intermediate 1-10 (603 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=20:1) was carried out to obtain the white solid intermediate 24 (a yield being 66%), wherein the product emitted sky-blue light under a 365 nm ultraviolet lamp. 1H NMR (500 MHz, CDCl3) δ 8.23 (s, 1H), 8.19 (d, J=7.5 Hz, 2H), 8.14 (d, J=2.0 Hz, 2H), 7.94 (m, 2H), 7.76 (m, 2H), 7.58 (d, J=2.0 Hz, 1H), 7.56 (d, J=8.0 Hz, 2H), 7.50 (dd, J=8.5 Hz, J=2.0 Hz, 1H), 7.46 (m, 2H), 7.39 (d, J=8.0 Hz, 1H), 7.33 (m, 2H), 1.53 (s, 9H), 1.48 (s, 9H).

### 25) Preparation of Intermediate 25

A synthetic route of the intermediate 25 was as shown below:

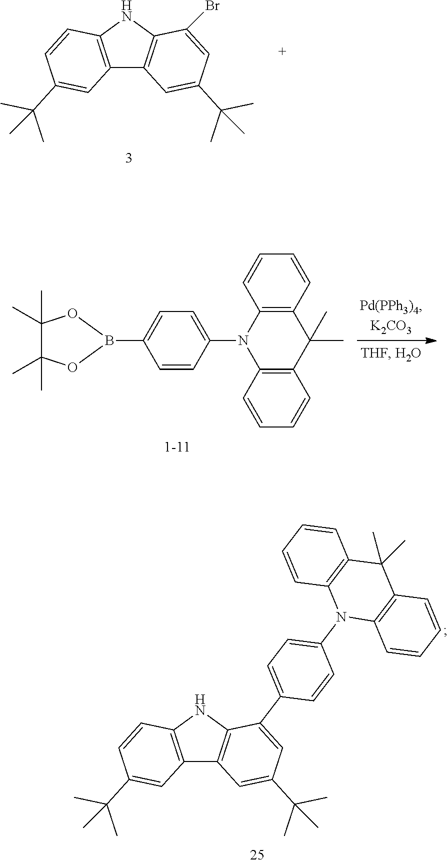

a preparation method thereof specifically included the following steps:
the intermediate 3 (700 mg, 1.955 mmol), an intermediate 1-11 (668 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=20:1) was carried out to obtain the white solid intermediate 25 (a yield being 61%), wherein the product emitted sky-blue light under a 365 nm ultraviolet lamp. 1H NMR (500 MHz, CDCl3) δ 8.25 (s, 1H, NH), 8.13 (d, J=1.5 Hz, 2H), 7.96 (d, J=8.5 Hz, 2H), 7.59 (d, J=2.0 Hz, 1H), 7.50 (m, 5H), 7.40 (d, J=8.5 Hz, 1H), 7.03 (m, 2H), 6.96 (td, J=7.5 Hz, J=1.0 Hz, 2H), 6.45 (dd, J=8.5 Hz, J=1.0 Hz, 2H), 1.73 (s, 6H), 1.53 (s, 9H), 1.48 (s, 9H).

### 26) Preparation of Intermediate 26

A synthetic route of the intermediate 26 was as shown below:

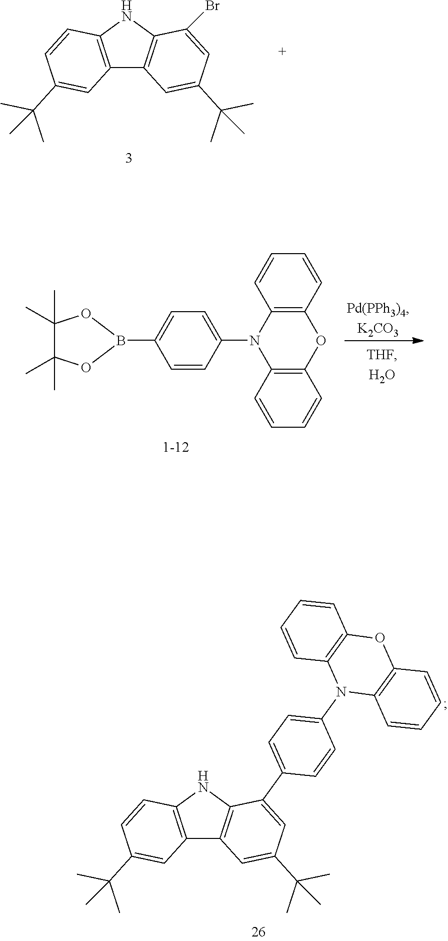 [SMILES: CC(C)(C)c1ccc2[nH]c3c(Br)cc(C(C)(C)C)cc3c2c1 ; CC1(C)OB(c2ccc(N3c4ccccc4Oc4ccccc43)cc2)OC1(C)C ; CC(C)(C)c1ccc2[nH]c3c(-c4ccc(N5c6ccccc6Oc6ccccc65)cc4)cc(C(C)(C)C)cc3c2c1]

a preparation method thereof specifically included the following steps:
the intermediate 3 (700 mg, 1.955 mmol), an intermediate 1-12 (630 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=20:1) was carried out to obtain the white solid intermediate 26 (a yield being 77%), wherein the product emitted sky-blue light under a 365 nm ultraviolet lamp. 1H NMR (400 MHz, Acetone) δ 10.23 (s, 1H, NH), 8.28 (dd, J=10.4 Hz, J=2.0 Hz, 2H), 8.08 (m, 2H), 7.64 (d, J=1.6 Hz, 1H), 7.57 (m, 2H), 7.50 (dd, J=8.4 Hz, J=2.0 Hz, 1H), 7.44 (d, J=8.4 Hz, 1H), 6.71 (m, 6H), 6.08 (m, 2H), 1.52 (s, 9H), 1.45 (s, 9H).

### 27) Preparation of Intermediate 27

A synthetic route of the intermediate 27 was as shown below:

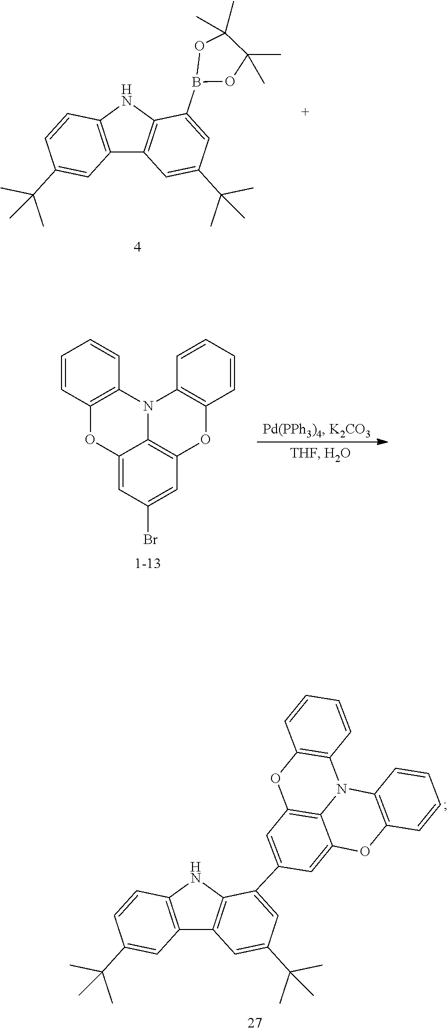

a preparation method thereof specifically included the following steps:
the intermediate 4 (791 mg, 1.955 mmol), an intermediate 1-13 (570 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=8:1) was carried out to obtain the pale-yellow solid intermediate 27 (a yield being 53%). 1H NMR (500 MHz, DMSO) δ 10.86 (s, 1H, NH), 8.16 (s, 2H), 7.43 (m, 5H), 7.03 (m, 8H), 1.44 (s, 9H), 1.41 (s, 9H).

### 28) Preparation of Intermediate 28

A synthetic route of the intermediate 28 was as shown below:

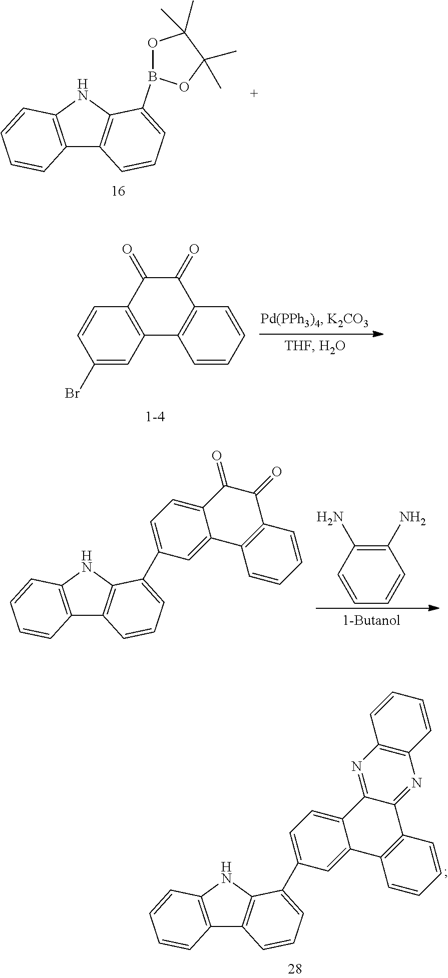

a preparation method thereof specifically included the following steps:
the intermediate 16 (586 mg, 1.955 mmol), an intermediate 1-4 (470 mg, 1.63 mmol), K₂CO₃ (1.126 g, 8.15 mmol) and tetrakis(triphenylphosphine)palladium (95 mg, 0.0815 mmol) were dissolved in 30 ml of an anhydrous tetrahydrofuran solution and 10 ml of deoxygenated water and stirred, a temperature was slowly raised to 108° C., reaction was performed overnight, dichloromethane and water were used for extraction, reduced pressure distillation was carried out, and column chromatography purification (an eluent being petroleum ether:dichloromethane=10:1) was carried out to obtain a white product (a yield being 80%).

Afterwards, the product obtained in the last step (970 mg, 2 mmol) and 1,2-phenylenediamine (216 mg, 2 mmol) were added into a double-neck reaction flask, 20 mL of 1-butanol was injected under a nitrogen atmosphere, reaction was performed at 120° C., and reflux was carried out for 12 hours. After the reaction was completed, a solvent was spin-dried, and the deep-yellow product 28 was obtained through column chromatography purification (a yield being 90%). 1H NMR (600 MHz, Chloroform-d) δ 9.56 (d, J=8.1 Hz, 1H), 9.48-9.44 (m, 1H), 8.87 (d, J=1.6 Hz, 1H), 8.63-8.60 (m, 1H), 8.52 (s, 1H), 8.42-8.35 (m, 2H), 8.18 (dd, J=7.7, 5.9 Hz, 2H), 8.07 (dd, J=8.2, 1.6 Hz, 1H), 7.93-7.86 (m, 2H), 7.84-7.77 (m, 2H), 7.66 (dd, J=7.2, 1.1 Hz, 1H), 7.51-7.41 (m, 3H), 7.30 (ddd, J=8.0, 6.5, 1.5 Hz, 1H).

### Example 3

This example provided a preparation method for a metal complex PtNCN1-12, a synthetic route of which was as shown below:

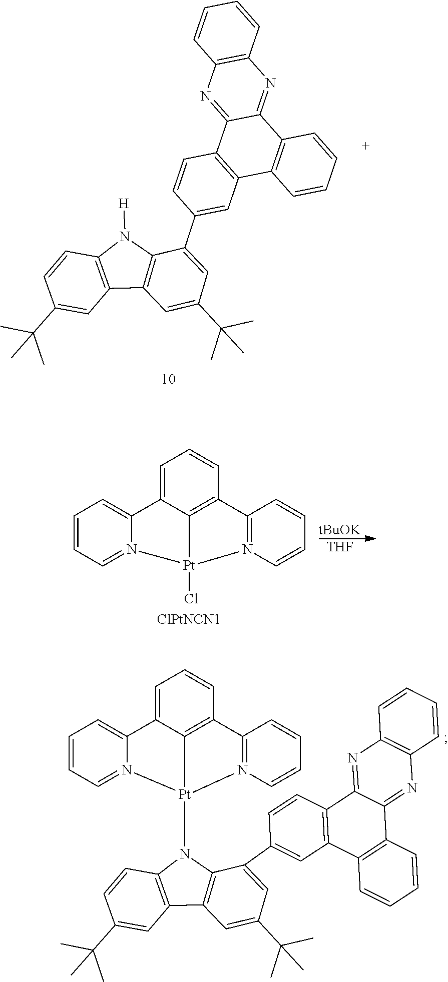

the preparation method thereof specifically included the following steps:
the intermediate 10 (190 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain red powder, which is the metal complex PtNCN1-12 (a yield being 75%). 1H NMR (400 MHz, CDCl3) δ 9.18 (dd, J=8.0 Hz, J=1.2 Hz, 1H), 8.48 (m, 2H), 8.36 (m, 3H), 8.30 (m, 1H), 8.22 (s, 1H), 7.92 (m, 2H), 7.70 (m, 2H), 7.65 (d, J=8.8 Hz, 2H), 7.54 (m, 2H), 7.46 (d, J=2.4 Hz, 1H), 7.33 (dd, J=8.4 Hz, J=2.0 Hz, 1H), 7.15 (m, 2H), 6.94 (t, J=5.6 Hz, 3H), 6.35 (m, 3H), 5.97 (t, J=7.6 Hz, 1H), 1.60 (s, 9H), 1.52 (s, 9H). 13C NMR (126 MHz, CDCl3) δ 167.45, 166.11, 151.80, 149.42, 148.07, 144.81, 142.43, 142.21, 142.13, 141.69, 138.11, 137.78, 137.58, 132.26, 131.05, 130.16, 129.71, 129.43, 129.37, 129.18, 129.10, 127.87, 126.95, 126.64, 126.08, 125.68, 125.50, 124.90, 124.44, 122.80, 121.86, 121.68, 121.39, 118.73, 115.34, 115.28, 114.16, 34.69, 34.61, 32.47, 32.39.

### Example 4

This example provided a preparation method for a metal complex PtNCN2-12, a synthetic route of which was as shown below:

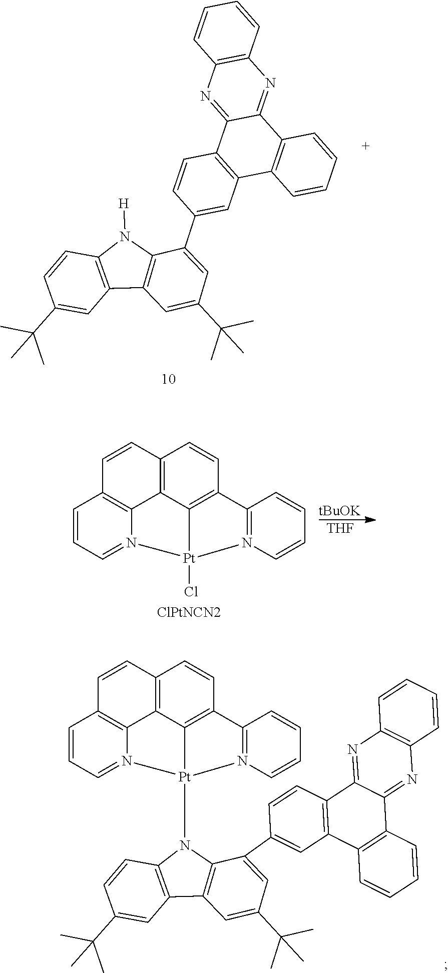

the preparation method thereof specifically included the following steps:
the intermediate 10 (190 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN2 (482 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the red powder complex PtNCN2-12 (a yield being 70%).

### Example 5

This example provided a preparation method for a metal complex PtNCN3-12, a synthetic route of which was as shown below:

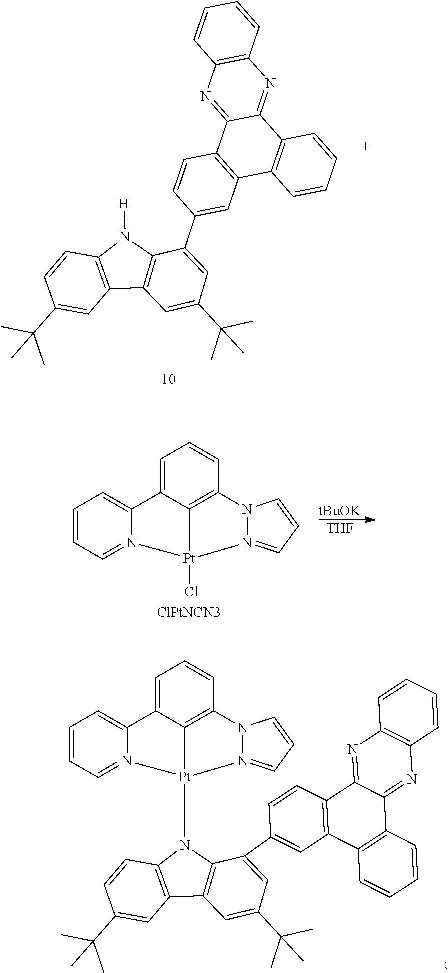

the preparation method thereof specifically included the following steps:
the intermediate 10 (190 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN3 (450 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the red powder complex PtNCN3-12 (a yield being 65%).

### Example 6

This example provided a preparation method for a metal complex PtCCC1-12, a synthetic route of which was shown below:

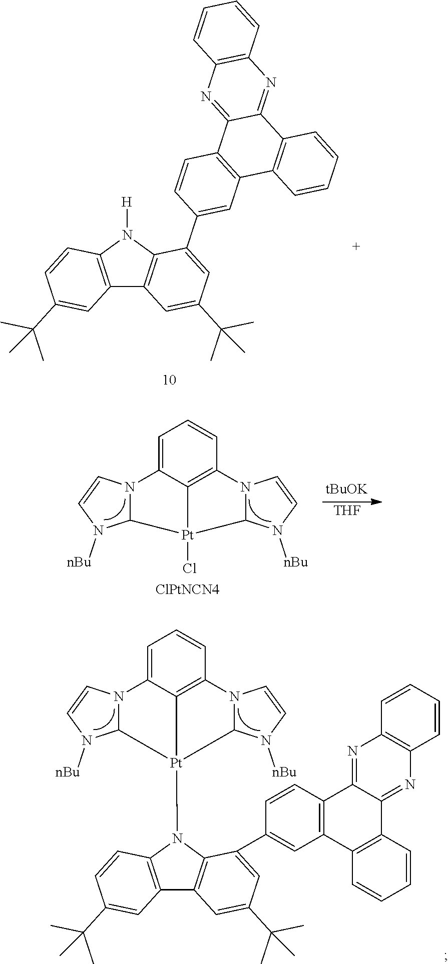

the preparation method thereof specifically included the following steps:
the intermediate 10 (190 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtCCC1 (553 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the red powder complex PtCCC1-12 (a yield being 63%).

### Example 7

This example provided a preparation method for a metal complex PtNCN1-5, a synthetic route of which was as shown below:

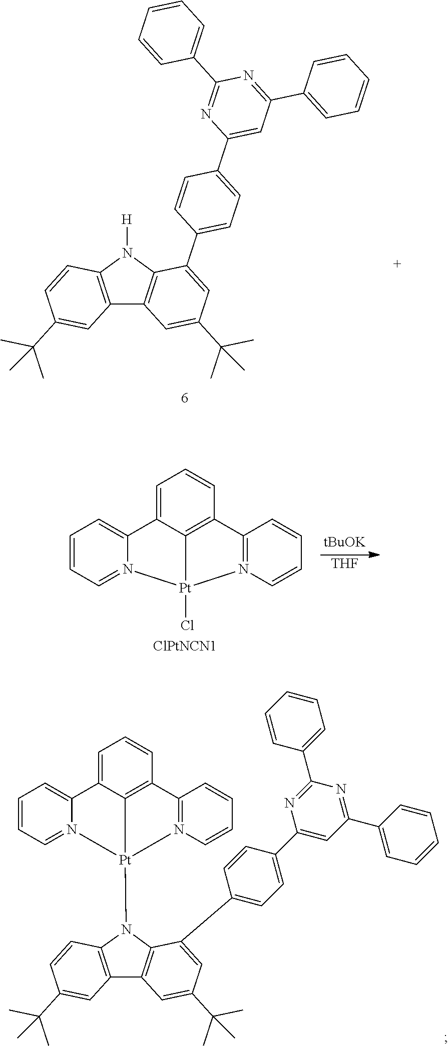

the preparation method thereof specifically included the following steps:
the intermediate 6 (200 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the yellow powder complex PtNCN1-5 (a yield being 55%). 1H NMR (500 MHz, CDCl3) δ 8.66 (dd, J=7.7, 1.8 Hz, 2H), 8.30 (dd, J=9.7, 1.9 Hz, 2H), 8.22 (dd, J=7.8, 1.5 Hz, 2H), 7.93 (dd, J=12.7, 6.6 Hz, 2H), 7.85 (td, J=7.8, 1.5 Hz, 2H), 7.69 (d, J=8.5 Hz, 1H), 7.60 (m, 7H), 7.52 (d, J=7.7 Hz, 2H), 7.45 (d, J=8.1 Hz, 2H), 7.33 (m, 5H), 7.05 (d, J=7.7 Hz, 2H), 6.94 (t, J=6.6 Hz, 2H), 6.64 (t, J=7.7 Hz, 1H), 1.54 (s, 9H), 1.49 (s, 9H).

### Example 8

This example provided a preparation method for a metal complex PtNCN1-3, a synthetic route of which was as shown below:

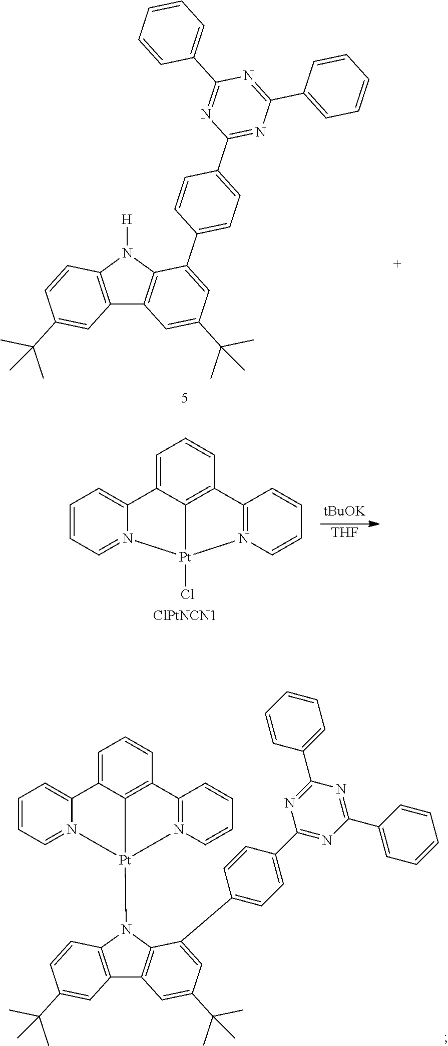

the preparation method thereof specifically included the following steps:
the intermediate 5 (201 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange powder complex PtNCN1-3 (a yield being 75%). 1H NMR (500 MHz, CDCl3) δ 8.70 (dd, J=8.2, 1.3 Hz, 4H), 8.30 (dd, J=8.6, 1.9 Hz, 2H), 7.88 (m, 6H), 7.65 (m, 7H), 7.48 (d, J=7.7 Hz, 2H), 7.33 (dd, J=8.6, 2.0 Hz, 2H), 7.31 (d, J=2.0 Hz, 2H), 7.26 (m, 1H), 6.94 (ddd, J=7.2, 5.7, 1.3 Hz, 2H), 6.88 (d, J=7.7 Hz, 2H), 6.48 (t, J=7.6 Hz, 1H), 1.54 (s, 9H), 1.49 (s, 9H).

### Example 9

This example provided a preparation method for a metal complex PtNCN1-1, a synthetic route of which was as shown below:

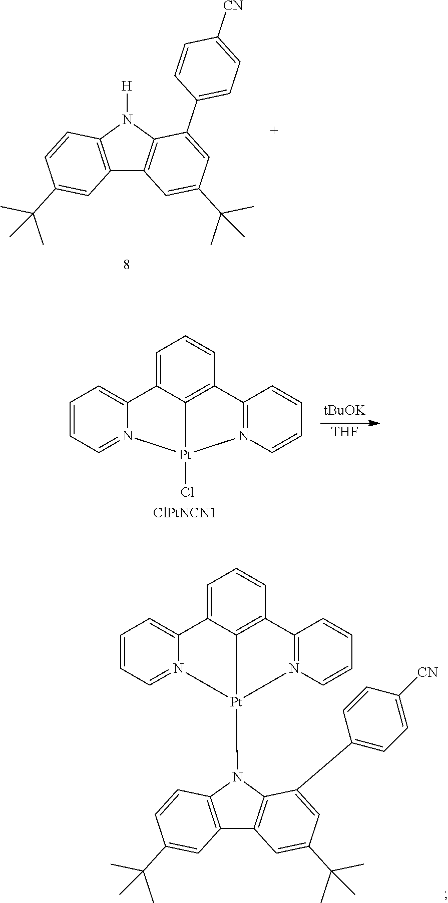

the preparation method thereof specifically included the following steps:
the intermediate 8 (130 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the yellow-green powder complex PtNCN1-1 (a yield being 71%).

### Example 10

This example provided a preparation method for a metal complex PtNCN1-7, a synthetic route of which was as shown below:

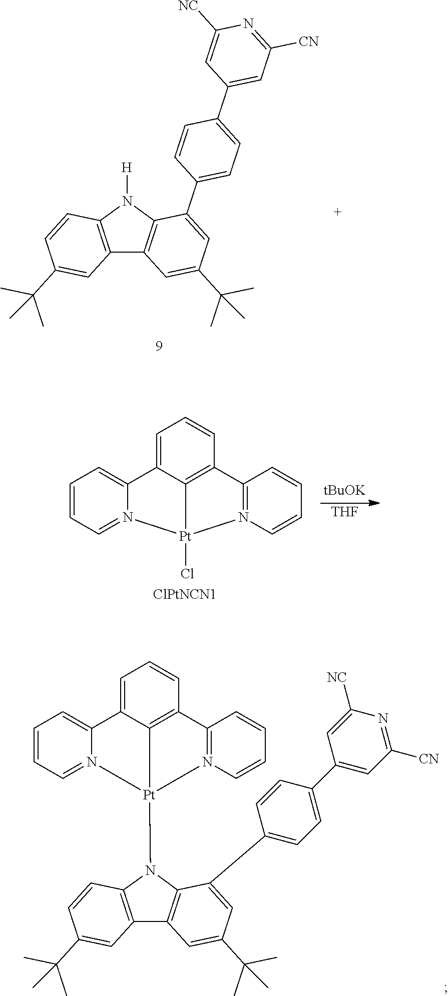

the preparation method thereof specifically included the following steps:
the intermediate 9 (165 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange powder complex PtNCN1-7 (a yield being 63%).

### Example 11

This example provided a preparation method for a metal complex PtNCN1-16, a synthetic route of which was as shown below:

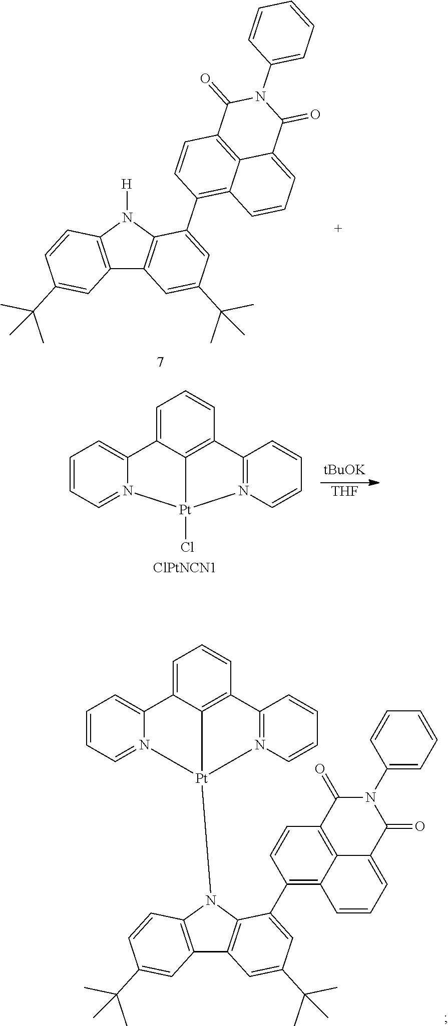

the preparation method thereof specifically included the following steps:
the intermediate 7 (206 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the red powder complex PtNCN1-16 (a yield being 80%).

### Example 12

This example provided a preparation method for a metal complex PtNCN1-A8, a synthetic route of which was as shown below:

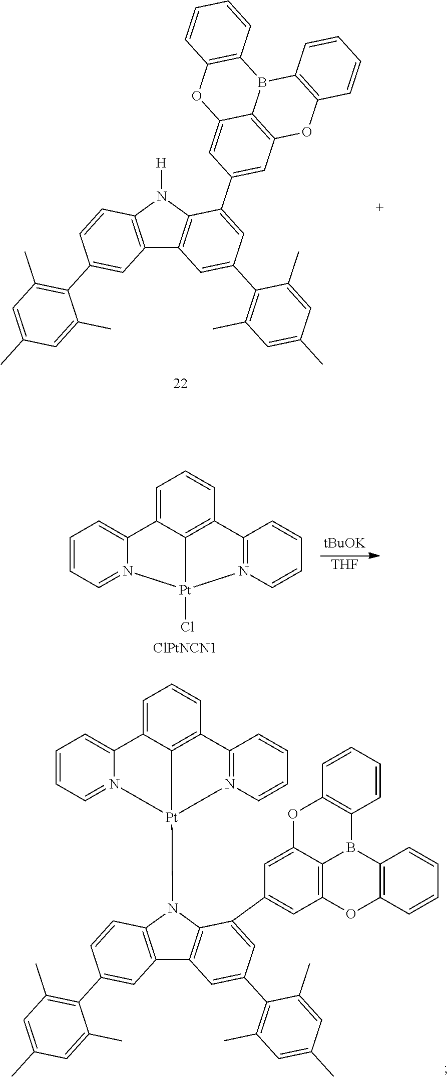

the preparation method thereof specifically included the following steps:
the intermediate 22 (230 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the yellow powder complex PtNCN1-A8 (a yield being 70%).

### Example 13

This example provided a preparation method for a metal complex PtCNN1-18, a synthetic route of which was as shown below:

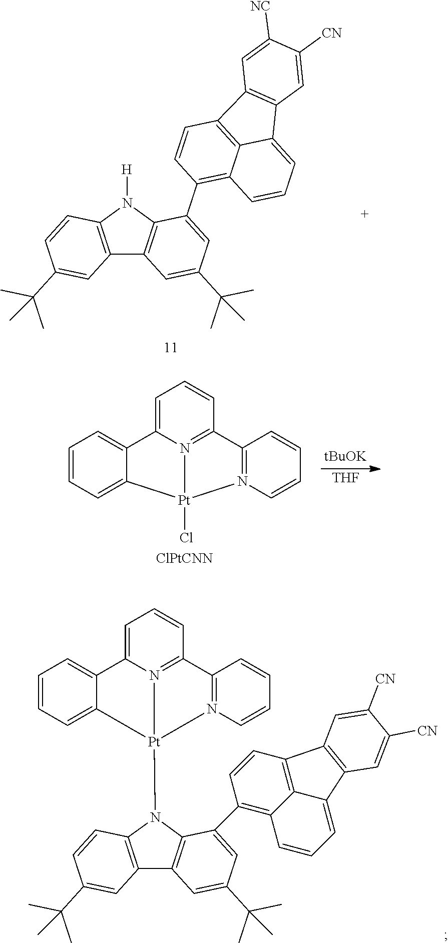

the preparation method thereof specifically included the following steps:
the intermediate 11 (180 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtCNN (157 mg, 0.3413 mmol) was added, reaction was performed overnight at the room temperature, a reaction liquid was filtered using diatomite, reduced pressure distillation was carried out on a filtrate, and washing was carried out using cold n-pentane to obtain the red powder complex PtCNN1-5 (a yield being 75%).

### Example 14

This example provided a preparation method for a metal complex PtNCN1-14, a synthetic route of which was as shown below:

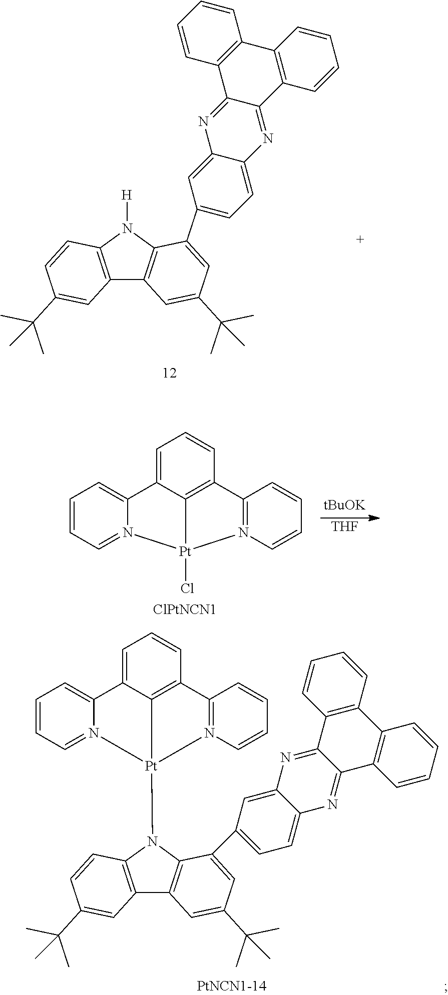

the preparation method thereof specifically included the following steps:
the intermediate 12 (190 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN1-14 (a yield being 67%).

### Example 15

This example provided a preparation method for a metal complex PtNCN1-17, a synthetic route of which was as shown below:

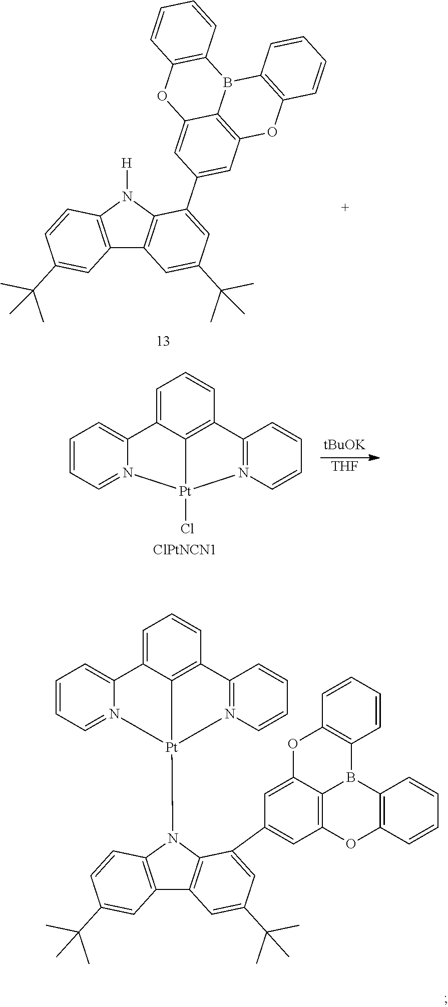

the preparation method thereof specifically included the following steps:
the intermediate 13 (186 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the yellow-green powder complex PtNCN1-17 (a yield being 63%).

### Example 16

This example provided a preparation method for a metal complex PtNCN3-16, a synthetic route of which was as shown below:

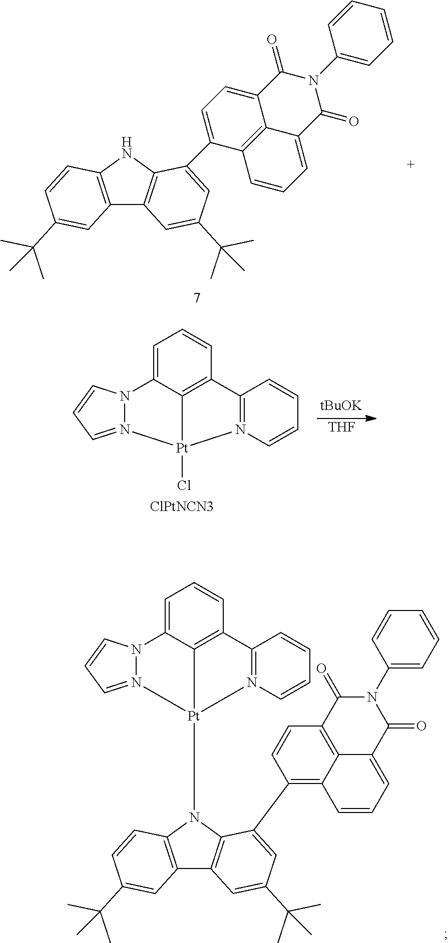

the preparation method thereof specifically included the following steps:
the intermediate 7 (206 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN3 (154 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN3-16 (a yield being 61%).

### Example 17

This example provided a preparation method for a metal complex PtNCN1-B2, a synthetic route of which was as shown below:

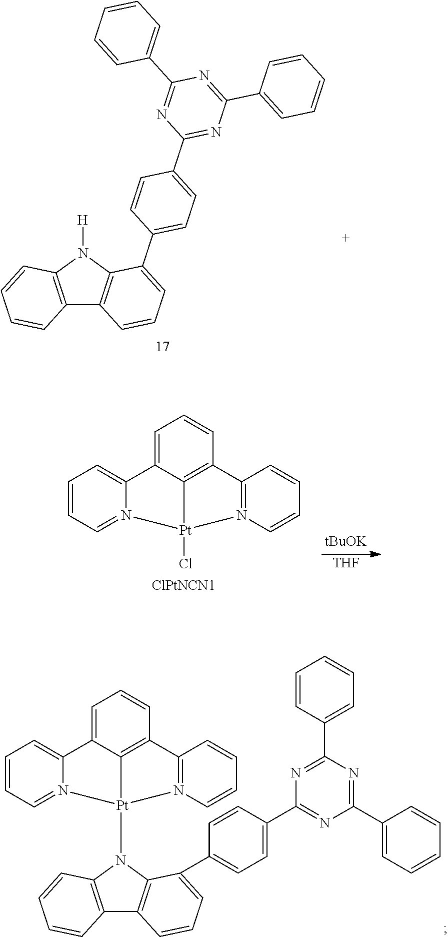

the preparation method thereof specifically included the following steps:
the intermediate 17 (165 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN1-B2 (a yield being 70%).

### Example 18

This example provided a preparation method for a metal complex PtNCN1-B8, a synthetic route of which was as shown below:

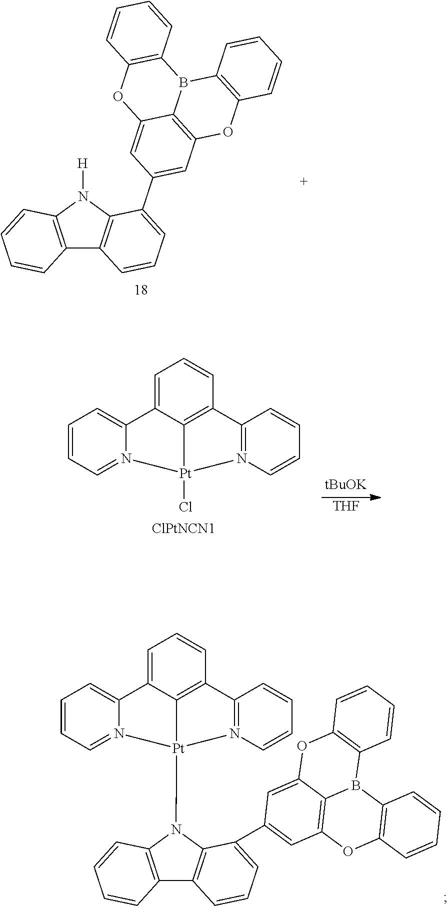

the preparation method thereof specifically included the following steps:
the intermediate 18 (150 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN1-B8 (a yield being 60%).

### Example 19

This example provided a preparation method for a metal complex PtNCN1-A2, a synthetic route of which was as shown below:

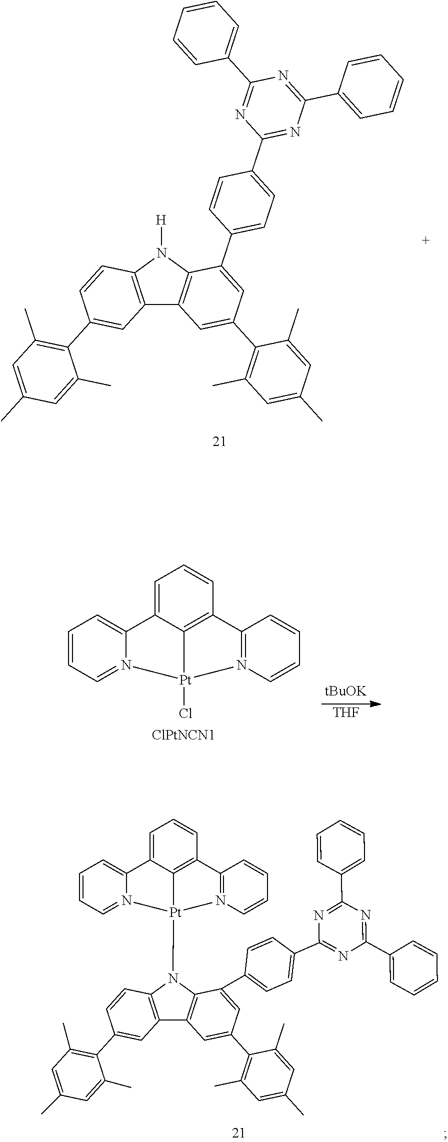

the preparation method thereof specifically included the following steps:
the intermediate 21 (242 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN1-A2 (a yield being 70%).

### Example 20

This example provided a preparation method for a metal complex PtNCN1-19, a synthetic route of which was as shown below:

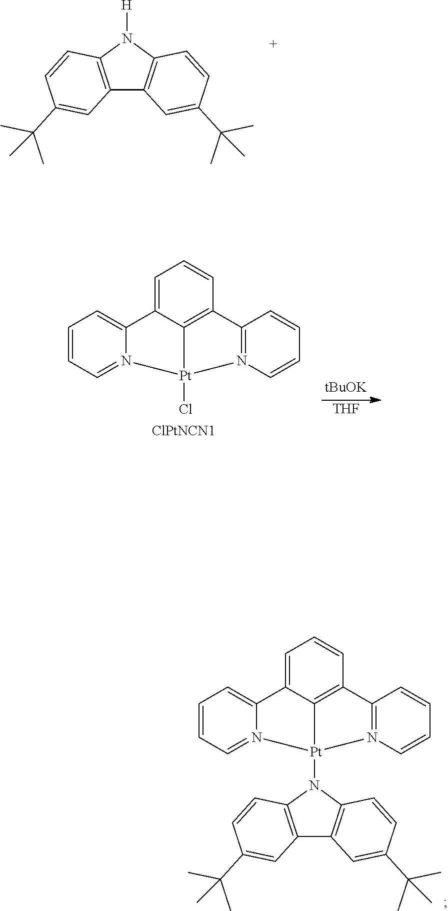

the preparation method thereof specifically included the following steps:
tert-butyl carbazole (95 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the yellow-green powder complex PtNCN1-19 (a yield being 63%). 1H NMR (600 MHz, CDCl3) δ 8.30 (d, J=1.8 Hz, 2H), 8.10 (dd, J=5.7, 0.9 Hz, 2H), 7.89 (td, J=7.8, 1.6 Hz, 2H), 7.77 (d, J=7.9 Hz, 2H), 7.70 (d, J=8.5 Hz, 2H), 7.61 (d, J=7.7 Hz, 2H), 7.35 (m, 4H), 6.96 (ddd, J=7.3, 5.7, 1.4 Hz, 2H), 1.60 (s, 18H).

### Example 21

This example provided a preparation method for a metal complex PtNCN1-20, a synthetic route of which was as shown below:

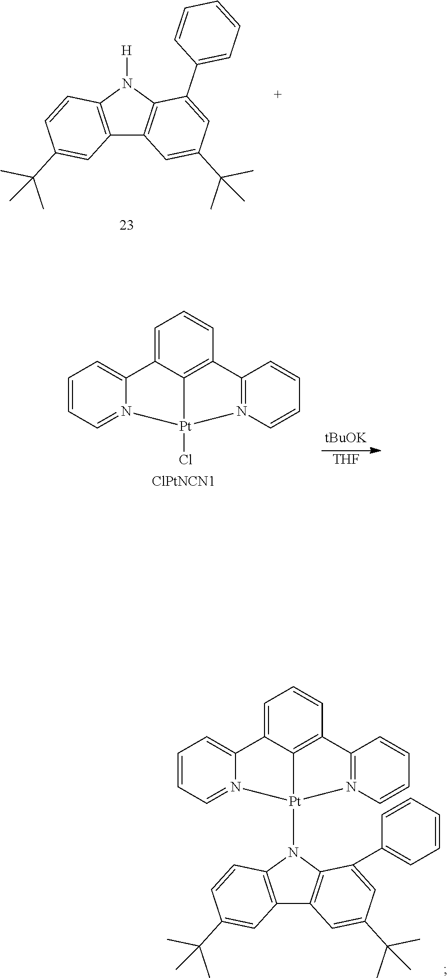

the preparation method thereof specifically included the following steps:
the intermediate 23 (120 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN1-20 (a yield being 53%). 1H NMR (400 MHz, CDCl3) δ 8.30 (s, 2H), 7.97 (d, J=5.4 Hz, 2H), 7.84 (td, J=7.9, 1.3 Hz, 2H), 7.70 (d, J=8.5 Hz, 2H), 7.62 (d, J=7.7 Hz, 2H), 7.45 (d, J=7.7 Hz, 2H), 7.32 (dd, J=8.5, 1.9 Hz, 2H), 7.25 (m, 2H), 7.21 (d, J=7.8 Hz, 1H), 6.90 (dd, J=9.5, 3.5 Hz, 2H), 6.59 (m, 3H), 1.53 (s, 9H), 1.51 (s, 9H).

### Example 22

This example provided a preparation method for a metal complex PtNCN1-21, a synthetic route of which was as shown below:

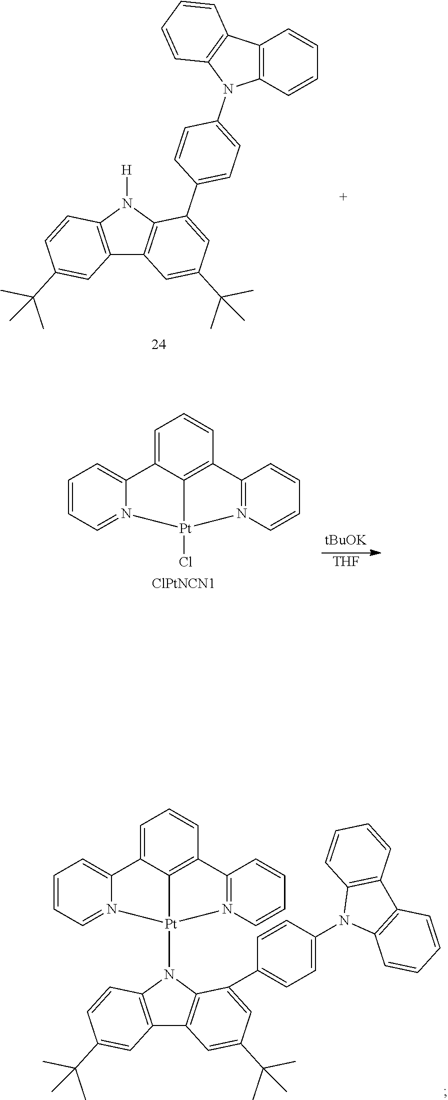

the preparation method thereof specifically included the following steps:
the intermediate 24 (177 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN1-21 (a yield being 66%). 1H NMR (400 MHz, CDCl3) δ 8.34 (dd, J=14.2, 1.8 Hz, 2H), 8.16 (d, J=5.7 Hz, 2H), 8.05 (dd, J=6.2, 2.3 Hz, 2H), 7.83 (m, 2H), 7.71 (d, J=8.5 Hz, 1H), 7.65 (dd, J=7.7, 6.0 Hz, 4H), 7.51 (d, J=7.7 Hz, 2H), 7.36 (d, J=2.0 Hz, 1H), 7.32 (dd, J=8.7, 2.1 Hz, 2H), 7.22 (m, 4), 6.98 (m, 4H), 6.83 (m, 2H), 1.58 (s, 9H), 1.51 (s, 9H).

### Example 23

This example provided a preparation method for a metal complex PtNCN3-22, a synthetic route of which was as shown below:

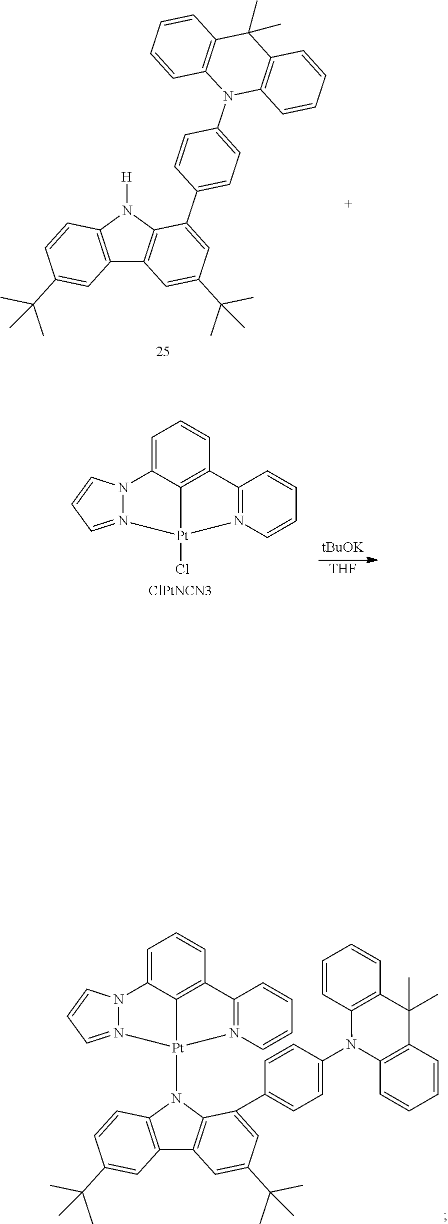

the preparation method thereof specifically included the following steps:
the intermediate 25 (192 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN3-22 (a yield being 76%).

### Example 24

This example provided a preparation method for a metal complex PtNCN3-23, a synthetic route of which was as shown below:

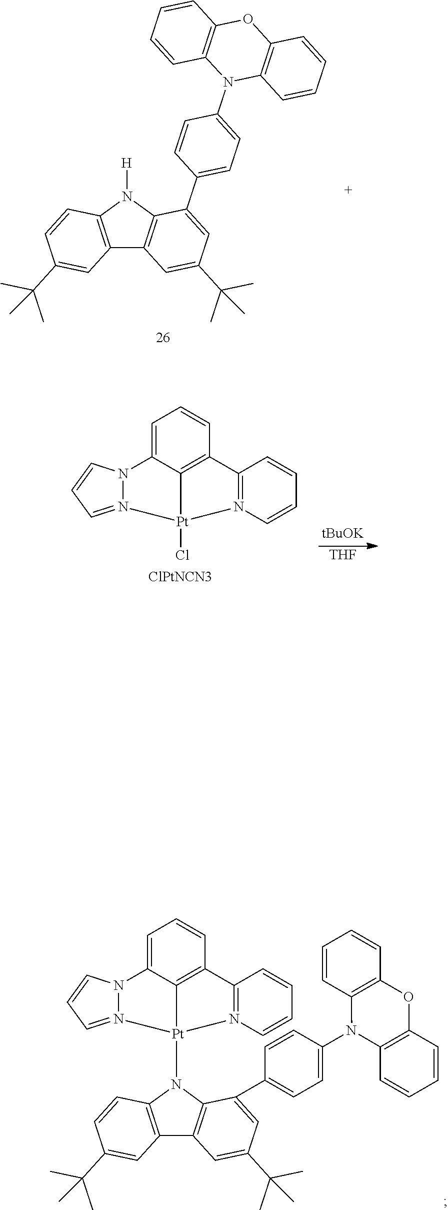

the preparation method thereof specifically included the following steps:
the intermediate 26 (192 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN3-23 (a yield being 73%).

### Example 25

This example provided a preparation method for a metal complex PtNCN3-24, a synthetic route of which was as shown below:

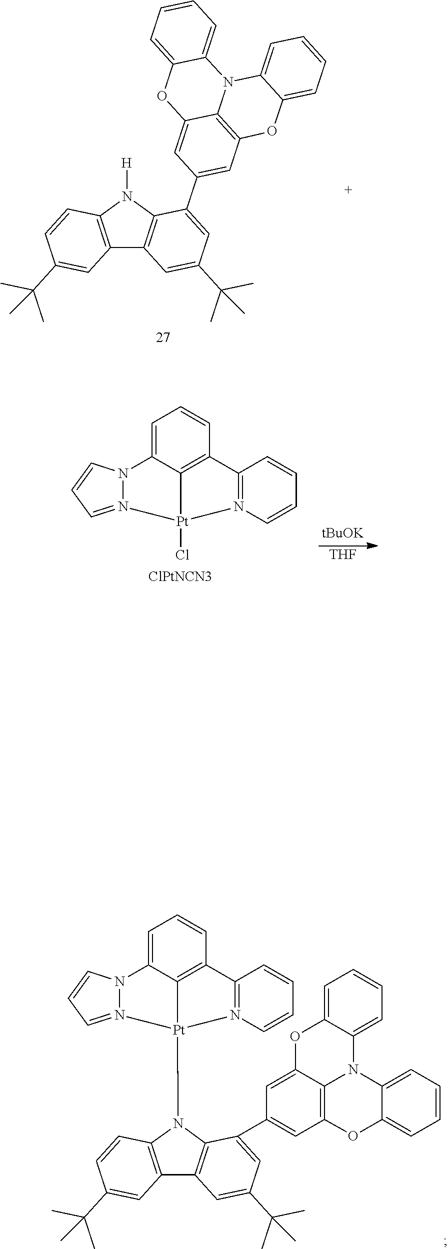

the preparation method thereof specifically included the following steps:
the intermediate 27 (188 mg, 0.3413 mmol) and potassium tert-butoxide (46 mg, 0.409 mmol) were dissolved in 20 ml of an anhydrous tetrahydrofuran solution and stirred for 1 h at the room temperature, then the intermediate ClPtNCN1 (157 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange-red powder complex PtNCN3-24 (a yield being 80%).

### Example 26

This example provided a preparation method for a metal complex PdCCC1-3, a synthetic route of which was as shown below:

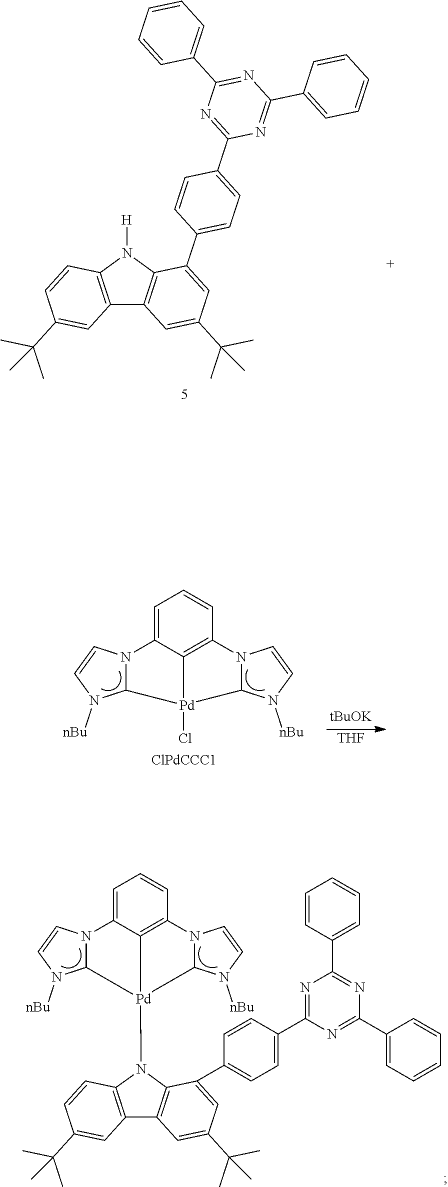

the preparation method thereof specifically included the following steps:
the intermediate 10 (200 mg, 0.3413 mmol) and potassium tert-butoxide (46 mg, 0.409 mmol) were dissolved in 20 mL of an anhydrous tetrahydrofuran solution and stirred for 1 h at the room temperature, then the intermediate ClPdCCC1 (160 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange powder complex PdCCC1-3 (a yield being 70%). 1H NMR (600 MHz, CDCl3) δ 8.75 (d, J=8.1 Hz, 4H), 8.21 (s, 1H), 8.15 (s, 1H), 8.02 (d, J=7.9 Hz, 2H), 7.67 (m, 6H), 7.57 (d, J=8.4 Hz, 1H), 7.43 (d, J=7.9 Hz, 2H), 7.31 (s, 1H), 7.28 (m, 2H), 6.79 (s, 2H), 6.38 (m, 1H), 6.31 (d, J=7.8 Hz, 2H), 3.31 (m, 2H), 3.10 (m, 2H), 1.55 (s, 9H), 1.48 (s, 9H), 1.18 (m, 4H), 0.52 (m, 2H), 0.44 (t, J=7.1 Hz, 6H), 0.26 (m, 2H).

### Example 27

This example provided a preparation method for a metal complex PdCCC1-12, a synthetic route of which was as shown below:

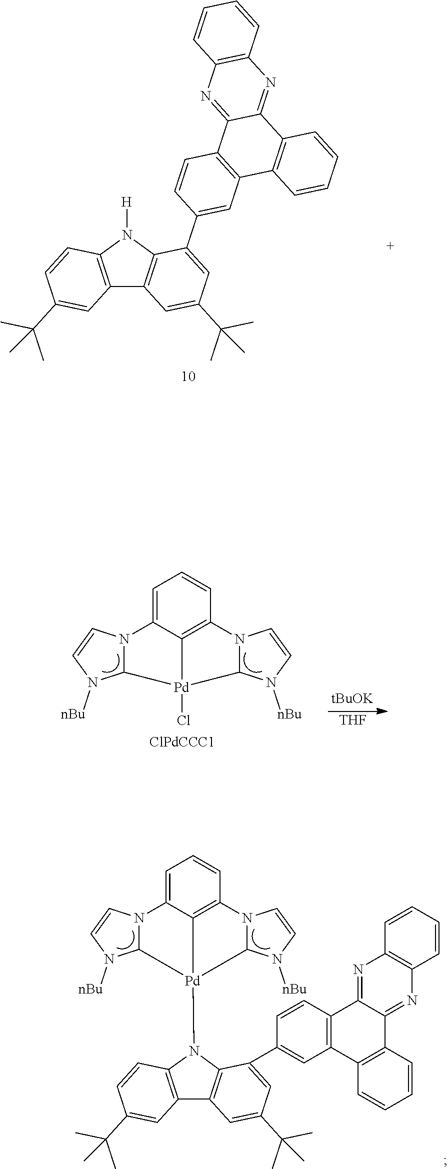

the preparation method thereof specifically included the following steps:
the intermediate 10 (190 mg, 0.3413 mmol) and potassium tert-butoxide (46 mg, 0.409 mmol) were dissolved in 20 mL of an anhydrous tetrahydrofuran solution and stirred for 1 h at the room temperature, then the intermediate ClPdCCC1 (160 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the red powder complex PdCCC1-12 (a yield being 63%). 1H NMR (400 MHz, CDCl3) δ 9.17 (dd, J=8.0, J=1.0 Hz, 1H), 8.62 (d, J=8.0 Hz, 1H), 8.53 (s, 1H), 8.35-8.31 (m, 1H), 8.29-8.25 (m, 1H), 8.23 (s, 1H), 8.14 (d, J=1.7 Hz, 1H), 7.87 (dq, J=6.7, J=3.3 Hz, 2H), 7.69 (d, J=8.1 Hz, 1H), 7.55 (t, J=7.2 Hz, 1H), 7.33 (m, 4H), 7.11-7.0 (m, 1H), 6.72 (s, 2H), 6.62 (d, J=1.6 Hz, 2H), 5.83 (t, J=7.8 Hz, 1H), 5.67 (d, J=7.7 Hz, 2H), 3.29-3.15 (m, 4H), 1.55 (s, 9H), 1.45 (s, 9H), 1.18 (s, 4H), 0.39 (m, 6H). 13C NMR (126 MHz, CDCl3) δ 145.10, 142.68, 142.40, 142.07, 141.67, 132.31, 130.82, 130.08, 129.53, 129.46, 129.33, 129.27, 129.16, 129.03, 127.24, 126.39, 125.76, 124.25, 123.12, 122.08, 119.50, 118.56, 114.54, 113.86, 108.02, 107.89, 106.43, 49.35, 33.95, 32.18, 32.06, 19.19, 13.90, 13.84, 13.54.

### Example 28

This example provided a preparation method for a metal complex PdCCC1-5, a synthetic route of which was as shown below:

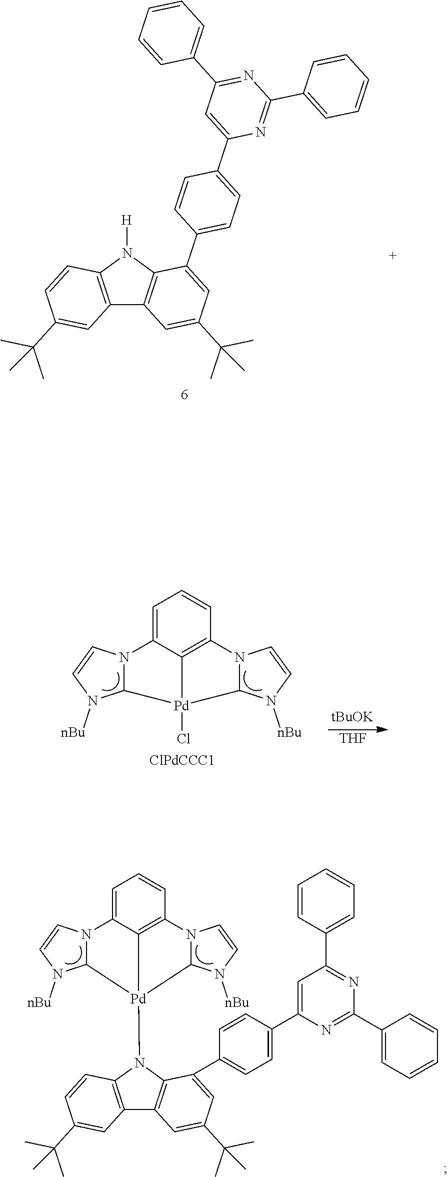

the preparation method thereof specifically included the following steps:
the intermediate 10 (200 mg, 0.3413 mmol) and potassium tert-butoxide (46 mg, 0.409 mmol) were dissolved in 20 mL of an anhydrous tetrahydrofuran solution and stirred for 1 h at the room temperature, then the intermediate ClPdCCC1 (160 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange powder complex PdCCC1-5 (a yield being 72%).

### Example 29

This example provided a preparation method for a metal complex PdCCC1-17, a synthetic route of which was as shown below:

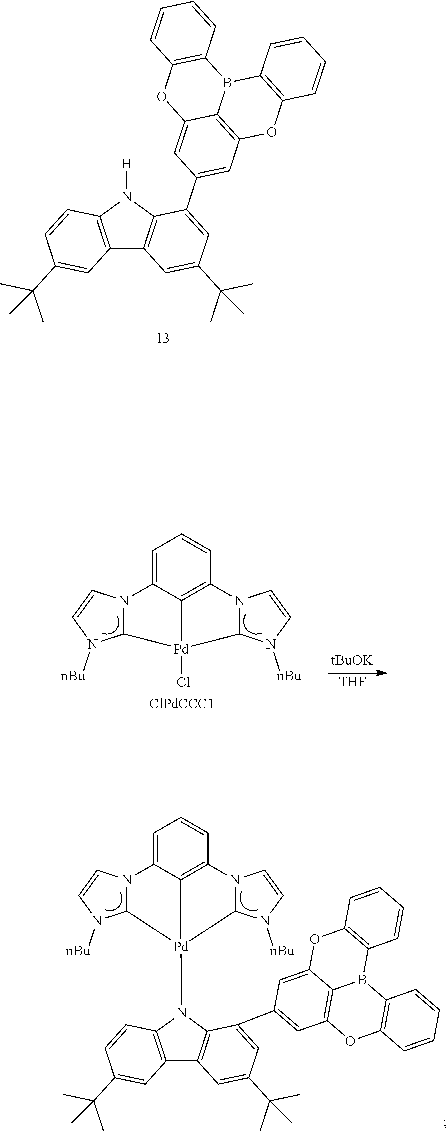

the preparation method thereof specifically included the following steps:
the intermediate 13 (186 mg, 0.3413 mmol) and potassium tert-butoxide (46 mg, 0.409 mmol) were dissolved in 20 mL of an anhydrous tetrahydrofuran solution and stirred for 1 h at the room temperature, then the intermediate ClPdCCC1 (160 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange powder complex PdCCC1-17 (a yield being 72%). 1H NMR (600 MHz, Chloroform-d) δ 8.51 (dd, J=7.7, 1.7 Hz, 2H), 8.20 (d, J=2.0 Hz, 1H), 8.12 (d, J=2.0 Hz, 1H), 7.62 (ddd, J=8.4, 6.9, 1.6 Hz, 2H), 7.51 (d, J=8.5 Hz, 1H), 7.33-7.31 (m, 2H), 7.23 (dd, J=8.5, 1.9 Hz, 1H), 7.19 (d, J=7.9 Hz, 2H), 7.05 (s, 2H), 6.79 (d, J=1.8 Hz, 2H), 6.72 (d, J=1.8 Hz, 2H), 6.29 (t, J=7.8 Hz, 1H), 5.83 (d, J=7.8 Hz, 2H), 3.31-3.25 (m, 2H), 3.19-3.13 (m, 2H), 1.52 (s, 9H), 1.44 (s, 9H), 1.23-1.13 (m, 4H), 0.50-0.44 (m, 2H), 0.38 (t, J=7.2 Hz, 6H), 0.24-0.17 (m, 2H).

### Example 30

This example provided a preparation method for a metal complex PdCCC1-B5, a synthetic route of which was as shown below:

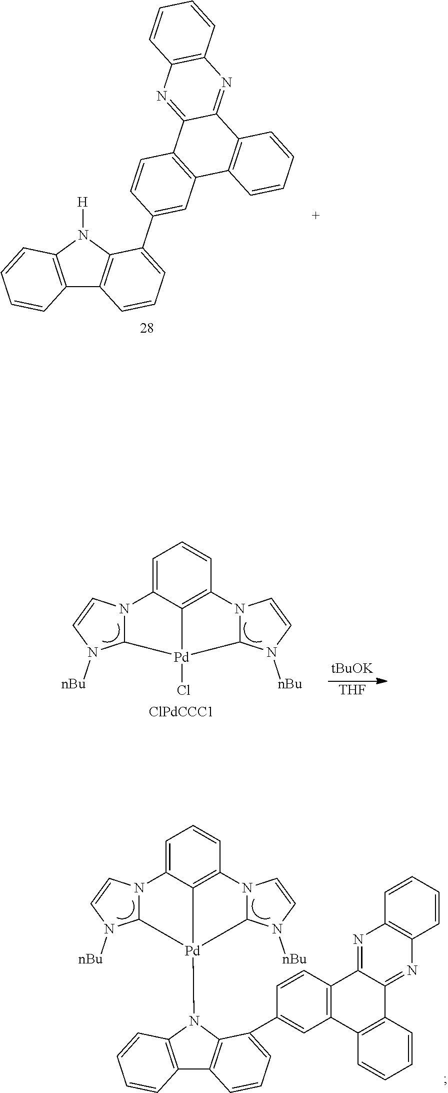

the preparation method thereof specifically included the following steps:
the intermediate 28 (152 mg, 0.3413 mmol) and potassium tert-butoxide (46 mg, 0.409 mmol) were dissolved in 20 mL of an anhydrous tetrahydrofuran solution and stirred for 1 h at the room temperature, then the intermediate ClPdCCC1 (160 mg, 0.3413 mmol) was added, reaction was performed overnight at the room temperature, a reaction liquid was filtered using diatomite, reduced pressure distillation was carried out on a filtrate, washing was carried out using cold n-pentane, and then recrystallization was carried out with a ratio of dichloromethane:n-hexane=1:100 to obtain the orange powder complex PdCCC1-B5 (a yield being 76%). 1H NMR (600 MHz, Chloroform-d) δ 9.17 (d, J=8.0 Hz, 1H), 8.64 (d, J=8.0 Hz, 1H), 8.51 (s, 1H), 8.34 (dd, J=6.0, 3.8 Hz, 1H), 8.26 (d, J=3.6 Hz, 2H), 8.18 (d, J=7.8 Hz, 1H), 7.88 (dd, J=6.4, 3.4 Hz, 2H), 7.66 (d, J=8.1 Hz, 1H), 7.61 (d, J=8.1 Hz, 1H), 7.56 (t, J=7.4 Hz, 1H), 7.40-7.33 (m, 3H), 7.19 (t, J=7.2 Hz, 1H), 7.16-7.12 (m, 1H), 7.01-6.96 (m, 1H), 6.72 (s, 2H), 6.64 (s, 2H), 5.86 (t, J=7.7 Hz, 1H), 5.67 (s, 2H), 3.22 (s, 4H), 1.16 (s, 4H), 0.47 (dq, J=14.4, 7.7, 7.1 Hz, 2H), 0.35 (s, 6H), 0.26 (dt, J=12.8, 7.1 Hz, 2H).

### Device Example 1

This example provided an organic electroluminescent device, as shown in FIG. 1, including an anode layer 1, a hole injection layer 2, a first hole transport layer 3, a second hole transport layer 4, an electron block layer 5, a light-emitting layer 6, a first electron transport layer 7, a second electron transport layer 8, an electron injection layer 9 and a cathode layer 10 which were sequentially arranged on a glass substrate 100 from bottom to top.

Materials for manufacturing the organic electroluminescent device were as follows:

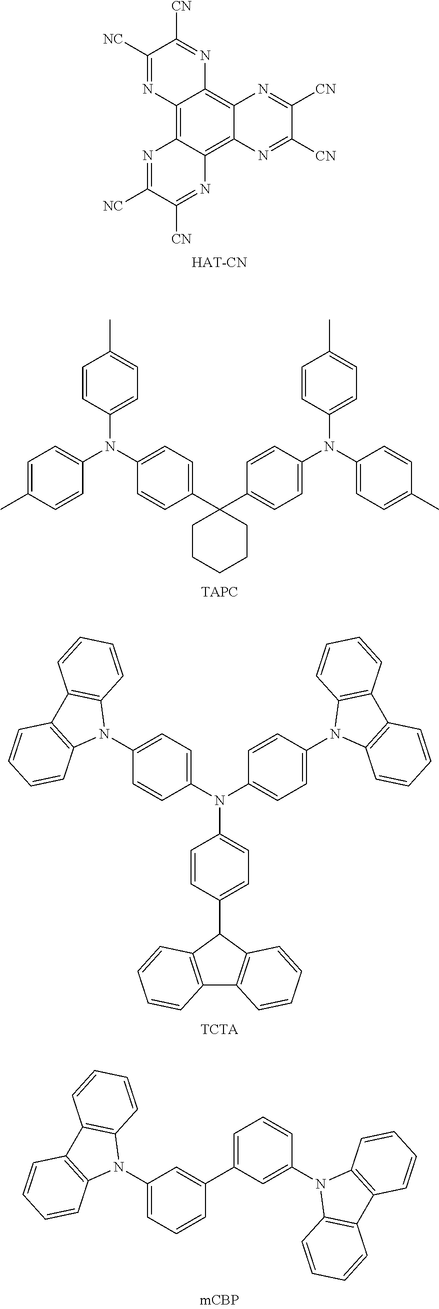

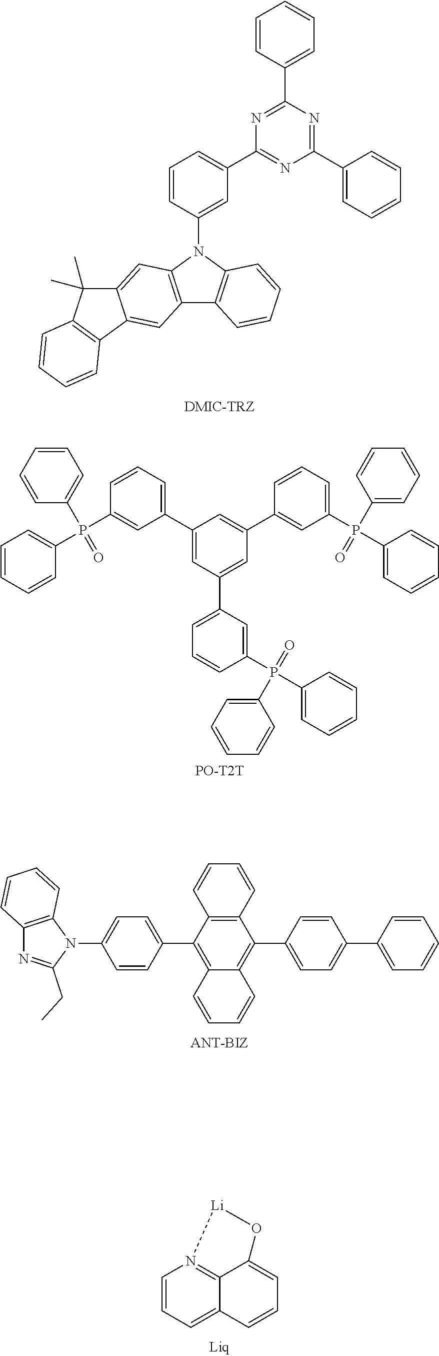

an ITO material, namely an indium tin oxide material, was selected for the anode layer 1; 1,2-hexaazatriphenylenehexacarbonitrile (HAT-CN) was selected as a material of the hole injection layer 2; 4,4′-cyclohexylidenebis[N,N-bis(4-methylphenyl)benzenamine](TAPC) was selected as a material of the first hole transport layer 3; tris(4-carbazoyl-9-ylphenyl)amine (TCTA) was selected as a material of the second hole transport layer 4; 3,3′-di(9H-carbazol-9-yl)-1,1′-biphenyl (mCBP) was selected as a material of the electron block layer 5; the light-emitting layer 6 was formed by co-doping of a host material and a guest material, wherein 5-(3-(4,6-diphenyl-1,3,5-triazin-2-yl)phenyl)-7,7-dimethyl-5,7-dihydroindeno[2,1-b]carbazole (DMIC-TRZ) was selected as the host material, and the metal complex X of the present application was selected as the guest material, where X was PtNCN1-12, and a doping amount of the guest material accounted for 1% of the total mass of the host material and the guest material; 2,4,6-tris[3-(diphenylphosphinyl)phenyl]-1,3,5-triazole (PO-T2T) was selected as a material of the first electron transport layer 7; (1-(4-(10-([1,1′-biphenyl]-4-yl)anthracen-9-yl)phenyl)-2-ethyl-1H-benzo[d]imidazole) (ANT-BIZ) was selected as a material of the second electron transport layer 8; Liq (lithium 8-quinolinolate) was selected as a material of the electron injection layer 9; and a metal A1 material was selected as a material of the cathode layer 10.

A structure of the device was ITO/hole injection layer (HAT-CN) (5 nm of thickness)/first hole transport layer (TAPC) (40 nm of thickness)/second hole transport layer (TCTA) (10 nm of thickness)/electron block layer (mCBP) (10 nm of thickness)/light-emitting layer (DMIC-TRZ: X) (40 nm of thickness)/first electron transport layer (PO-T2T) (20 nm of thickness)/second electron transport layer (ANT-BIZ) (30 nm of thickness)/electron injection layer (Liq) (1.2 nm of thickness)/A1 (100 nm of thickness). X was PtNCN1-12.

### Device Example 2

This example provided an organic electroluminescent device, which was different from the organic electroluminescent device provided in Device Example 1 in that: a doping amount of the guest material PtNCN1-12 in the light-emitting layer accounted for 3% of the total mass of the host material and the guest material.

### Device Example 3

This example provided an organic electroluminescent device, which was different from the organic electroluminescent device provided in Device Example 1 in that: a doping amount of the guest material PtNCN1-12 in the light-emitting layer accounted for 5% of the total mass of the host material and the guest material.

### Device Example 4

This example provided an organic electroluminescent device, which was different from the organic electroluminescent device provided in Device Example 1 in that: a doping amount of the guest material PtNCN1-12 in the light-emitting layer accounted for 10% of the total mass of the host material and the guest material.

### Device Example 5

This example provided an organic electroluminescent device, which was different from the organic electroluminescent device provided in Device Example 1 in that: the guest material X in the light-emitting layer was PdCCC1-12, and a doping amount of PdCCC1-12 accounted for 1% of the total mass of the host material and the guest material.

### Device Example 6

This example provided an organic electroluminescent device, which was different from the organic electroluminescent device provided in Device Example 1 in that: the guest material X in the light-emitting layer was PdCCC1-12, and a doping amount of PdCCC1-12 accounted for 3% of the total mass of the host material and the guest material.

### Device Example 7

This example provided an organic electroluminescent device, which was different from the organic electroluminescent device provided in Device Example 1 in that: the guest material X in the light-emitting layer was PdCCC1-12, and a doping amount of PdCCC1-12 accounted for 5% of the total mass of the host material and the guest material.

### Device Example 8

This example provided an organic electroluminescent device, which was different from the organic electroluminescent device provided in Device Example 1 in that: the guest material X in the light-emitting layer was PdCCC1-5, and a doping amount of PdCCC1-5 accounted for 1% of the total mass of the host material and the guest material.

### Device Example 9

This example provided an organic electroluminescent device, which was different from the organic electroluminescent device provided in Device Example 1 in that: the guest material X in the light-emitting layer was PdCCC1-5, and a doping amount of PdCCC1-5 accounted for 3% of the total mass of the host material and the guest material.

### Device Example 10

This example provided an organic electroluminescent device, which was different from the organic electroluminescent device provided in Device Example 1 in that: the guest material X in the light-emitting layer was PdCCC1-3, and a doping amount of PdCCC1-3 accounted for 1% of the total mass of the host material and the guest material.

### Device Example 11

This example provided an organic electroluminescent device, which was different from the organic electroluminescent device provided in Device Example 1 in that: the guest material X in the light-emitting layer was PdCCC1-3, and a doping amount of PdCCC1-3 accounted for 3% of the total mass of the host material and the guest material.

### Device Example 12

This example provided an organic electroluminescent device, including an anode layer, a hole injection layer, a hole transport layer, an electron block layer, a light-emitting layer, an electron transport layer, an electron injection layer and a cathode layer which were sequentially arranged on a glass substrate from bottom to top.

Materials for manufacturing the organic electroluminescent device were as follows:

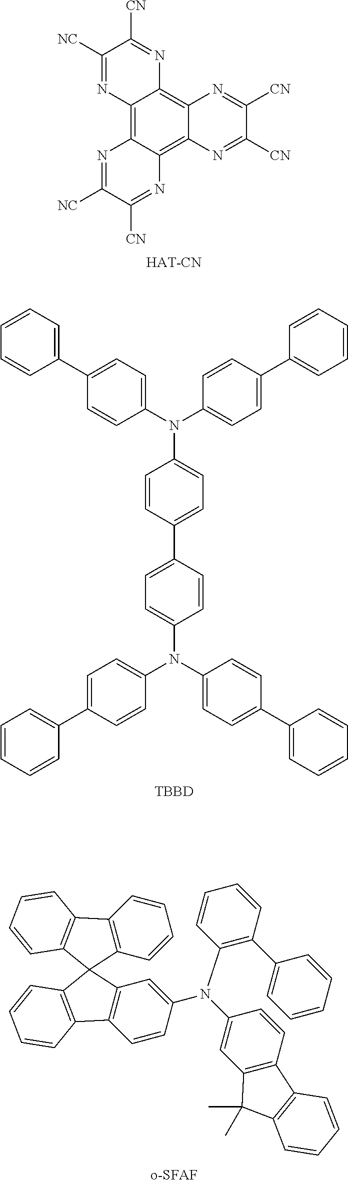

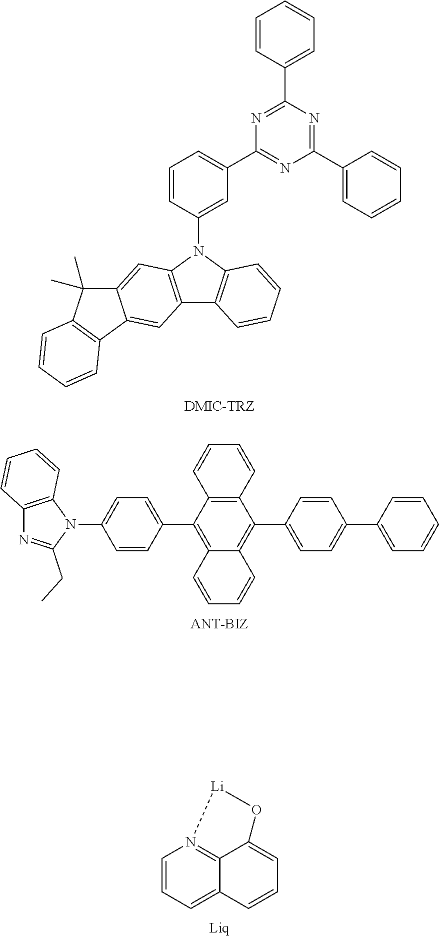

an ITO material, namely an indium tin oxide material, was selected for the anode layer; 1,2-hexaazatriphenylenehexacarbonitrile (HAT-CN) was selected as a material of the hole injection layer; N4,N4,N4′,N4′-tetra(4-biphenyl)-biphenyl-4,4′-diamine (TBBD) was selected as a material of the hole transport layer; N-([1,1′-biphenyl]-2-yl)-N-(9,9-dimethyl-9H-fluorenyl-2-yl)-9,9′-spirobi[fluorene]-2-amine (o-SFAF) was selected as a material of the electron block layer; the light-emitting layer was formed by co-doping of a host material and a guest material, wherein 5-(3-(4,6-diphenyl-1,3,5-triazin-2-yl)phenyl)-7,7-dimethyl-5,7-dihydroindeno[2,1-b]carbazole (DMIC-TRZ) was selected as the host material, the metal complex PdCCC1-12 of the present application was selected as the guest material, and a doping amount of the guest material accounted for 1% of the total mass of the host material and the guest material; (1-(4-(10-([1,1′-biphenyl]-4-yl)anthracen-9-yl)phenyl)-2-ethyl-1H-benzo[d]imidazole) (ANT-BIZ) was selected as a material of the electron transport layer; Liq (lithium 8-quinolinolate) was selected as a material of the electron injection layer; and a metal A1 material was selected as a material of the cathode layer.

A structure of the device was ITO/hole injection layer (HAT-CN) (5 nm of thickness)/hole transport layer (TBBD) (30 nm of thickness)/electron block layer (o-SFAF) (15 nm of thickness)/light-emitting layer (DMIC-TRZ: PdCCC1-12) (45 nm of thickness)/electron transport layer (ANT-BIZ) (40 nm of thickness)/electron injection layer (Liq) (2 nm of thickness)/A1 (100 nm of thickness).

### Test and Representation of Metal Complex:

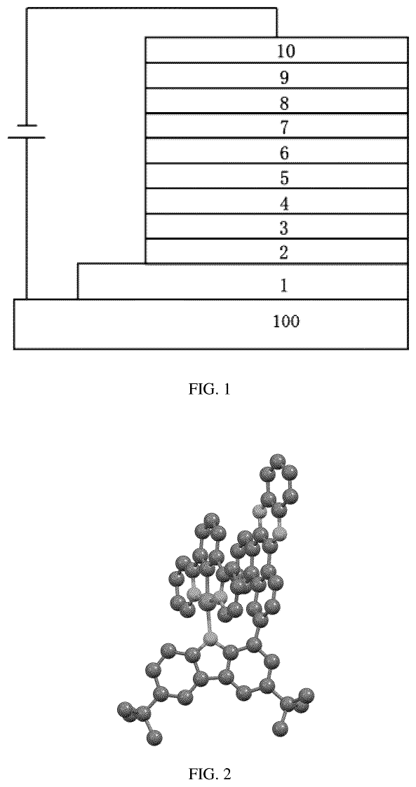

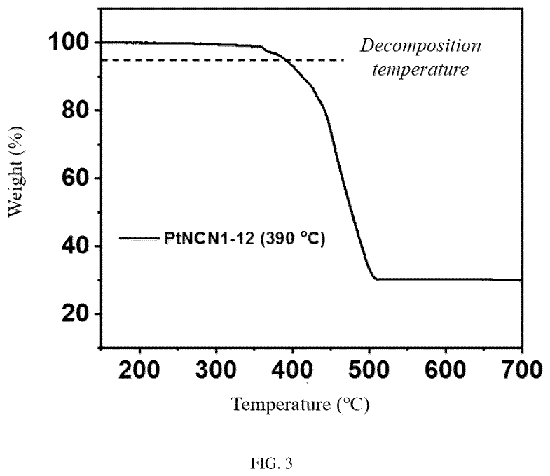

Proton nuclear magnetic resonance analysis was performed on a metal complex PtNCN1-12, and its crystal structure was as shown in FIG. 2; and thermal stability analysis was performed on the metal complex PtNCN1-12, and FIG. 3 showed a thermogravimetric analysis curve of PtNCN1-12.

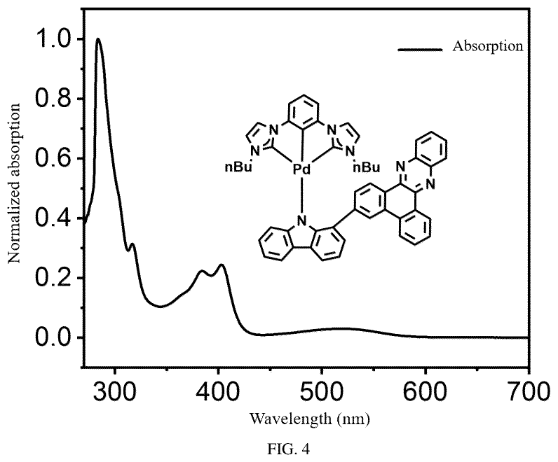

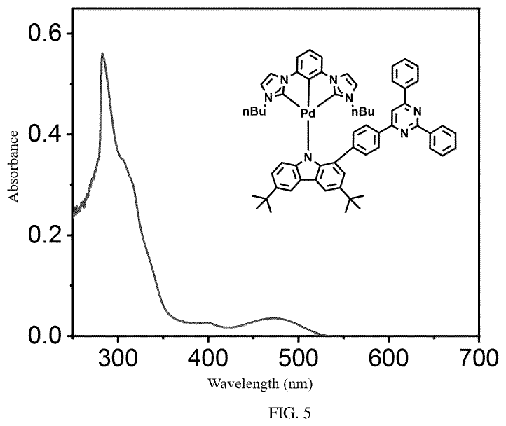

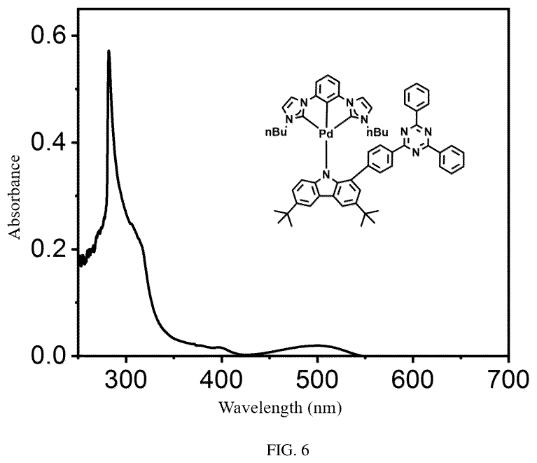

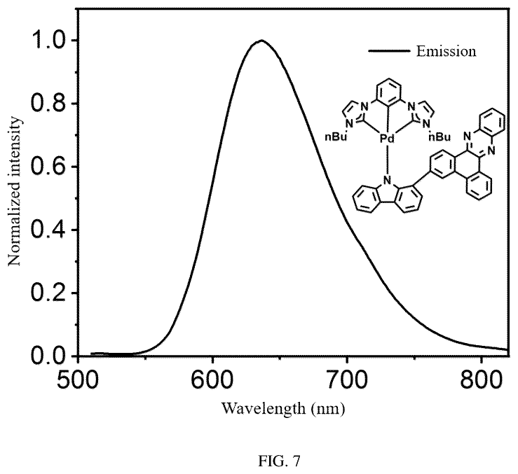

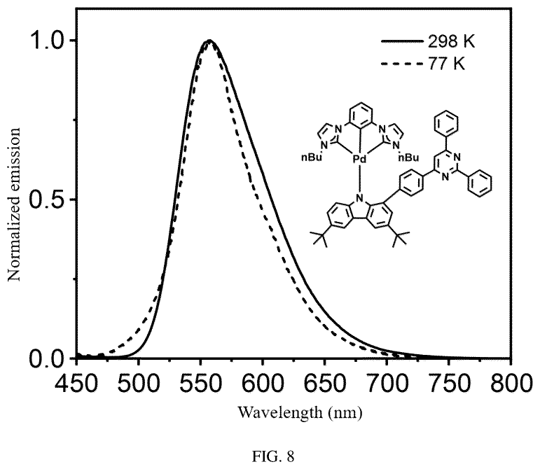

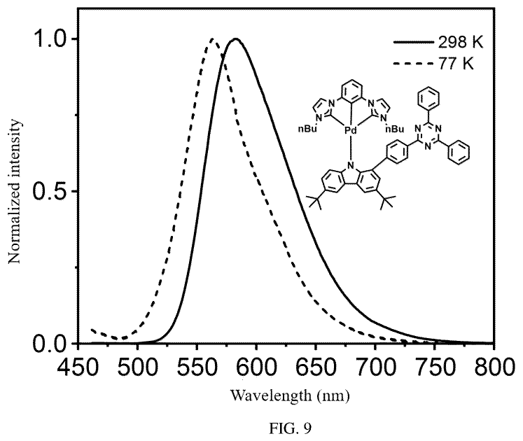

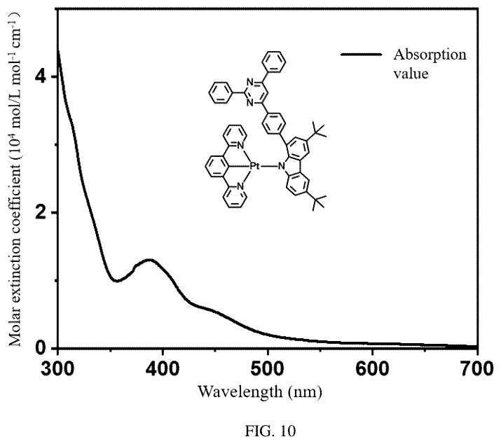

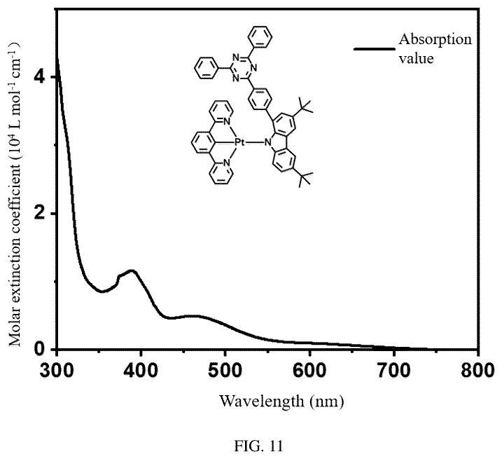

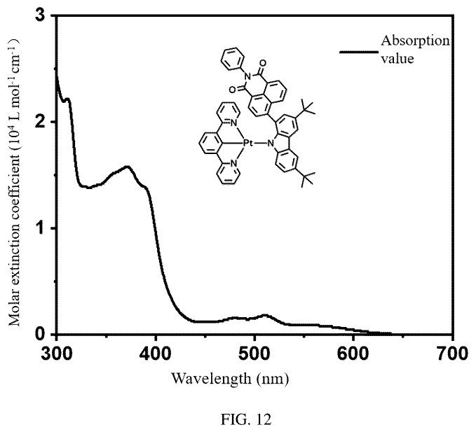

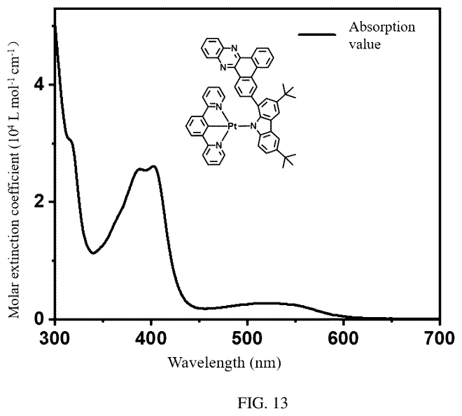

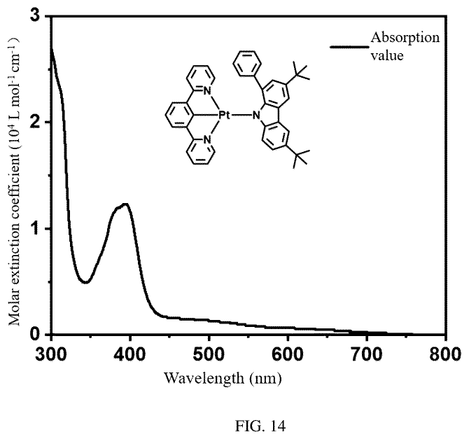

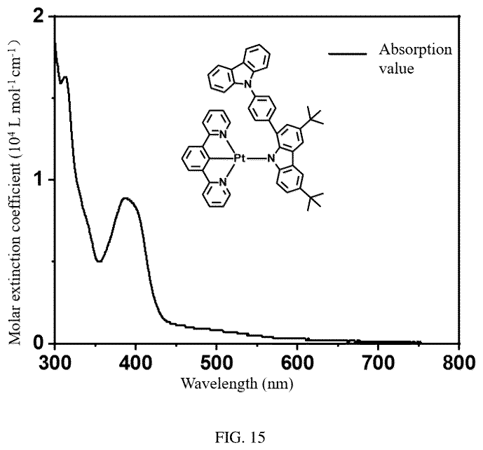

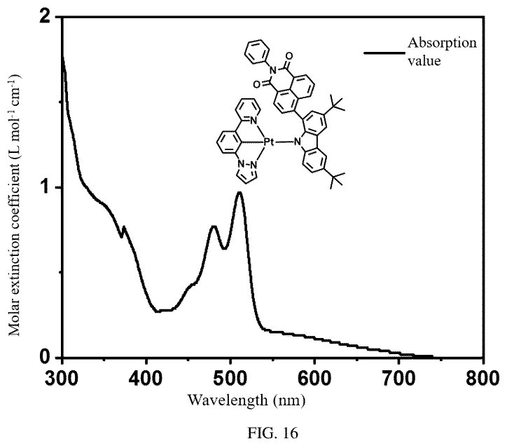

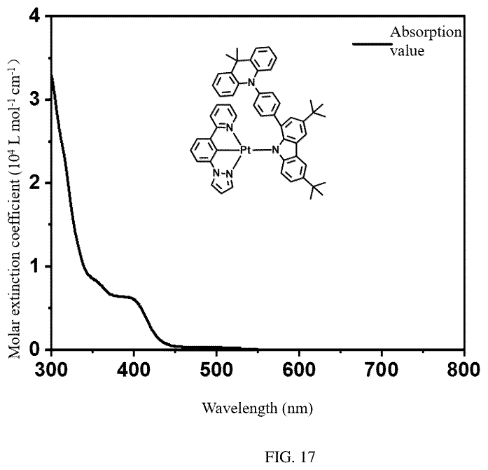

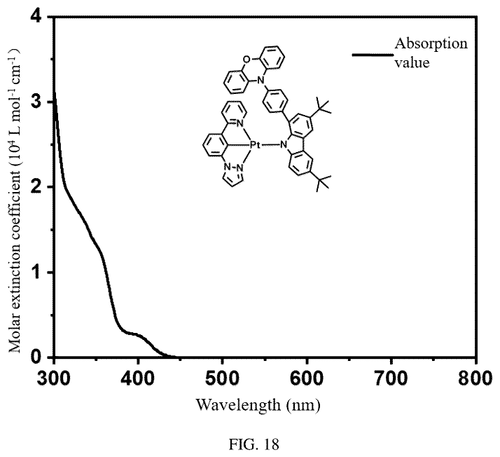

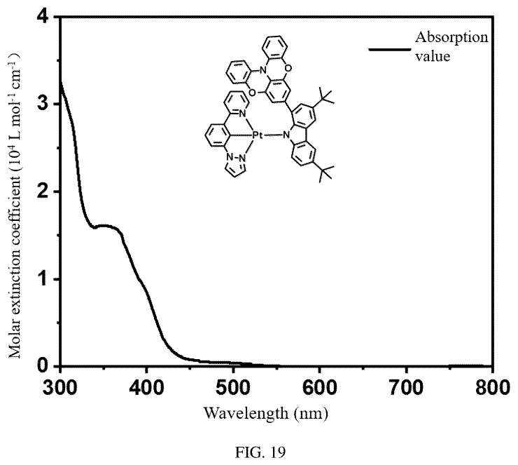

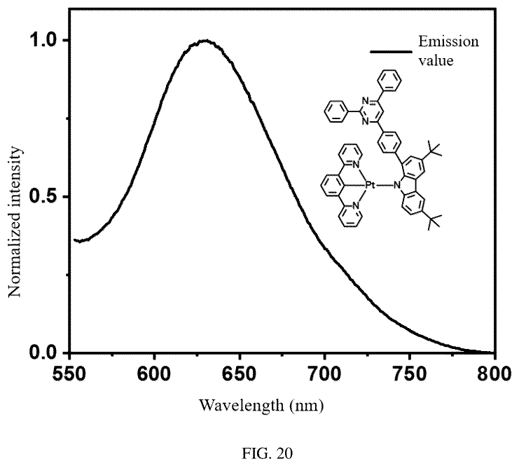

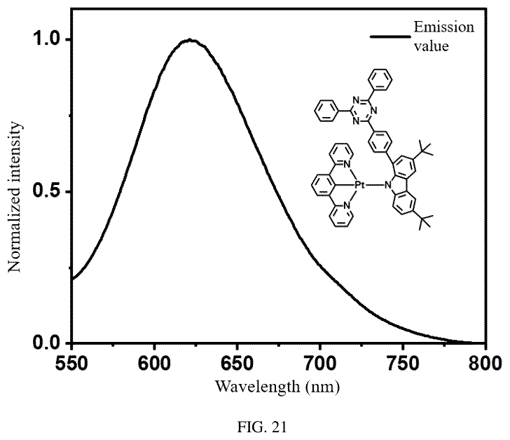

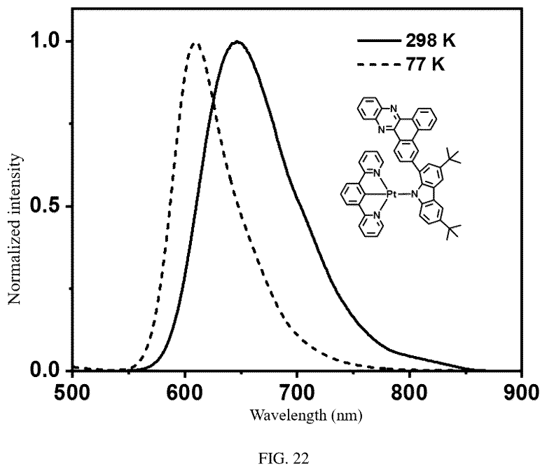

An absorption spectrum and an emission spectrum of the metal complex of the present application in a solution were tested, wherein the solution was a toluene solution or a tetrahydrofuran solution, a concentration of the metal complex in the toluene solution was 1×10⁻⁵ mol L⁻¹, and a concentration of the metal complex in the tetrahydrofuran solution was 1×10⁻⁵ mol L⁻¹. FIG. 4 is an absorption spectrogram of PdCCC1-B5 in the toluene solution. FIG. 5 is an absorption spectrogram of PdCCC1-5 in the toluene solution. FIG. 6 is an absorption spectrogram of PdCCC1-3 in the toluene solution. FIG. 7 is an emission spectrogram of PdCCC1-B5 in the toluene solution. FIG. 8 is an emission spectrogram of PdCCC1-5 in the toluene solution. FIG. 9 is an emission spectrogram of PdCCC1-3 in the toluene solution. FIG. 10 is an absorption spectrogram of PtNCN1-5 in the toluene solution. FIG. 11 is an absorption spectrogram of PtNCN1-3 in the toluene solution. FIG. 12 is an absorption spectrogram of PtNCN1-16 in the toluene solution. FIG. 13 is an absorption spectrogram of PtNCN1-12 in the toluene solution. FIG. 14 is an absorption spectrogram of PtNCN1-20 in the toluene solution. FIG. 15 is an absorption spectrogram of PtNCN1-21 in the toluene solution. FIG. 16 is an absorption spectrogram of PtNCN3-16 in the toluene solution. FIG. 17 is an absorption spectrogram of PtNCN3-22 in the toluene solution. FIG. 18 is an absorption spectrogram of PtNCN3-23 in the toluene solution. FIG. 19 is an absorption spectrogram of PtNCN3-24 in the toluene solution. FIG. 20 is an emission spectrogram of PtNCN1-5 in the tetrahydrofuran solution. FIG. 21 is an emission spectrogram of PtNCN1-3 in the tetrahydrofuran solution. FIG. 22 is an emission spectrogram of PtNCN1-12 in the toluene solution.

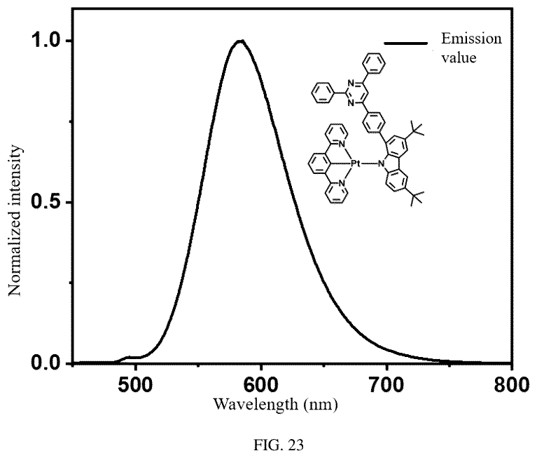

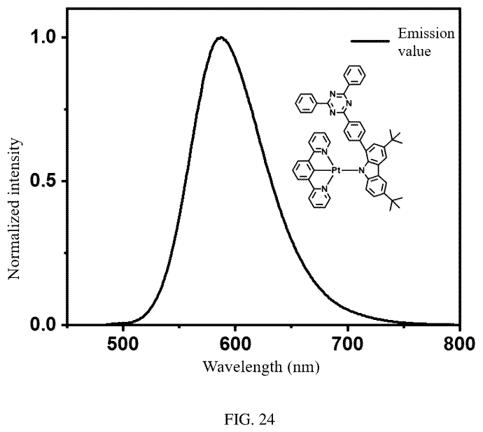

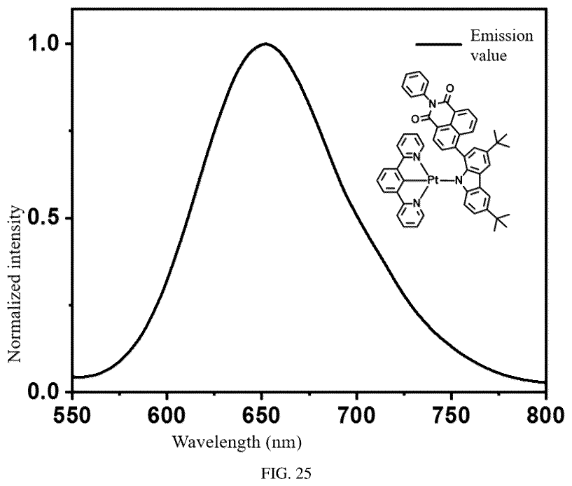

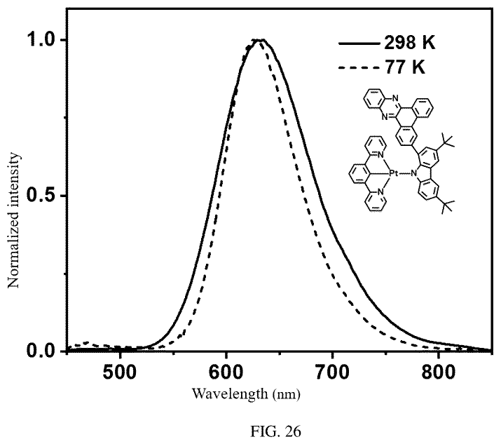

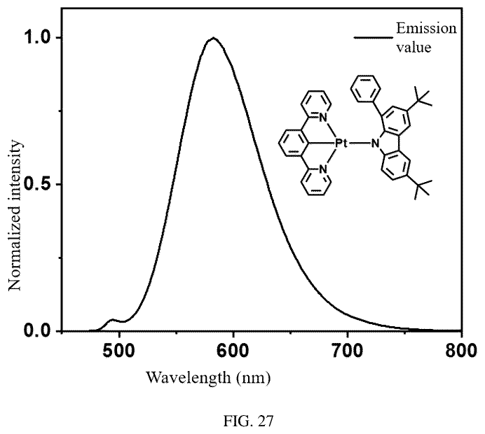

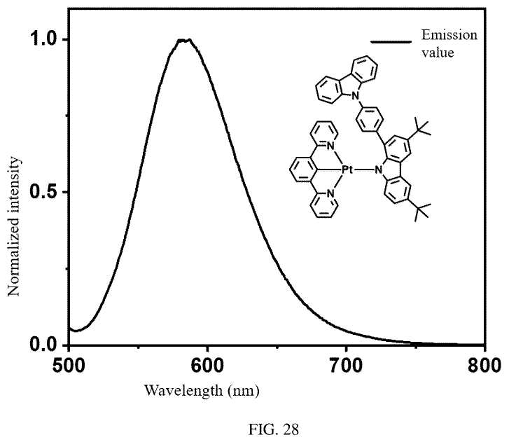

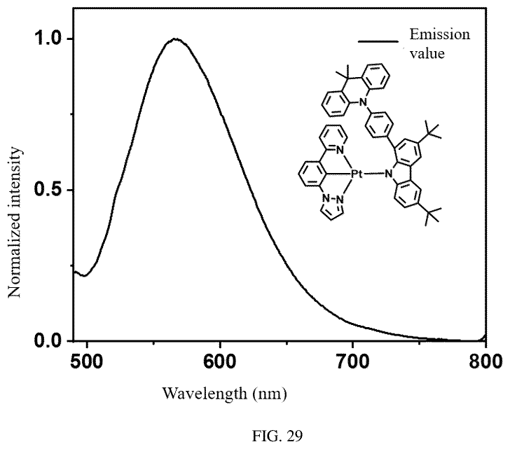

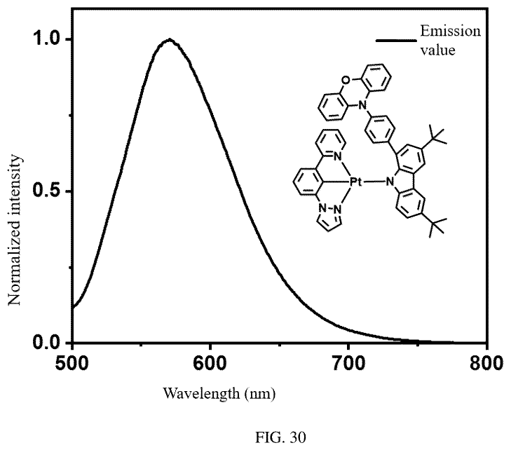

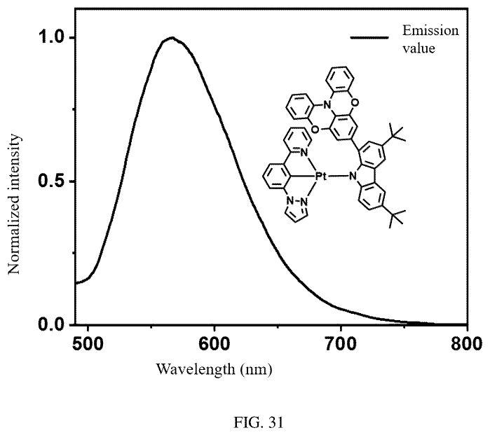

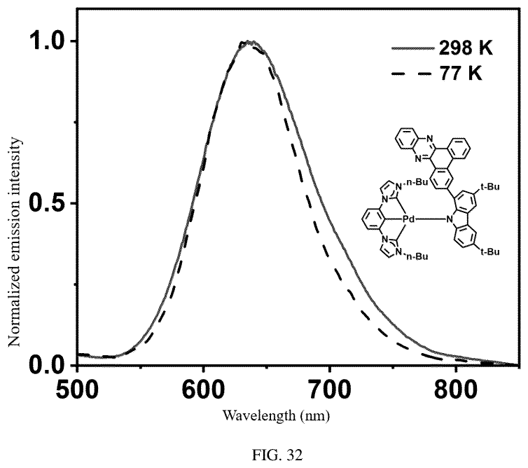

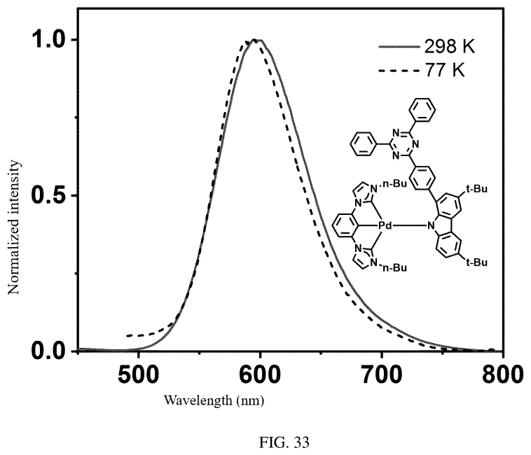

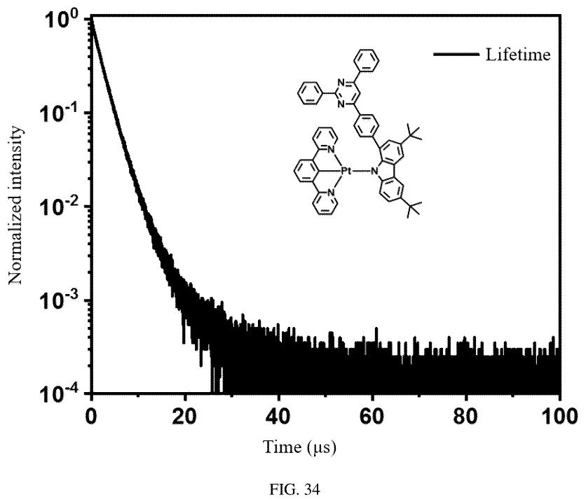

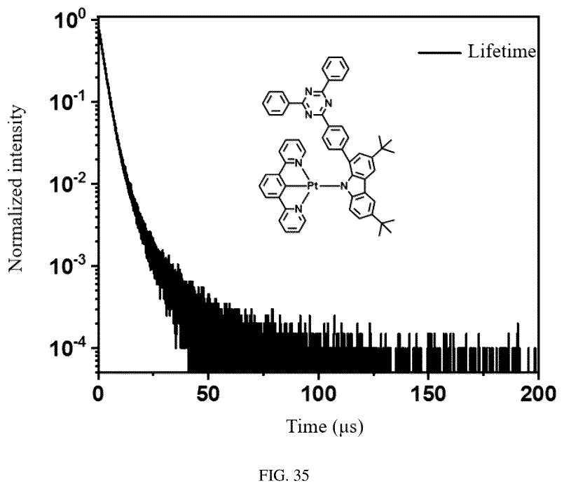

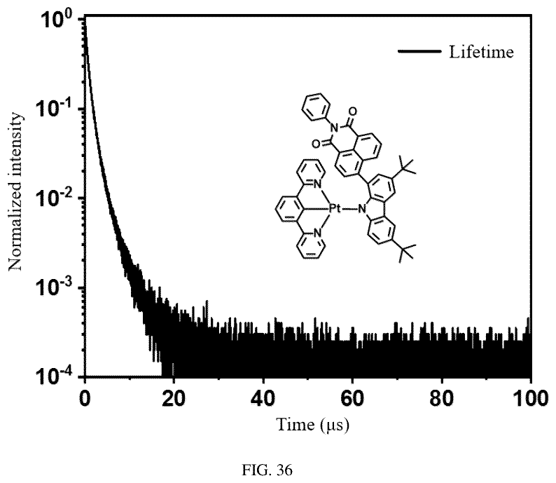

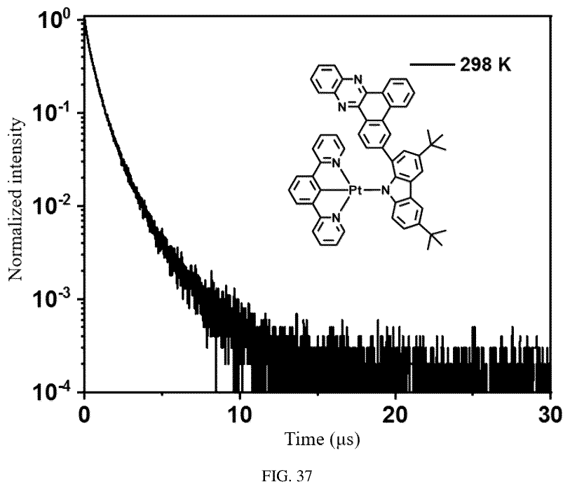

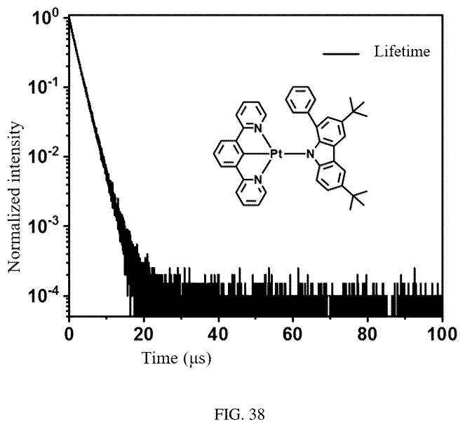

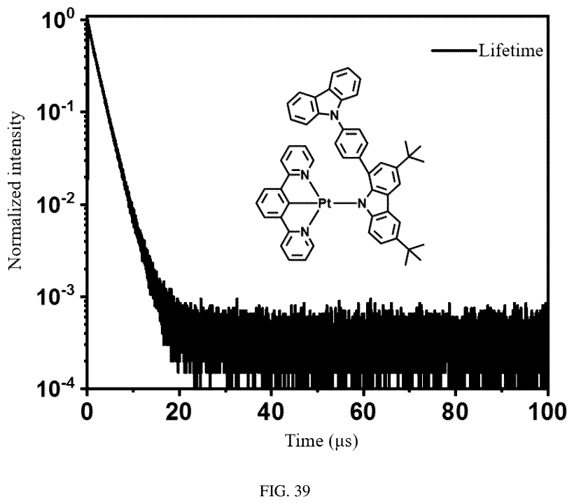

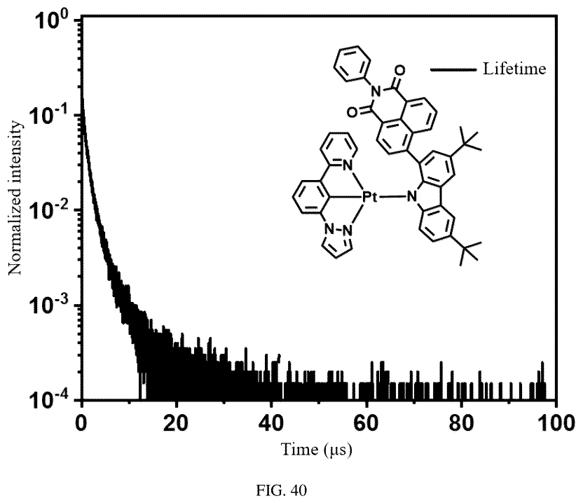

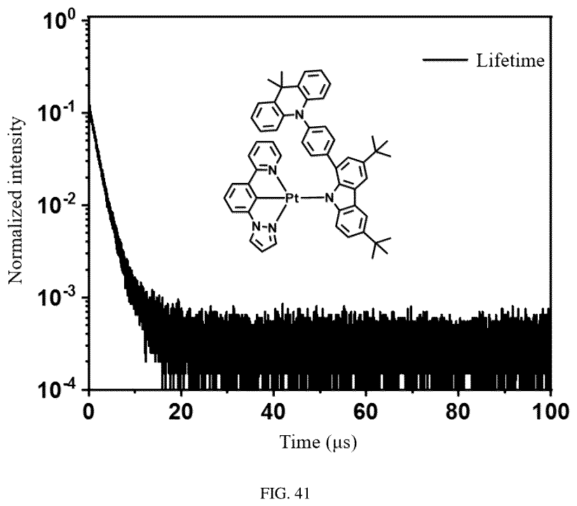

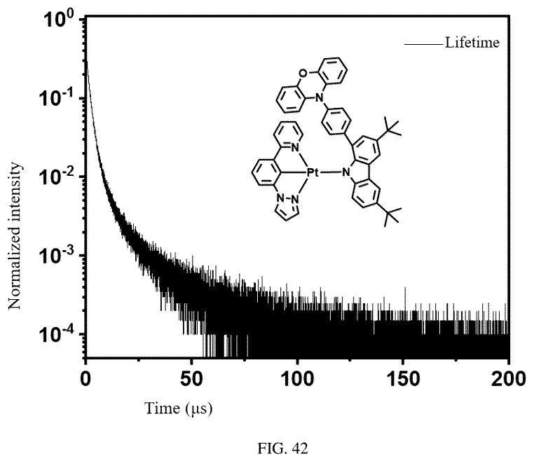

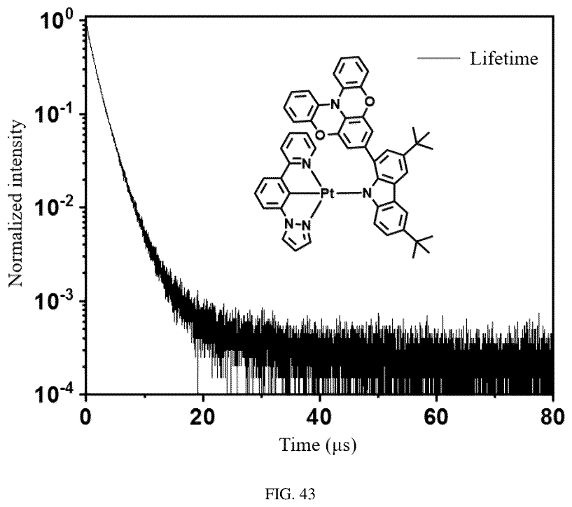

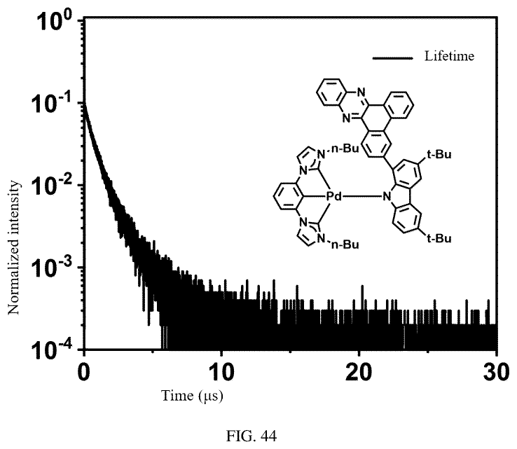

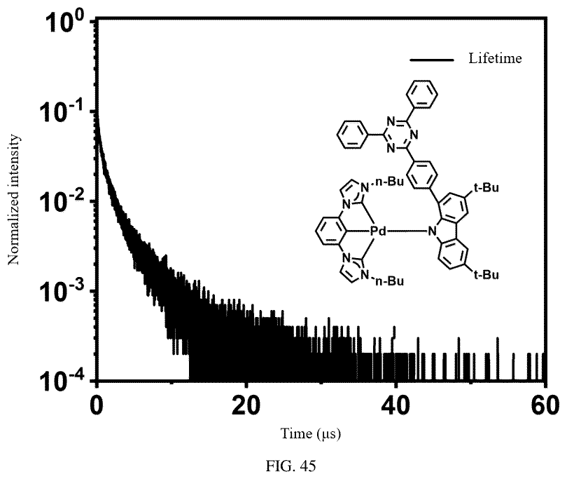

An emission spectrum and lifetime of the metal complex of the present application in a polymethyl methacrylate thin film were tested, and a doping concentration of the metal complex in the polymethyl methacrylate thin film was 5 wt %. FIG. 23 is an emission spectrogram of PtNCN1-5 in the polymethyl methacrylate thin film. FIG. 24 is an emission spectrogram of PtNCN1-3 in the polymethyl methacrylate thin film. FIG. 25 is an emission spectrogram of PtNCN1-16 in the polymethyl methacrylate thin film. FIG. 26 is an emission spectrogram of PtNCN1-12 in the polymethyl methacrylate thin film. FIG. 27 is an emission spectrogram of PtNCN1-20 in the polymethyl methacrylate thin film. FIG. 28 is an emission spectrogram of PtNCN1-21 in the polymethyl methacrylate thin film. FIG. 29 is an emission spectrogram of PtNCN3-22 in the polymethyl methacrylate thin film. FIG. 30 is an emission spectrogram of PtNCN3-23 in the polymethyl methacrylate thin film. FIG. 31 is an emission spectrogram of PtNCN3-24 in the polymethyl methacrylate thin film. FIG. 32 is an emission spectrogram of PdCCC1-12 in the polymethyl methacrylate thin film. FIG. 33 is an emission spectrogram of PdCCC1-3 in the polymethyl methacrylate thin film. FIG. 34 is a lifetime attenuation graph of PtNCN1-5 in the polymethyl methacrylate thin film. FIG. 35 is a lifetime attenuation graph of PtNCN1-3 in the polymethyl methacrylate thin film. FIG. 36 is a lifetime attenuation graph of PtNCN1-16 in the polymethyl methacrylate thin film. FIG. 37 is a lifetime attenuation graph of PtNCN1-12 in the polymethyl methacrylate thin film. FIG. 38 is a lifetime attenuation graph of PtNCN1-20 in the polymethyl methacrylate thin film. FIG. 39 is a lifetime attenuation graph of PtNCN1-21 in the polymethyl methacrylate thin film. FIG. 40 is a lifetime attenuation graph of PtNCN3-16 in the polymethyl methacrylate thin film. FIG. 41 is a lifetime attenuation graph of PtNCN3-22 in the polymethyl methacrylate thin film. FIG. 42 is a lifetime attenuation graph of PtNCN3-23 in the polymethyl methacrylate thin film. FIG. 43 is a lifetime attenuation graph of PtNCN3-24 in the polymethyl methacrylate thin film. FIG. 44 is a lifetime attenuation graph of PdCCC1-12 in the polymethyl methacrylate thin film. FIG. 45 is a lifetime attenuation graph of PdCCC1-3 in the polymethyl methacrylate thin film.

### Test Example 1

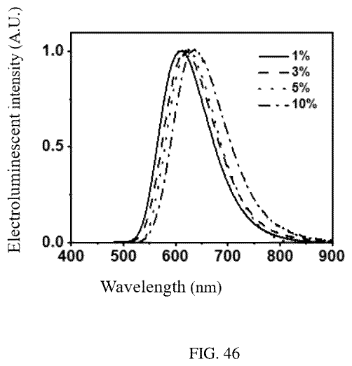

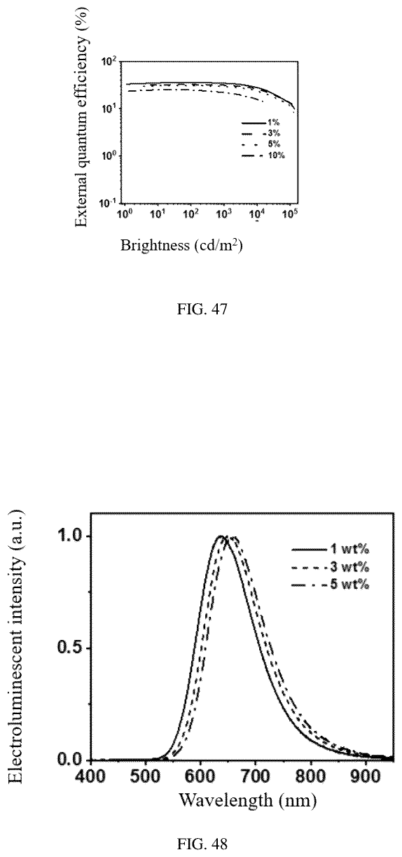

The organic electroluminescent device provided in Device Examples 1-4 was tested, PtNCN-12 was selected as a guest material, a current-brightness-voltage characteristic of the device was determined by a Keithley source measuring system (Keithley 2400 Sourcemeter, Keithley 2000 Currentmeter) with corrected silicon photoelectric diodes, all tests were completed in room-temperature atmosphere, and test results were shown in Table 1 and FIGS. 46-47, wherein FIG. 46 is an electroluminescent diagram based on the compound PtNCN1-12 in Device Examples 1-4 of the present application, and FIG. 47 is an electroluminescent quantum efficiency diagram based on the compound PtNCN1-12 in Device Examples 1-4 of the present application.

TABLE 1
Device performance test results

| | | | CE | | PE | | EQE | | |
|---|---|---|---|---|---|---|---|---|---|
| | | L | [cd A⁻¹][b] | | [lm W⁻¹][c] | | [%][d] | | CIE |
| | λₘₐₓ | [cd | | at 1000 | | at 1000 | | at 1000 | [(x, |
| | (nm) | m⁻²][a] | Max | cd m⁻² | Max | cd m⁻² | Max | cd m⁻² | y)][e] |
| Device | 610 | 136834 | 61.2 | 58.8 | 60.7 | 42.0 | 35.6 | 34.3 | 0.58, 0.42 |
| Example 1 | | | | | | | | | |
| Device | 615 | 127051 | 45.9 | 44.7 | 43.5 | 29.3 | 32.1 | 31.0 | 0.60, 0.40 |
| Example 2 | | | | | | | | | |
| Device | 624 | 113679 | 39.1 | 37.2 | 36.0 | 22.5 | 30.8 | 29.5 | 0.61, 0.39 |
| Example 3 | | | | | | | | | |
| Device | 633 | 63276 | 25.1 | 22.0 | 20.3 | 9.1 | 27.3 | 23.0 | 0.63, 0.36 |
| Example 4 | | | | | | | | | |

[a]maximum brightness;
[b]current efficiency;
[c]luminous efficiency;
[d]external quantum efficiency;
[e]CIE coordinates (1000 cd m⁻²)

As shown in FIGS. 46-47, in a doped light-emitting OLED prepared with PtNCN1-12 as the guest material at a doping concentration of 1% of the present application, the maximum luminous brightness could reach 136834 cd m⁻², the maximum current efficiency was 61.2 cd A⁻¹, the maximum luminous efficiency was 60.7 lm W⁻¹, the maximum external quantum efficiency reached up to 35.6%, and the CIE coordinates under the brightness of 1000 cd m⁻² were (0.58, 0.42).

### Test Example 2

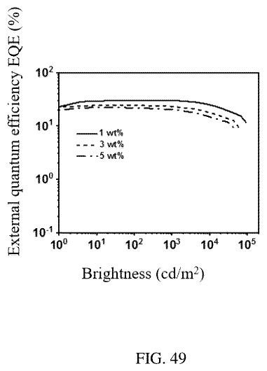

The organic electroluminescent device provided in Device Examples 5-7 was tested, PdCCC1-12 was selected as a guest material, a current-brightness-voltage characteristic of the device was determined by a Keithley source measuring system (Keithley 2400 Sourcemeter, Keithley 2000 Currentmeter) with corrected silicon photoelectric diodes, all tests were completed in room-temperature atmosphere, and test results were shown in Table 2 and FIGS. 48-49, wherein FIG. 48 is an electroluminescent diagram based on the compound PdCCC1-12 in Device Examples 5-7 of the present application, and FIG. 49 is an electroluminescent quantum efficiency diagram based on the compound PdCCC1-12 in Device Examples 5-7 of the present application.

TABLE 2
Device performance test results

| | | | CE | | PE | | EQE | | |
|---|---|---|---|---|---|---|---|---|---|
| | | L | [cd A⁻¹][b] | | [lm W⁻¹][c] | | [%][d] | | CIE |
| | λₘₐₓ | [cd | | at 1000 | | at 1000 | | at 1000 | [(x, |
| | (nm) | m⁻²][a] | Max | cd m⁻² | Max | cd m⁻² | Max | cd m⁻² | y)][e] |
| Device | 640 | 92000 | 29.6 | 28.9 | 27.5 | 18.1 | 30.1 | 29.8 | 0.63, 0.37 |
| Example 5 | | | | | | | | | |
| Device | 645 | 60500 | 16.7 | 15.8 | 14.7 | 8.9 | 24.2 | 23.0 | 0.65, 0.35 |
| Example 6 | | | | | | | | | |
| Device | 662 | 45600 | 11.9 | 11.0 | 10.0 | 5.6 | 22.0 | 19.9 | 0.66, 0.34 |
| Example 7 | | | | | | | | | |

[a]maximum brightness;
[b]current efficiency;
[c]luminous efficiency;
[d]external quantum efficiency;
[e]CIE coordinates (1000 cd m⁻²)

As shown in FIGS. 48-49, in a doped light-emitting OLED prepared with PdCCC1-12 as the guest material at a doping concentration of 1% of the present application, the maximum luminous brightness could reach 92000 cd m⁻², the maximum current efficiency was 29.6 cd A⁻¹, the maximum luminous efficiency was 27.5 lm W⁻¹, the maximum external quantum efficiency reached up to 30.1%, and the CIE coordinates under the brightness of 1000 cd m⁻² were (0.63, 0.37).

### Test Example 3

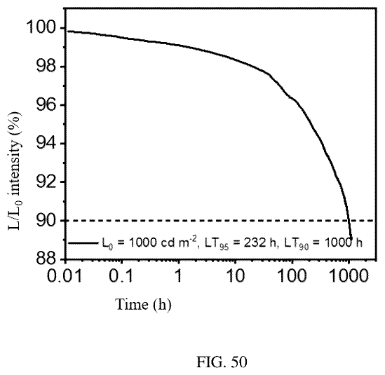

A stability test was performed on the organic electroluminescent device provided in Device Example 12, PdCCC1-12 was selected as a guest material, the organic electroluminescent device was packaged in a glove box filled with nitrogen using a glass lid through an ultraviolet light curing adhesive, and then was taken out of the glove box to measure the brightness of the working device using an OLED lifetime measuring system (FS-MP64, Suzhou FSTAR Scientific Instrument Co., Ltd, China) under a constant current density, and all tests were completed in room-temperature atmosphere. As shown in FIG. 50, in the doped light-emitting OLED prepared with PdCCC1-12 as the guest material at a doping concentration of 1% of the present application, LT95 (LT95 was defined as time consumed for brightness attenuation of 5%) at the initial brightness of 1000 cd m⁻² was 232 hours, and LT90 (LT90 was defined as time consumed for brightness attenuation of 50%) at the initial brightness of 1000 cd m⁻² was 1000 hours.

### Test Example 4

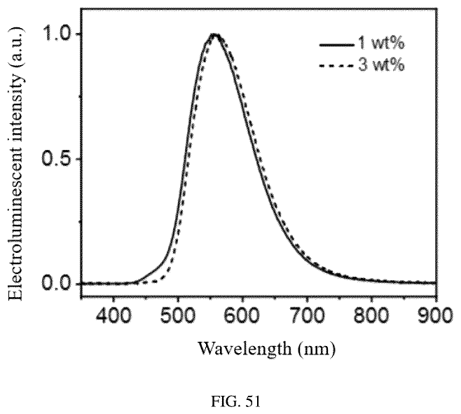

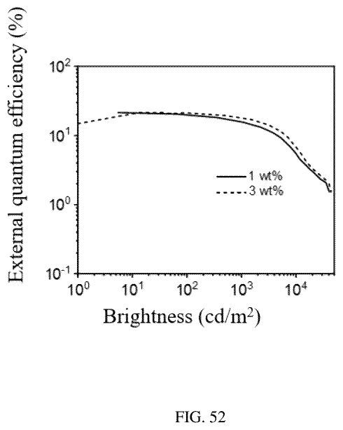

The organic electroluminescent device provided in Device Examples 8-9 was tested, PdCCC1-5 was selected as a guest material, a current-brightness-voltage characteristic of the device was determined by a Keithley source measuring system (Keithley 2400 Sourcemeter, Keithley 2000 Currentmeter) with corrected silicon photoelectric diodes, all tests were completed in room-temperature atmosphere, and test results were shown in Table 3 and FIGS. 51-52. FIG. 51 is an electroluminescent diagram based on the compound PdCCC1-5 in Device Examples 8-9 of the present application, and FIG. 52 is an electroluminescent quantum efficiency diagram based on the compound PdCCC1-5 in Device Examples 8-9 of the present application.

TABLE 3
Device performance test results

| | | | CE | | PE | | EQE | | |
|---|---|---|---|---|---|---|---|---|---|
| | | L | [cd A⁻¹][b] | | [lm W⁻¹][c] | | [%][d] | | CIE |
| | λₘₐₓ | [cd | | at 1000 | | at 1000 | | at 1000 | [(x, |
| | (nm) | m⁻²][a] | Max | cd m⁻² | Max | cd m⁻² | Max | cd m⁻² | y)][e] |
| Device | 555 | 40550 | 65.8 | 47.0 | 73.8 | 37.0 | 21.5 | 15.8 | 0.42, 0.53 |
| Example 8 | | | | | | | | | |
| Device | 560 | 43700 | 64.0 | 52.7 | 62.8 | 39 | 21.4 | 18.0 | 0.44, 0.53 |
| Example 9 | | | | | | | | | |

[a]maximum brightness;
[b]current efficiency;
[c]luminous efficiency;
[d]external quantum efficiency;
[e] CIE coordinates (1000 cd m⁻²)

As shown in FIGS. 51-52, in a doped light-emitting OLED prepared with PdCCC1-5 as the guest material at a doping concentration of 1% of the present application, the maximum luminous brightness could reach 40550 cd m⁻², the maximum current efficiency was 65.8 cd A⁻¹, the maximum luminous efficiency was 73.8 lm W⁻¹, the maximum external quantum efficiency reached up to 21.5%, and the CIE coordinates under the brightness of 1000 cd m⁻² were (0.42, 0.53).

### Test Example 5

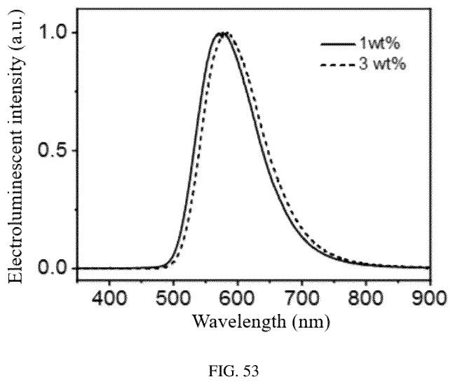

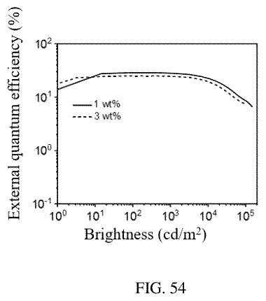

The organic electroluminescent device provided in Device Examples 10-11 was tested, PdCCC1-3 was selected as a guest material, a current-brightness-voltage characteristic of the device was determined by a Keithley source measuring system (Keithley 2400 Sourcemeter, Keithley 2000 Currentmeter) with corrected silicon photoelectric diodes, all tests were completed in room-temperature atmosphere, and test results were shown in Table 4 and FIGS. 53-54. FIG. 53 is an electroluminescent diagram based on the compound PdCCC1-3 in Device Examples 10-11 of the present application, and FIG. 54 is an electroluminescent quantum efficiency diagram based on the compound PdCCC1-3 in Device Examples 10-11 of the present application.

TABLE 4
Device performance test results

| | | | CE | | PE | | EQE | | |
|---|---|---|---|---|---|---|---|---|---|
| | | L | [cd A⁻¹][b] | | [lm W⁻¹][c] | | [%][d] | | CIE |
| | λₘₐₓ | [cd | | at 1000 | | at 1000 | | at 1000 | [(x, |
| | (nm) | m⁻²][a] | Max | cd m⁻² | Max | cd m⁻² | Max | cd m⁻² | y)][e] |
| Device | 573 | 150300 | 79.1 | 77.1 | 76.4 | 57.1 | 28.8 | 28.1 | 0.49, 0.50 |
| Example 10 | | | | | | | | | |
| Device | 583 | 103100 | 62.7 | 61.2 | 56.3 | 39.4 | 25.1 | 24.7 | 0.51, 0.48 |
| Example 11 | | | | | | | | | |

[a]maximum brightness;
[b]current efficiency;
[c]luminous efficiency;
[d]external quantum efficiency;
[e]CIE coordinates (1000 cd m⁻²)

As shown in FIGS. 53-54, in a doped light-emitting OLED prepared with PdCCC1-3 as the guest material at a doping concentration of 1% of the present application, the maximum luminous brightness could reach 150300 cd m⁻², the maximum current efficiency was 79.1 cd A⁻¹, the maximum luminous efficiency was 76.4 lm W⁻¹, the maximum external quantum efficiency reached up to 28.8%, and the CIE coordinates under the brightness of 1000 cd m⁻² were (0.49, 0.50).

In conclusion, the “V”-shaped molecular structure containing tridentate ligand-metal-secondary amine-receptors has good TADF performance, through the unique molecule design, receptor units are additionally introduced on metal ligands to construct multiple excited states, and thus the transition of metal to complex charge transfer in the process of molecular excited transition is weakened, and the charge transfer process within and between ligands is enhanced. The excited state properties of the metal complex in the present application can effectively suppress the excited-state structural distortion of the metal complex, and thus a non-radiative transition process is suppressed, so that the manufactured organic electroluminescent device has the external quantum efficiency of up to 35.6%, and the manufactured organic electroluminescent device has a long device lifetime.

Obviously, the above examples are only instances for clear explanation, rather than limiting implementations. For those of ordinary skill in the art, other different forms of changes or variations can further be made based on the above explanation. It is not necessary and impossible to exhaustively list all implementations here. The obvious changes or variations arising from this are still within the scope of protection of the present application.

1. A metal complex, having the following structure: 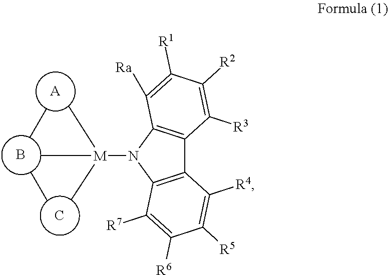
wherein M is selected from platinum or palladium;
the ring A, the ring B and the ring C are each independently selected from a substituted or unsubstituted C₆-C₄₈ aromatic ring, and a substituted or unsubstituted C₄-C₄₈ heteroaromatic ring; the ring A and the ring B are interconnected by single bond connection or by forming a fused ring; the ring B and the ring C are interconnected by single bond connection or by forming a fused ring; and the ring A, the ring B and the ring C together form a negative monovalent tridentate ligand in coordination with the metal M at the center;
R¹-R⁷ are the same or different and are each independently selected from hydrogen, a substituted or unsubstituted C₁-C₄₀ alkyl group, a substituted or unsubstituted C₆-C₄₈ aryl group and a substituted or unsubstituted C₃-C₄₈ heteroaryl group; and
Ra is a substituted or unsubstituted C₆-C₄₈ aryl group or a substituted or unsubstituted C₆-C₄₈ heteroaryl group.

2. The metal complex according to claim 1, wherein R¹, R³, R⁴, R⁶ and R⁷ are hydrogen, and R² and R⁵ are the same or different and are each independently selected from a substituted or unsubstituted C₁-C₄₀ alkyl group, a substituted or unsubstituted C₆-C₄₈ aryl group, and a substituted or unsubstituted C₃-C₄₈ heteroaryl group.

3. The metal complex according to claim 1, wherein the substituted C₁-C₄₀ alkyl group, the substituted C₆-C₄₈ aryl group and the substituted C₃-C₄₈ heteroaryl group are substituted by one or more substituents R_{b}; and each R_{b} is independently selected from hydrogen, halogen, cyano, a C₁-C₁₀ alkyl group and a C₆-C₃₀ aryl group.

4. The metal complex according to claim 3, wherein
the C₁-C₄₀ alkyl group is selected from methyl, ethyl, n-propyl, isopropyl, n-butyl, isobutyl, sec-butyl and tert-butyl;
the C₁-C₁₀ alkyl group is selected from methyl, ethyl, n-propyl, isopropyl, n-butyl, isobutyl, sec-butyl and tert-butyl;
the C₆-C₄₈ aryl group is selected from phenyl, naphthyl and anthryl; and
the C₆-C₃₀ aryl group is selected from phenyl, naphthyl and anthryl.

5. The metal complex according to claim 1, wherein
the tridentate ligand formed by the ring A, the ring B and the ring C has any one of the following structures:

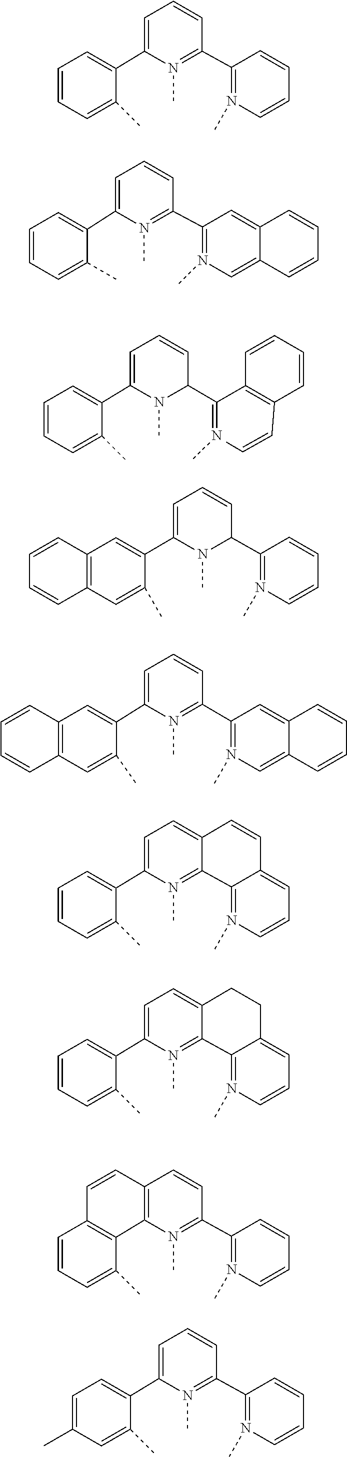

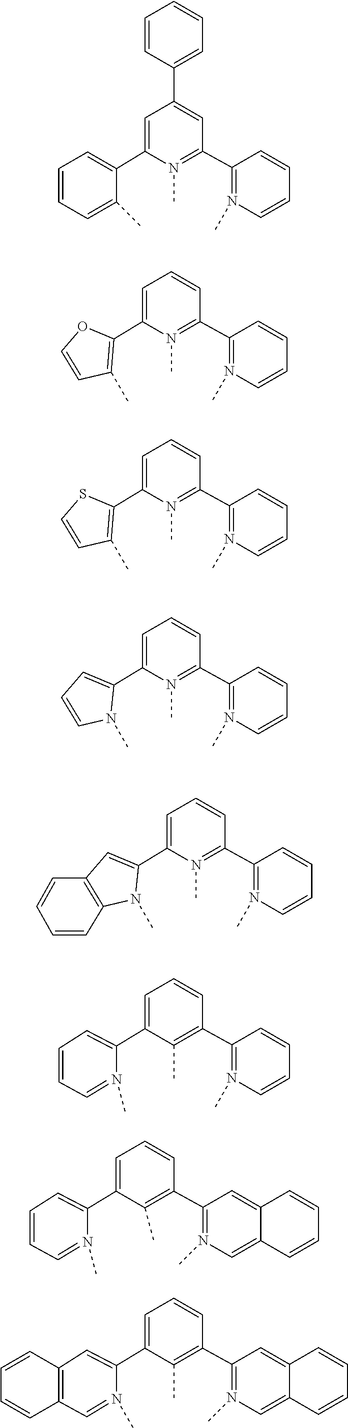

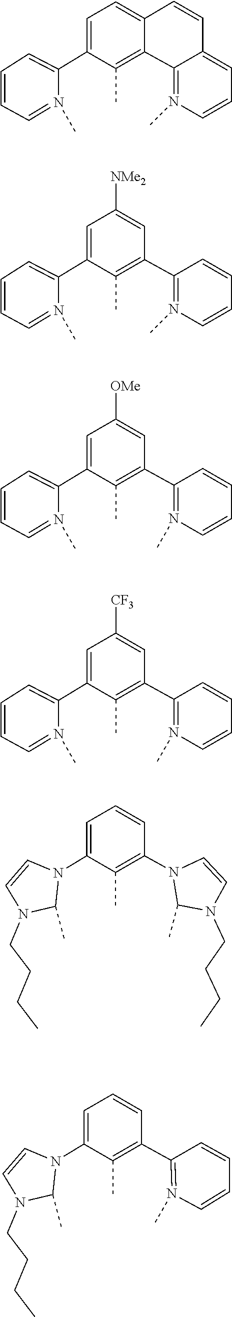

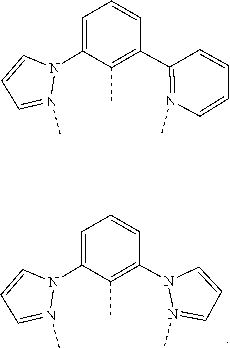

6. The metal complex according to claim 1, wherein Ra has any one of the following structures:

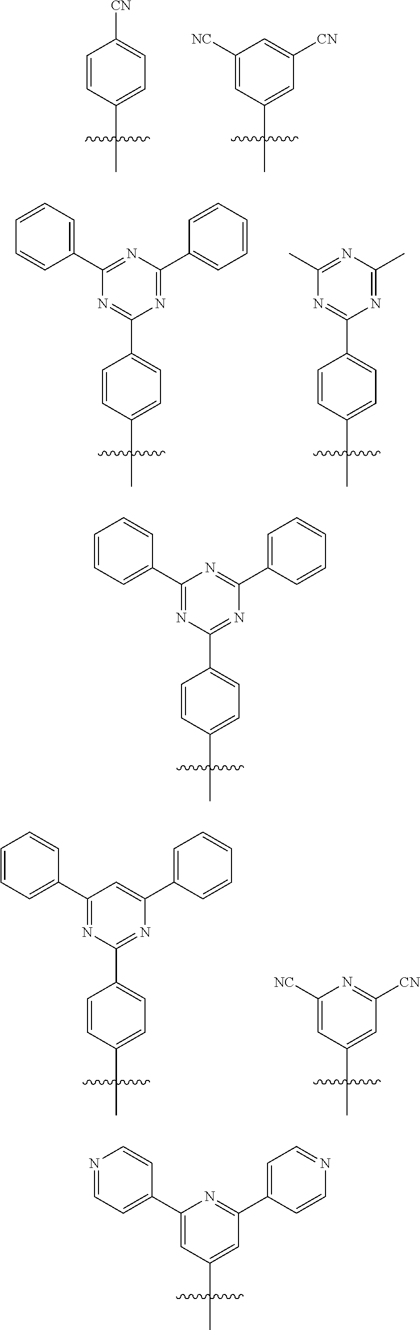

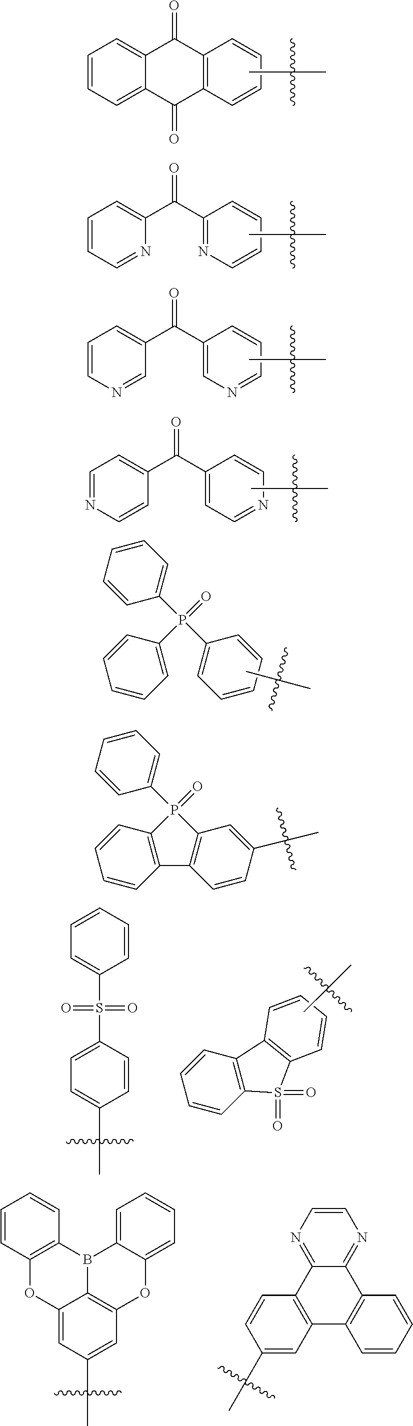

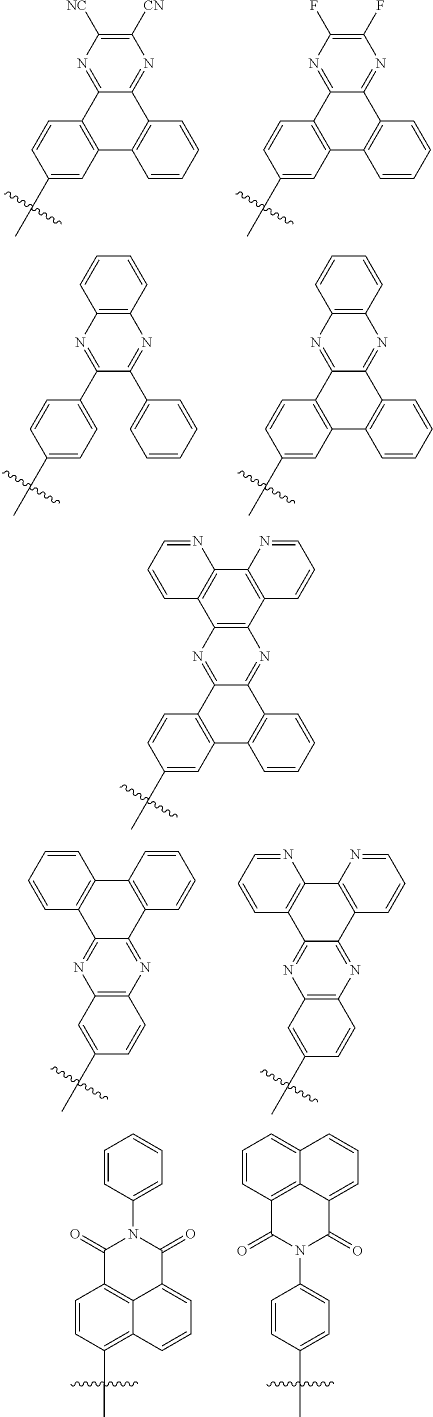

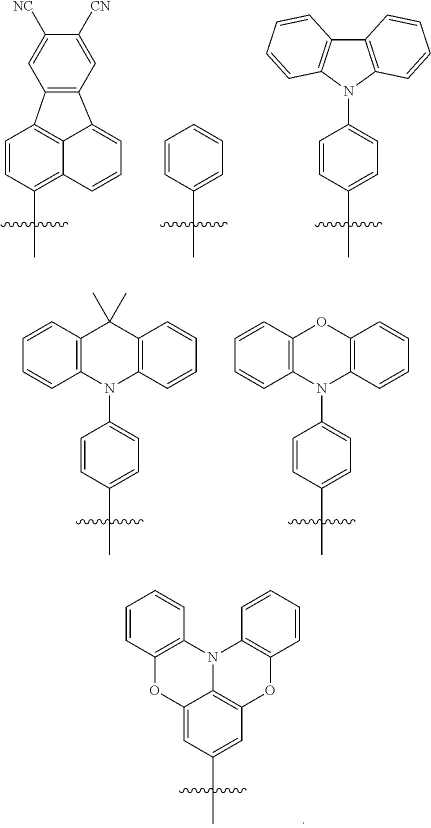

7. The metal complex according to claim 1, wherein the metal complex has any one of the following structures:

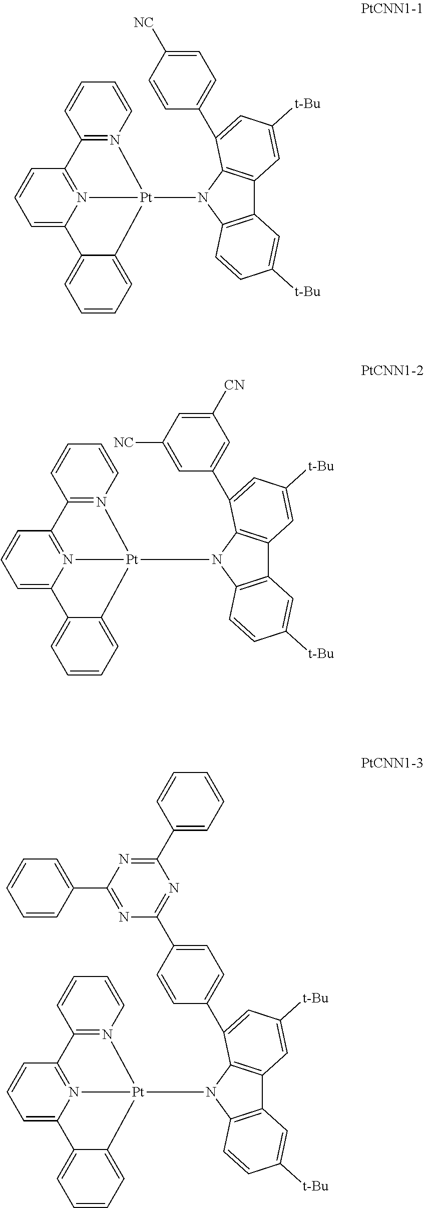

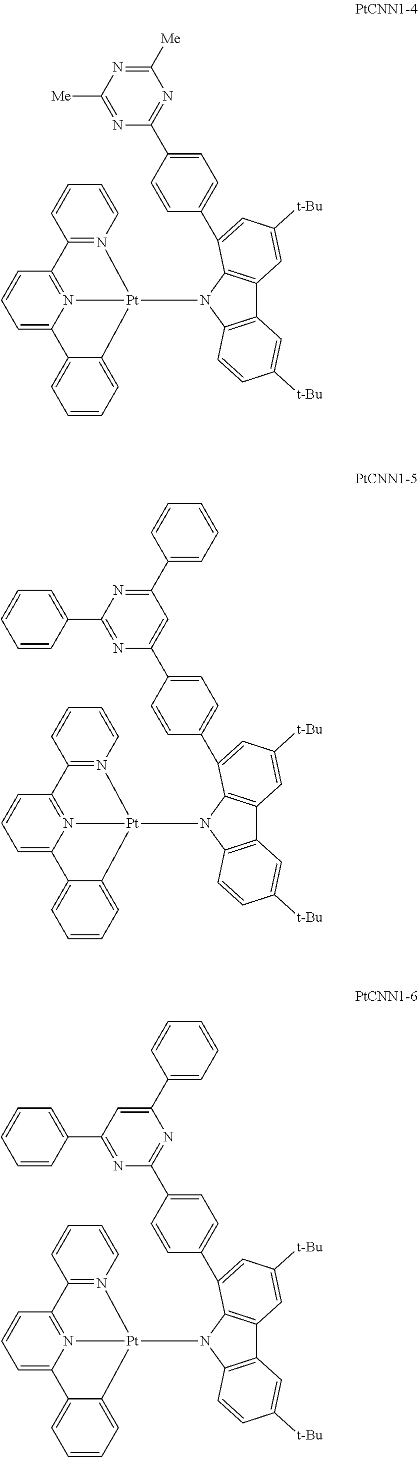

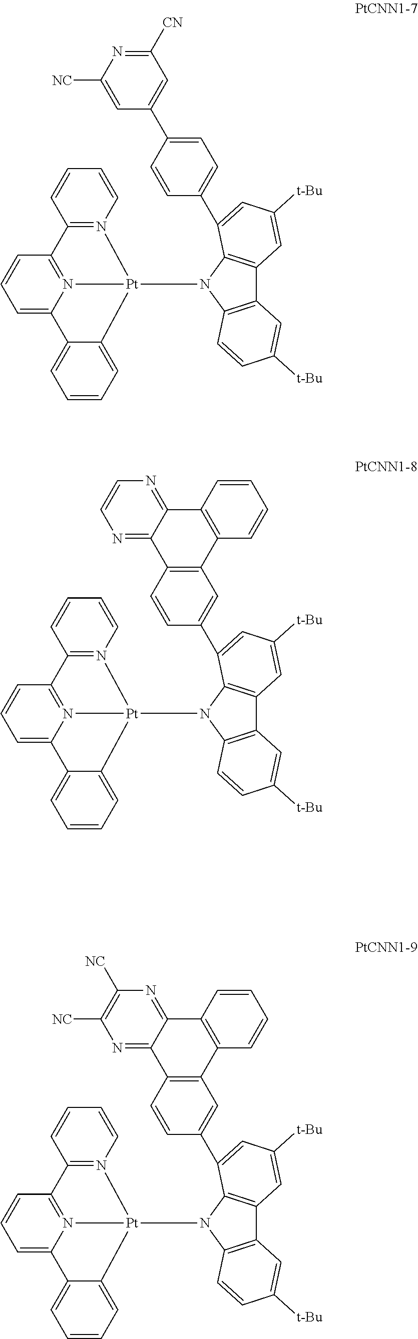

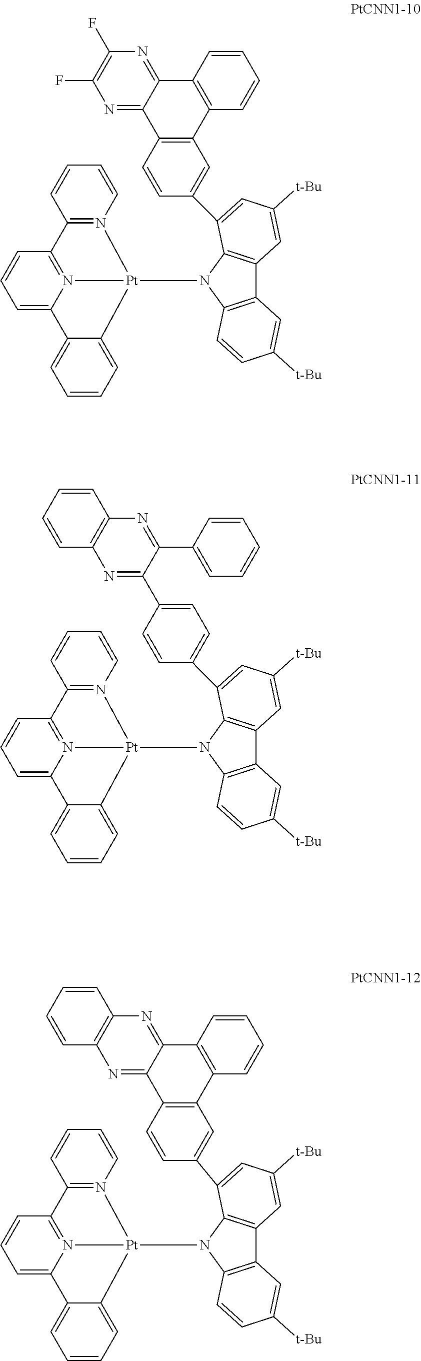

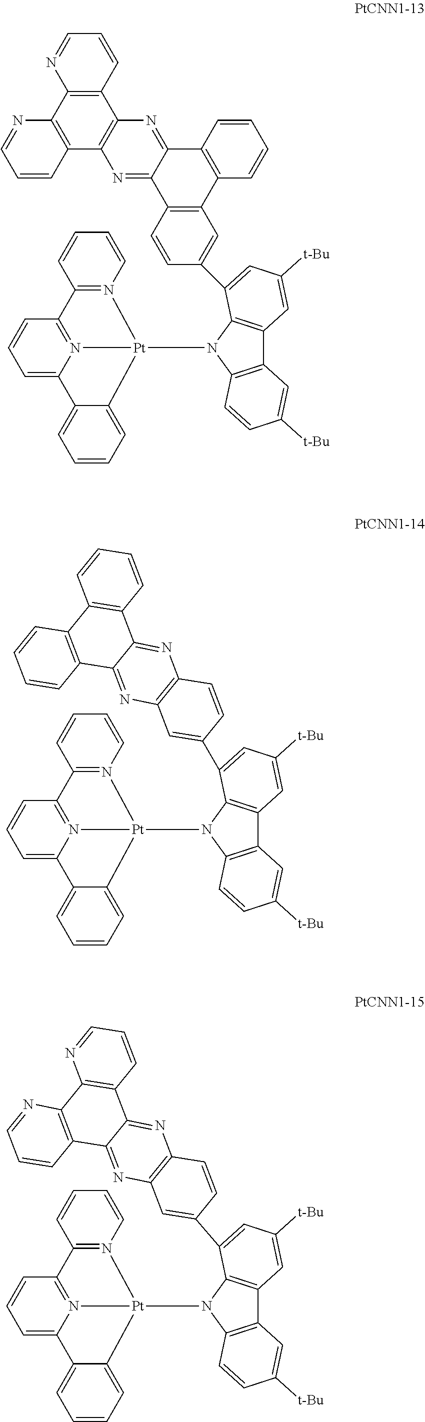

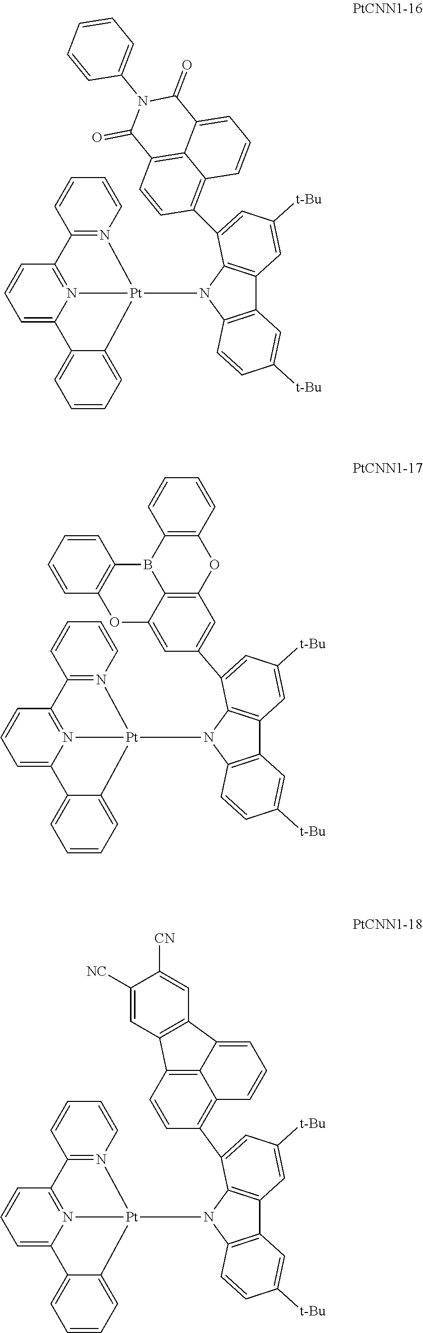

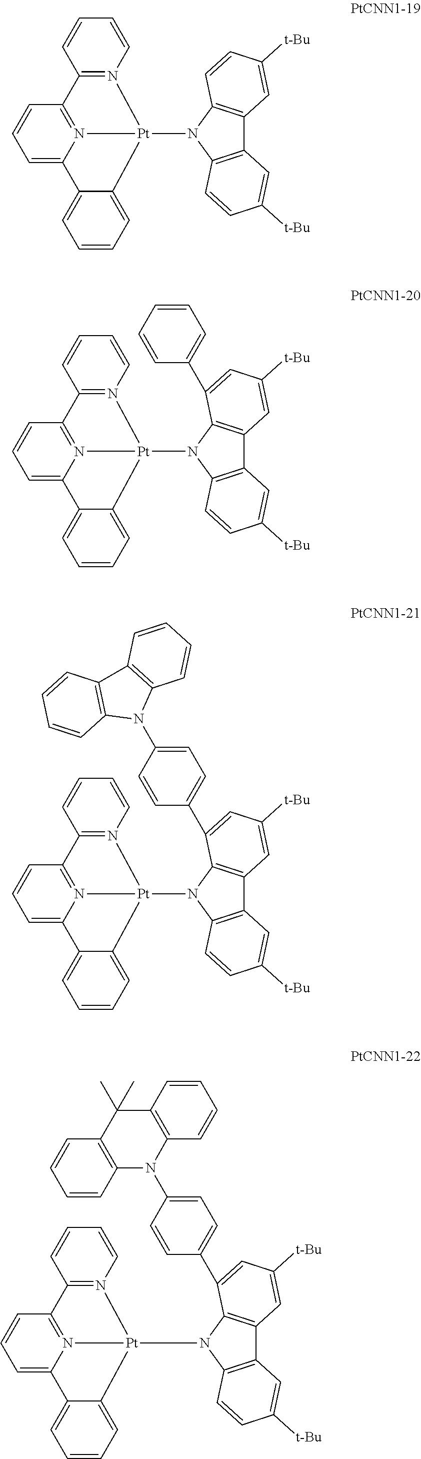

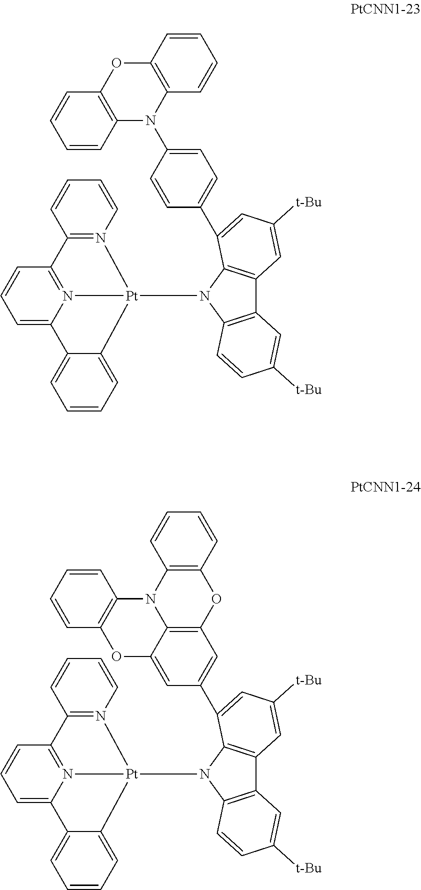

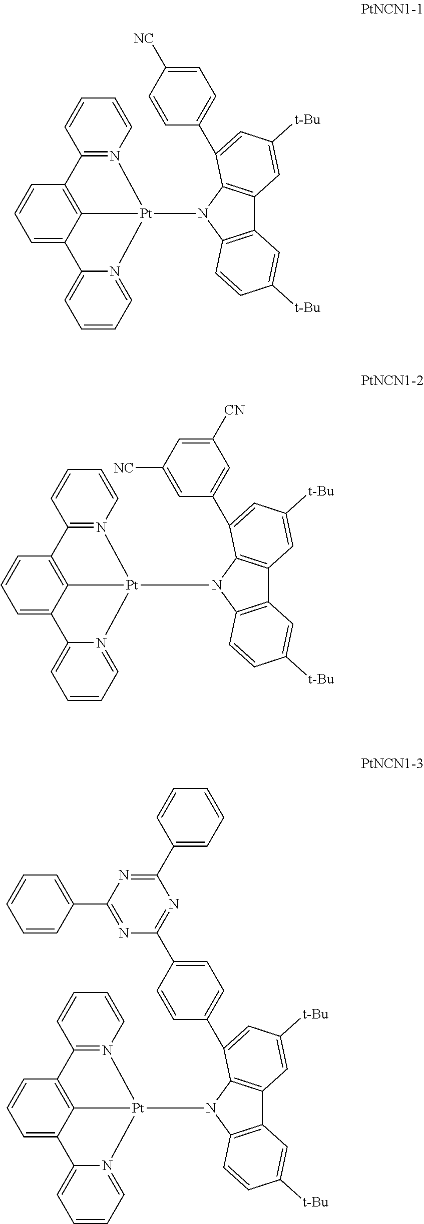

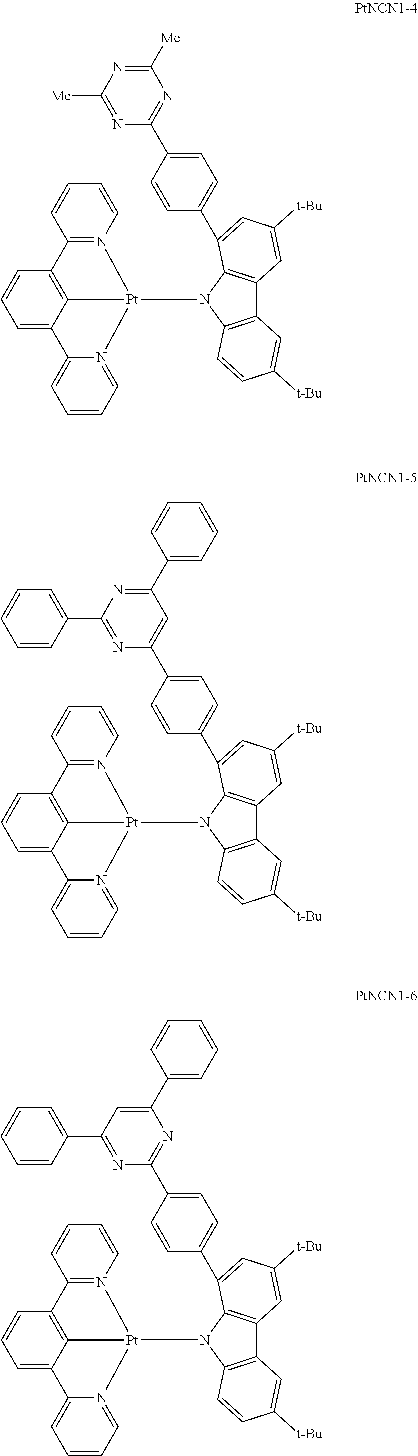

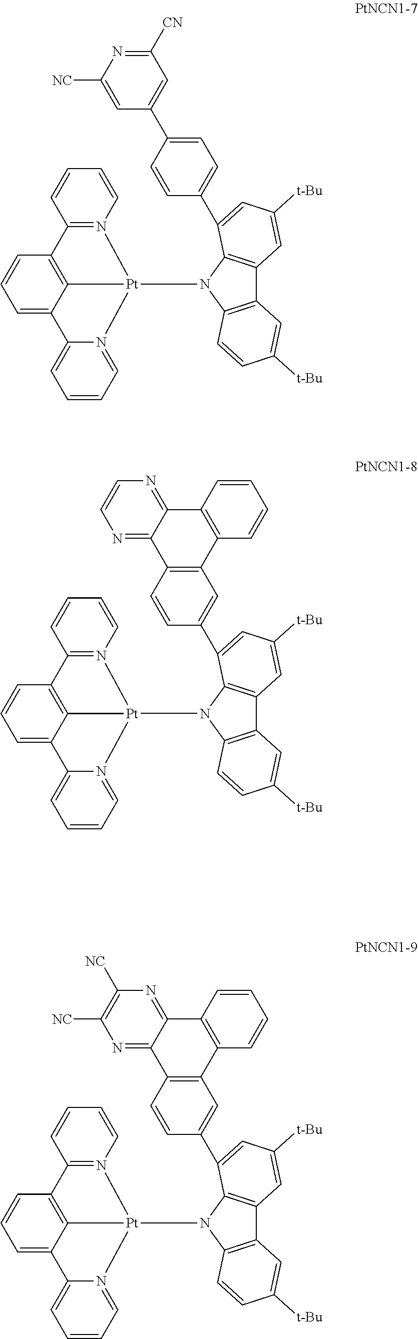

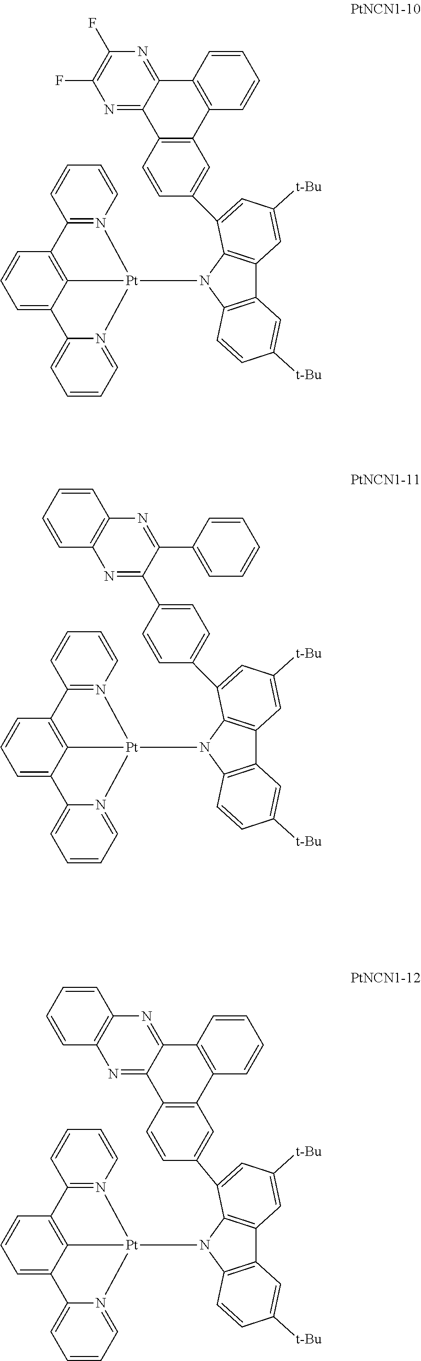

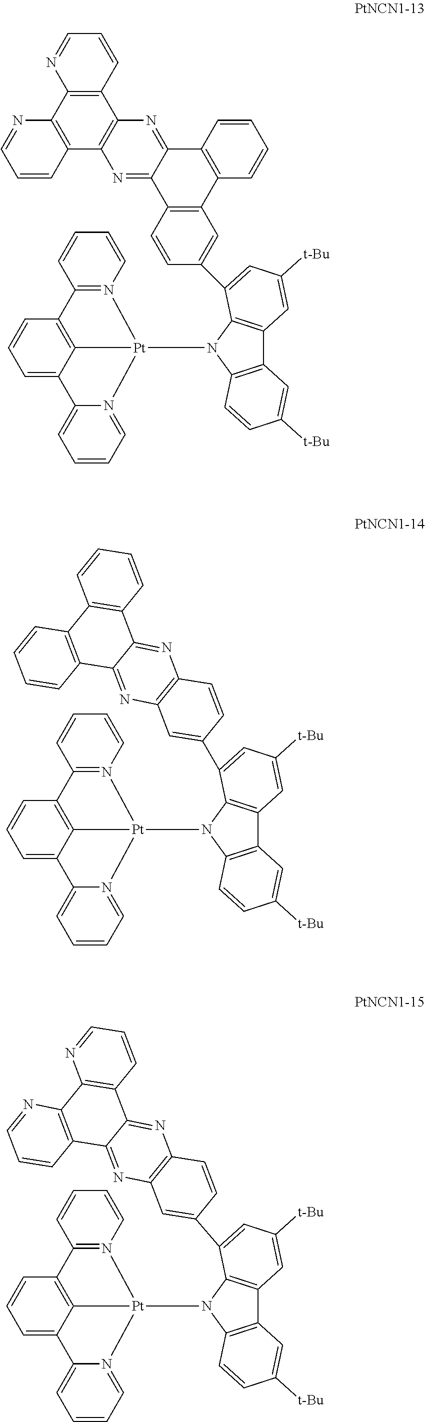

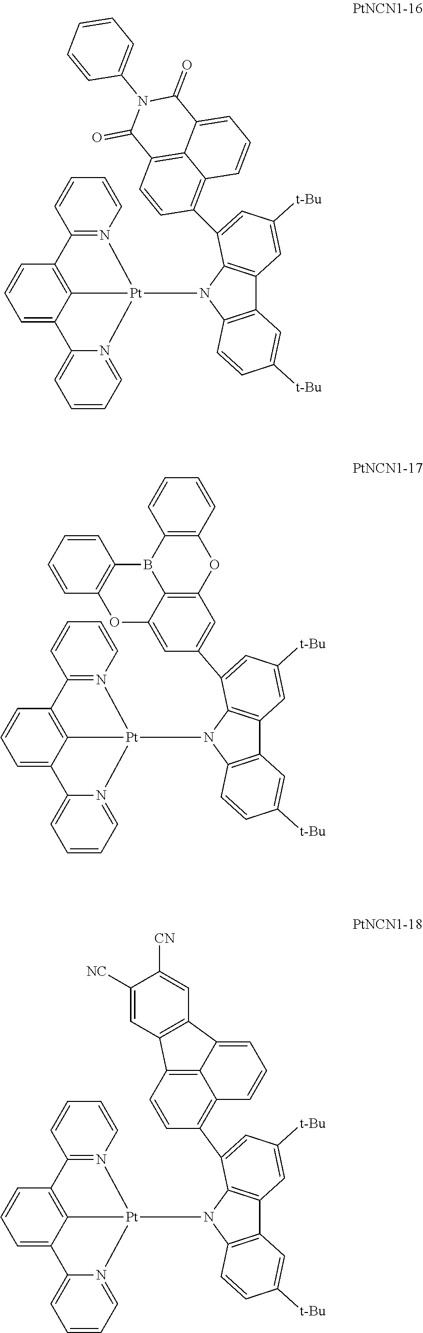

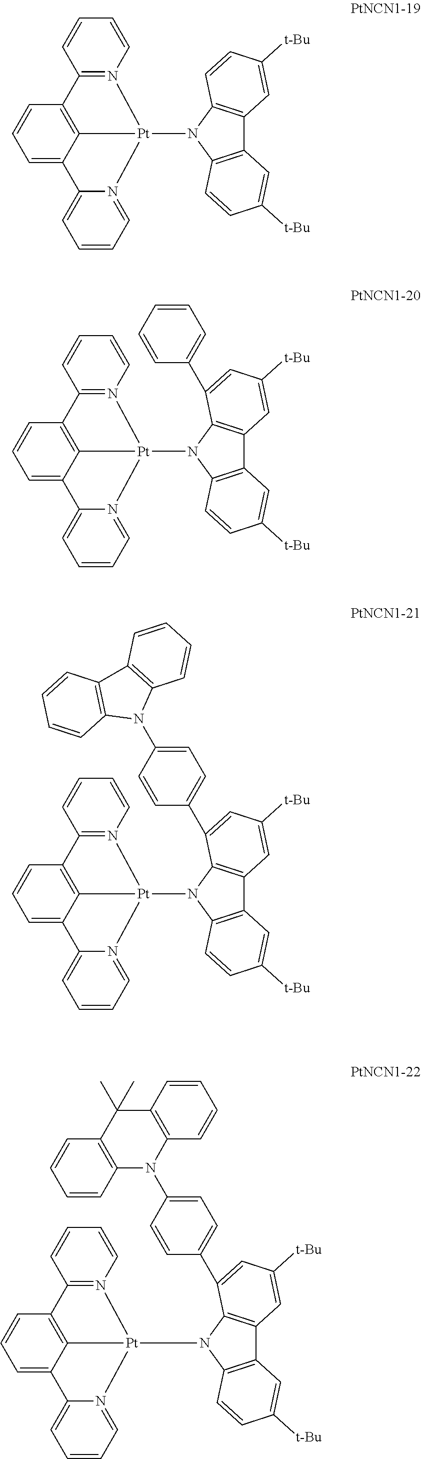

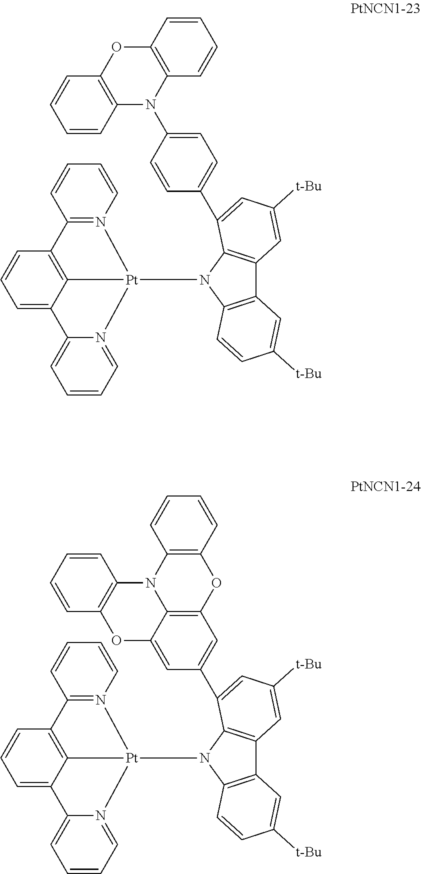

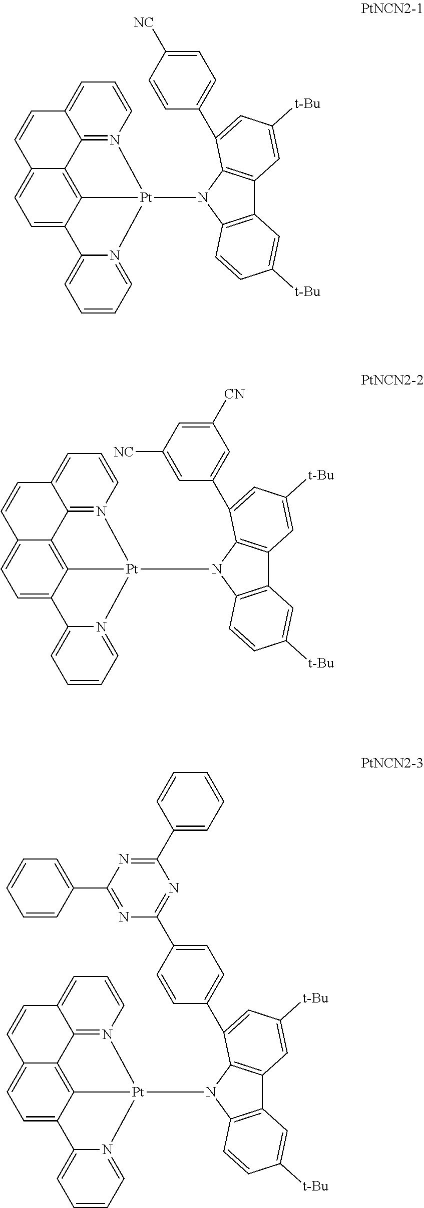

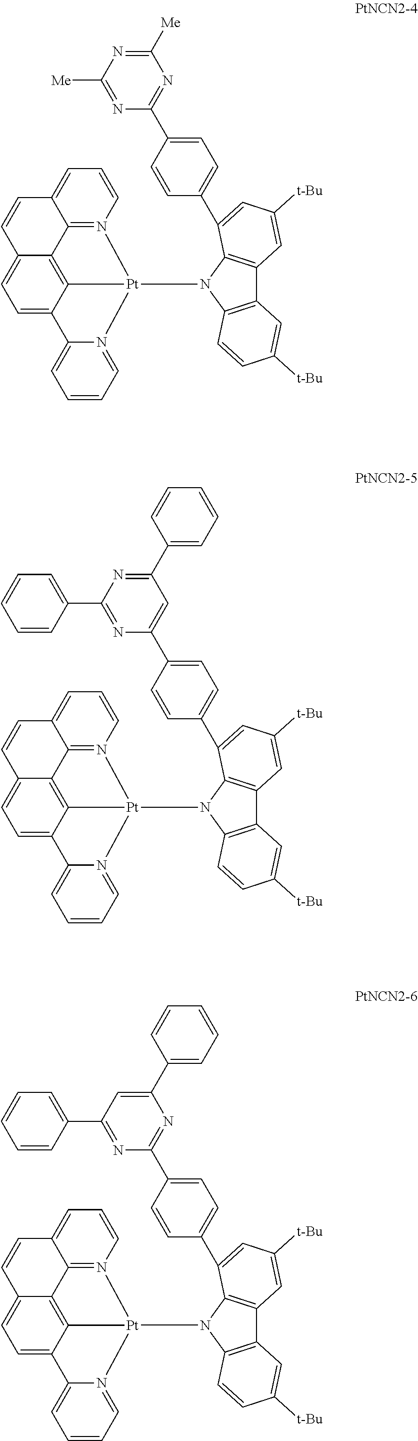

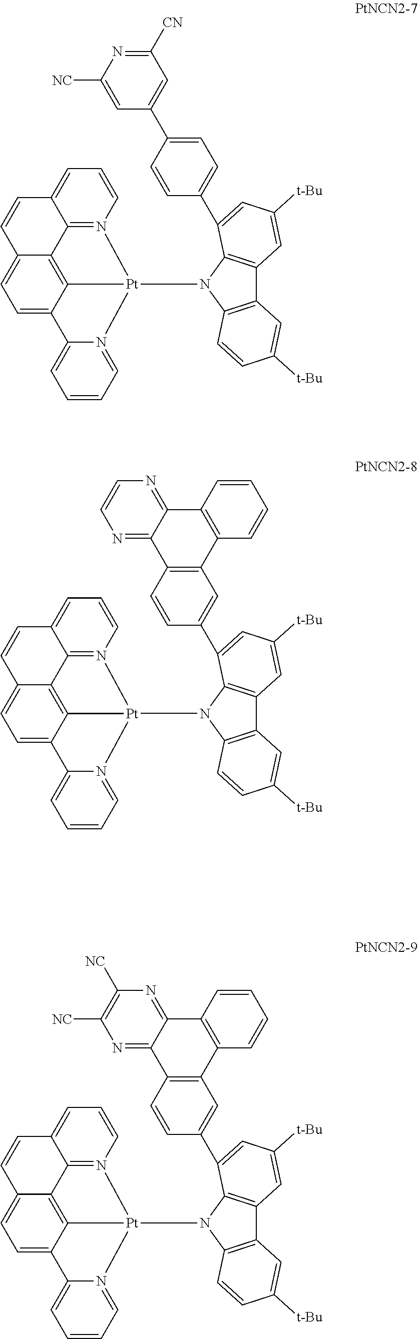

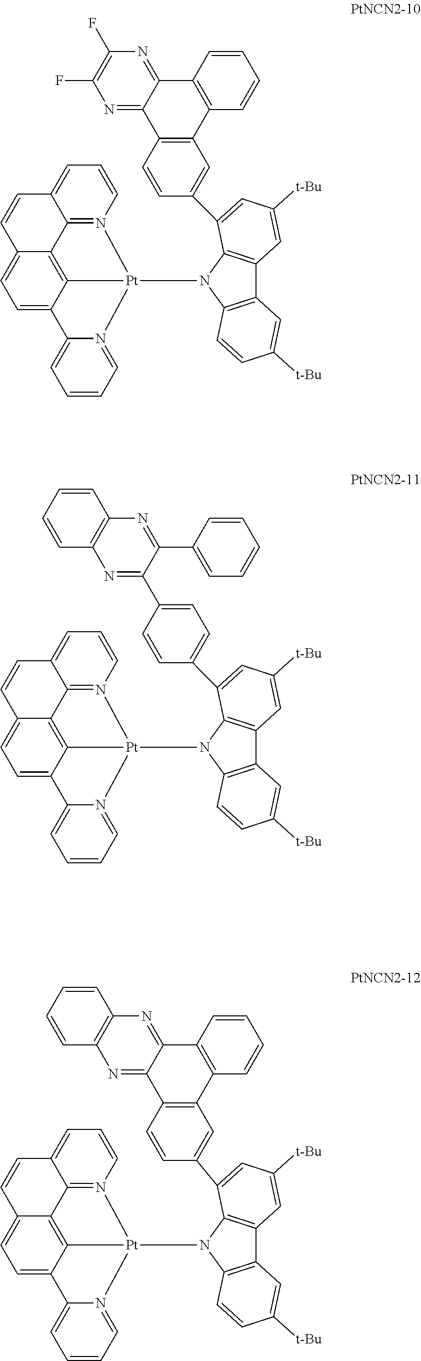

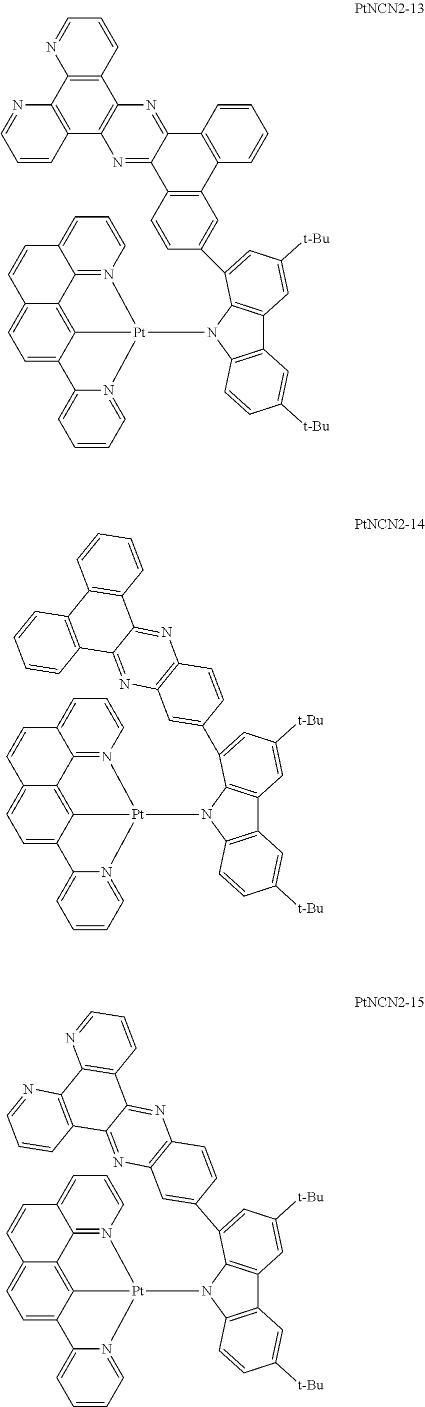

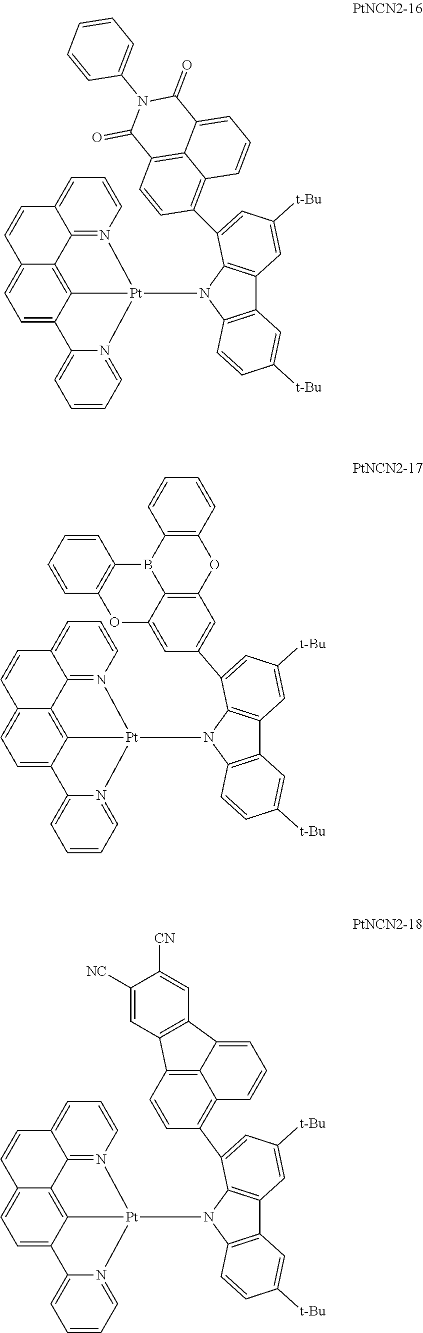

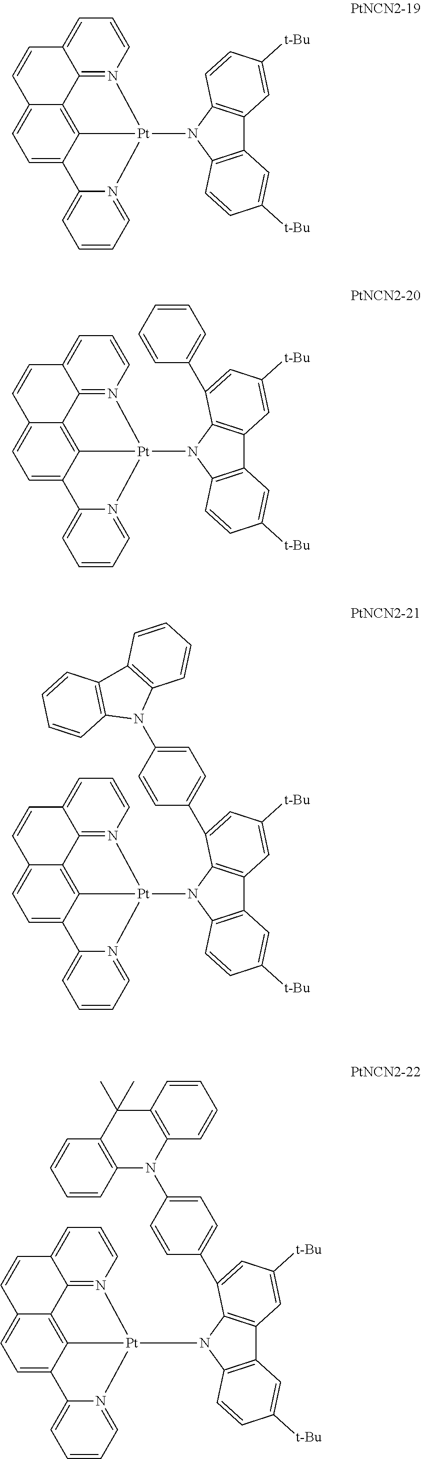

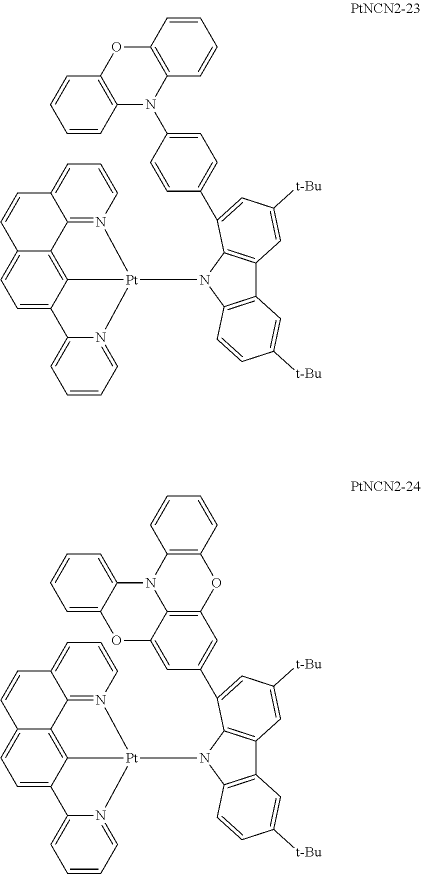

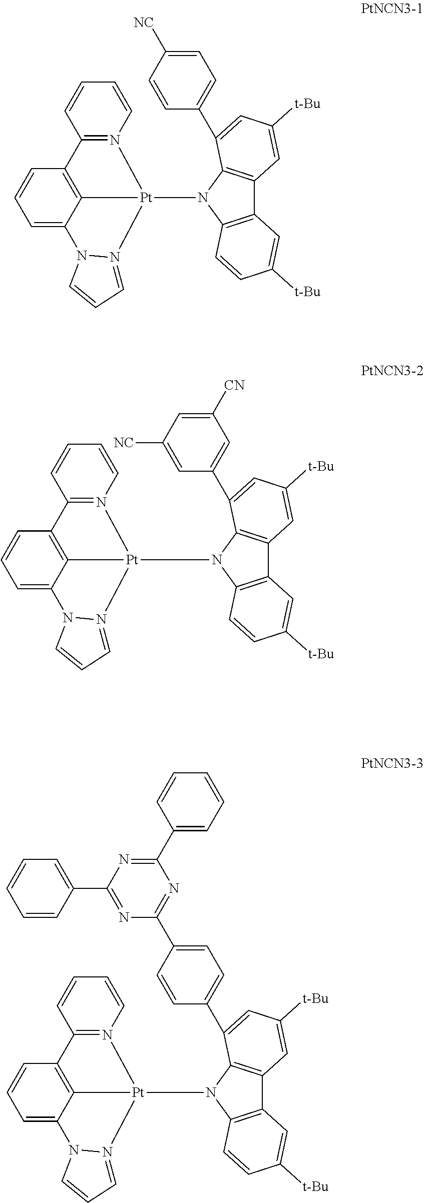

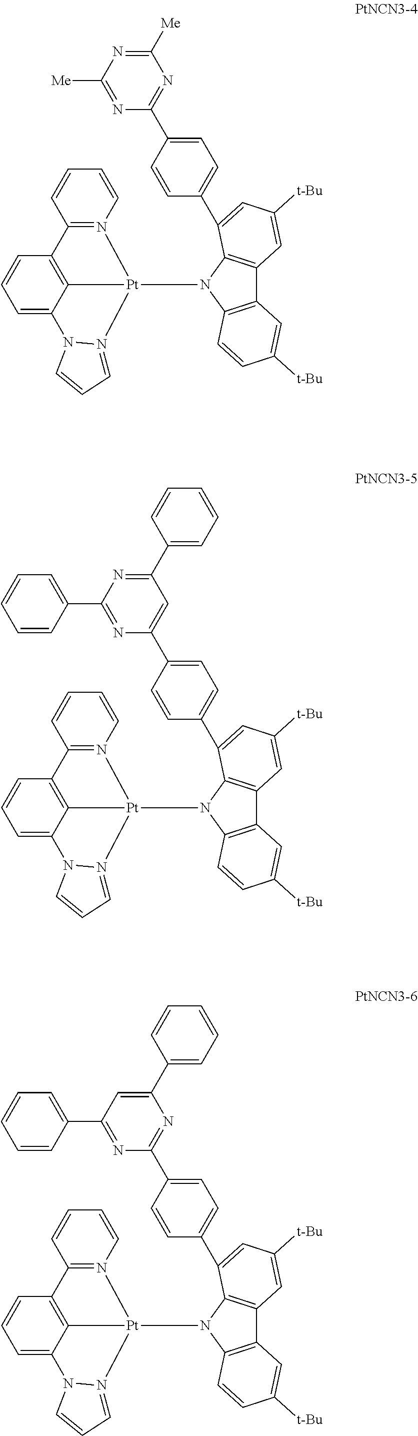

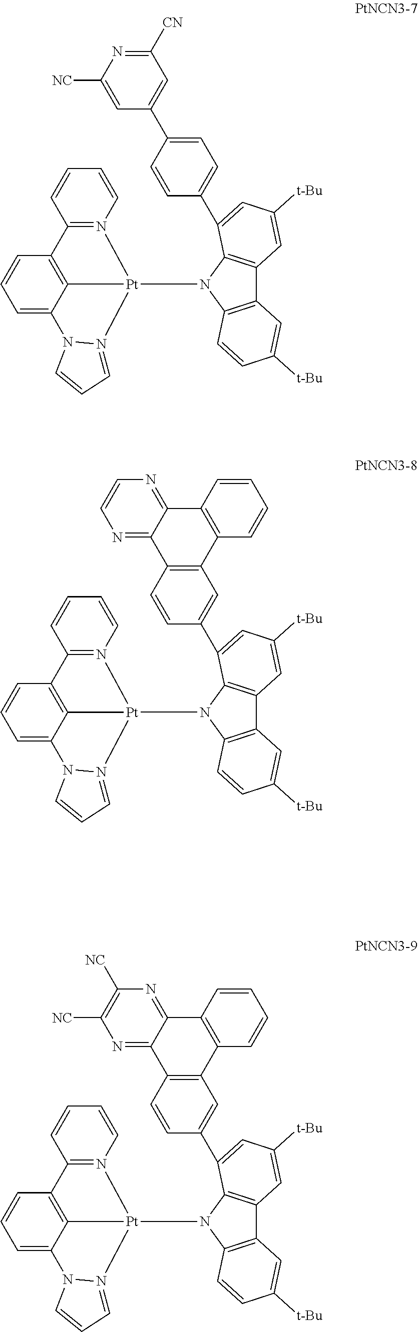

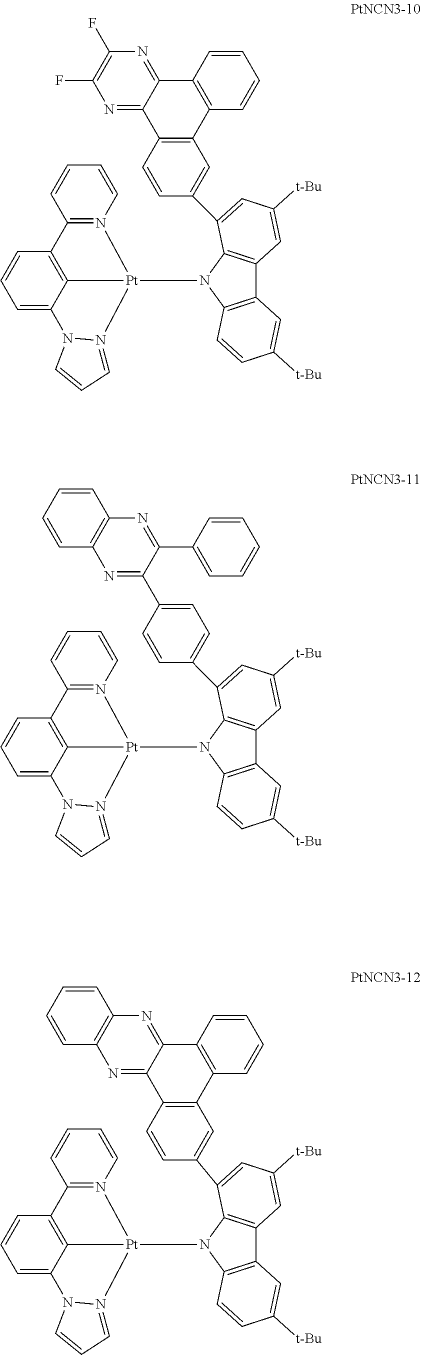

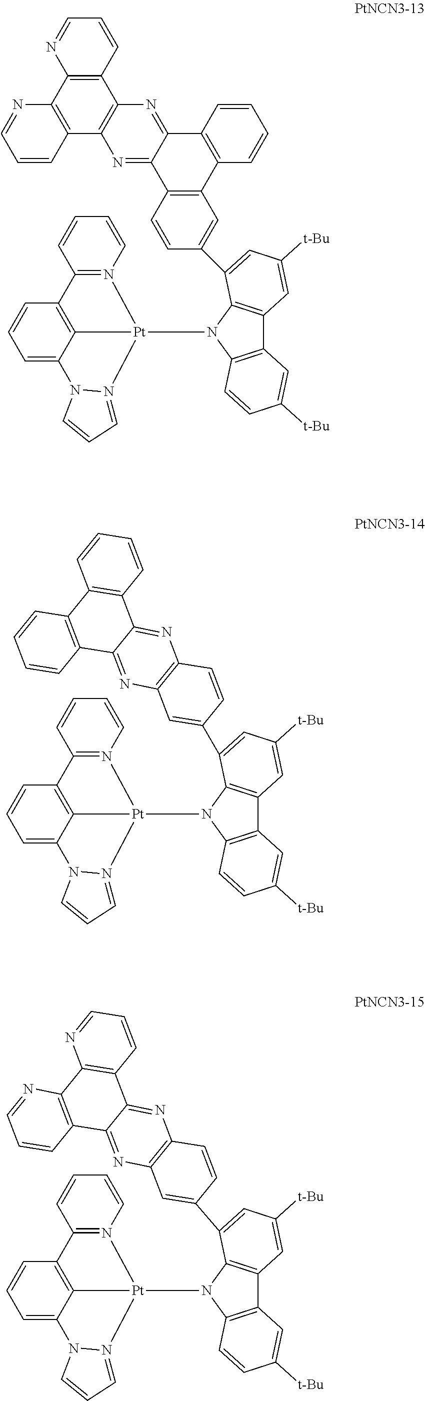

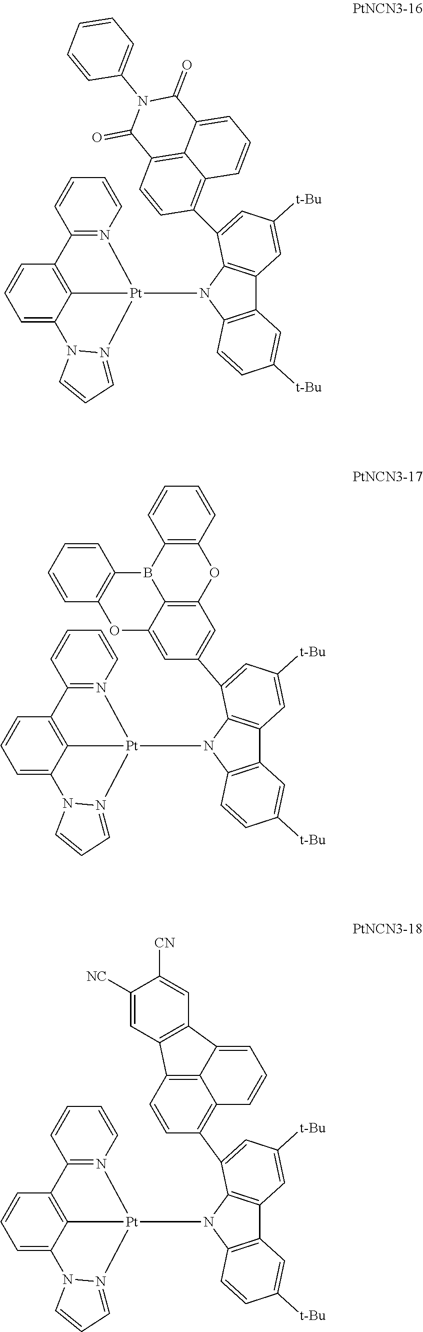

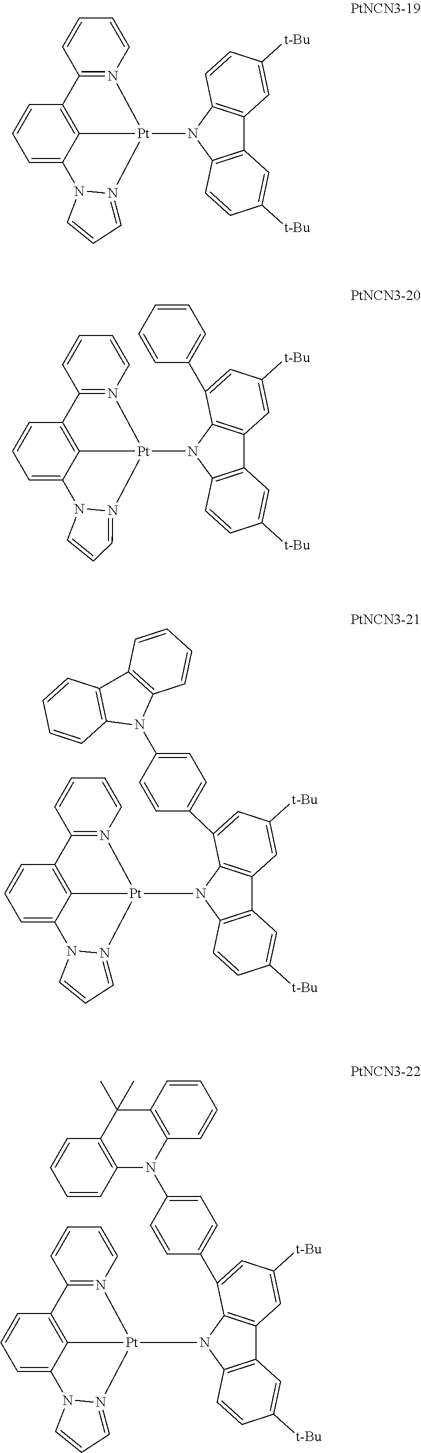

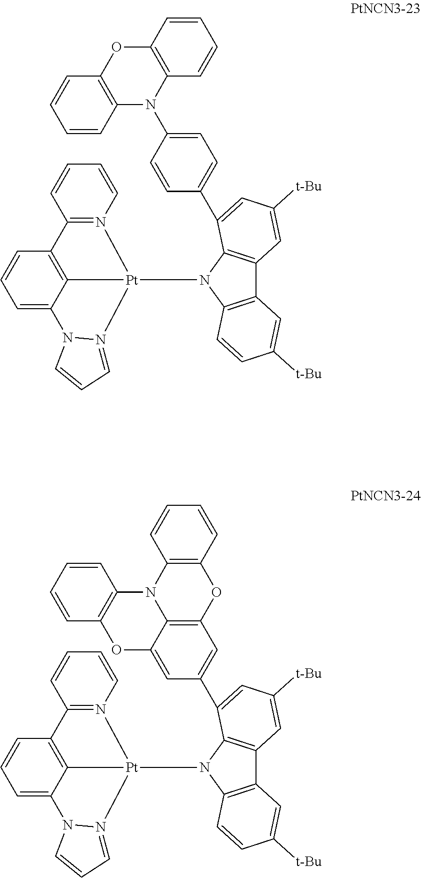

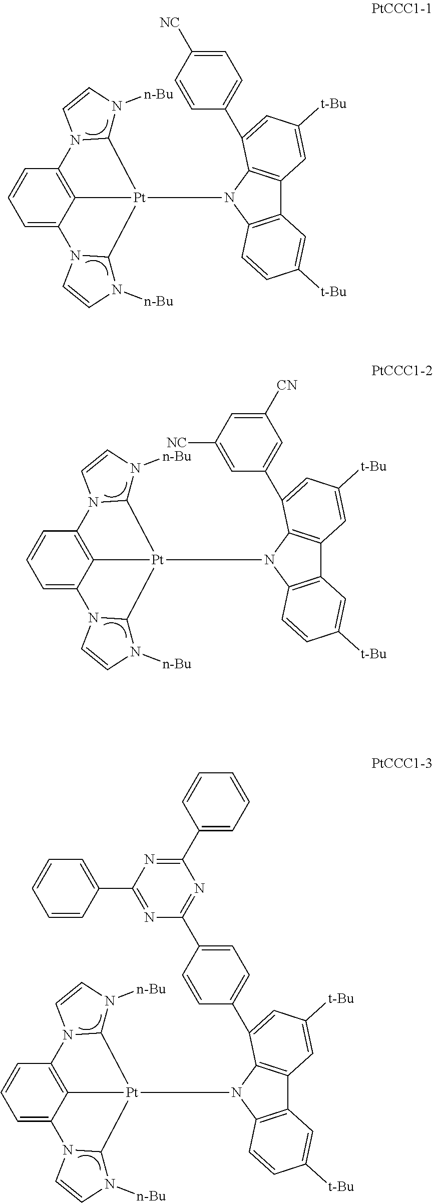

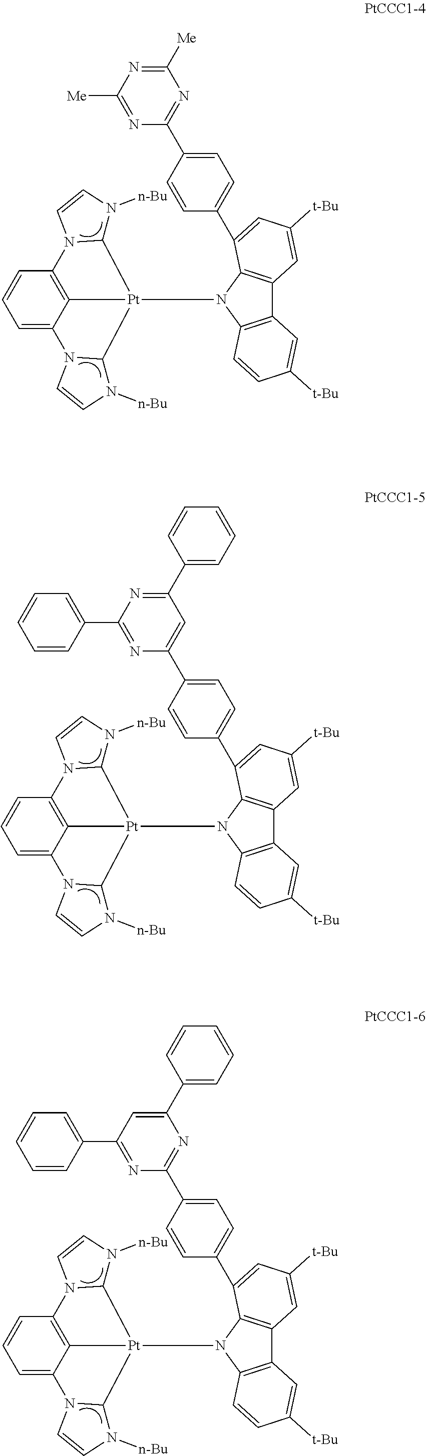

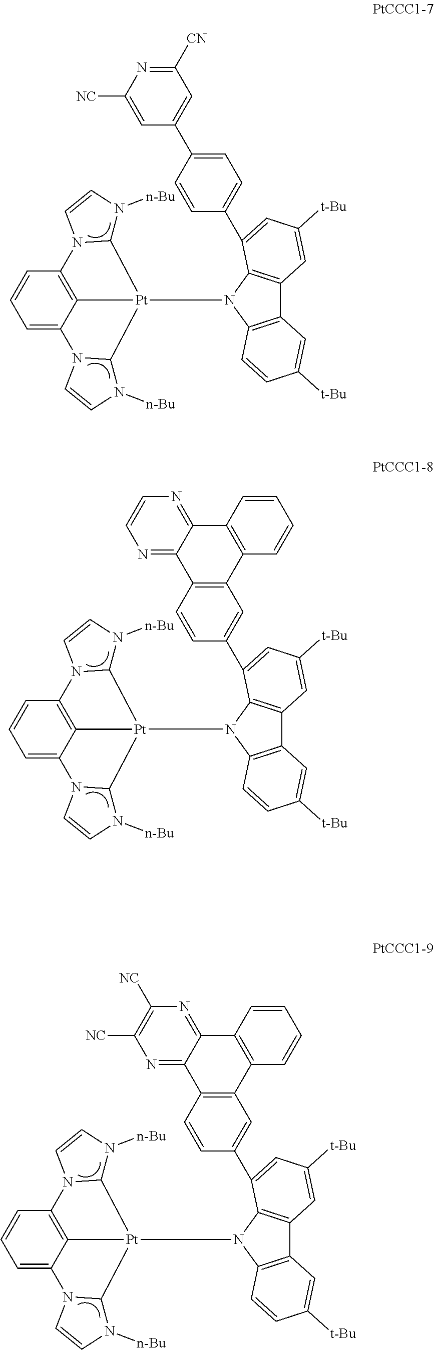

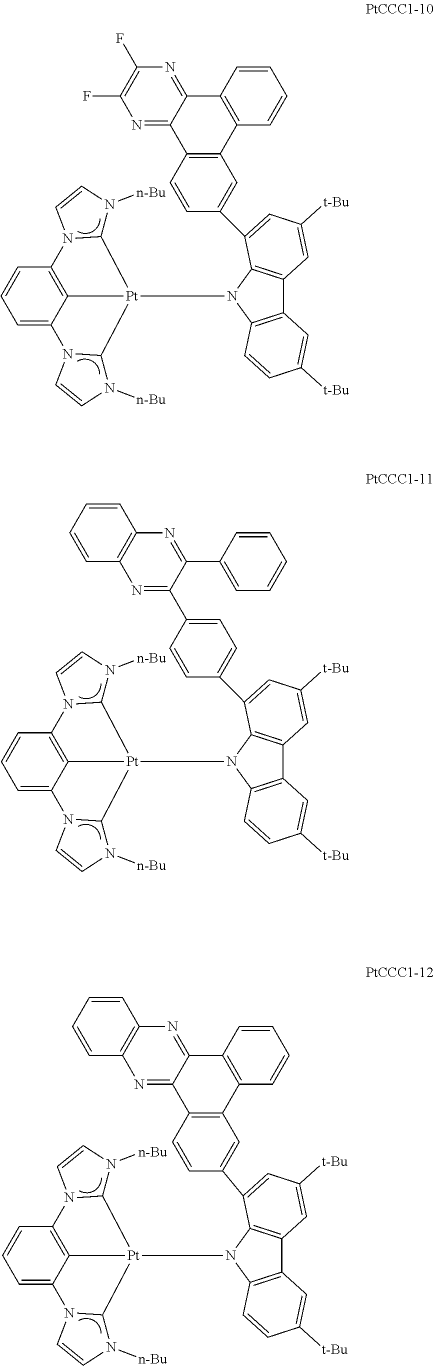

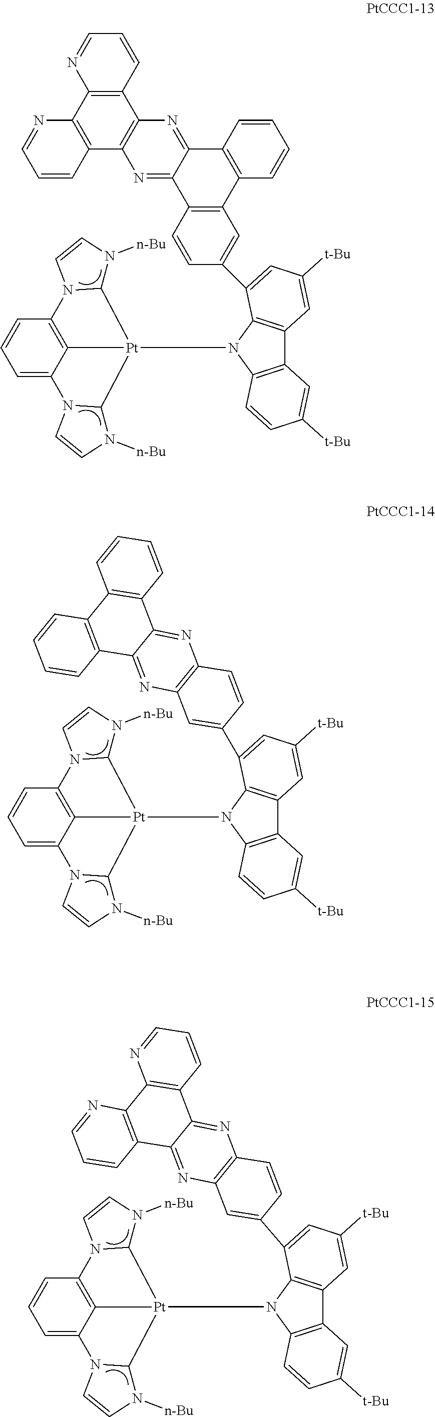

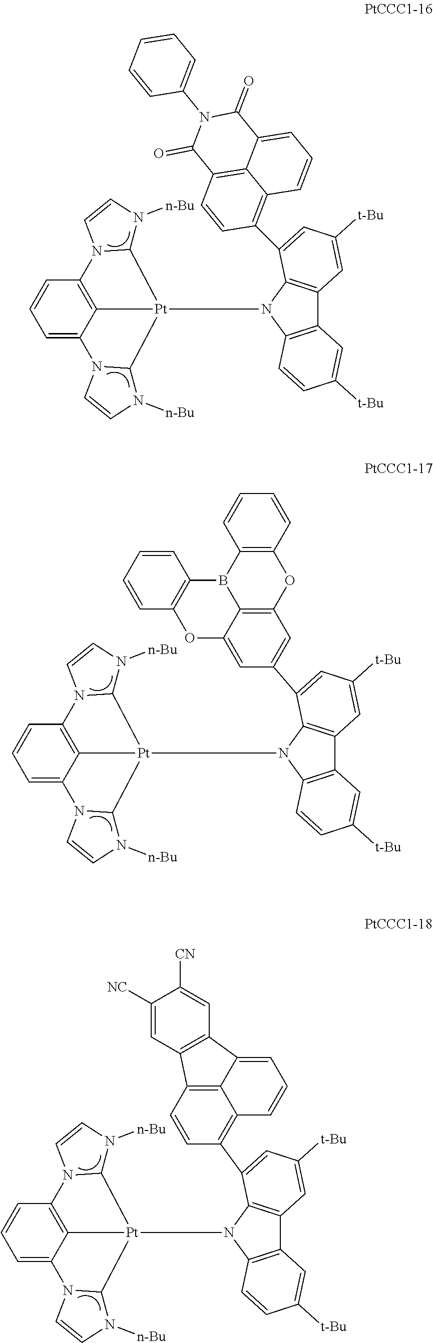

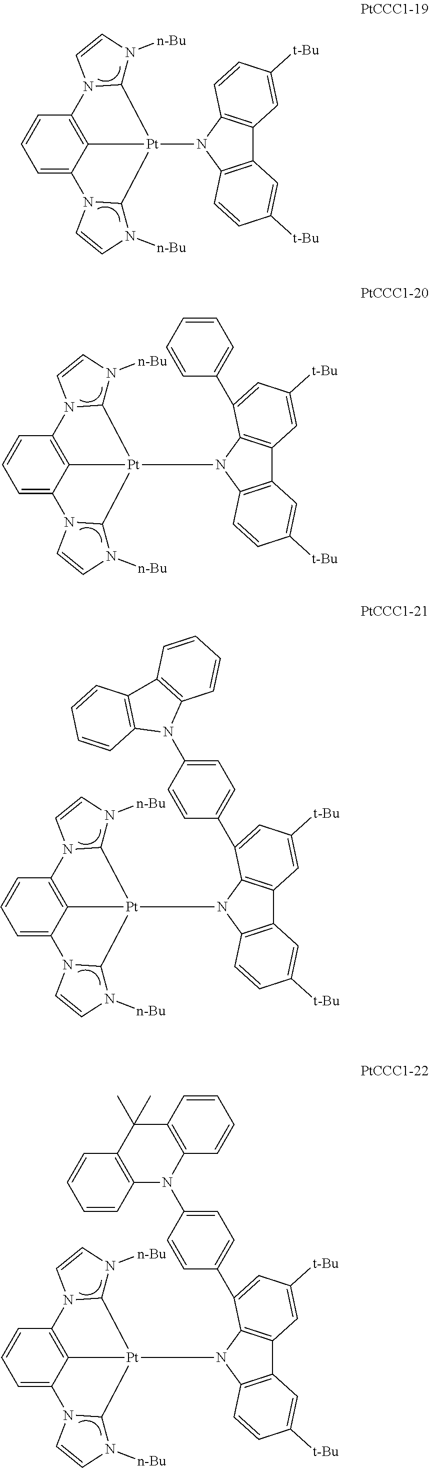

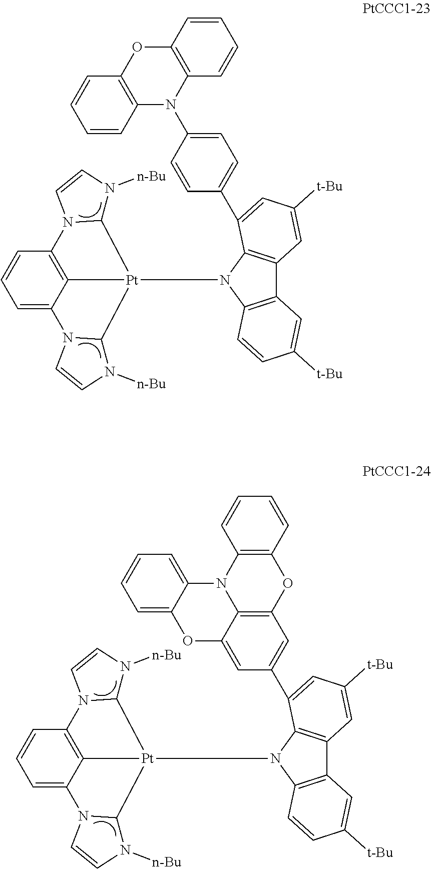

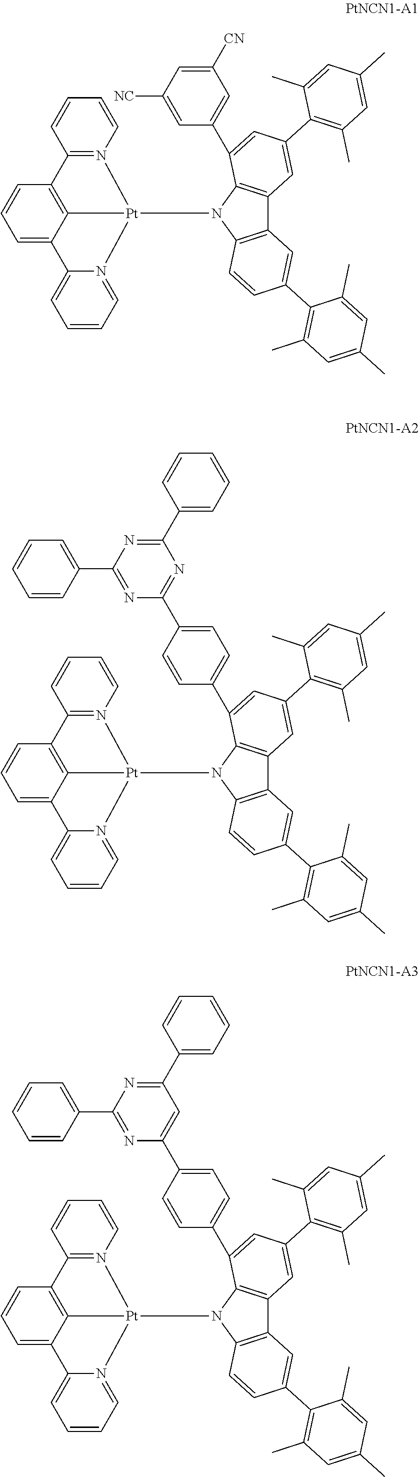

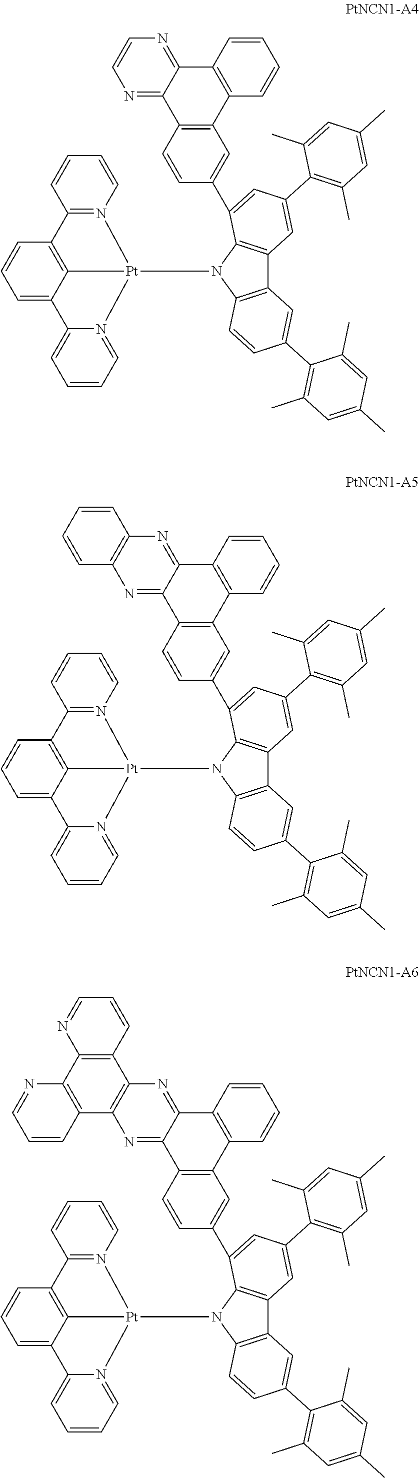

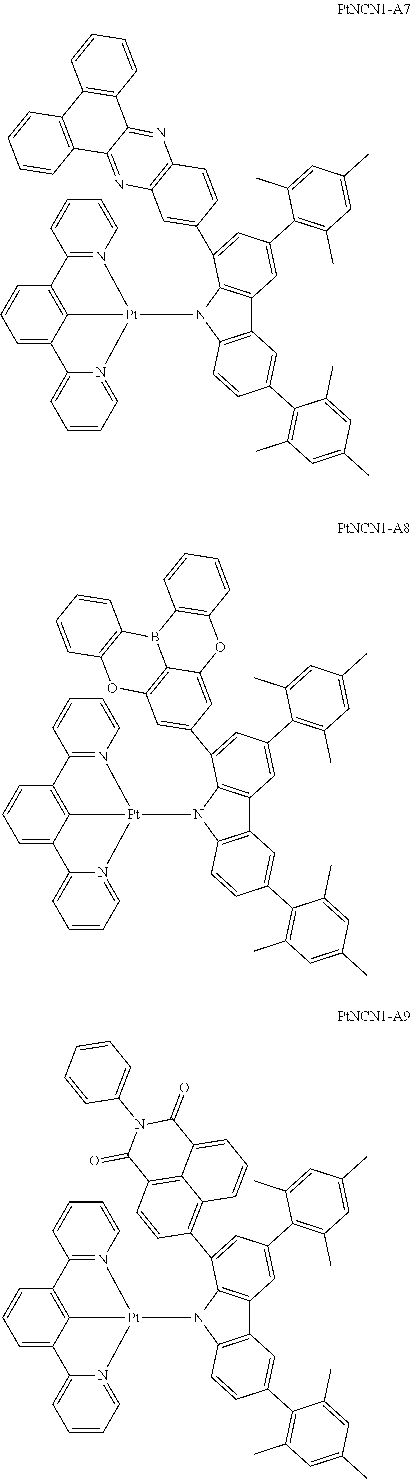

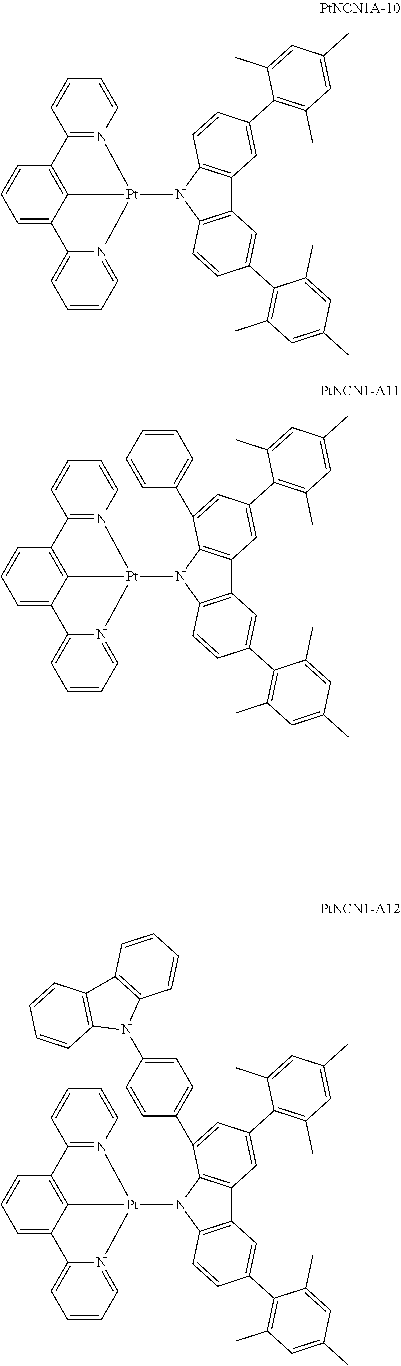

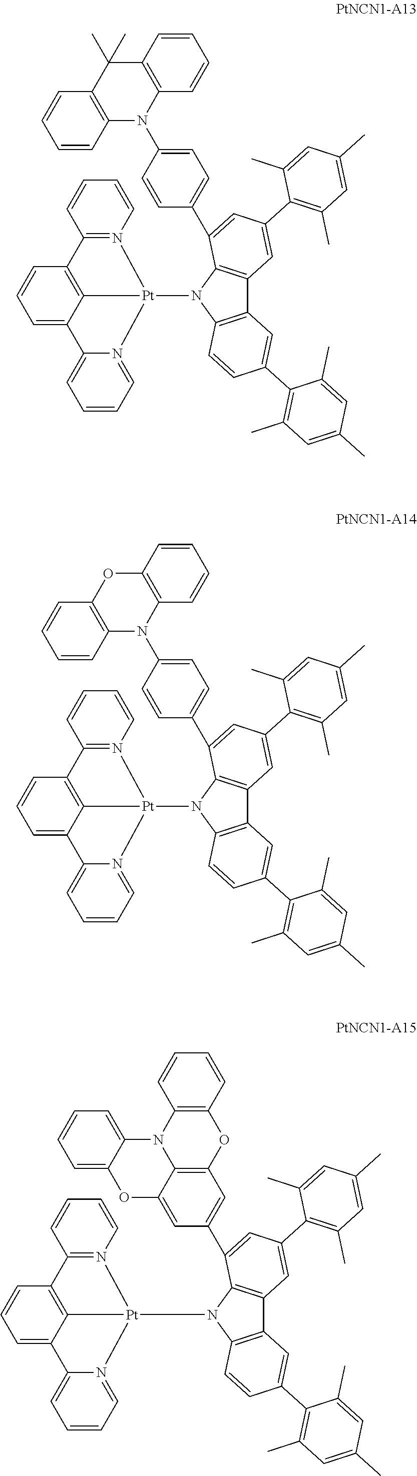

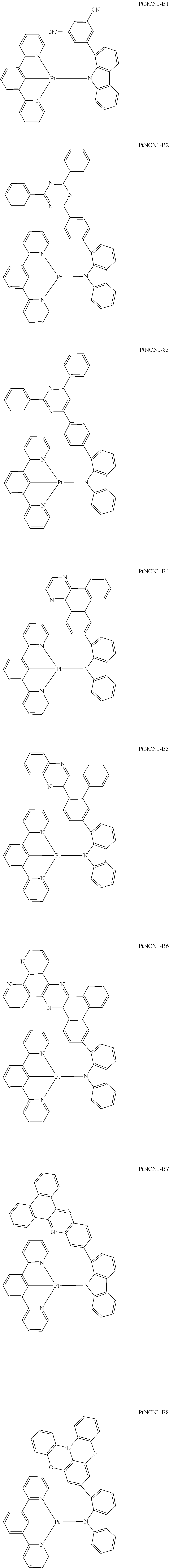

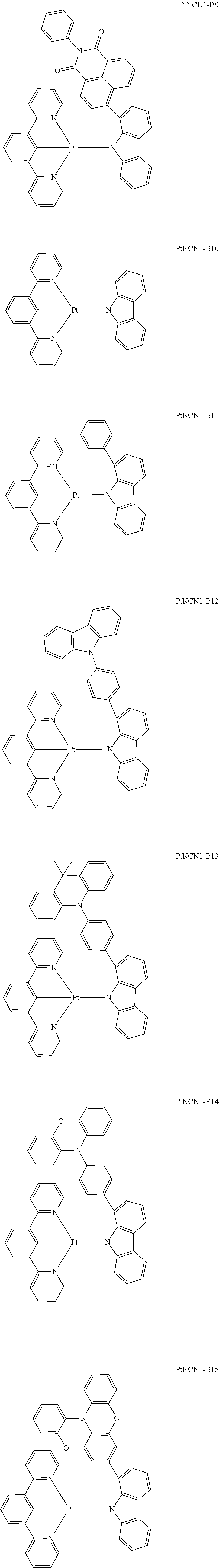

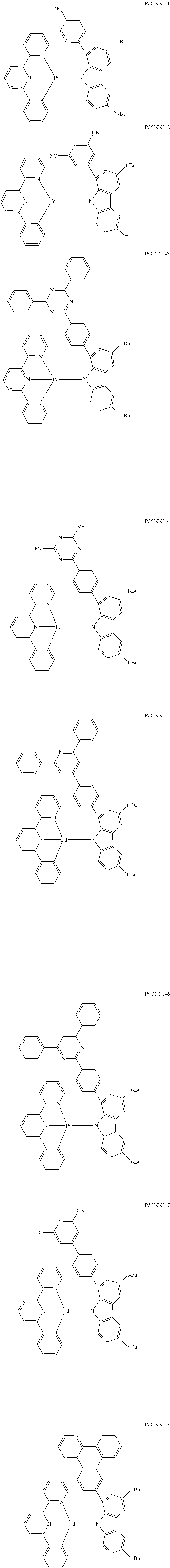

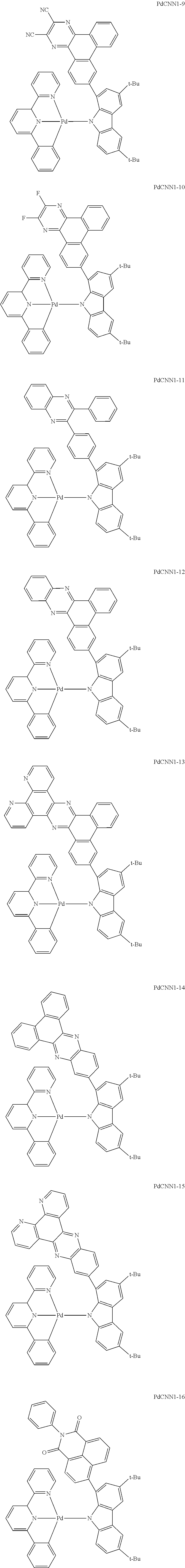

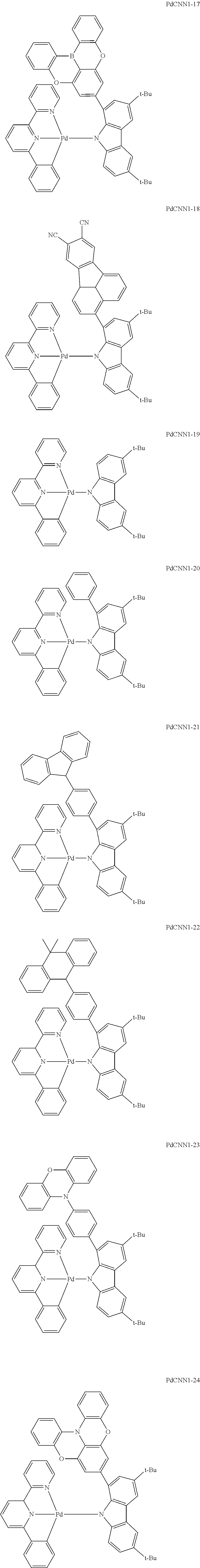

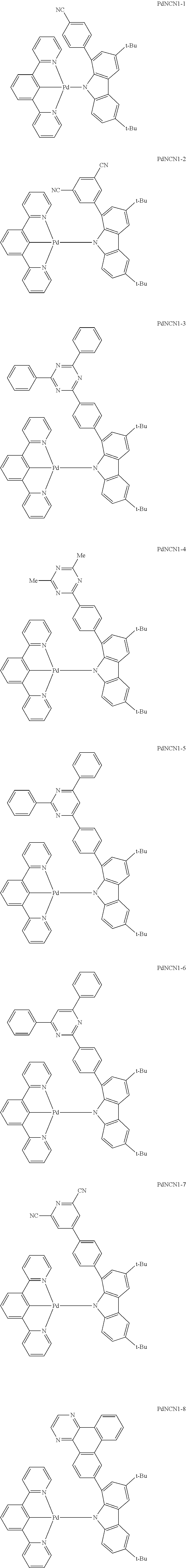

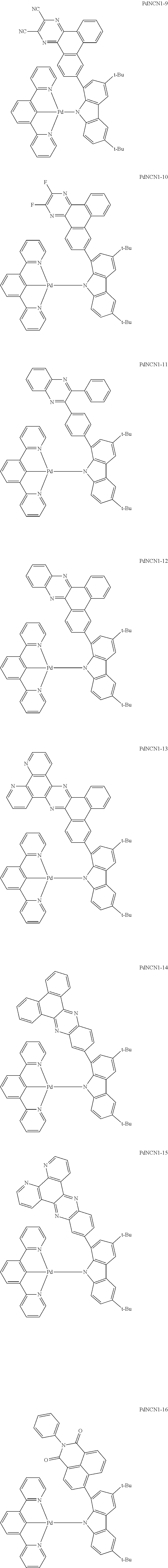

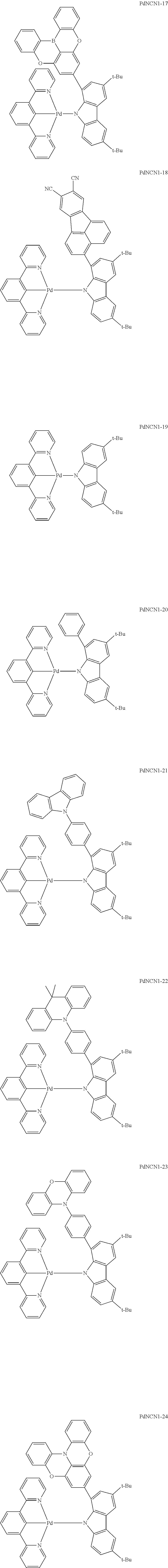

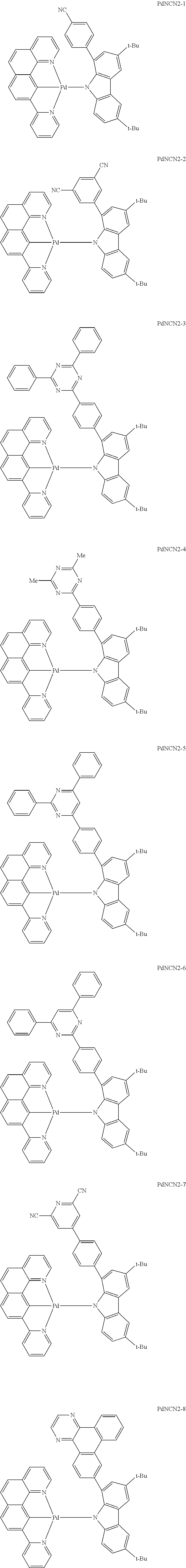

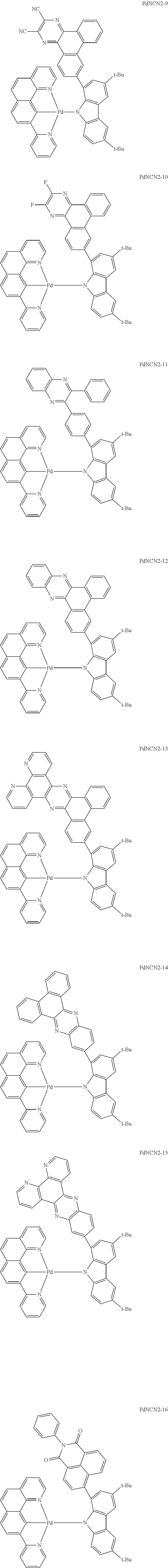

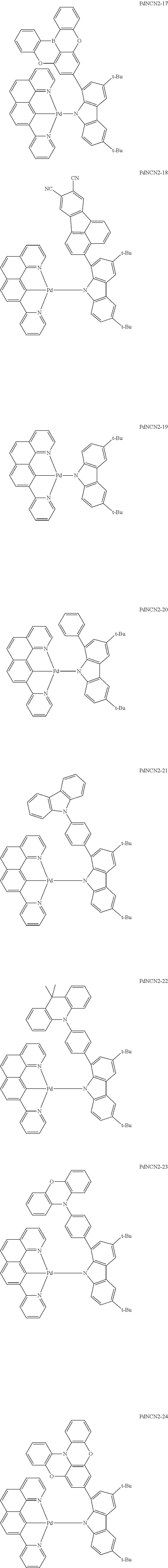

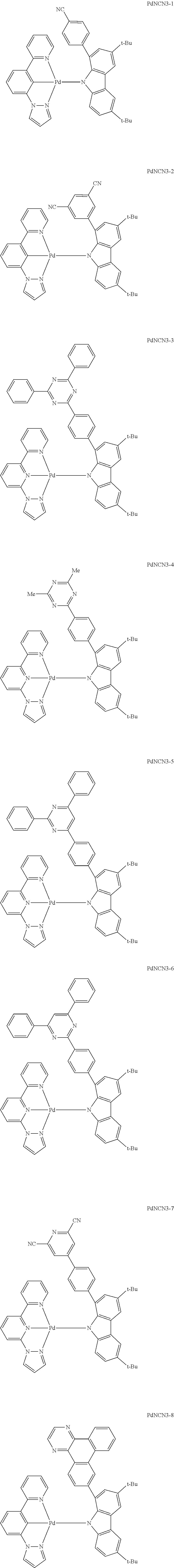

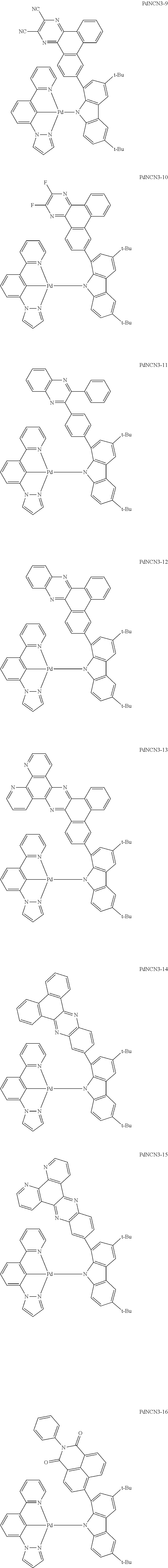

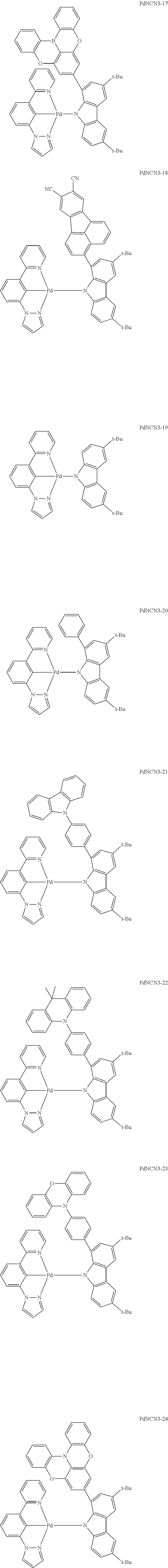

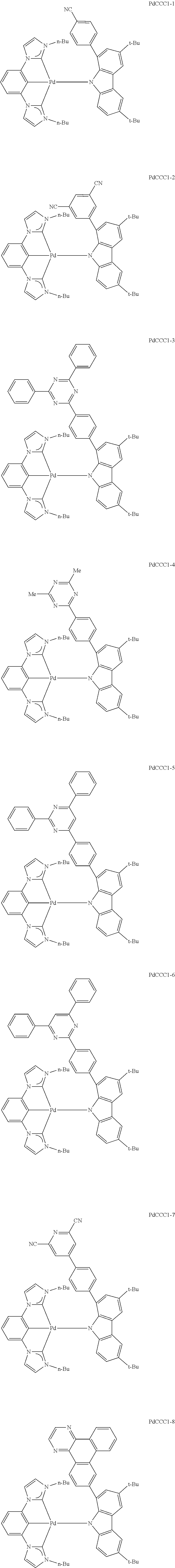

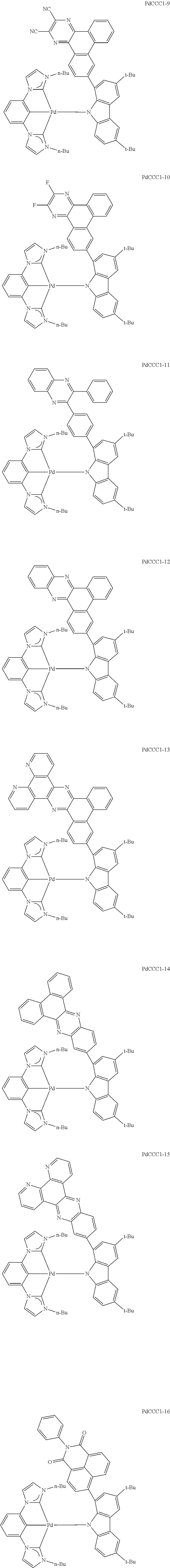

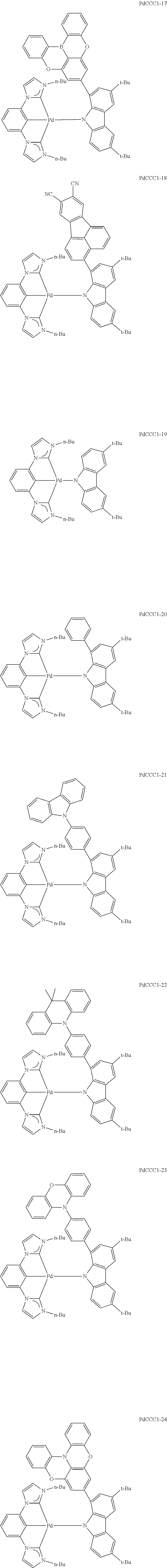

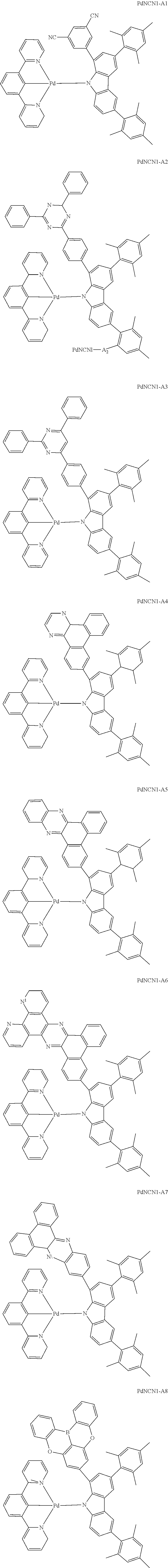

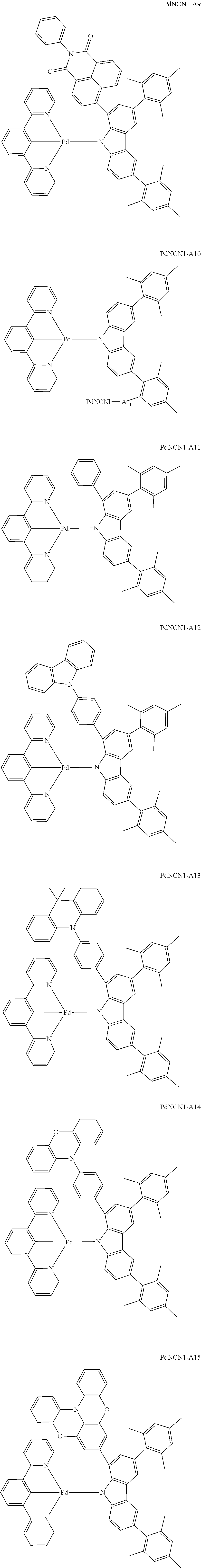

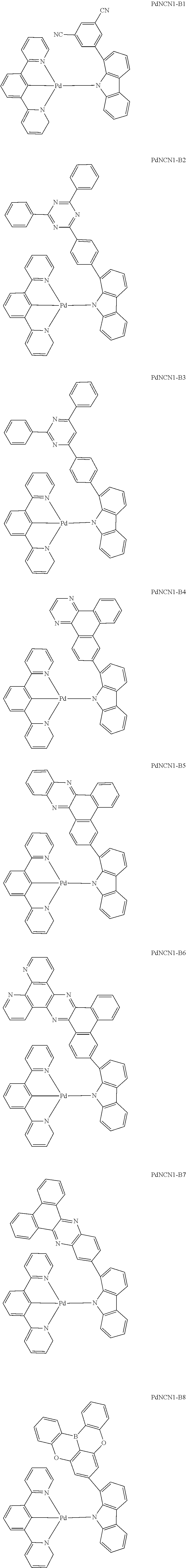

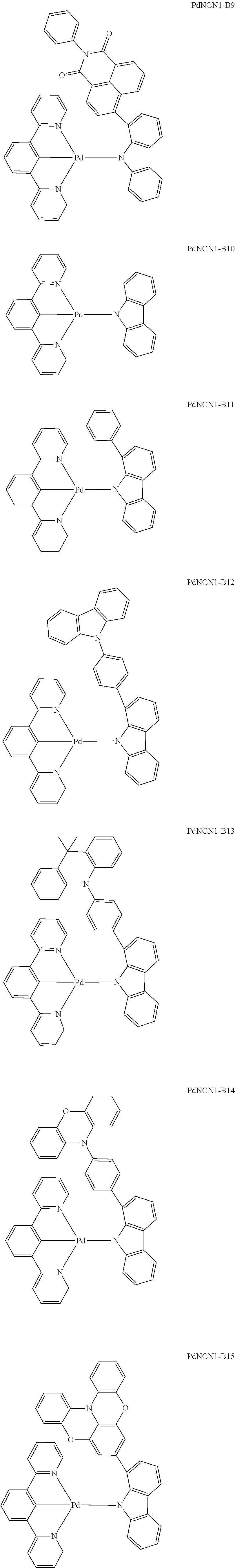

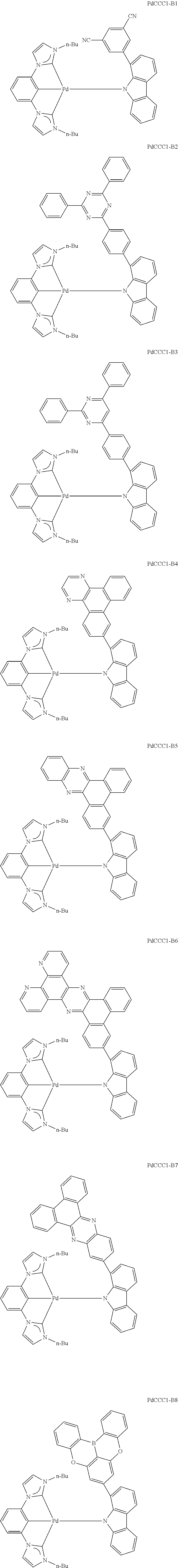

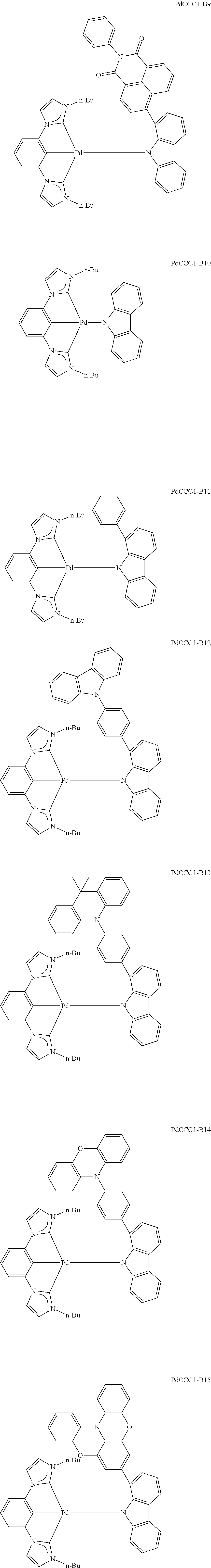

8. An organic electroluminescent device, wherein the organic electroluminescent device comprises a first electrode, a second electrode and a light-emitting layer located between the first electrode and the second electrode, and the light-emitting layer comprises any one type of or a combination of at least two types of the metal complex according to claim 1.

9. The organic electroluminescent device according to claim 8, wherein the light-emitting layer comprises the metal complex together with an organic functional material, and by mass percentage, a proportion of the metal complex is 0.01%-100%, and a proportion of the organic functional material is 0-99.9%.

10. A use of the organic electroluminescent device according to claim 8 in an electronic device.
